(19) United States
(12) Patent Application Publication
(10) Pub. No.: US 2024/0176235 A1
(43) Pub. Date: May 30, 2024

(54) RESIST COMPOSITION AND PATTERN FORMING PROCESS

(71) Applicant: Shin-Etsu Chemical Co., Ltd., Tokyo (JP)

(72) Inventors: Jun Hatakeyama, Joetsu-shi (JP); Tatsuya Yamahira, Joetsu-shi (JP); Takayuki Fujiwara, Joetsu-shi (JP); Yuki Suda, Joetsu-shi (JP)

(73) Assignee: Shin-Etsu Chemical Co., Ltd., Tokyo (JP)

(21) Appl. No.: 18/371,016

(22) Filed: Sep. 21, 2023

(30) Foreign Application Priority Data
Oct. 7, 2022 (JP) 2022-162391

(51) Int. Cl. G03F 7/004; G03F 7/038; G03F 7/039; G03F 7/20

(52) U.S. Cl. CPC G03F 7/0045; G03F 7/0048; G03F 7/0382; G03F 7/0388; G03F 7/0397; G03F 7/2004

(57) ABSTRACT

A resist composition comprising a quencher containing a sulfonium salt composed of a C₅-C₂₀ aromatic carboxylic acid anion substituted with a halogen atom or a halogen atom-containing group and a sulfonium cation having the following formula (1).

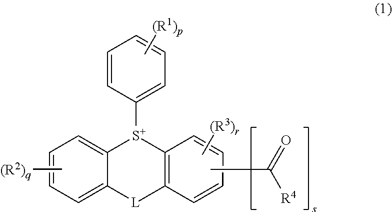

### CROSS-REFERENCE TO RELATED APPLICATIONS

This non-provisional application claims priority under 35 U.S.C. § 119(a) on Patent Application No. 2022-162391 filed in Japan on Oct. 7, 2022, the entire contents of which are hereby incorporated by reference.

### TECHNICAL FIELD

The present invention relates to a resist composition and a pattern forming process.

### BACKGROUND ART

To meet the demand for higher integration density and operating speed of LSIs, the effort to reduce the pattern rule is in rapid progress. As the use of 5G high-speed communications and artificial intelligence (AI) is widely spreading, high-performance devices are needed for their processing. As the advanced miniaturization technology, manufacturing of microelectronic devices at the 5-nm node by the lithography using extreme ultraviolet (EUV) having a wavelength of 13.5 nm has been implemented in a mass scale. Studies are made on the application of EUV lithography to 3-nm node devices of the next generation and 2-nm node devices of the next-but-one generation, and the IMEC of Belgium has expressed development of 1 nm node devices and 0.7 nm node devices.

As the feature size reduces, image blurs due to acid diffusion become a problem. To insure resolution for fine patterns with a size of 45 nm et seq., not only an improvement in dissolution contrast is important as previously reported, but the control of acid diffusion is also important as reported (Non-Patent Document 1). However, since chemically amplified resist compositions are designed such that sensitivity and contrast are enhanced by acid diffusion, an attempt to minimize acid diffusion by reducing the temperature and/or time of post exposure bake (PEB) fails, resulting in drastic reductions of sensitivity and contrast.

The triangular tradeoff relationship among sensitivity, resolution, and edge roughness (LWR) has been pointed out. A resolution improvement requires to suppress acid diffusion whereas a short acid diffusion distance leads to a decline of sensitivity.

The addition of an acid generator capable of generating a bulky acid is an effective means for suppressing acid diffusion. It has been then proposed to incorporate repeat units derived from an onium salt having a polymerizable unsaturated bond in a polymer. In this case, this polymer functions as an acid generator (polymer-bound acid generator). Patent Document 1 discloses a sulfonium or iodonium salt having a polymerizable unsaturated bond, capable of generating a specific sulfonic acid. Patent Document 2 discloses a sulfonium salt having a sulfonic acid directly attached to the backbone.

Resist compositions adapted for the EUV lithography and the ArF lithography are typically based on (meth)acrylate polymers having acid labile groups. These acid labile groups undergo deprotection reaction when a photoacid generator capable of generating a sulfonic acid which is substituted at α-position with a fluorine atom (referred to as “α-fluorinated sulfonic acid,” hereinafter) is used, but not when an acid generator capable of generating a sulfonic acid which is not substituted at α-position with a fluorine atom (referred to as “α-non-fluorinated sulfonic acid,” hereinafter) or carboxylic acid is used. When a sulfonium or iodonium salt capable of generating α-fluorinated sulfonic acid is mixed with a sulfonium or iodonium salt capable of generating α-non-fluorinated sulfonic acid, the sulfonium or iodonium salt capable of generating α-non-fluorinated sulfonic acid undergoes ion exchange with the α-fluorinated sulfonic acid. Through the ion exchange, the α-fluorinated sulfonic acid once generated upon light exposure is converted back to the sulfonium or iodonium salt. Then the sulfonium or iodonium salt of α-non-fluorinated sulfonic acid or carboxylic acid functions as a quencher. A resist composition comprising a sulfonium or iodonium salt capable of generating carboxylic acid as the quencher is disclosed (Patent Document 3).

Sulfonium salt type quenchers capable of generating carboxylic acid are known. Specifically, salicylic acid or β-hydroxycarboxylic acid (Patent Document 4), salicylic acid derivatives (Patent Documents 5 and 6), fluorosalicylic acid (Patent Document 7), a sulfonium salt of hydroxynaphthoic acid (Patent Document 8), and a sulfonium salt of thiol carboxylic acid (Patent Document 9) are known. In particular, salicylic acid has a high effect of suppressing acid diffusion by an intramolecular hydrogen bond between a carboxylic acid and a hydroxy group.

A sulfonium salt obtained by combining a carboxylic acid anion with a phenyl dibenzothiophenium cation substituted with a carbonyl group or an alkoxycarbonyl group (Patent Document 10) is known. Examples of the carboxylic acid anion include adamantane carboxylic acid or an analog thereof, salicylic acid, and fluoroalkyl carboxylic acid.

### CITATION LIST

Patent Document 1: JP-A 2006-45311
Patent Document 2: JP-A 2006-178317
Patent Document 3: JP-A 2007-114431
Patent Document 4: WO 2018/159560
Patent Document 5: JP-A 2020-203984
Patent Document 6: JP-A 2020-91404
Patent Document 7: JP-A 2020-91312
Patent Document 8: JP-A 2019-120760
Patent Document 9: JP-A 2019-74588
Patent Document 10: JP-A 2021-35937
Non-Patent Document 1: SPIE Vol. 6520 65203L-1 (2007)

### SUMMARY OF THE INVENTION

It is desired to develop a quencher capable of reducing the LWR of line patterns, improving the dimensional uniformity (CDU) of hole patterns, and increasing the sensitivity in the resist composition. To this end, it is necessary to further reduce image blurs due to acid diffusion.

It is an object of the present invention to provide a resist composition which exhibits a high sensitivity, reduced LWR, and improved CDU independent of whether it is of positive or negative tone, and a pattern forming process using the same.

The present inventors have conducted intensive studies to achieve the above object, and as a result, have found that a sulfonium salt obtained by combining a C₅-C₂₀ aromatic carboxylic acid anion substituted with a halogen atom or a halogen atom-containing group and a sulfonium cation having a specific structure such as phenyl dibenzothiophenium cation having a hydrocarbylcarbonyl group or a hydrocarbyloxycarbonyl group is a quencher for suppressing acid diffusion, the halogen atom in the molecule of the anion increases the absorption of EUV light to reduce shot noise, thereby improving physical contrast, and aggregation of quenchers can be prevented by electrical repulsion due to negative charge of the halogen atom. The phenyl dibenzothiophenium cation having a hydrocarbylcarbonyl group or a hydrocarbyloxycarbonyl group as an electron withdrawing group has high decomposition efficiency in exposure and a high effect of suppressing acid diffusion. The present inventors have found that by using the sulfonium salt, a resist composition which exhibits a high sensitivity, reduced LWR, improved CDU, high resolution, and wide process margin can be obtained, thereby completing the present invention.

That is, the present invention provides the following resist composition and pattern forming process.
1. A resist composition comprising a quencher containing a sulfonium salt composed of a C₅-C₂₀ aromatic carboxylic acid anion substituted with a halogen atom or a halogen atom-containing group and a sulfonium cation having the following formula (1):

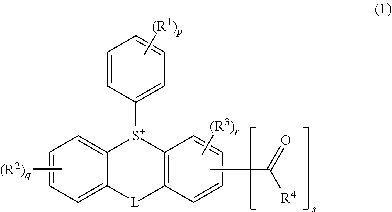

wherein p, q, and r are each independently an integer of 0 to 3, s is 1 or 2, provided that 1≤r+s≤3,
R¹ and R² are each independently a halogen atom, a trifluoromethyl group, a trifluoromethoxy group, a trifluoromethylthio group, a nitro group, a cyano group, —C(═O)—R⁴, —O—C(═O)—R⁵, or —O—R^{5.}
R³ is a halogen atom, a trifluoromethyl group, a trifluoromethoxy group, a trifluoromethylthio group, a nitro group, a cyan group, —O—C(═O)—R⁵, or —O—R⁵,
R⁴ is a C₁-C₁₀ hydrocarbyl group, a C₁-C₁₀ hydrocarbyloxy group, or —O—R^{4A}, the hydrocarbyl group and hydrocarbyloxy group may be substituted with a fluorine atom or a hydroxy group, R^{4A} is an acid labile group,
R⁵ is a C₁-C₁₀ hydrocarbyl group,
L is a single bond, an ether bond, a carbonyl group, —N(R)—, a sulfide bond, or a sulfonyl group, and R is a hydrogen atom or a C₁-C₆ saturated hydrocarbyl group.
2. The resist composition according to 1, wherein the C₅-C₂₀ aromatic carboxylic acid anion substituted with a halogen atom or a halogen atom-containing group has the following formula (2):

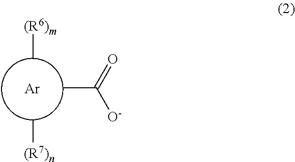

wherein in is an integer of 1 to 5, n is an integer of 0 to 4,
circle Ar is a group derived from benzene, naphthalene, or thiophene,
R⁶ is a halogen atom, —R^{6A}, —O—R^{6A}, —S—R^{6A}, —C(═O)—O—R^{6A}, —O—C(═O)—R^{6A}, —O—C(═O)—O—R^{6A}, —N(R^{6B})—S(═O)₂R^{6A}, —O—S(═O)₂—R^{6A}, or a halogenated phenyl group, R^{6A} is a C₁-C₄ halogenated alkyl group, R^{6B} is a C₁-C₆ saturated hydrocarbyl group,
R⁷ is a hydroxy group, a cyano group, a nitro group, an amino group, a mercapto group, —R^{7A}, —O—R^{7A}, —O—C(═O)—R^{7A}, —O—C(═O)—O—R^{7A}, or —N(R^{7B})—C(═O)—R^{7C}, R^{7A} is a C₁-C₁₆ hydrocarbyl group. R^{7B} is a hydrogen atom or a C₁-C₆ saturated hydrocarbyl group, and R^{7C} is a C₁-C₁₆ aliphatic hydrocarbyl group, a C₆-C₁₄ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group.
3. The resist composition according to 1 or 2, further comprising a base polymer.
4. The resist composition according to 3, wherein the base polymer comprises repeat units having the following formula (a1) or repeat units having the following formula (a2):

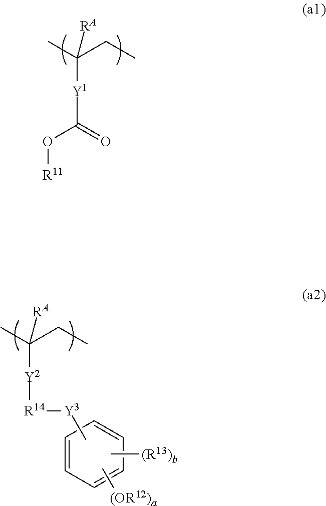

wherein R^{A} is each independently a hydrogen atom or a methyl group,
Y¹ is a single bond, a phenylene group, a naphthylene group, or a C₁-C₁₂ linking group containing at least one selected from an ester bond and a lactone ring,
Y² is a single bond or an ester bond,
Y³ is a single bond, an ether bond, or an ester bond,
R¹¹ and R¹² are each independently an acid labile group,
R¹³ is a fluorine atom, a trifluoromethyl group, a cyano group, or a C₁-C₆ saturated hydrocarbyl group,
R¹⁴ is a single bond or a C₁-C₆ alkanediyl group in which some of carbon atoms may be replaced by an ether bond or an ester bond,
a is 1 or 2, and b is an integer of 0 to 4, provided that 1≤a+b≤5.
5. The resist composition according to 4, which is a chemically amplified positive resist composition.
6. The resist composition according to 3, wherein the base polymer is free of an acid labile group.
7. The resist composition according to 6, which is a chemically amplified negative resist composition.
8. The resist composition according to any one of 3 to 7, wherein the base polymer comprises at least one selected from repeat units having the following formulae (f1) to (f3):

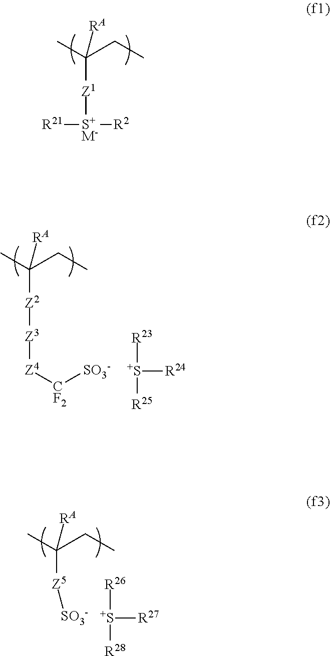

wherein R^{A} is each independently a hydrogen atom or a methyl group,
Z¹ is a single bond, a C₁-C₆ aliphatic hydrocarbylene group, a phenylene group, a naphthylene group, or a C₇-C₁₈ group obtained by combining the foregoing, or —O—Z¹¹—, —C(═O)—O—Z¹¹—, or —C(═O)—NH—Z¹¹—, Z¹¹ is a C₁-C₆ aliphatic hydrocarbylene group, a phenylene group, a naphthylene group, or a C₇-C₁₈ group obtained by combining the foregoing, which may contain a carbonyl group, an ester bond, an ether bond, or a hydroxy group,
Z² is a single bond or an ester bond,
Z³ is a single bond, —Z³¹—C(═O)—O—, —Z³¹—O—, or —Z³¹—O—C(═O)—, Z³¹ is a C₁-C₁₂ aliphatic hydrocarbylene group, a phenylene group, or a C₇-C₁₈ group obtained by combining the foregoing, which may contain a carbonyl group, an ester bond, an ether bond, a urethane bond, a nitro group, a cyano group, a fluorine atom, an iodine atom, or a bromine atom,
Z⁴ is a methylene group, a 2,2,2-trifluoro-1,1-ethanediyl group, or a carbonyl group,
Z⁵ is a single bond, a methylene group, an ethylene group, a phenylene group, a fluorinated phenylene group, a trifluoromethyl-substituted phenylene group, —O—Z⁵¹—, —C(═O)—O—Z⁵¹—, or —C(═O)NH—Z⁵¹—, Z⁵¹ is a C₁-C₆ aliphatic hydrocarbylene group, a phenylene group, a fluorinated phenylene group, or a trifluoromethyl-substituted phenylene group, which may contain a carbonyl group, an ester bond, an ether bond, a halogen atom, or a hydroxy group,
R²¹ to R²⁸ are each independently a halogen atom, or a C₁-C₂₀ hydrocarbyl group which may contain a heteroatom, a pair of R²³ and R²⁴ or R²⁶ and R²⁷ may bond together to form a ring with a sulfur atom to which they are attached, and
M⁻is a non-nucleophilic counter ion.
9. The resist composition according to any one of 1 to 8, further comprising an acid generator capable of generating a strong acid.
10. The resist composition according to 9, wherein the acid generator generates a sulfonic acid, imide acid, or methide acid.
11. The resist composition according to any one of 1 to 10, further comprising an organic solvent.
12. The resist composition according to any one of 1 to 11, further comprising a surfactant.
13. A pattern forming process comprising the steps of:
applying the resist composition according to any one of 1 to 12 onto a substrate to form a resist film on the substrate:
exposing the resist film to high-energy radiation; and
developing the exposed resist film in a developer.
14. The pattern forming process according to 13, wherein the high-energy radiation is KrF excimer laser light, ArF excimer laser light, an electron beam (EB), or EUV having a wavelength of 3 to 15 nm.

### Advantageous Effects of the Invention

The sulfonium salt composed of a C₅-C₂₀ aromatic carboxylic acid anion substituted with a halogen atom or a halogen atom-containing group and a sulfonium cation having formula (1) is a quencher capable of suppressing acid diffusion. As a result, a resist composition comprising the sulfonium salt is successful in restraining acid diffusion performance and improving LWR and CDU. This makes it possible to construct a resist composition having reduced LWR and improved CDU.

### DETAILED DESCRIPTION OF THE INVENTION

Resist Composition

A resist composition of the present invention comprises a quencher of a sulfonium salt composed of a C₅-C₂₀ aromatic carboxylic acid anion substituted with a halogen atom or a halogen atom-containing group and a sulfonium cation of a specific structure having a hydrocarbylcarbonyl group or a hydrocarbyloxycarbonyl group.

Quencher

The sulfonium cation has the following formula (1).

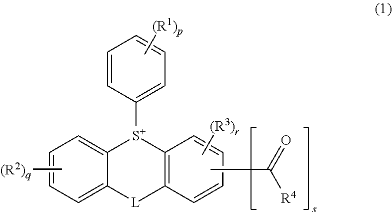

In formula (1), p, q, and r are each independently an integer of 0 to 3, s is 1 or 2. Provided that 1≤r+s≤3.

In formula (1), R¹ and R² are each independently a halogen atom, a trifluoromethyl group, a trifluoromethoxy group, a trifluoromethylthio group, a nitro group, a cyano group, —C(═O)—R⁴, —O—C(═O)—R⁵, or —O—R^{5.}

In formula (1), R³ is a halogen atom, a trifluoromethyl group, a trifluoromethoxy group, a trifluoromethylthio group, a nitro group, a cyano group, —O—C(═O)—R⁵ or —O—R^{5.}

In formula (1), R⁴ is a C₁-C₁₀ hydrocarbyl group, a C₁-C₁₀ hydrocarbyloxy group, or —O—R^{4A}, and the hydrocarbyl group and hydrocarbyloxy group may be substituted with a fluorine atom or a hydroxy group. R^{4A} is an acid labile group.

In formula (1), R⁵ is a C₁-C₁₀ hydrocarbyl group.

The hydrocarbyl moiety of the hydrocarbyl group represented by R⁴ and R⁵ and the hydrocarbyloxy group represented by R⁴ may be saturated or unsaturated and straight, branched, or cyclic. Specific examples thereof include C₁-C₁₀ alkyl groups such as a methyl group, an ethyl group, a n-propyl group, an isopropyl group, a n-butyl group, an isobutyl group, a sec-butyl group, a tert-butyl group, n-pentyl group, an isopentyl group, a sec-pentyl group, a 3-pentyl group, a tert-pentyl group, a neopentyl group, a n-hexyl group, a n-octyl group, a n-nonyl group, and a n-decyl group; C₃-C₁₀ cyclic saturated hydrocarbyl groups such as a cyclopropyl group, a cyclobutyl group, a cyclopentyl group, a cyclohexyl group, an adamantyl group, a norbornyl group, a cyclopropylmethyl group, a cyclopropylethyl group, a cyclobutylmethyl group, a cyclobutylethyl group, a cyclopentylmethyl group, a cyclopentylethyl group, a cyclohexylmethyl group, a cyclohexylethyl group, a methylcyclopropyl group, a methylcyclobutyl group, a methylcyclopentyl group, a methylcyclohexyl group, an ethylcyclopropyl group, an ethylcyclobutyl group, an ethylcyclopentyl group, and an ethylcyclohexyl group; C₂-C₁₀ alkenyl groups such as a vinyl group, a 1-propenyl group, a 2-propenyl group, a butenyl group, a pentenyl group, a hexenyl group, a heptenyl group, a nonenyl group, and a decenyl group; C₂-C₁₀ alkynyl groups such as an ethynyl group, a propynyl group, a butynyl group, a pentynyl group, a hexynyl group, a heptynyl group, an octynyl group, a nonynyl group, and a decenyl group; C₃-C₁₀ cyclic unsaturated aliphatic hydrocarbyl groups such as a cyclopentenyl group, a cyclohexenyl group, a methylcyclopentenyl group, a methylcyclohexenyl group, an ethylcyclopentenyl group, an ethylcyclohexenyl group, and a norbornenyl group; C₆-C₁₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, and a naphthyl group; C₇-C₁₀ amyl groups such as a benzyl group, a phenethyl group, a phenylpropyl group, and a phenylbutyl group; and groups obtained by combining these.

Examples of the acid labile group represented by R^{4A} include acid labile groups having formulae (AL-1) to (AL-3) described below.

In formula (1), L is a single bond, an ether bond, a carbonyl group, —N(R)—, a sulfide bond, or a sulfonyl group. R is a hydrogen atom or a C₁-C₆ saturated hydrocarbyl group.

Examples of the sulfonium cation having formula (1) are derived are shown below, but not limited thereto.

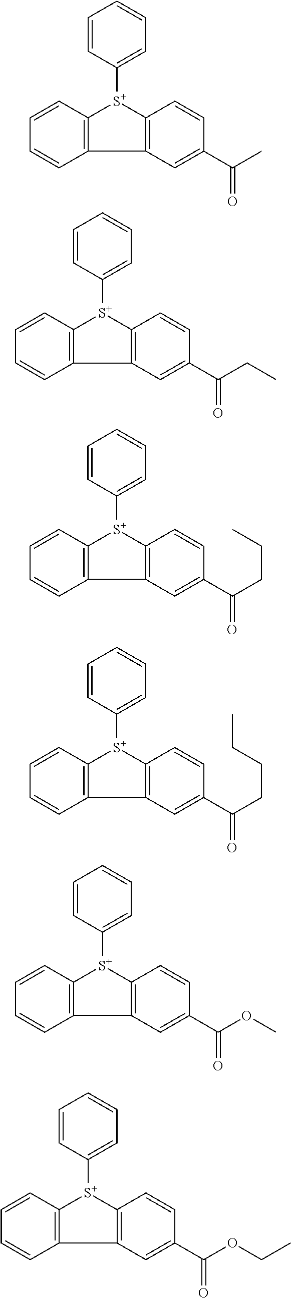 [SMILES: CC(=O)c1ccc2c(c1)c1ccccc1[s+]2-c1ccccc1 ; CCC(=O)c1ccc2c(c1)c1ccccc1[s+]2-c1ccccc1 ; CCCC(=O)c1ccc2c(c1)c1ccccc1[s+]2-c1ccccc1 ; CCCCC(=O)c1ccc2c(c1)c1ccccc1[s+]2-c1ccccc1 ; COC(=O)c1ccc2c(c1)c1ccccc1[s+]2-c1ccccc1 ; CCOC(=O)c1ccc2c(c1)c1ccccc1[s+]2-c1ccccc1]

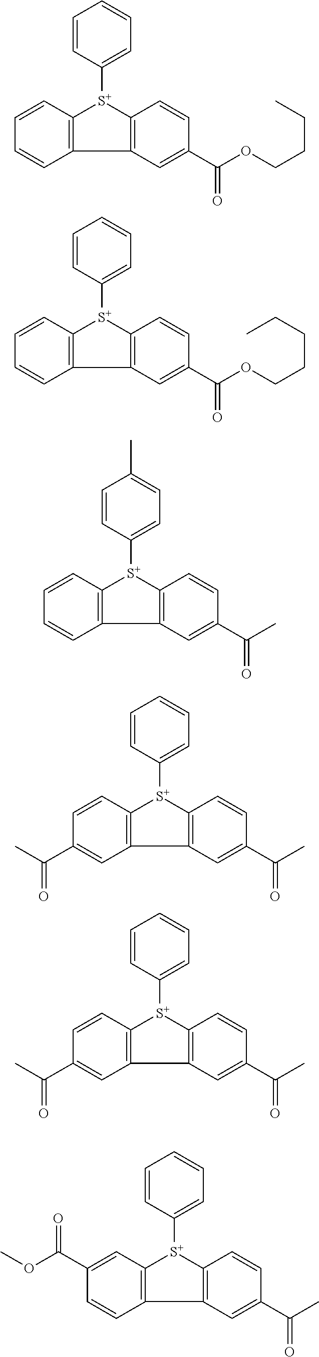

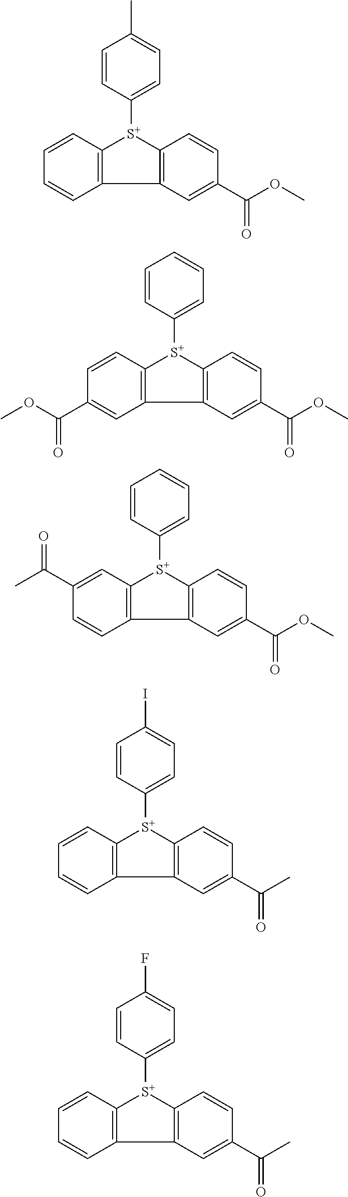

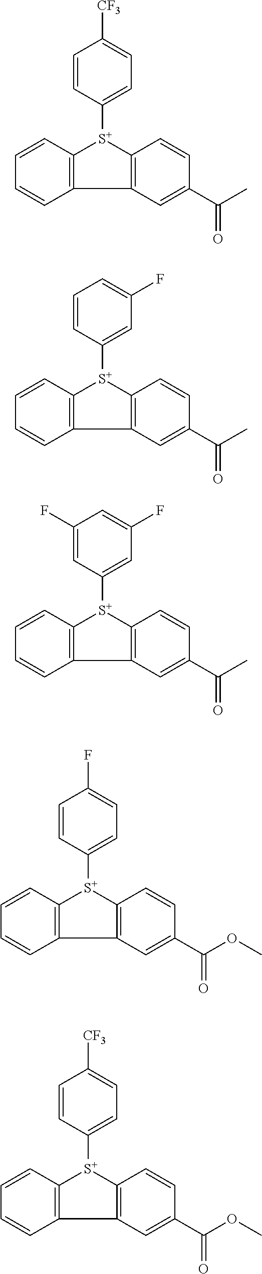 [SMILES: CC(=O)c1ccc2c(c1)c1ccccc1[s+]2-c1ccc(C(F)(F)F)cc1 ; CC(=O)c1ccc2c(c1)c1ccccc1[s+]2-c1cccc(F)c1 ; CC(=O)c1ccc2c(c1)c1ccccc1[s+]2-c1cc(F)cc(F)c1 ; COC(=O)c1ccc2c(c1)c1ccccc1[s+]2-c1ccc(F)cc1 ; COC(=O)c1ccc2c(c1)c1ccccc1[s+]2-c1ccc(C(F)(F)F)cc1]

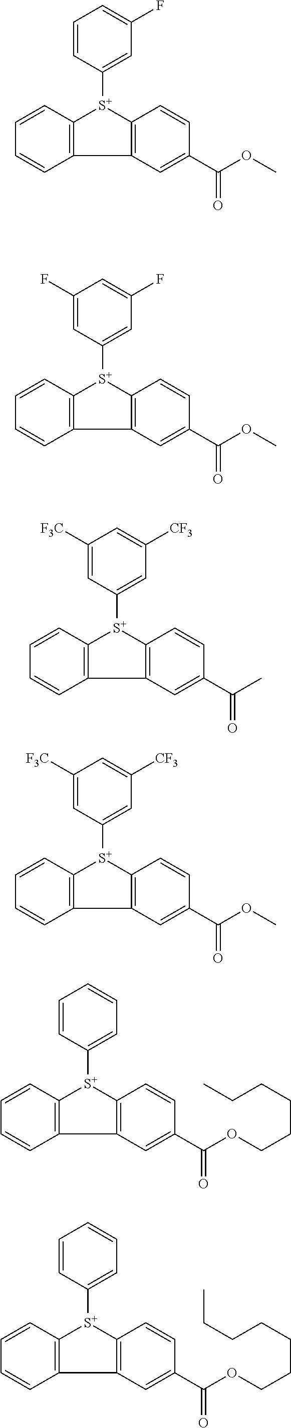 [SMILES: COC(=O)c1ccc2c(c1)c1ccccc1[s+]2-c1cccc(F)c1 ; COC(=O)c1ccc2c(c1)c1ccccc1[s+]2-c1cc(F)cc(F)c1 ; CC(=O)c1ccc2c(c1)c1ccccc1[s+]2-c1cc(C(F)(F)F)cc(C(F)(F)F)c1 ; COC(=O)c1ccc2c(c1)c1ccccc1[s+]2-c1cc(C(F)(F)F)cc(C(F)(F)F)c1 ; CCCCCCOC(=O)c1ccc2c(c1)c1ccccc1[s+]2-c1ccccc1 ; CCCCCCCOC(=O)c1ccc2c(c1)c1ccccc1[s+]2-c1ccccc1]

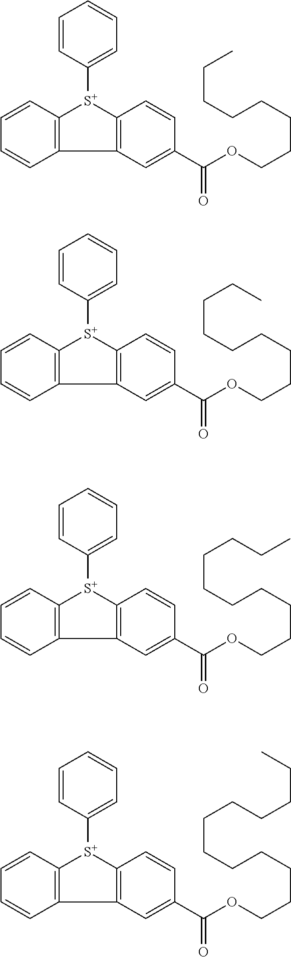 [SMILES: CCCCCCCCOC(=O)c1ccc2c(c1)c1ccccc1[s+]2-c1ccccc1 ; CCCCCCCCCOC(=O)c1ccc2c(c1)c1ccccc1[s+]2-c1ccccc1 ; CCCCCCCCCCOC(=O)c1ccc2c(c1)c1ccccc1[s+]2-c1ccccc1 ; CCCCCCCCCCCCOC(=O)c1ccc2c(c1)c1ccccc1[s+]2-c1ccccc1]

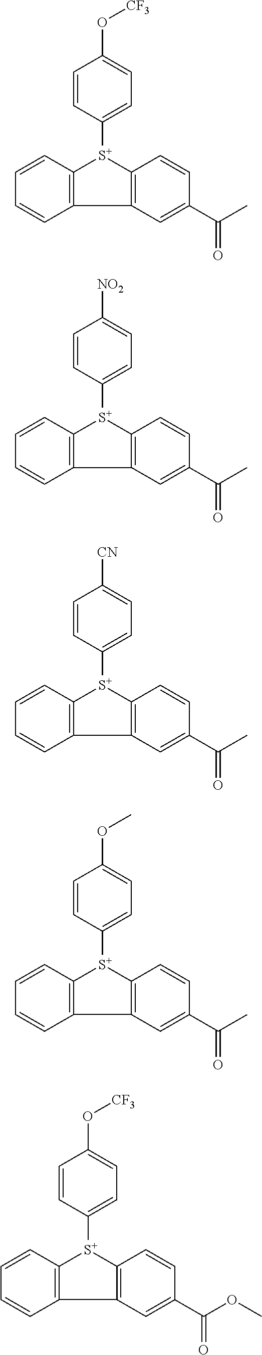 [SMILES: CC(=O)c1ccc2c(c1)c1ccccc1[s+]2-c1ccc(OC(F)(F)F)cc1 ; CC(=O)c1ccc2c(c1)c1ccccc1[s+]2-c1ccc([N+](=O)[O-])cc1 ; CC(=O)c1ccc2c(c1)c1ccccc1[s+]2-c1ccc(C#N)cc1 ; COc1ccc(-[s+]2c3ccccc3c3cc(C(C)=O)ccc32)cc1 ; COC(=O)c1ccc2c(c1)c1ccccc1[s+]2-c1ccc(OC(F)(F)F)cc1]

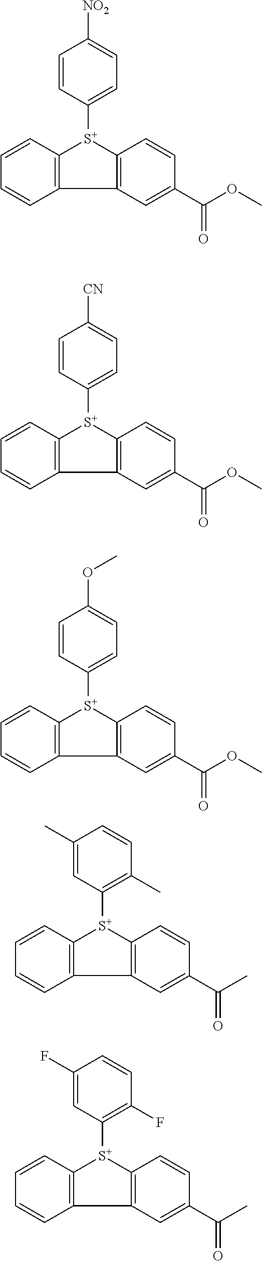 [SMILES: COC(=O)c1ccc2c(c1)c1ccccc1[s+]2-c1ccc([N+](=O)[O-])cc1 ; COC(=O)c1ccc2c(c1)c1ccccc1[s+]2-c1ccc(C#N)cc1 ; COC(=O)c1ccc2c(c1)c1ccccc1[s+]2-c1ccc(OC)cc1 ; CC(=O)c1ccc2c(c1)c1ccccc1[s+]2-c1cc(C)ccc1C ; CC(=O)c1ccc2c(c1)c1ccccc1[s+]2-c1cc(F)ccc1F]

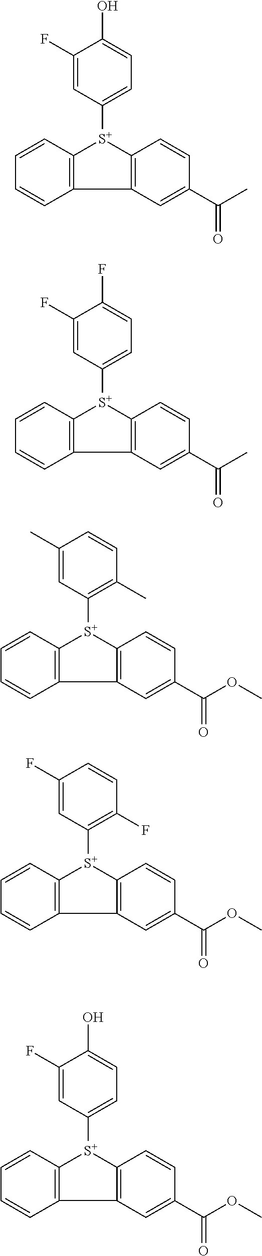 [SMILES: CC(=O)c1ccc2c(c1)c1ccccc1[s+]2-c1ccc(O)c(F)c1 ; CC(=O)c1ccc2c(c1)c1ccccc1[s+]2-c1ccc(F)c(F)c1 ; COC(=O)c1ccc2c(c1)c1ccccc1[s+]2-c1cc(C)ccc1C ; COC(=O)c1ccc2c(c1)c1ccccc1[s+]2-c1cc(F)ccc1F ; COC(=O)c1ccc2c(c1)c1ccccc1[s+]2-c1ccc(O)c(F)c1]

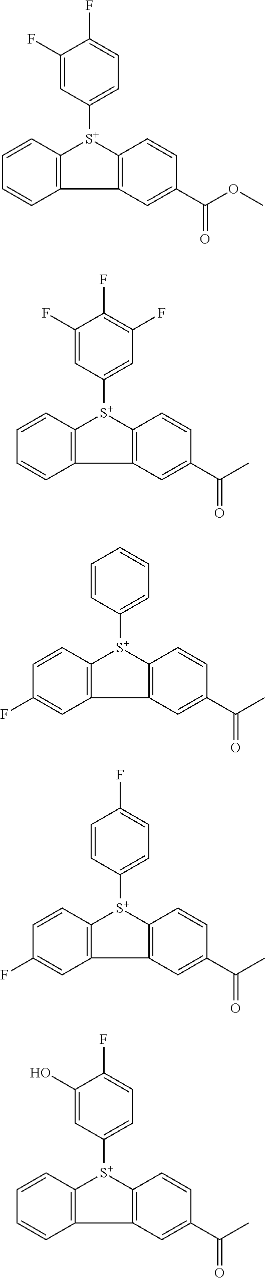 [SMILES: COC(=O)c1ccc2c(c1)c1ccccc1[s+]2-c1ccc(F)c(F)c1 ; CC(=O)c1ccc2c(c1)c1ccccc1[s+]2-c1cc(F)c(F)c(F)c1 ; CC(=O)c1ccc2c(c1)c1cc(F)ccc1[s+]2-c1ccccc1 ; CC(=O)c1ccc2c(c1)c1cc(F)ccc1[s+]2-c1ccc(F)cc1 ; CC(=O)c1ccc2c(c1)c1ccccc1[s+]2-c1ccc(F)c(O)c1]

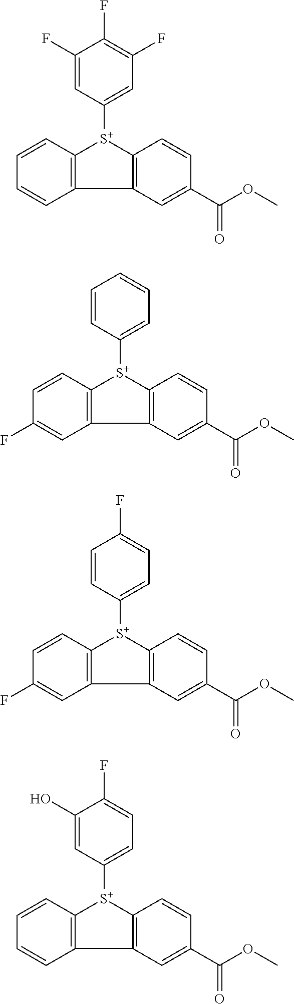 [SMILES: COC(=O)c1ccc2c(c1)c1ccccc1[s+]2-c1cc(F)c(F)c(F)c1 ; COC(=O)c1ccc2c(c1)c1cc(F)ccc1[s+]2-c1ccccc1 ; COC(=O)c1ccc2c(c1)c1cc(F)ccc1[s+]2-c1ccc(F)cc1 ; COC(=O)c1ccc2c(c1)c1ccccc1[s+]2-c1ccc(F)c(O)c1]

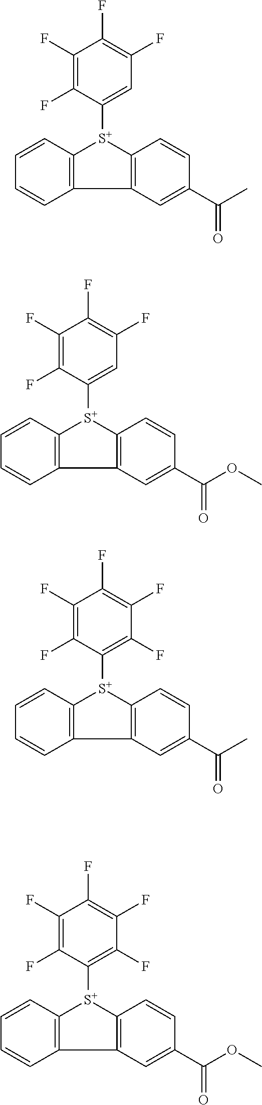 [SMILES: CC(=O)c1ccc2c(c1)c1ccccc1[s+]2-c1cc(F)c(F)c(F)c1F ; COC(=O)c1ccc2c(c1)c1ccccc1[s+]2-c1cc(F)c(F)c(F)c1F ; CC(=O)c1ccc2c(c1)c1ccccc1[s+]2-c1c(F)c(F)c(F)c(F)c1F ; COC(=O)c1ccc2c(c1)c1ccccc1[s+]2-c1c(F)c(F)c(F)c(F)c1F]

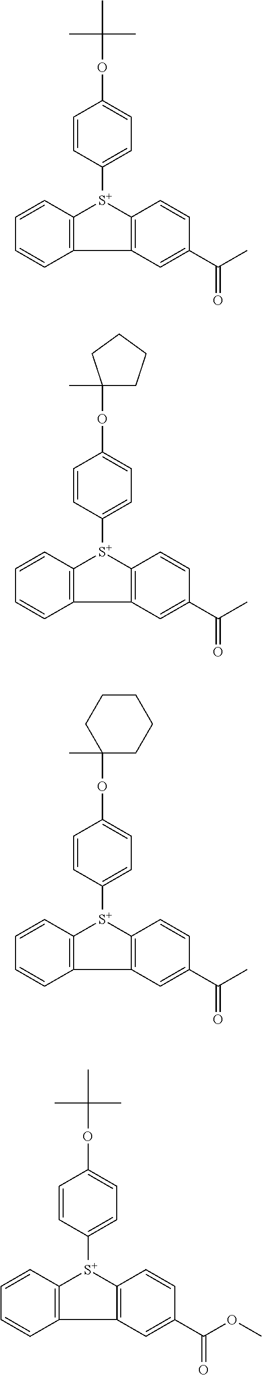 [SMILES: CC(=O)c1ccc2c(c1)c1ccccc1[s+]2-c1ccc(OC(C)(C)C)cc1 ; CC(=O)c1ccc2c(c1)c1ccccc1[s+]2-c1ccc(OC2(C)CCCC2)cc1 ; CC(=O)c1ccc2c(c1)c1ccccc1[s+]2-c1ccc(OC2(C)CCCCC2)cc1 ; COC(=O)c1ccc2c(c1)c1ccccc1[s+]2-c1ccc(OC(C)(C)C)cc1]

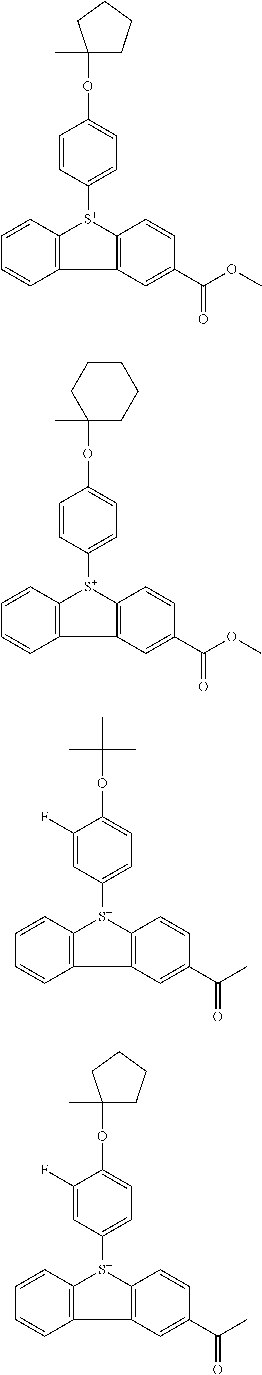 [SMILES: COC(=O)c1ccc2c(c1)c1ccccc1[s+]2-c1ccc(OC2(C)CCCC2)cc1 ; COC(=O)c1ccc2c(c1)c1ccccc1[s+]2-c1ccc(OC2(C)CCCCC2)cc1 ; CC(=O)c1ccc2c(c1)c1ccccc1[s+]2-c1ccc(OC(C)(C)C)c(F)c1 ; CC(=O)c1ccc2c(c1)c1ccccc1[s+]2-c1ccc(OC2(C)CCCC2)c(F)c1]

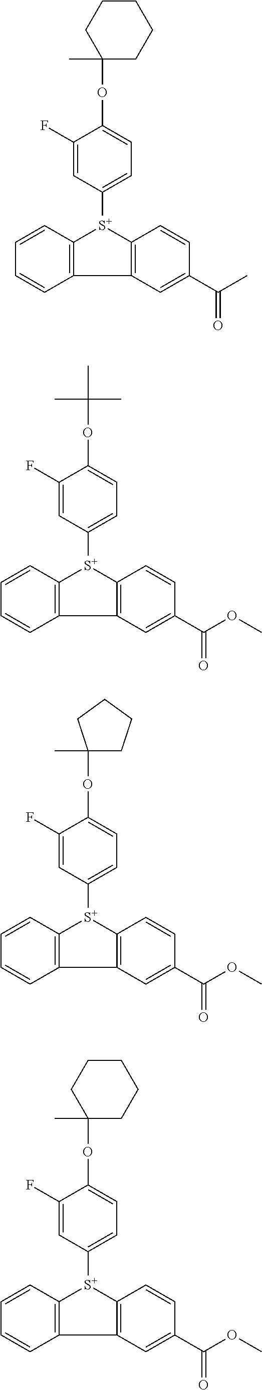 [SMILES: CC(=O)c1ccc2c(c1)c1ccccc1[s+]2-c1ccc(OC2(C)CCCCC2)c(F)c1 ; COC(=O)c1ccc2c(c1)c1ccccc1[s+]2-c1ccc(OC(C)(C)C)c(F)c1 ; COC(=O)c1ccc2c(c1)c1ccccc1[s+]2-c1ccc(OC2(C)CCCC2)c(F)c1 ; COC(=O)c1ccc2c(c1)c1ccccc1[s+]2-c1ccc(OC2(C)CCCCC2)c(F)c1]

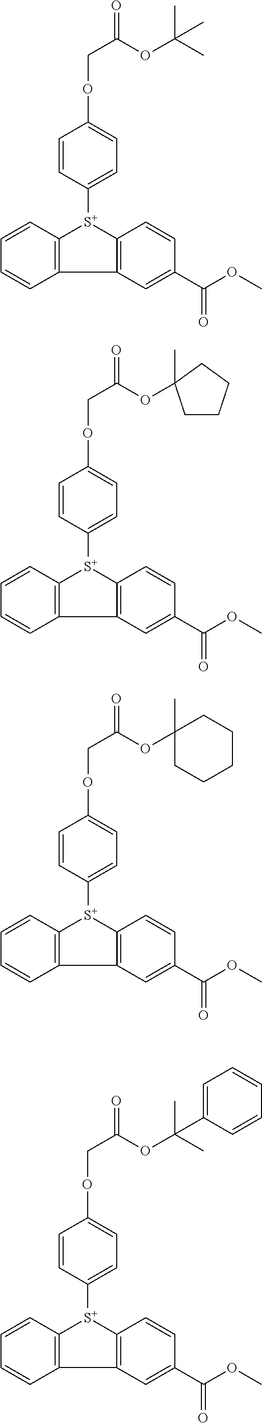 [SMILES: COC(=O)c1ccc2c(c1)c1ccccc1[s+]2-c1ccc(OCC(=O)OC(C)(C)C)cc1 ; COC(=O)c1ccc2c(c1)c1ccccc1[s+]2-c1ccc(OCC(=O)OC2(C)CCCC2)cc1 ; COC(=O)c1ccc2c(c1)c1ccccc1[s+]2-c1ccc(OCC(=O)OC2(C)CCCCC2)cc1 ; COC(=O)c1ccc2c(c1)c1ccccc1[s+]2-c1ccc(OCC(=O)OC(C)(C)c2ccccc2)cc1]

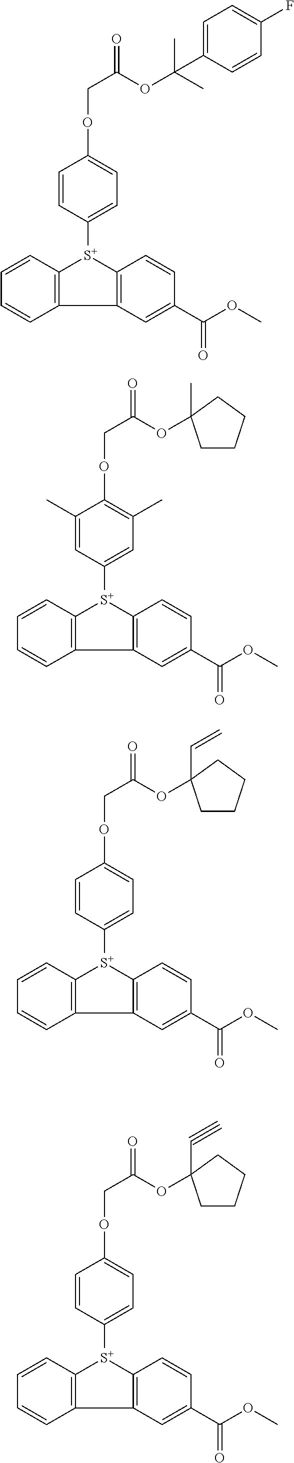 [SMILES: COC(=O)c1ccc2c(c1)c1ccccc1[s+]2-c1ccc(OCC(=O)OC(C)(C)c2ccc(F)cc2)cc1 ; COC(=O)c1ccc2c(c1)c1ccccc1[s+]2-c1cc(C)c(OCC(=O)OC2(C)CCCC2)c(C)c1 ; C=CC1(OC(=O)COc2ccc(-[s+]3c4ccccc4c4cc(C(=O)OC)ccc43)cc2)CCCC1 ; C#CC1(OC(=O)COc2ccc(-[s+]3c4ccccc4c4cc(C(=O)OC)ccc43)cc2)CCCC1]

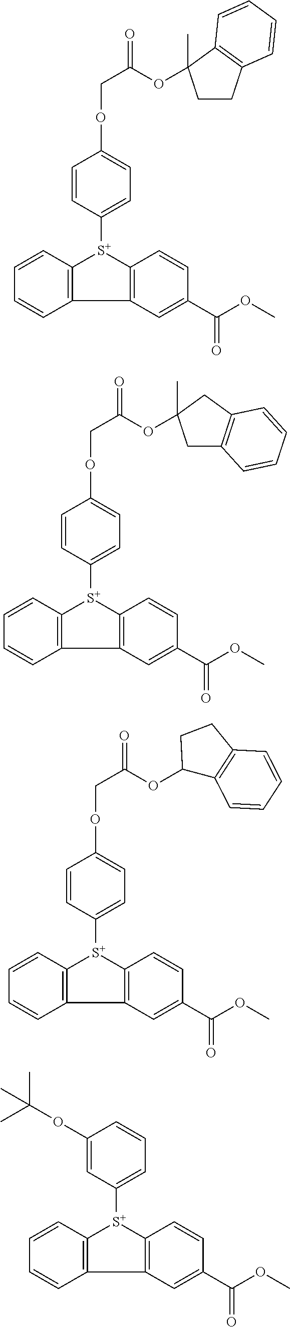 [SMILES: COC(=O)c1ccc2c(c1)c1ccccc1[s+]2-c1ccc(OCC(=O)OC2(C)CCc3ccccc32)cc1 ; COC(=O)c1ccc2c(c1)c1ccccc1[s+]2-c1ccc(OCC(=O)OC2(C)Cc3ccccc3C2)cc1 ; COC(=O)c1ccc2c(c1)c1ccccc1[s+]2-c1ccc(OCC(=O)OC2CCc3ccccc32)cc1 ; COC(=O)c1ccc2c(c1)c1ccccc1[s+]2-c1cccc(OC(C)(C)C)c1]

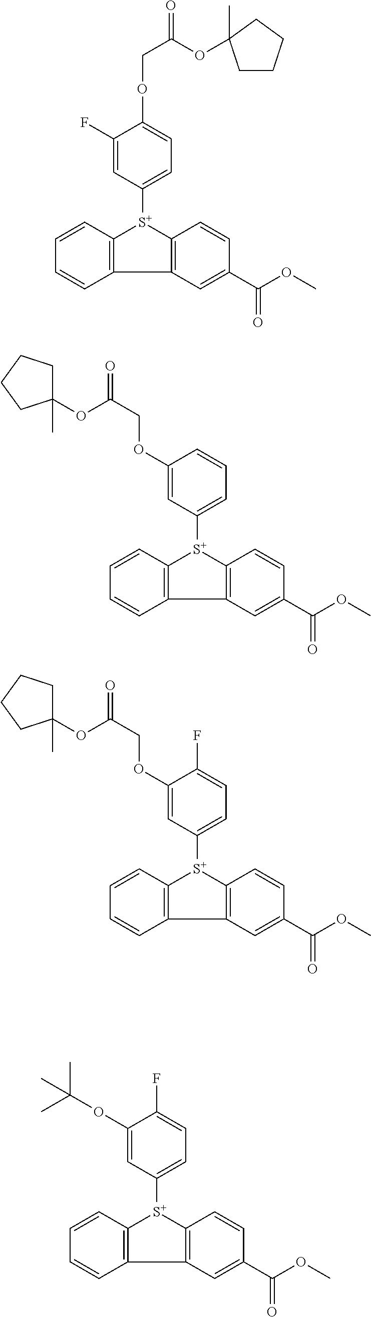

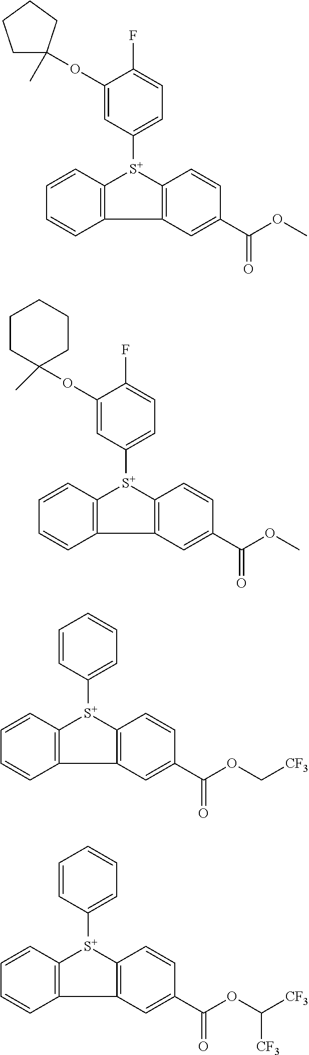 [SMILES: COC(=O)c1ccc2c(c1)c1ccccc1[s+]2-c1ccc(F)c(OC2(C)CCCC2)c1 ; COC(=O)c1ccc2c(c1)c1ccccc1[s+]2-c1ccc(F)c(OC2(C)CCCCC2)c1 ; O=C(OCC(F)(F)F)c1ccc2c(c1)c1ccccc1[s+]2-c1ccccc1 ; O=C(OC(C(F)(F)F)C(F)(F)F)c1ccc2c(c1)c1ccccc1[s+]2-c1ccccc1]

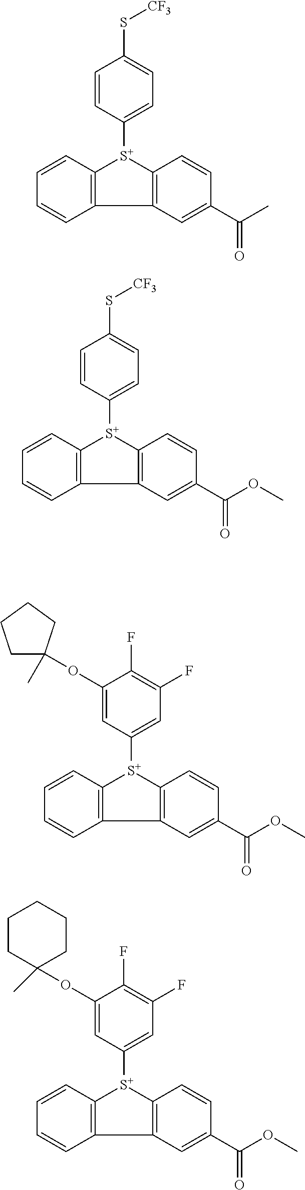 [SMILES: CC(=O)c1ccc2c(c1)c1ccccc1[s+]2-c1ccc(SC(F)(F)F)cc1 ; COC(=O)c1ccc2c(c1)c1ccccc1[s+]2-c1ccc(SC(F)(F)F)cc1 ; COC(=O)c1ccc2c(c1)c1ccccc1[s+]2-c1cc(F)c(F)c(OC2(C)CCCC2)c1 ; COC(=O)c1ccc2c(c1)c1ccccc1[s+]2-c1cc(F)c(F)c(OC2(C)CCCCC2)c1]

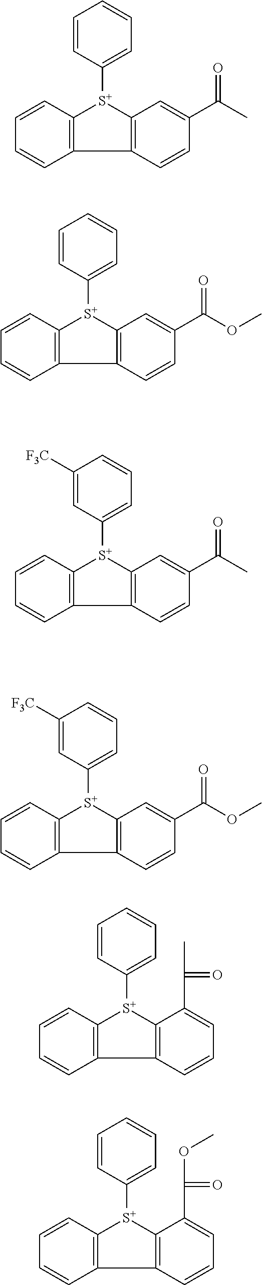 [SMILES: CC(=O)c1ccc2c3ccccc3[s+](-c3ccccc3)c2c1 ; COC(=O)c1ccc2c3ccccc3[s+](-c3ccccc3)c2c1 ; CC(=O)c1ccc2c3ccccc3[s+](-c3cccc(C(F)(F)F)c3)c2c1 ; COC(=O)c1ccc2c3ccccc3[s+](-c3cccc(C(F)(F)F)c3)c2c1 ; CC(=O)c1cccc2c3ccccc3[s+](-c3ccccc3)c12 ; COC(=O)c1cccc2c3ccccc3[s+](-c3ccccc3)c12]

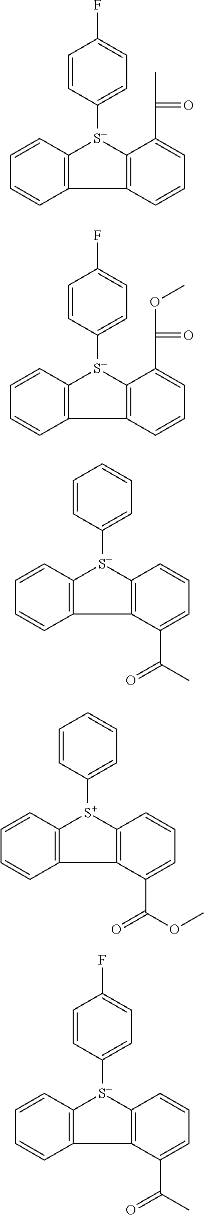 [SMILES: CC(=O)c1cccc2c3ccccc3[s+](-c3ccc(F)cc3)c12 ; COC(=O)c1cccc2c3ccccc3[s+](-c3ccc(F)cc3)c12 ; CC(=O)c1cccc2c1c1ccccc1[s+]2-c1ccccc1 ; COC(=O)c1cccc2c1c1ccccc1[s+]2-c1ccccc1 ; CC(=O)c1cccc2c1c1ccccc1[s+]2-c1ccc(F)cc1]

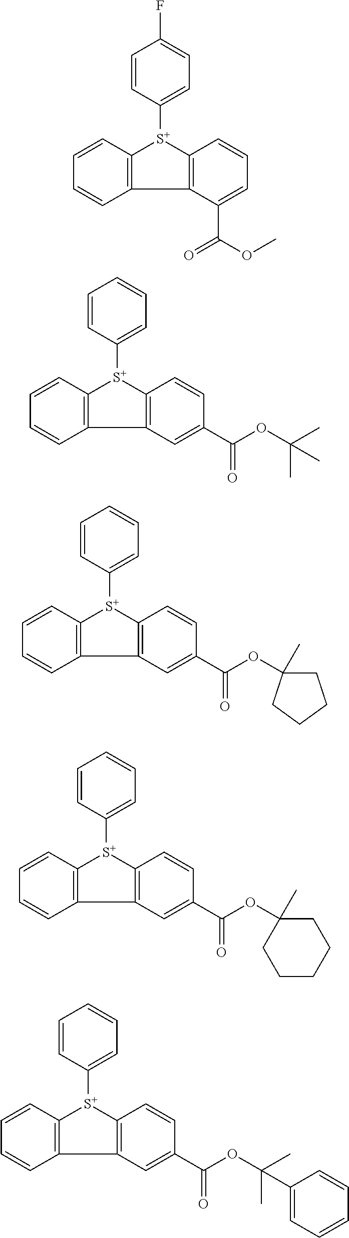 [SMILES: COC(=O)c1cccc2c1c1ccccc1[s+]2-c1ccc(F)cc1 ; CC(C)(C)OC(=O)c1ccc2c(c1)c1ccccc1[s+]2-c1ccccc1 ; CC1(OC(=O)c2ccc3c(c2)c2ccccc2[s+]3-c2ccccc2)CCCC1 ; CC1(OC(=O)c2ccc3c(c2)c2ccccc2[s+]3-c2ccccc2)CCCCC1 ; CC(C)(OC(=O)c1ccc2c(c1)c1ccccc1[s+]2-c1ccccc1)c1ccccc1]

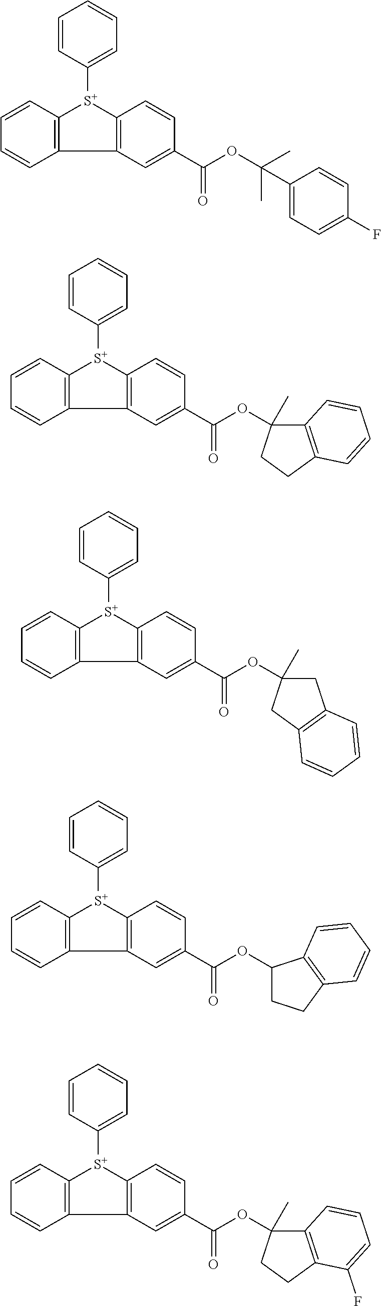 [SMILES: CC(C)(OC(=O)c1ccc2c(c1)c1ccccc1[s+]2-c1ccccc1)c1ccc(F)cc1 ; CC1(OC(=O)c2ccc3c(c2)c2ccccc2[s+]3-c2ccccc2)CCc2ccccc21 ; CC1(OC(=O)c2ccc3c(c2)c2ccccc2[s+]3-c2ccccc2)Cc2ccccc2C1 ; O=C(OC1CCc2ccccc21)c1ccc2c(c1)c1ccccc1[s+]2-c1ccccc1 ; CC1(OC(=O)c2ccc3c(c2)c2ccccc2[s+]3-c2ccccc2)CCc2c(F)cccc21]

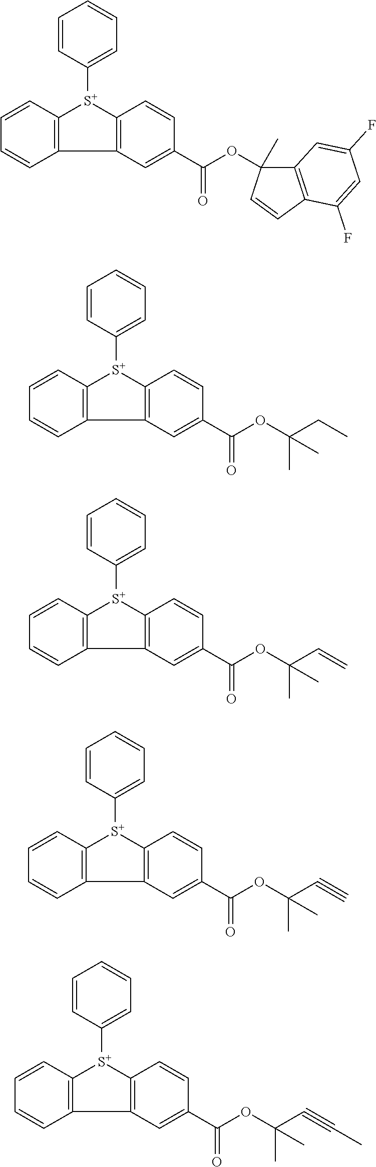 [SMILES: CC1(OC(=O)c2ccc3c(c2)c2ccccc2[s+]3-c2ccccc2)C=Cc2c(F)cc(F)cc21 ; CCC(C)(C)OC(=O)c1ccc2c(c1)c1ccccc1[s+]2-c1ccccc1 ; C=CC(C)(C)OC(=O)c1ccc2c(c1)c1ccccc1[s+]2-c1ccccc1 ; C#CC(C)(C)OC(=O)c1ccc2c(c1)c1ccccc1[s+]2-c1ccccc1 ; CC#CC(C)(C)OC(=O)c1ccc2c(c1)c1ccccc1[s+]2-c1ccccc1]

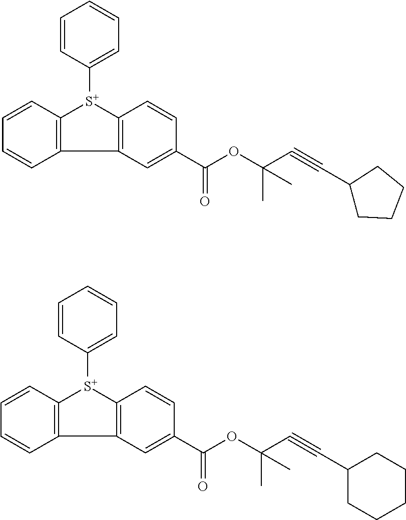 [SMILES: CC(C)(C#CC1CCCC1)OC(=O)c1ccc2c(c1)c1ccccc1[s+]2-c1ccccc1 ; CC(C)(C#CC1CCCCC1)OC(=O)c1ccc2c(c1)c1ccccc1[s+]2-c1ccccc1]

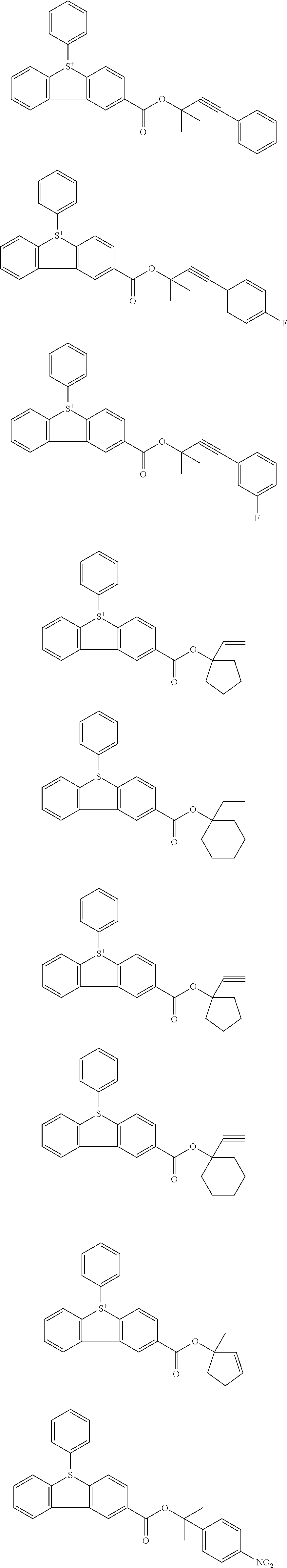

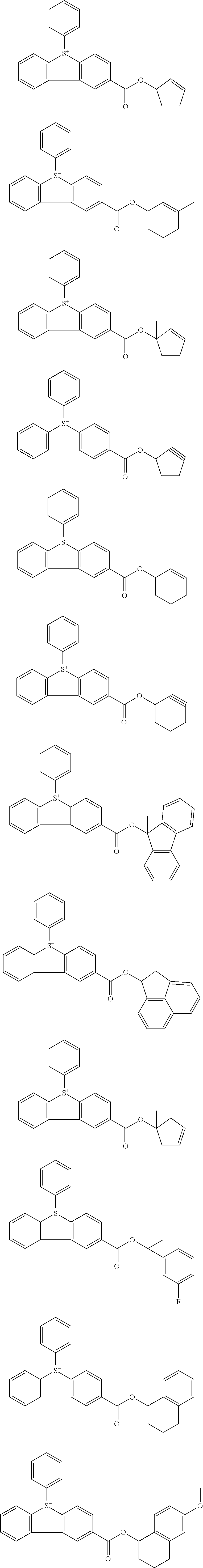

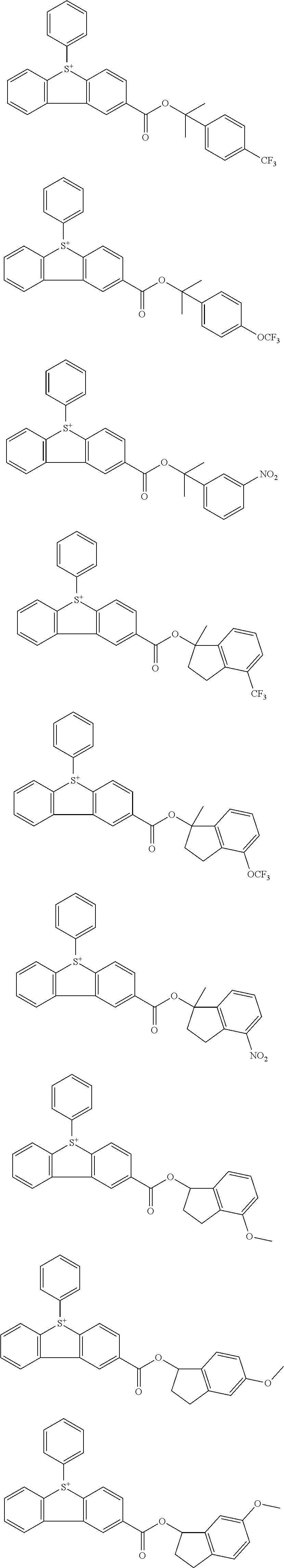

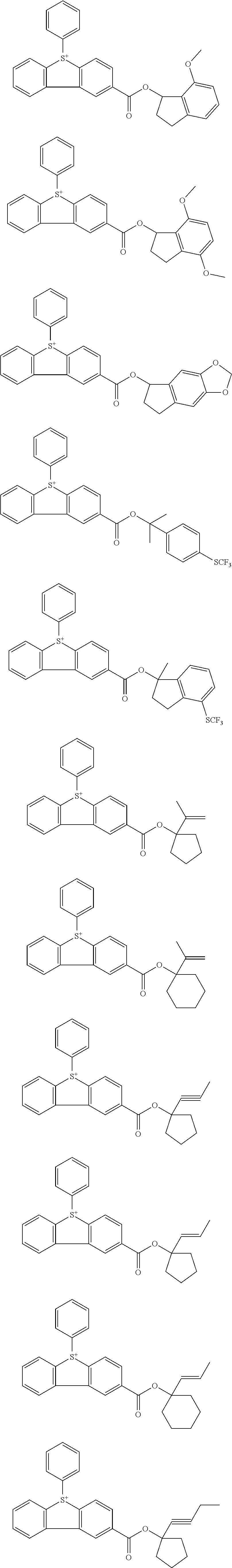

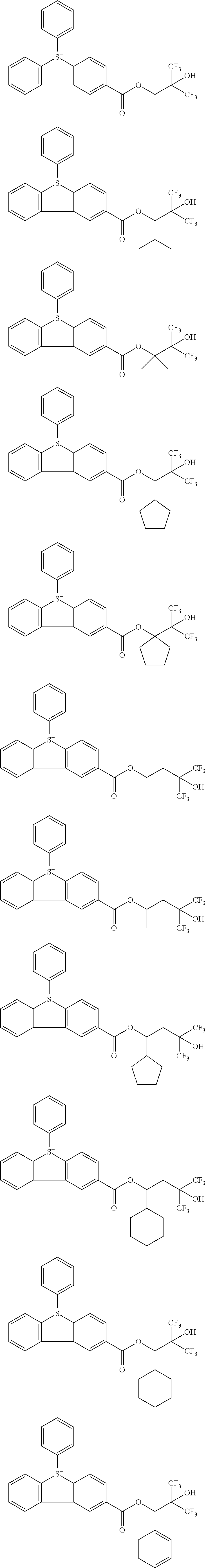

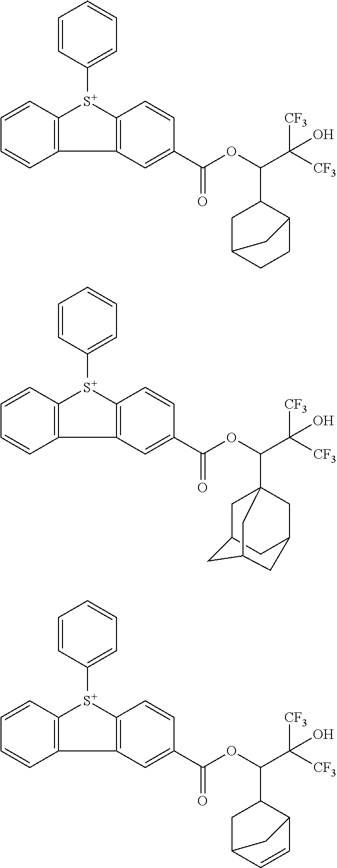 [SMILES: O=C(OC(C1CC2CCC1C2)C(O)(C(F)(F)F)C(F)(F)F)c1ccc2c(c1)c1ccccc1[s+]2-c1ccccc1 ; O=C(OC(C12CC3CC(CC(C3)C1)C2)C(O)(C(F)(F)F)C(F)(F)F)c1ccc2c(c1)c1ccccc1[s+]2-c1ccccc1 ; O=C(OC(C1CC2C=CC1C2)C(O)(C(F)(F)F)C(F)(F)F)c1ccc2c(c1)c1ccccc1[s+]2-c1ccccc1]

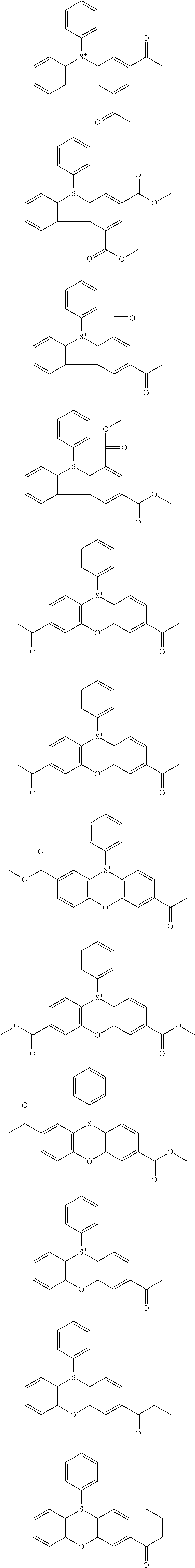

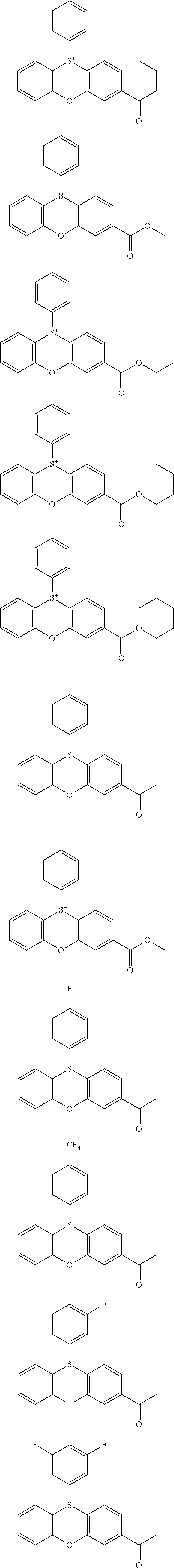

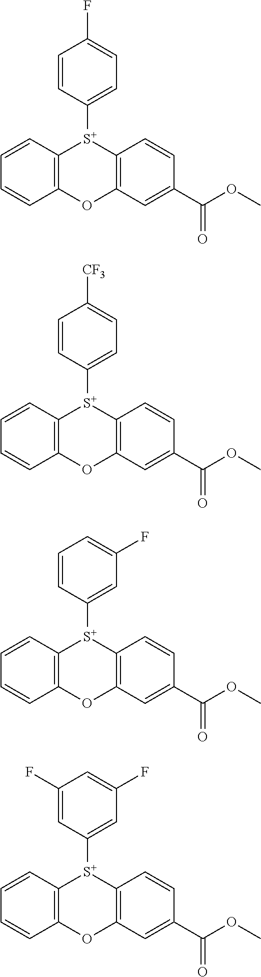 [SMILES: COC(=O)c1ccc2c(c1)Oc1ccccc1[S+]2c1ccc(F)cc1 ; COC(=O)c1ccc2c(c1)Oc1ccccc1[S+]2c1ccc(C(F)(F)F)cc1 ; COC(=O)c1ccc2c(c1)Oc1ccccc1[S+]2c1cccc(F)c1 ; COC(=O)c1ccc2c(c1)Oc1ccccc1[S+]2c1cc(F)cc(F)c1]

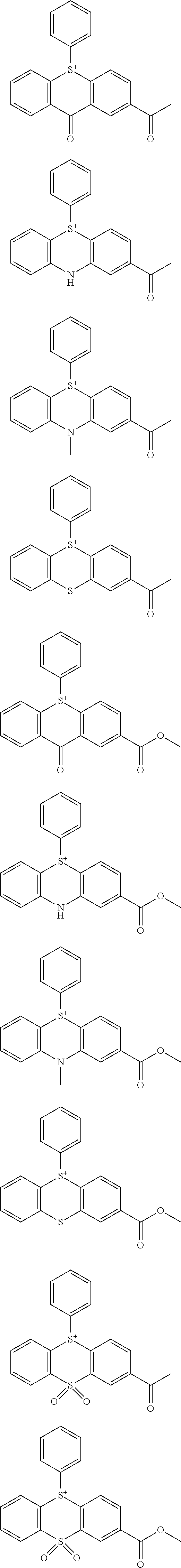

The C₅-C₂₀ aromatic carboxylic acid anion substituted with a halogen atom or a halogen atom-containing group preferably has the following formula (2).

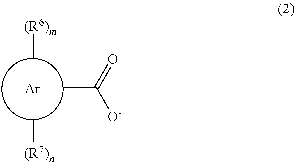

In formula (2), m is an integer of 1 to 5, and n is an integer of 0 to 4.

In formula (2), circle Ar is a group derived from benzene, naphthalene, or thiophene.

In formula (2), R⁶ is a halogen atom, —R^{6A}, —O—R^{6A}, —S—R⁶, —C(═O)—O—R^{6A}, —O—C(═O)—R^{6A}, —O—C(═O)—O—R^{6A}, —N(R^{6B})—S(═O)₂—R^{6A}, —O—S(═O)₂—R^{6A}, or a halogenated phenyl group. R^{6A} is a C₁-C₄ halogenated alkyl group. R^{6B} is a C₁-C₆ saturated hydrocarbyl group.

Examples of the C₁-C₄ halogenated alkyl group represented by R^{6A} include a fluoromethyl group, a difluoromethyl group, a trifluoromethyl group, a monofluoromethyl group, a difluoromethyl group, a trifluoromethyl group, a 2,2,2-trifluoroethyl group, a 1,1,2,2-tetrafluoroethyl group, a 1,1,2,2,2-pentafluoroethyl group, a 1,1,1,3,3,3-hexafluoro-2-propyl group, a 1,1,2,2,3,3,3-heptafluoropropyl group, and a 1,1,2,2,3,3,4,4,4-nonafluorobutyl group.

In formula (2), R⁷ is a hydroxy group, a cyano group, a nitro group, an amino group, a mercapto group, —R^{7A}, —O—R^{7A}, —O—C(═O)—R^{7A}, —O—C(═O)—O—R^{7A}, or —N(R^{7B})—C(═O)—R^{7C}. R^{7A} is a C₁-C₁₆ hydrocarbyl group. R^{7B} is a hydrogen atom or a C₁-C₆ saturated hydrocarbyl group. R^{7C} is a C₁-C₁₆ aliphatic hydrocarbyl group, a C₆-C₁₄ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group.

The C₁-C₁₆ hydrocarbyl group represented by R^{7A} may be saturated or unsaturated and straight, branched, or cyclic. Specific examples thereof are as exemplified above for the hydrocarbyl group represented by R⁴ and R⁵ in the description of formula (1).

Examples of the anion having formula (2) are derived are shown below, but not limited thereto.

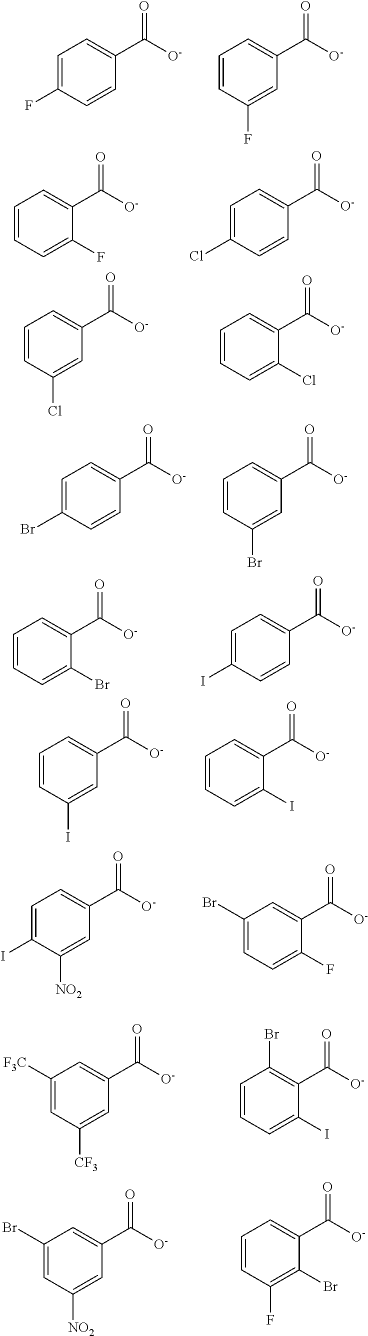

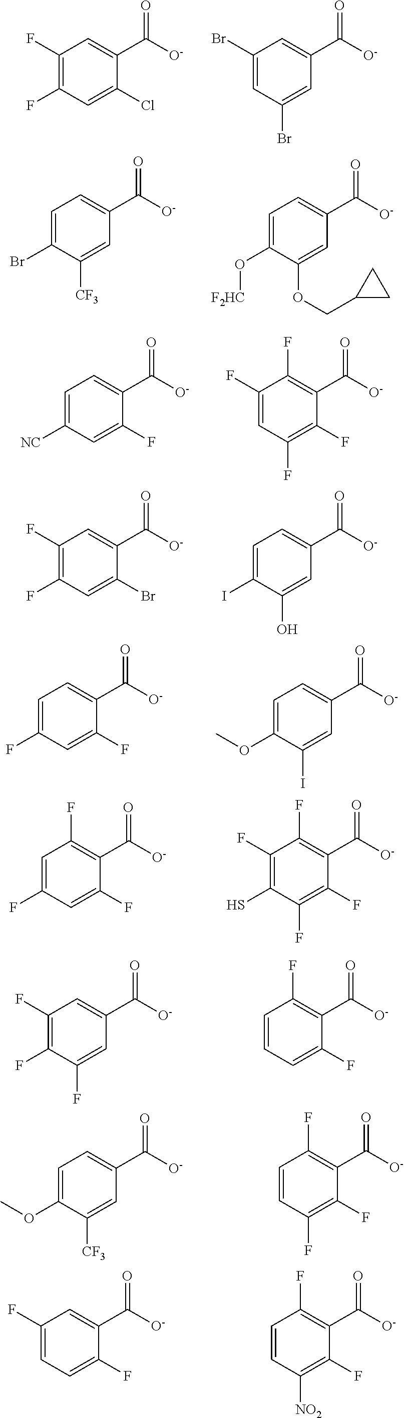

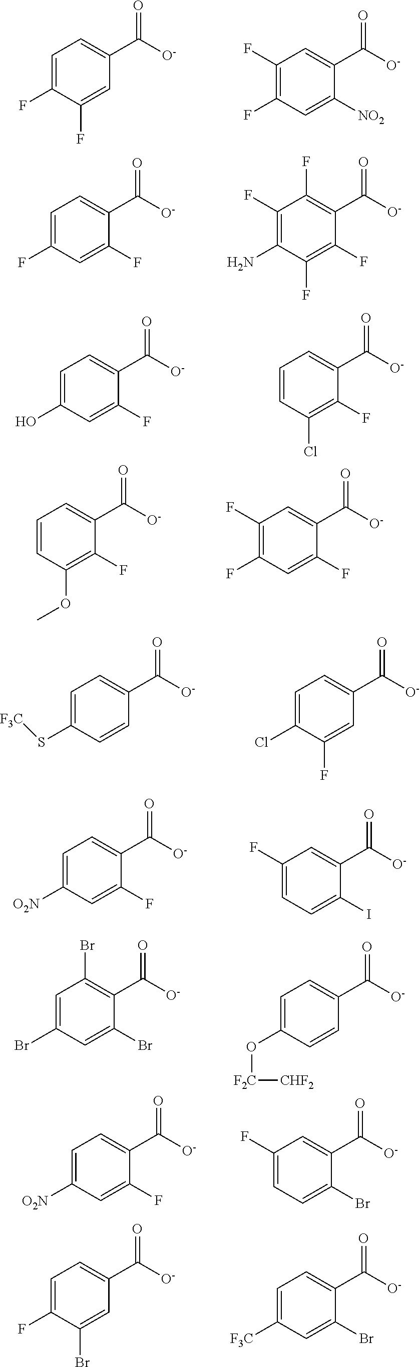

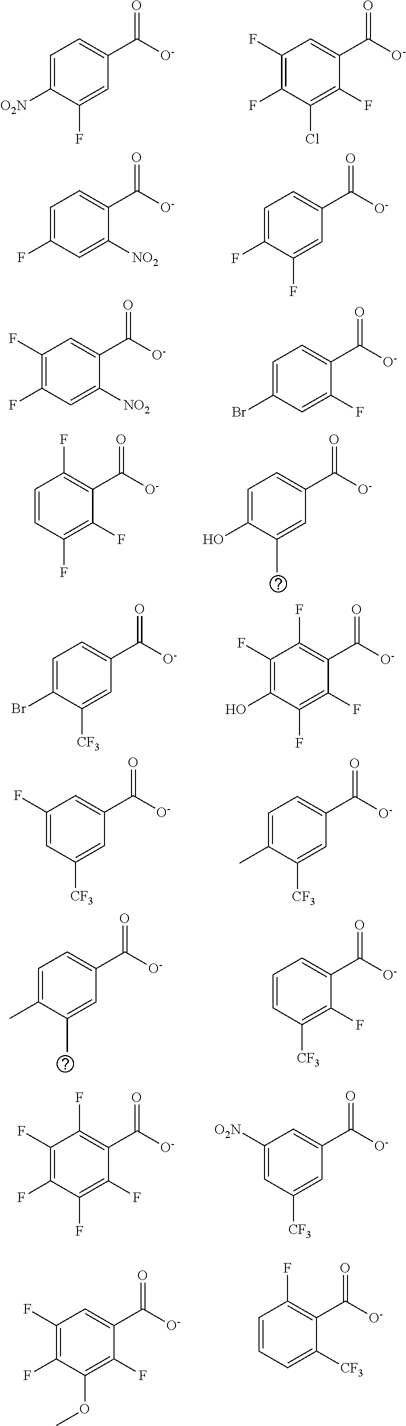

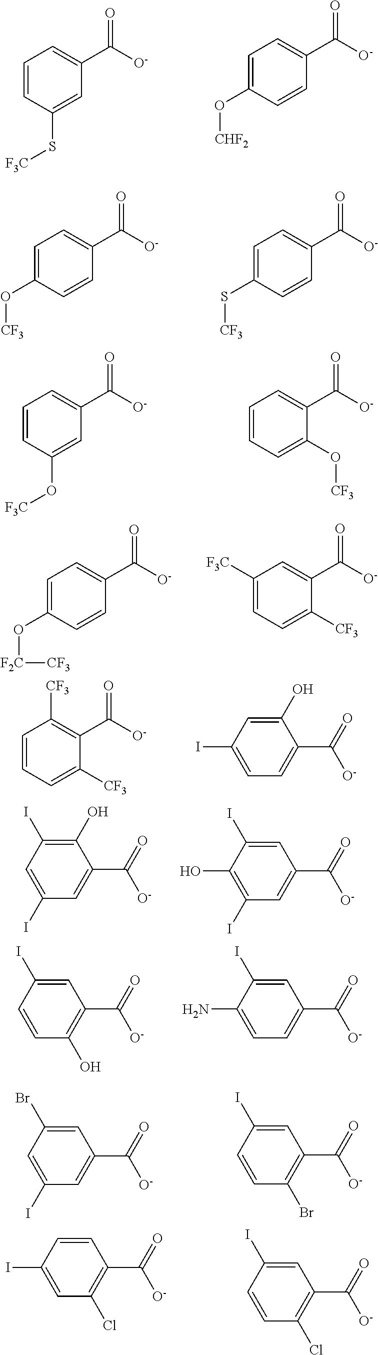

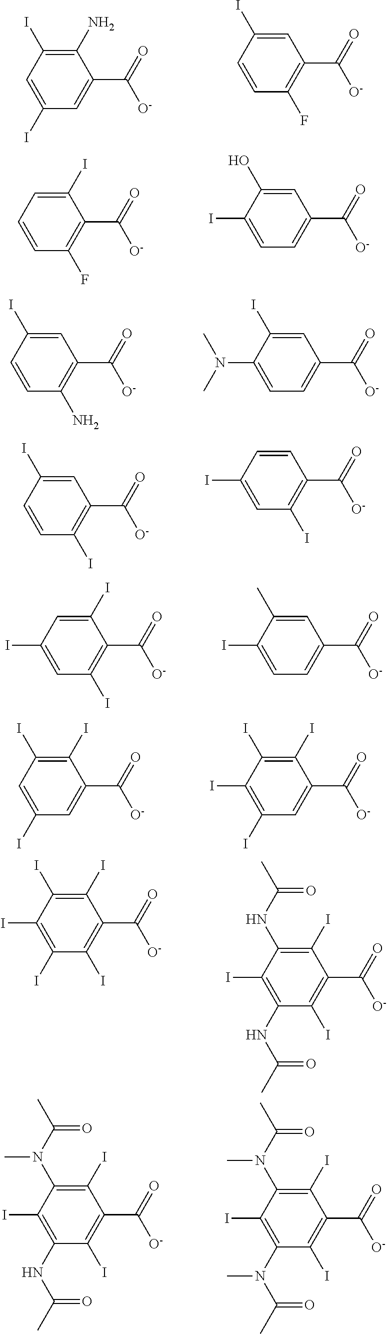

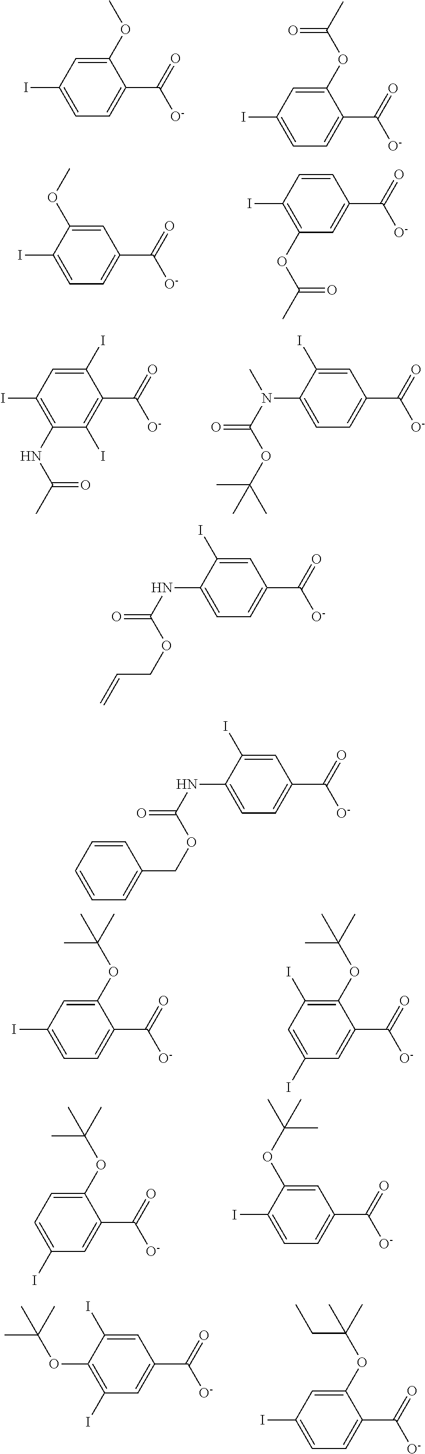

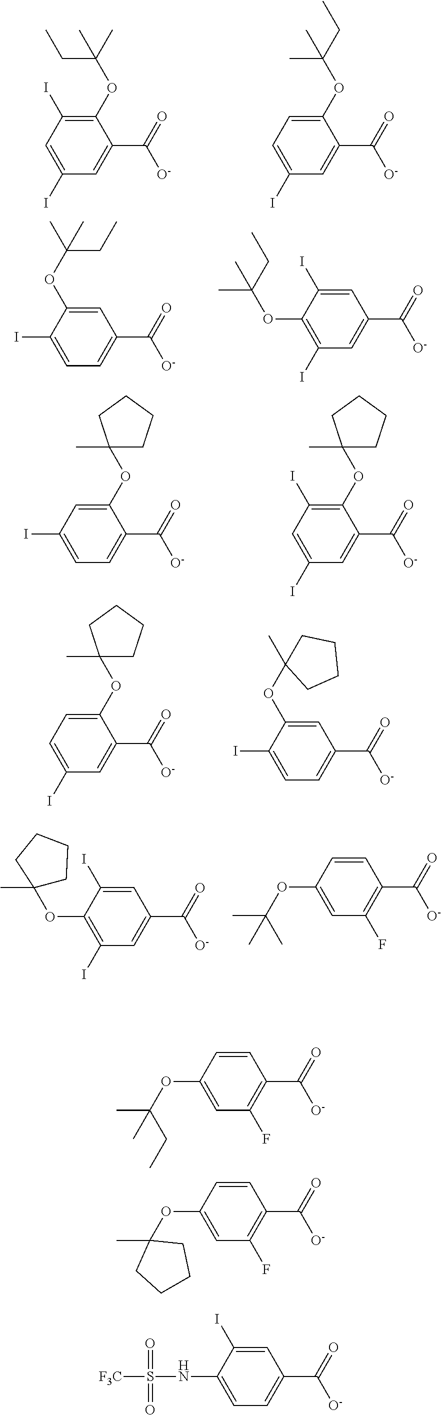

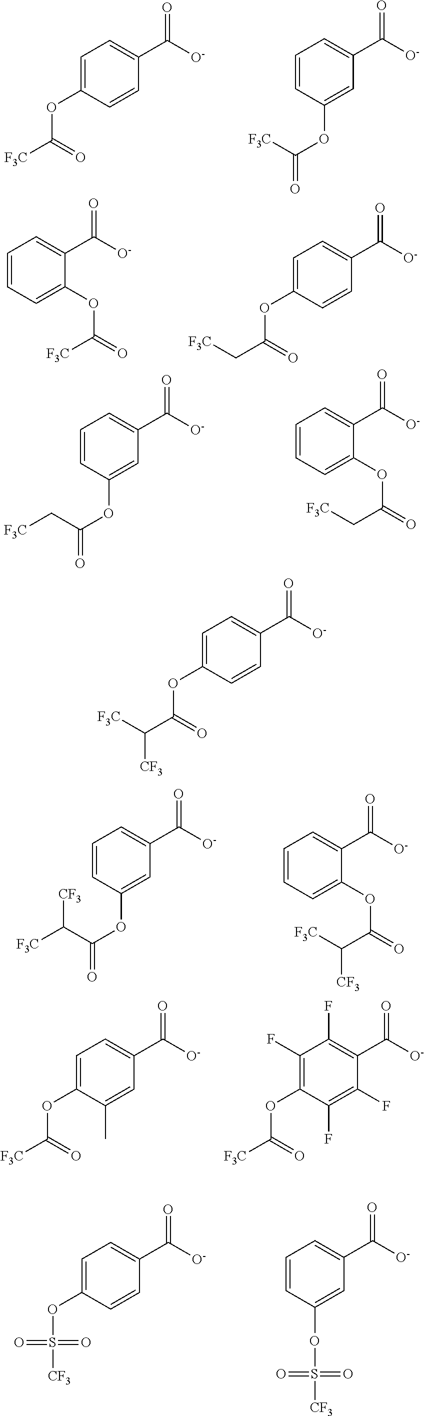

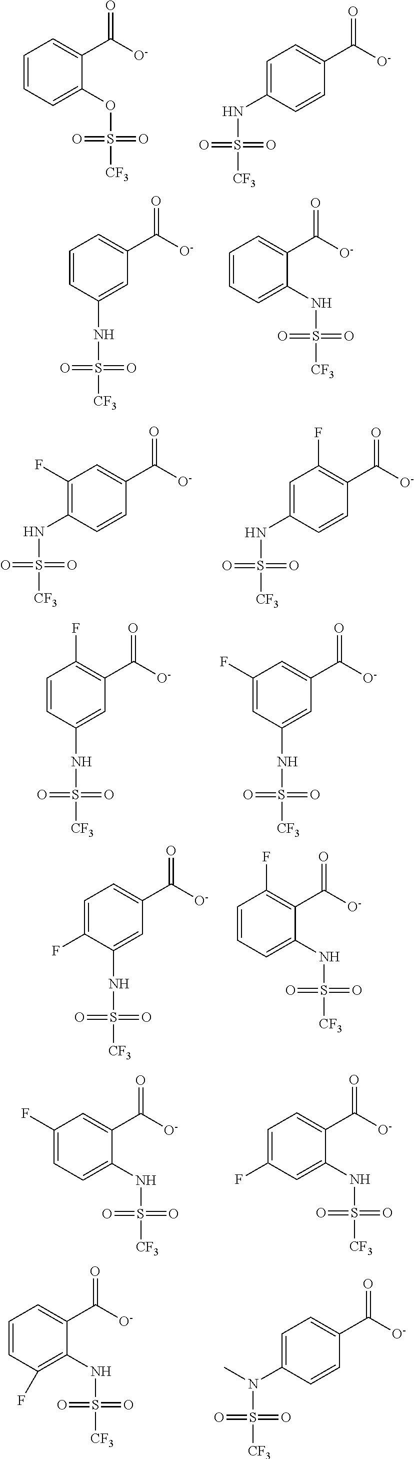

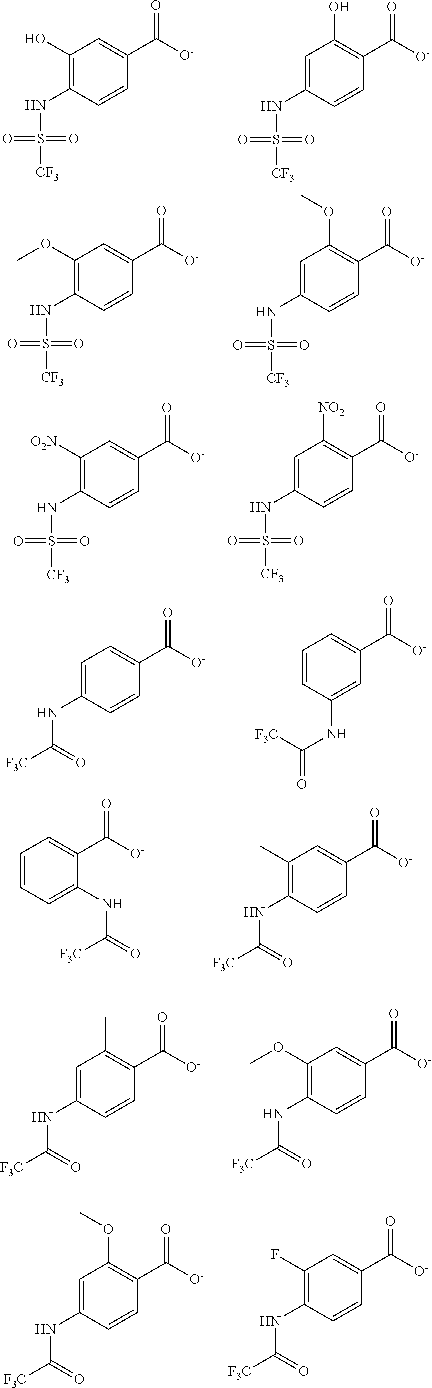

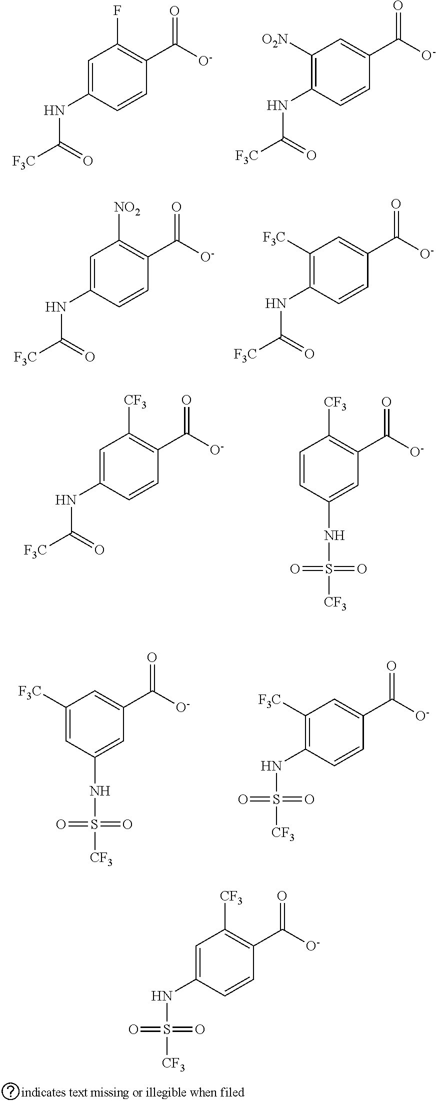

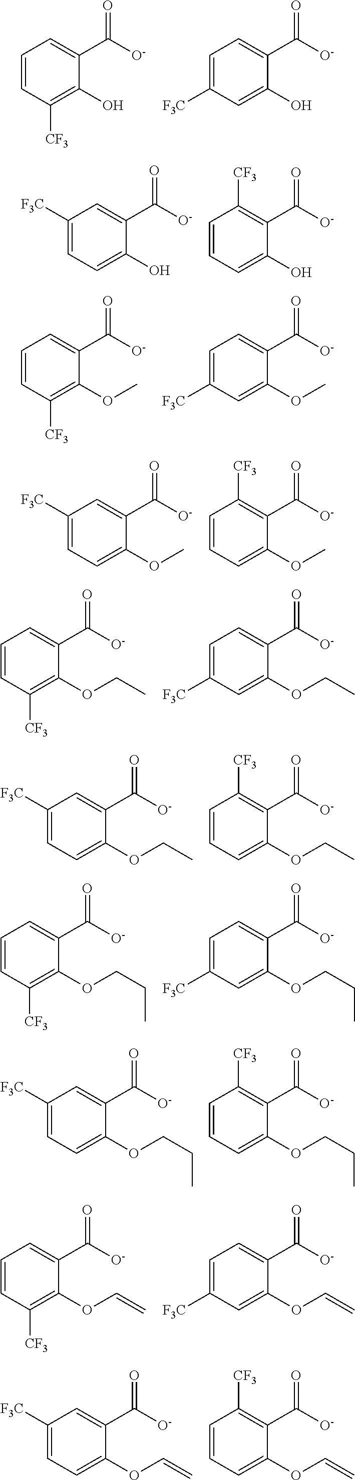

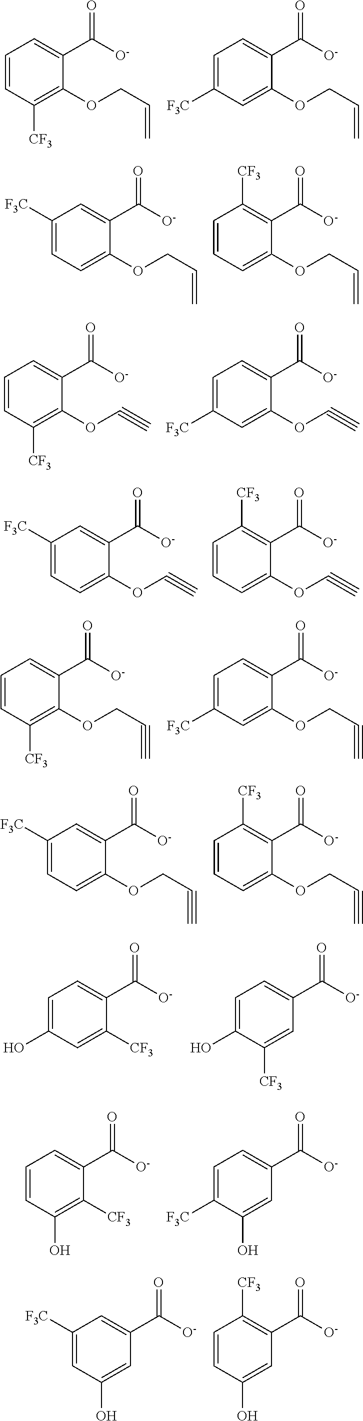

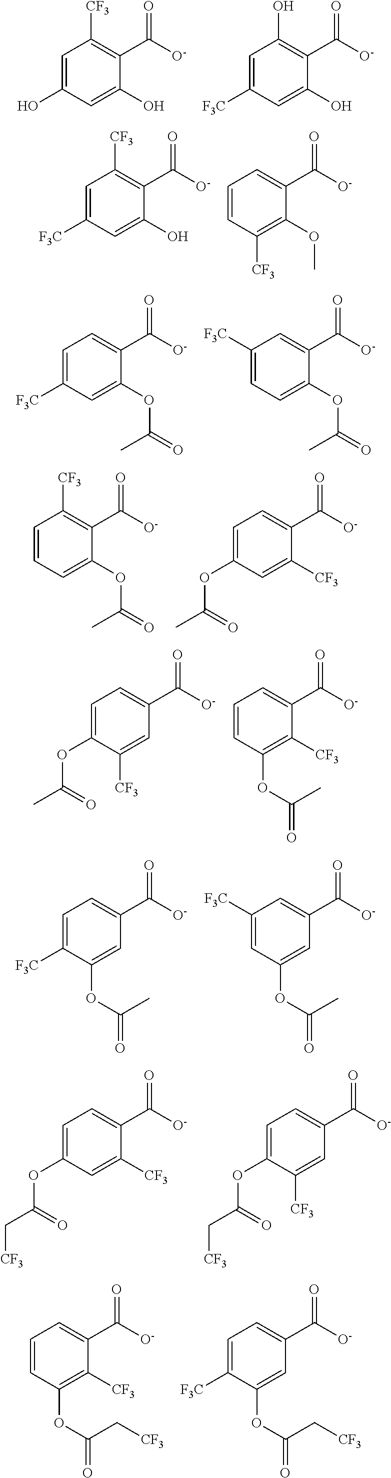

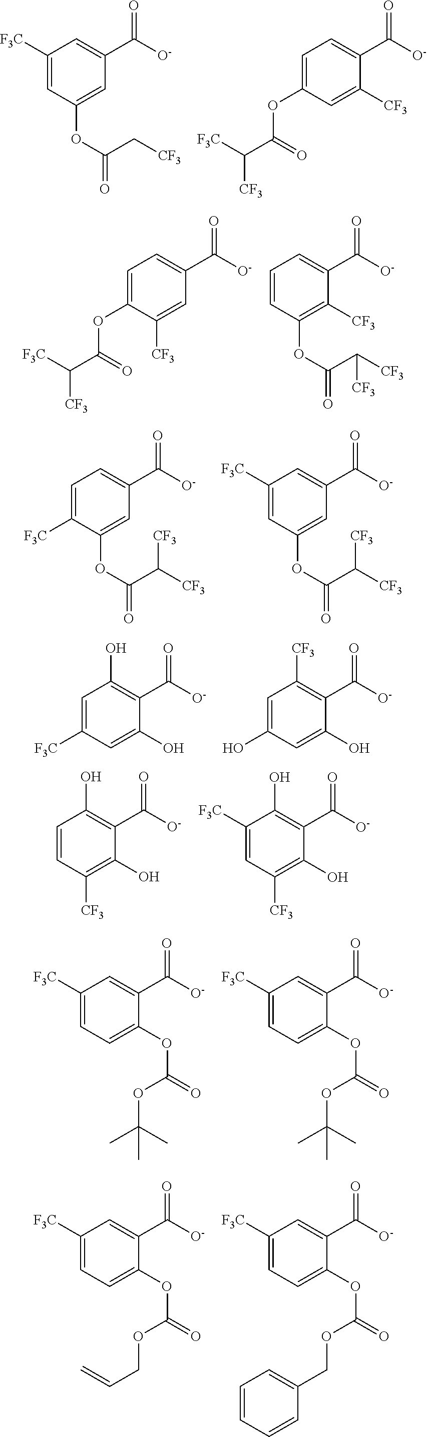

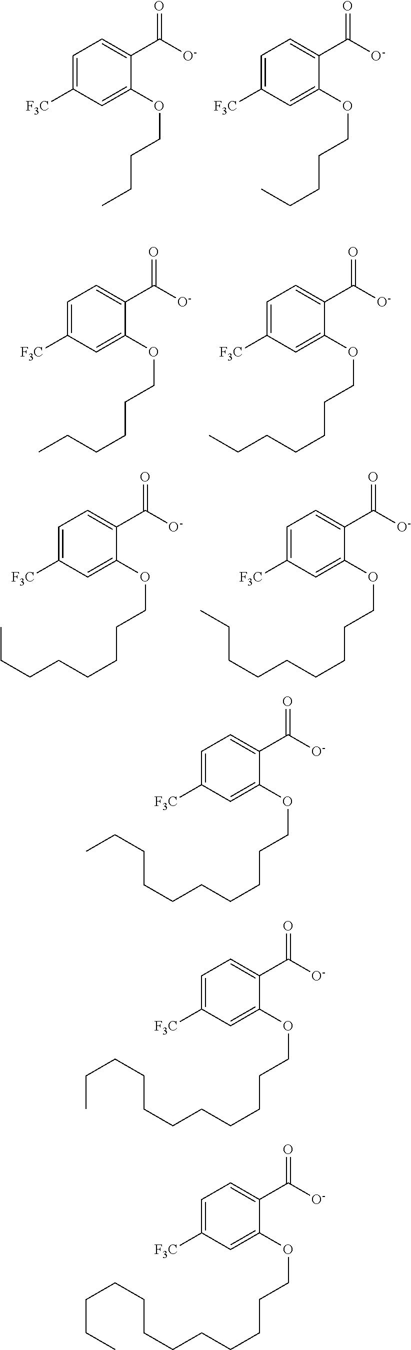

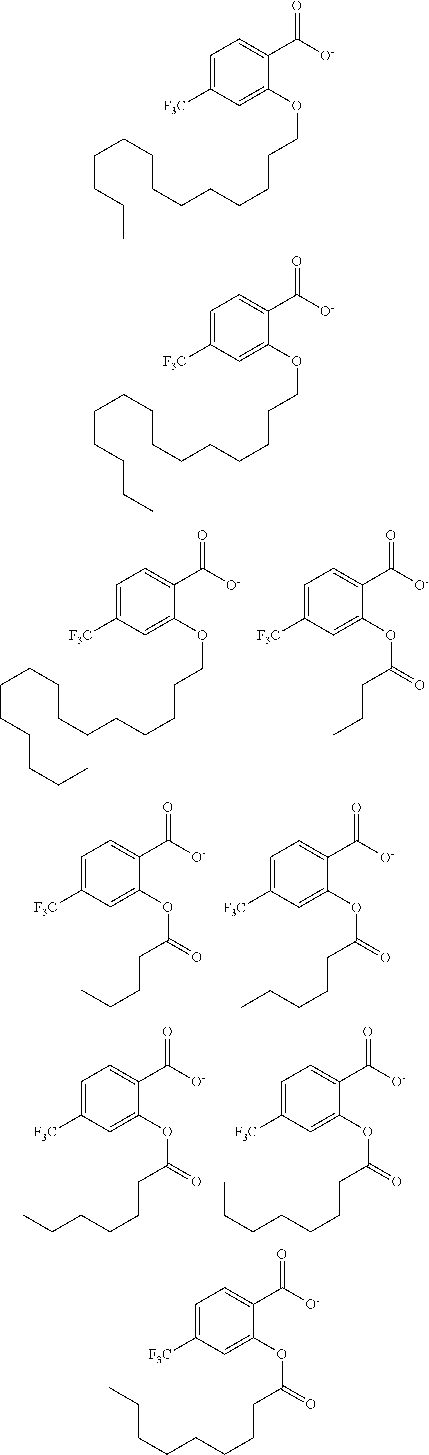

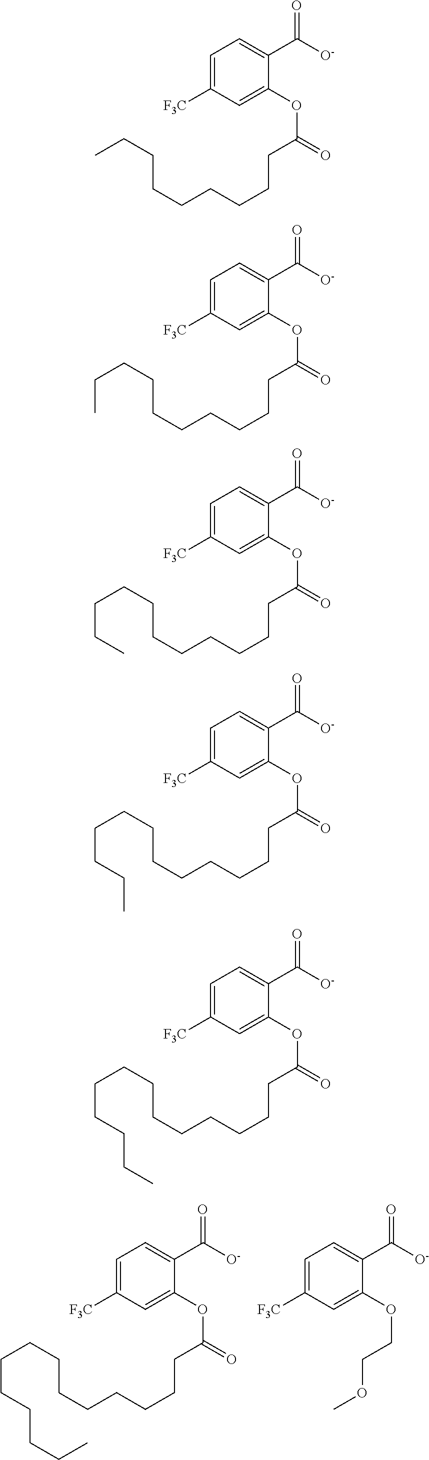

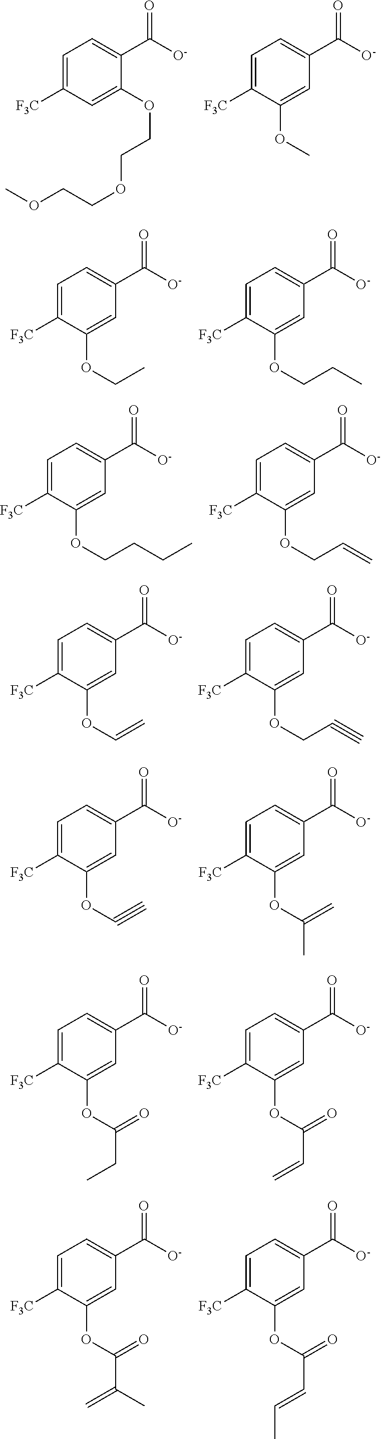

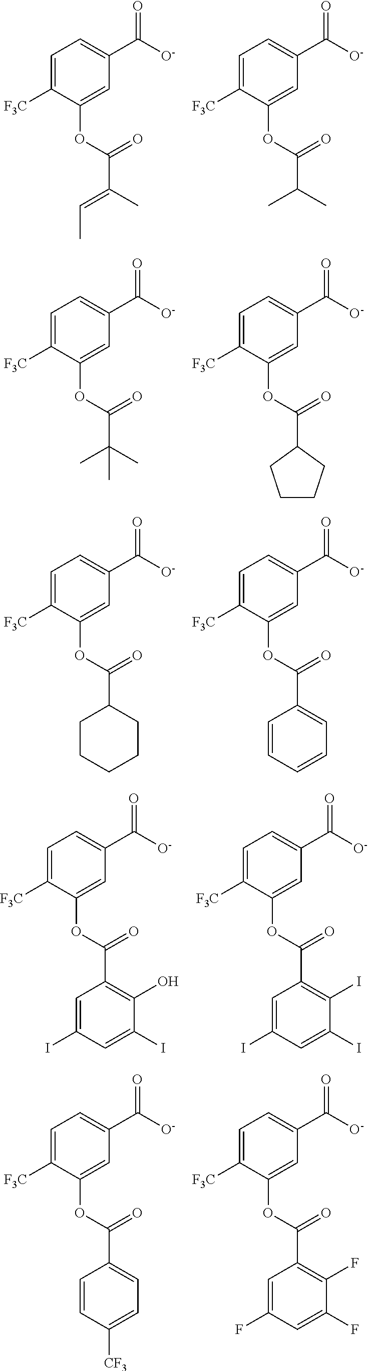

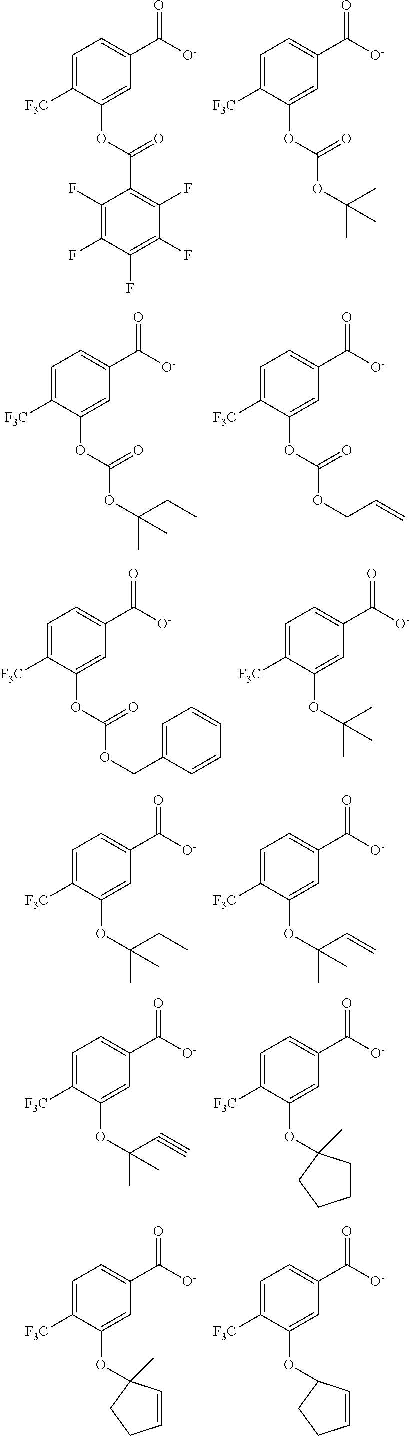

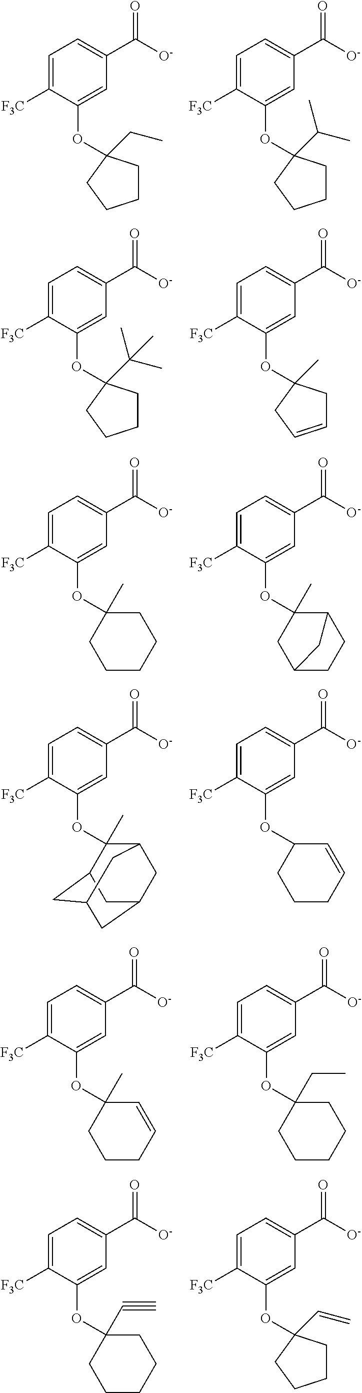

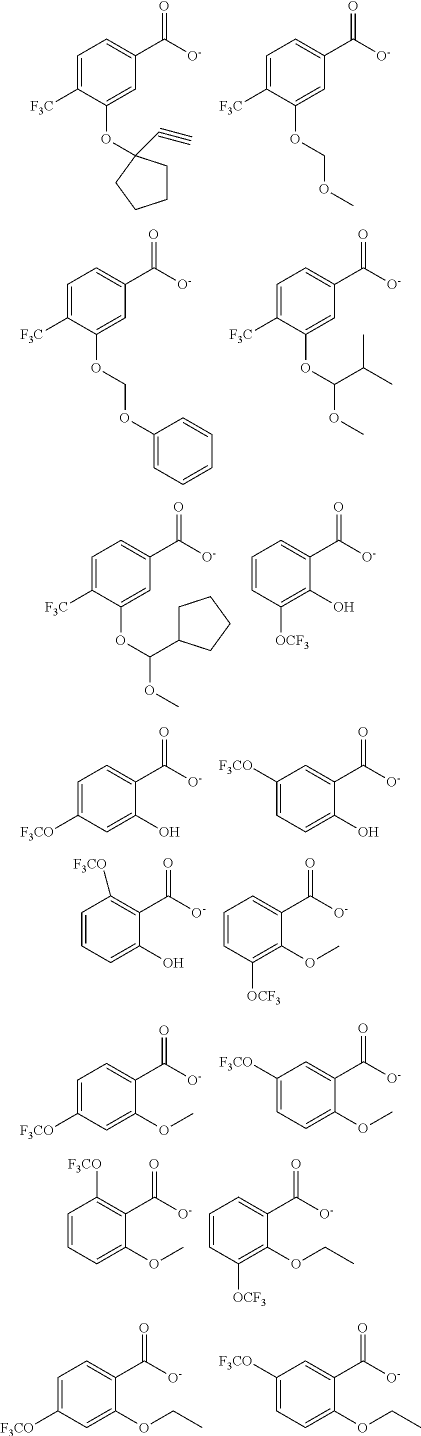

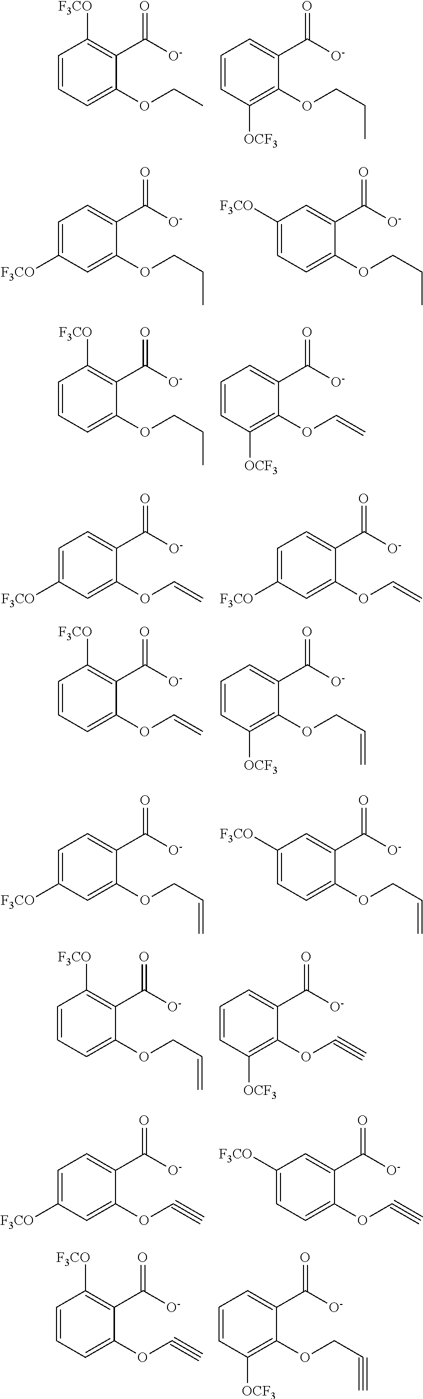

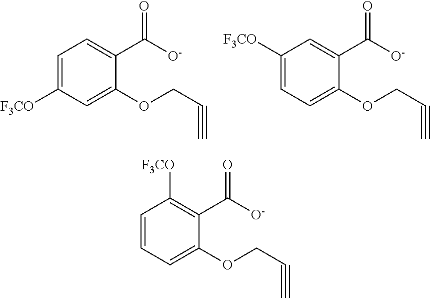 [SMILES: C#CCOc1cc(OC(F)(F)F)ccc1C(=O)[O-] ; C#CCOc1ccc(OC(F)(F)F)cc1C(=O)[O-] ; C#CCOc1cccc(OC(F)(F)F)c1C(=O)[O-]]

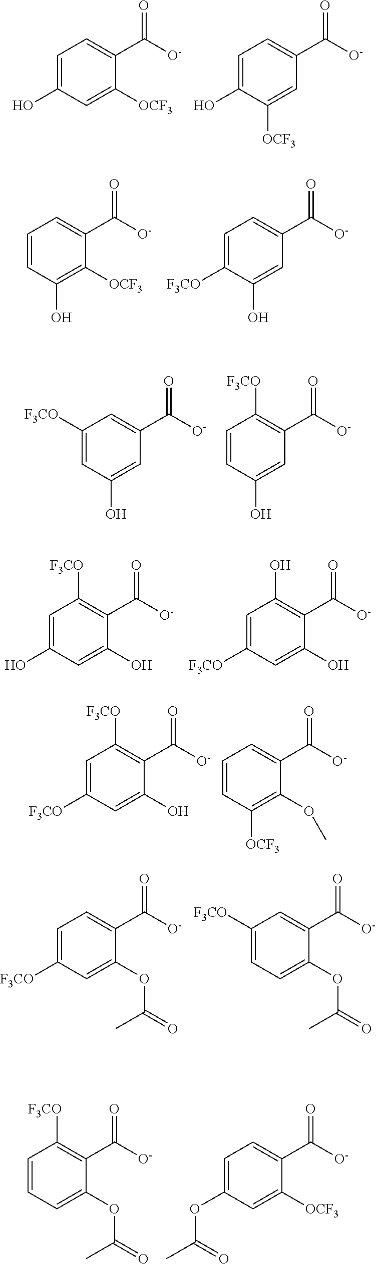

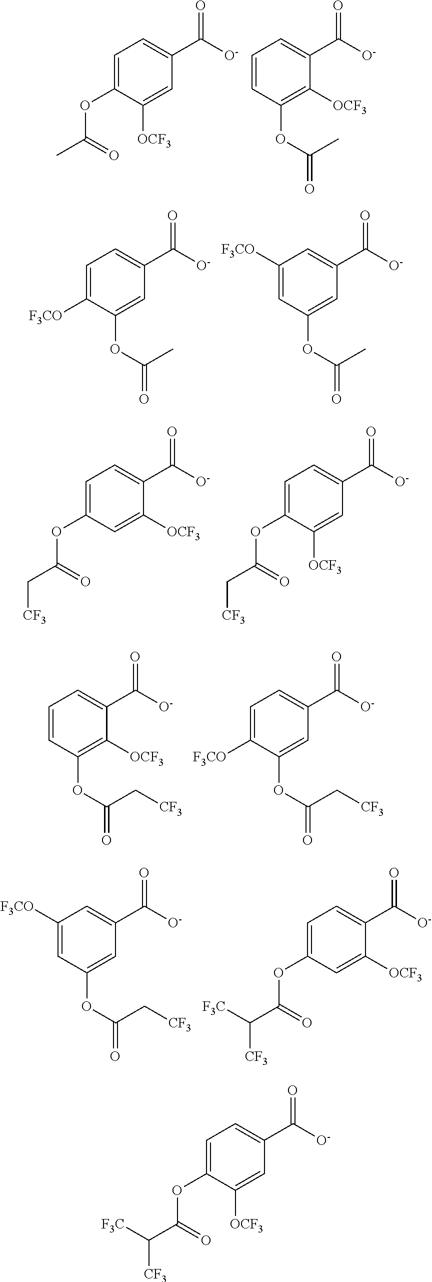

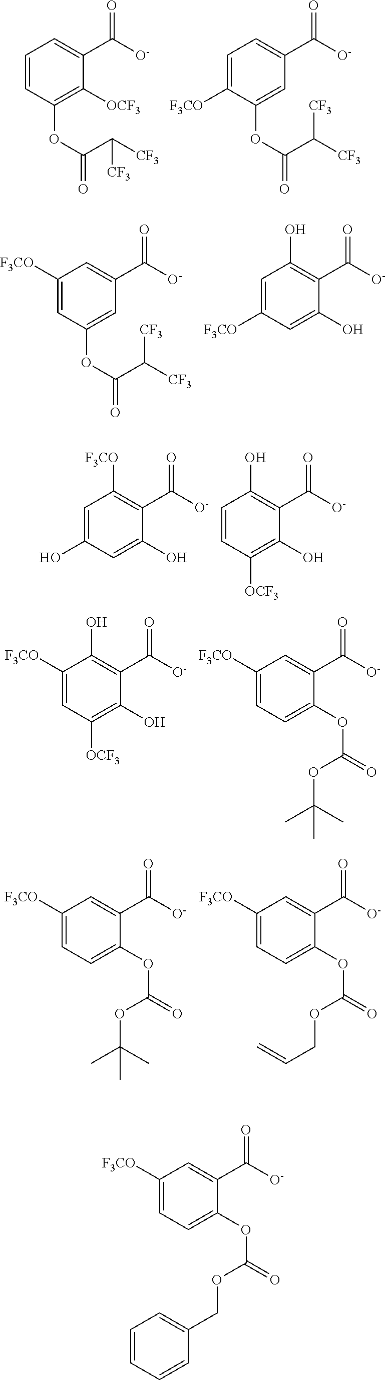

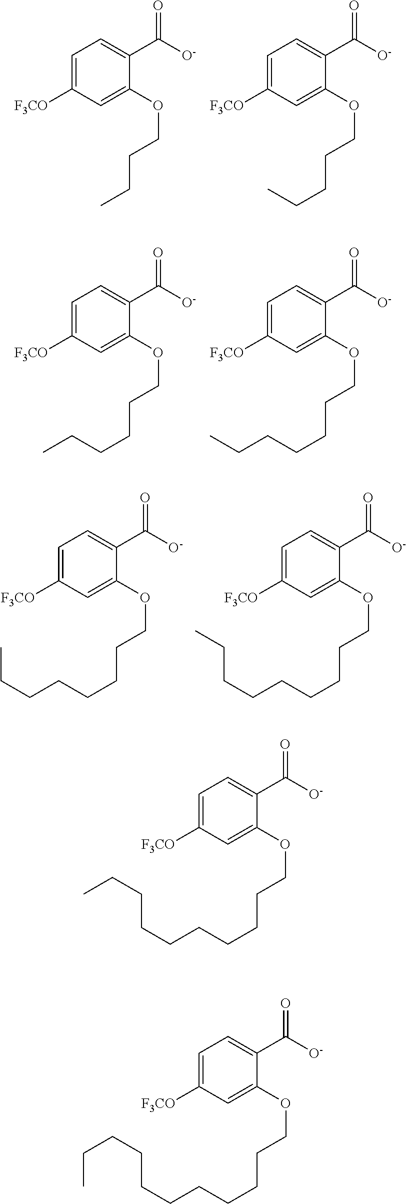

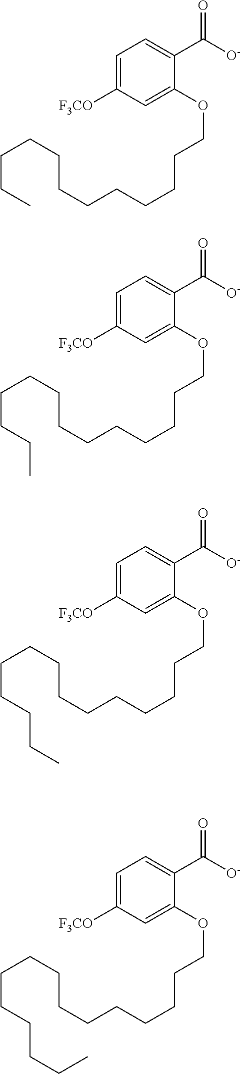 [SMILES: CCCCCCCCCCCCOc1cc(OC(F)(F)F)ccc1C(=O)[O-] ; CCCCCCCCCCCCCOc1cc(OC(F)(F)F)ccc1C(=O)[O-] ; CCCCCCCCCCCCCCOc1cc(OC(F)(F)F)ccc1C(=O)[O-] ; CCCCCCCCCCCCCCCOc1cc(OC(F)(F)F)ccc1C(=O)[O-]]

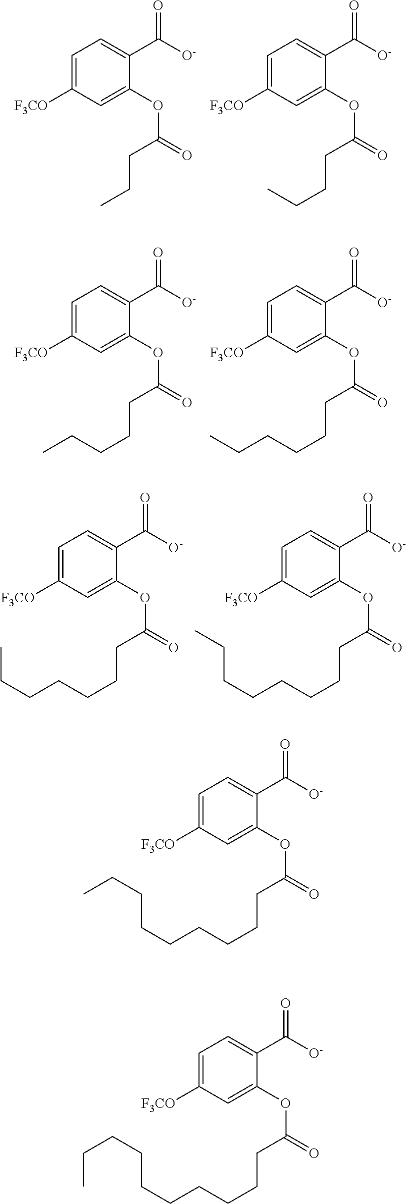

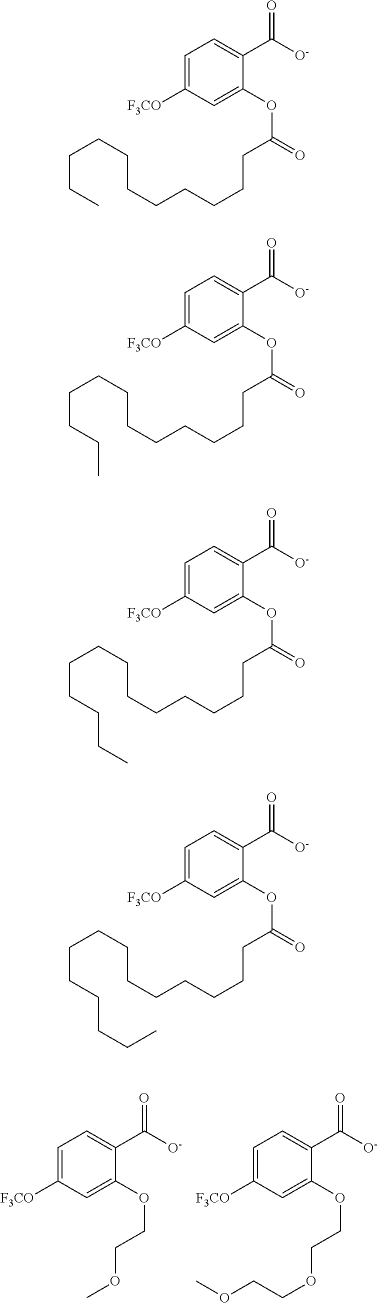 [SMILES: CCCCCCCCCCCC(=O)Oc1cc(OC(F)(F)F)ccc1C(=O)[O-] ; CCCCCCCCCCCCC(=O)Oc1cc(OC(F)(F)F)ccc1C(=O)[O-] ; CCCCCCCCCCCCCC(=O)Oc1cc(OC(F)(F)F)ccc1C(=O)[O-] ; CCCCCCCCCCCCCCC(=O)Oc1cc(OC(F)(F)F)ccc1C(=O)[O-] ; COCCOc1cc(OC(F)(F)F)ccc1C(=O)[O-] ; COCCOCCOc1cc(OC(F)(F)F)ccc1C(=O)[O-]]

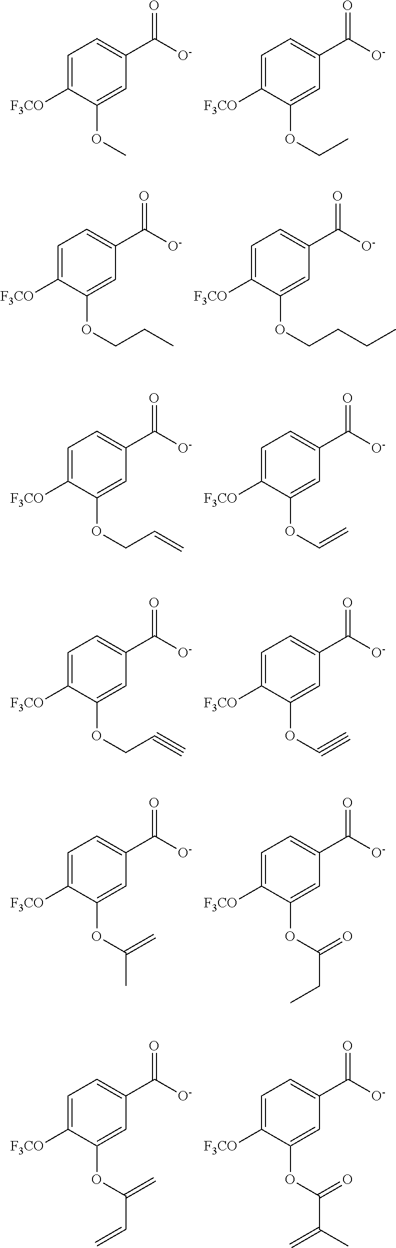

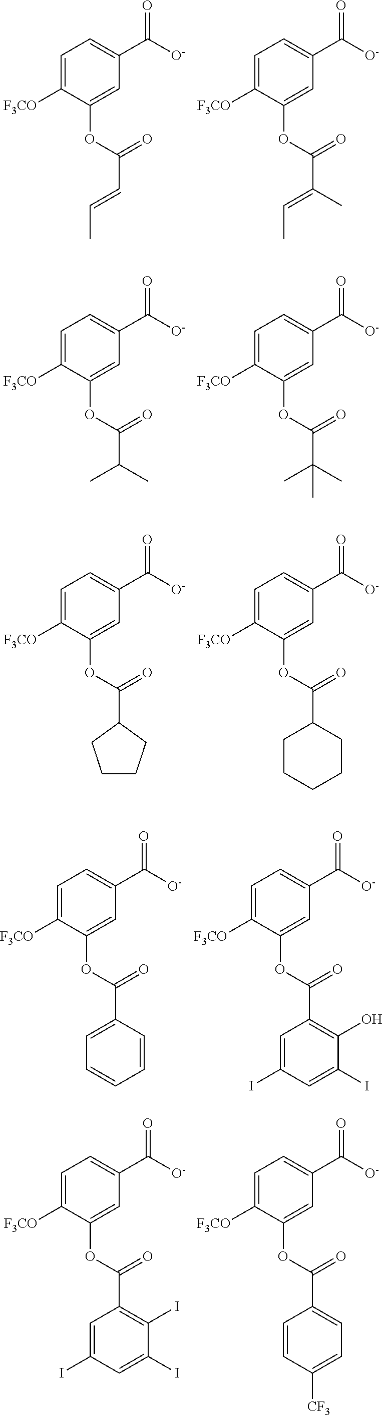

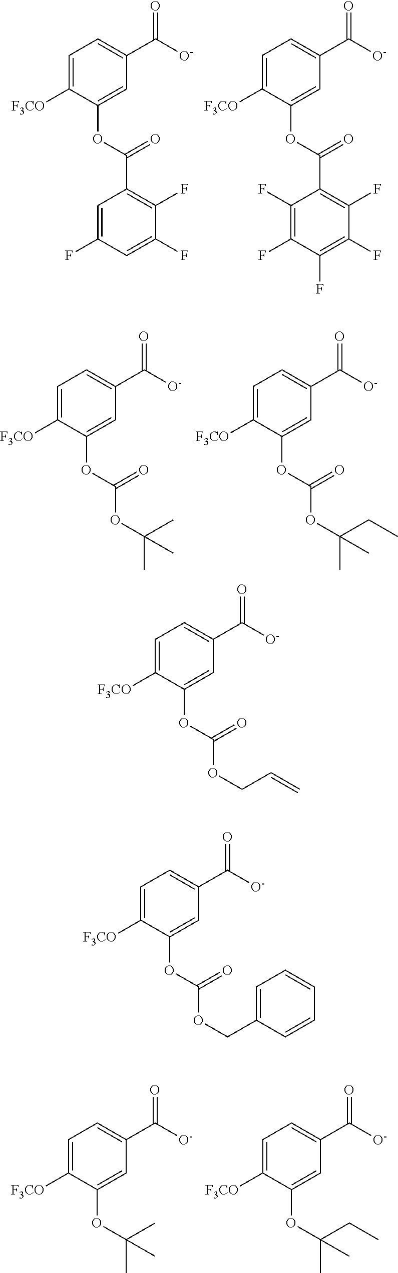

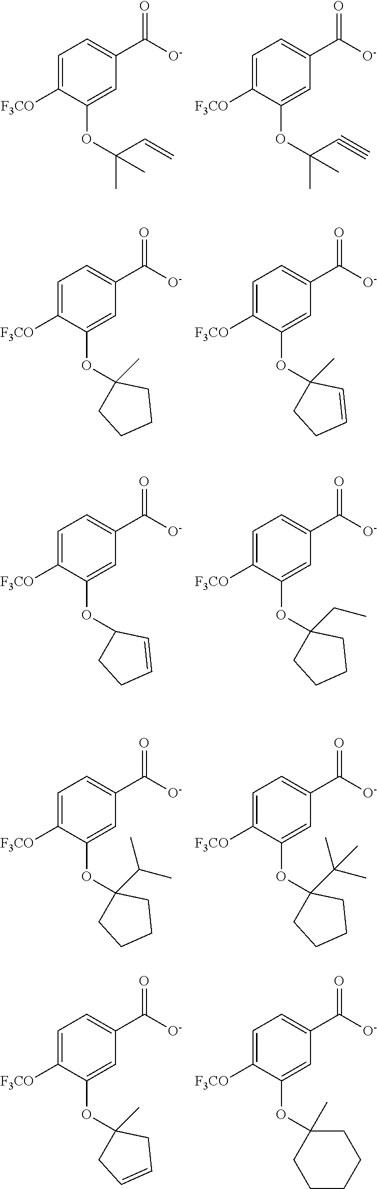

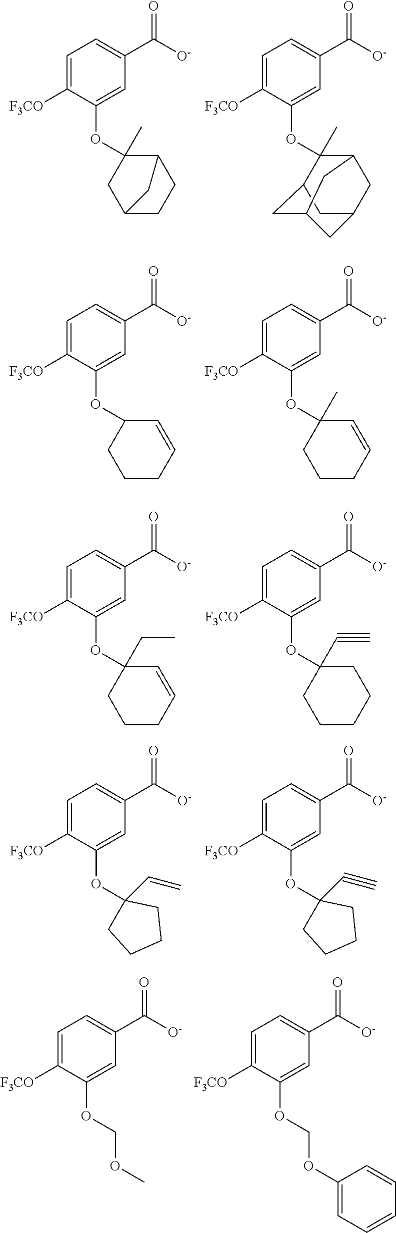

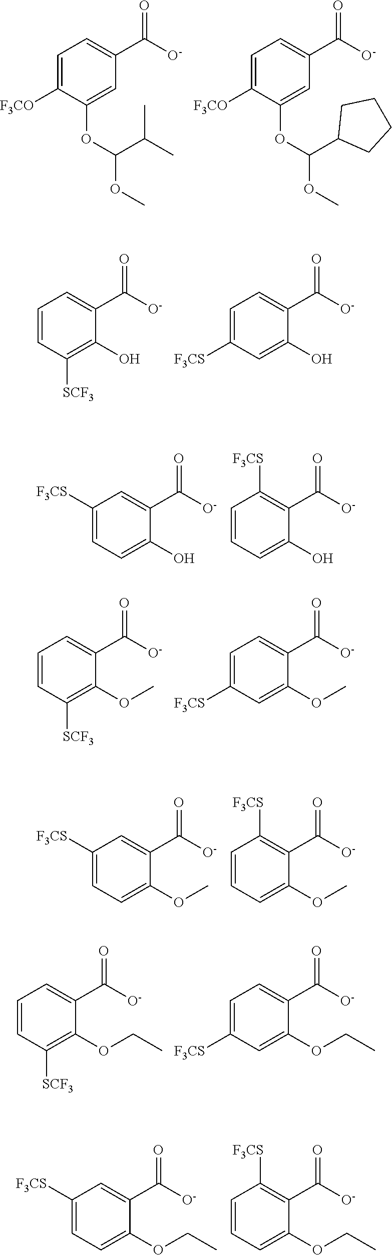

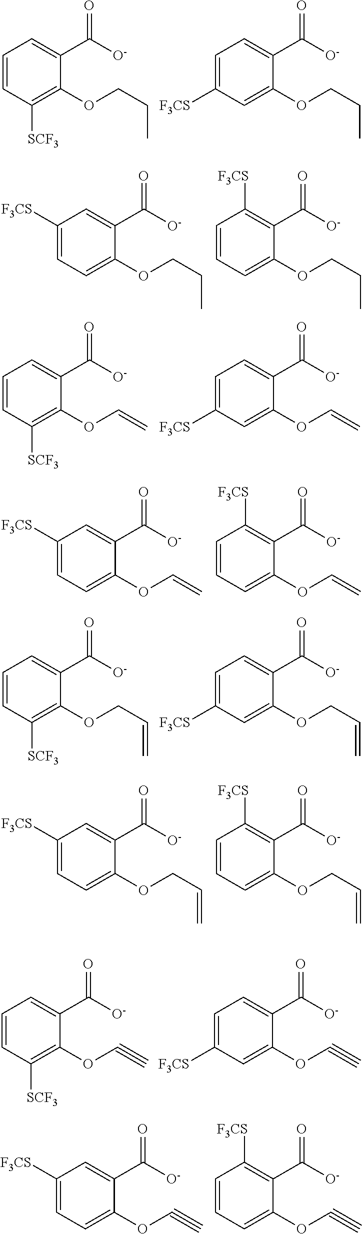

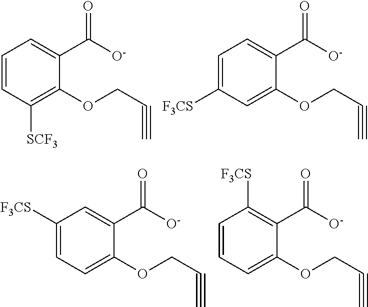

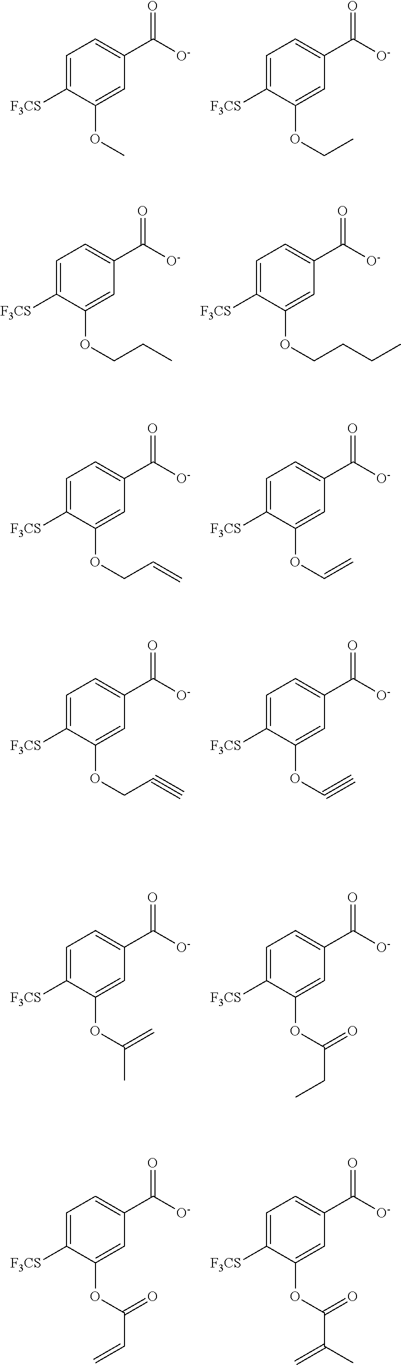

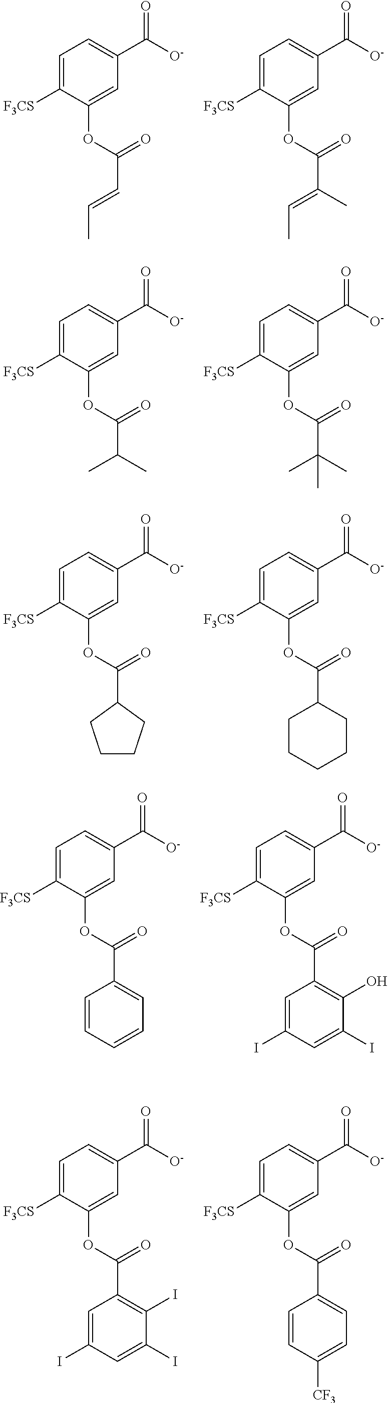

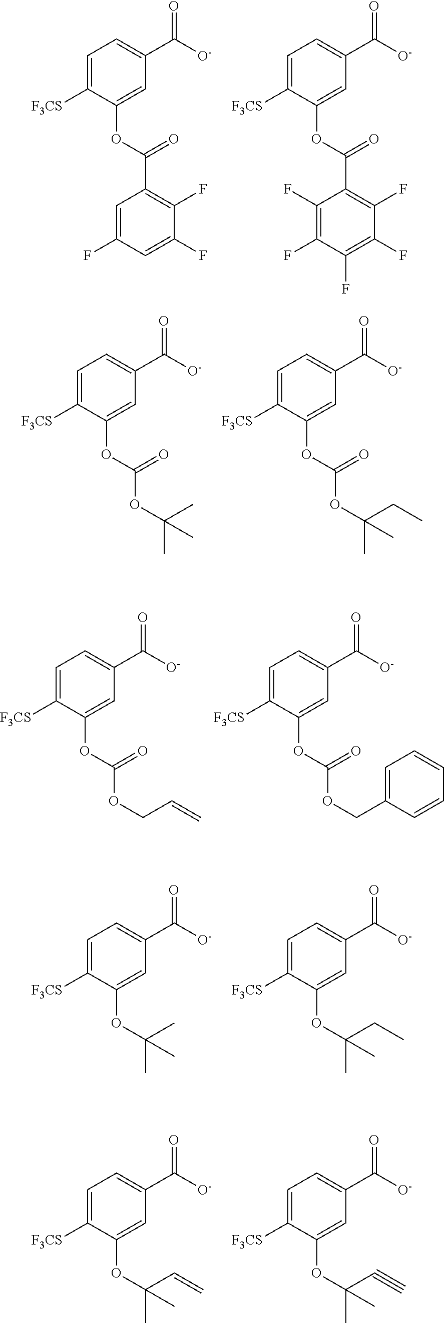

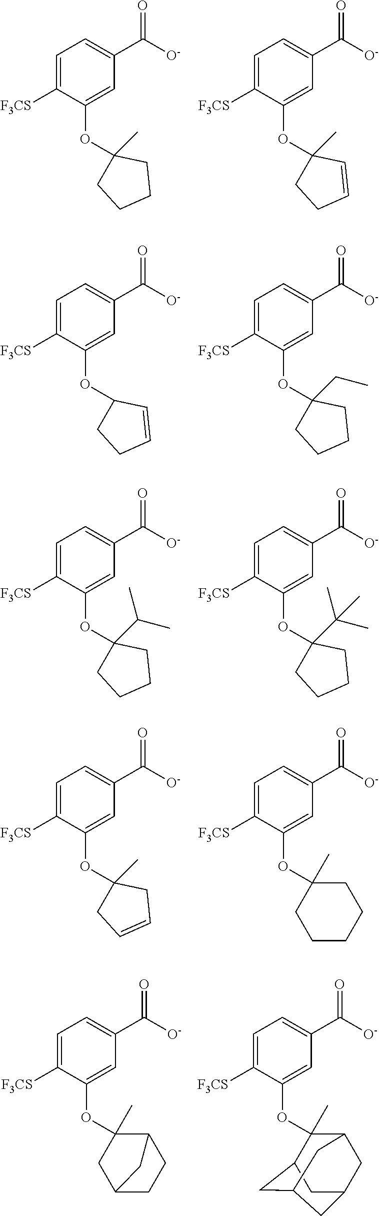

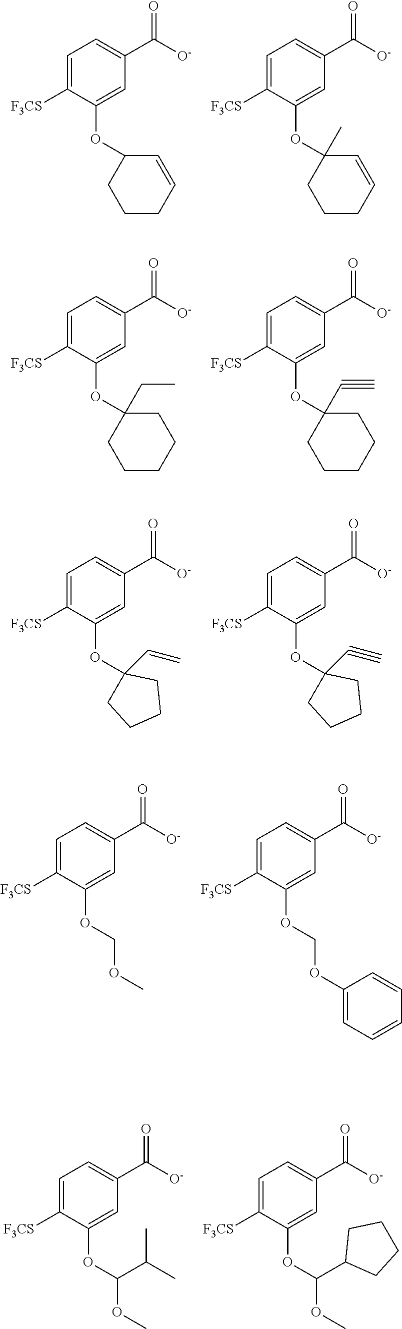

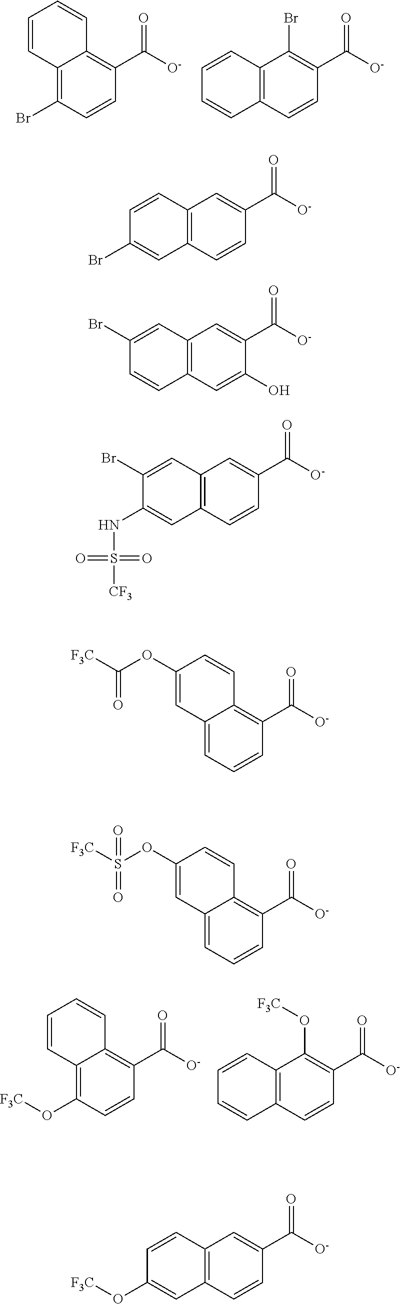

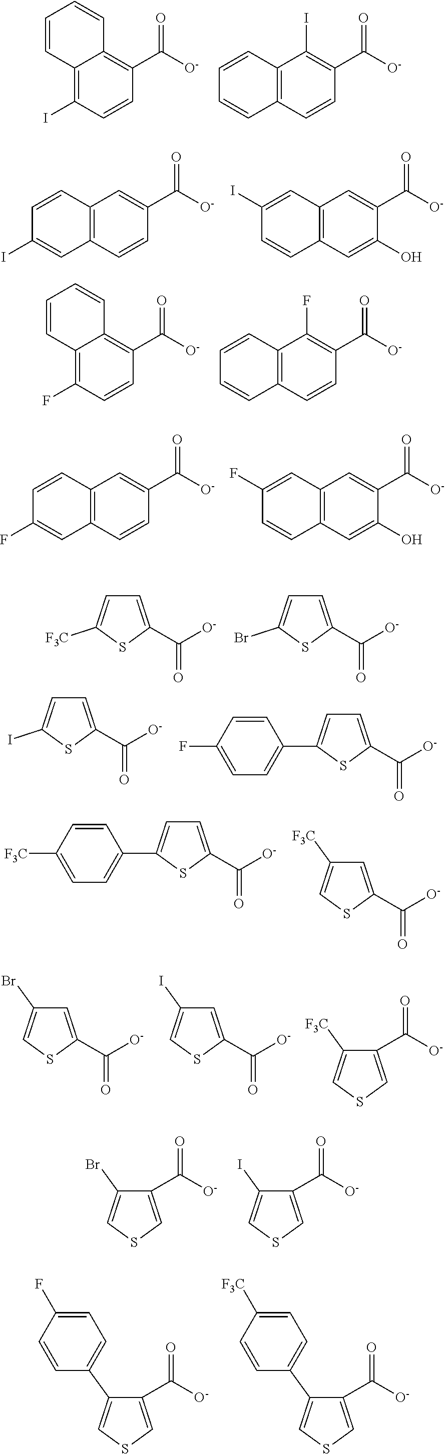

Examples of the method for synthesizing the sulfonium salt include a method in which the sulfonium salt having the sulfonium cation is ion-exchanged with the ammonium salt having the anion or the protic acid having the anion. The sulfonium cation can be obtained, for example, by reaction of a dibenzothiophene compound having a hydrocarbylcarbonyl group or a hydrocarbyloxycarbonyl group with a diphenyliodonium salt.

The content of the sulfonium salt in the resist composition of the present invention is preferably 0.001 to 50 parts by weight and more preferably 0.01 to 40 parts by weight per 100 parts by weight of a base polymer described below. The sulfonium salt may be used alone or in combination of two or more kinds thereof

Base Polymer

The resist composition of the present invention may comprise a base polymer. In the case of a positive resist composition, the base polymer includes repeat units containing an acid labile group. The preferred repeat units containing an acid labile group are repeat units having the following formula (a 1) (also referred to as repeat units a 1, hereinafter) or repeat units having the following formula (a2) (also referred to as repeat units a2, hereinafter).

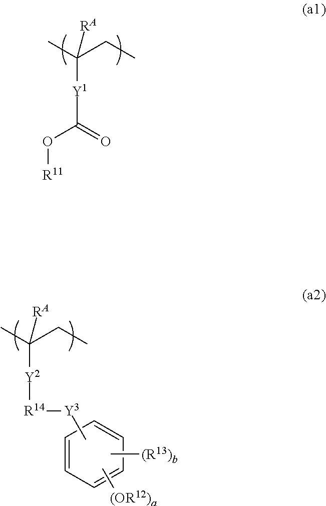

In formulae (a1) and (a2), R^{A} is each independently a hydrogen atom or a methyl group. Y¹ is a single bond, a phenylene group, a naphthylene group, or a C₁-C₁₂ linking group containing at least one selected from an ester bond and a lactone ring. Y² is a single bond or an ester bond. Y³ is a single bond, an ether bond, or an ester bond. R¹¹ and R¹² are each independently an acid labile group. It is noted that when the base polymer includes both the repeat units a1 and the repeat units a2, R¹¹ and R¹² may be the same as or different from each other. R¹³ is a fluorine atom, a trifluoromethyl group, a cyano group, or a C₁-C₆ saturated hydrocarbyl group. R¹⁴ is a single bond or a C₁-C₆ alkanediyl group in which some of carbon atoms may be replaced by an ether bond or an ester bond. a is 1 or 2. b is an integer of 0 to 4. Provided that 1≤a+b≤5.

Examples of the monomer from which repeat units a 1 are derived are shown below, but not limited thereto. In the following formula, R^{A} and R¹¹ are as defined above.

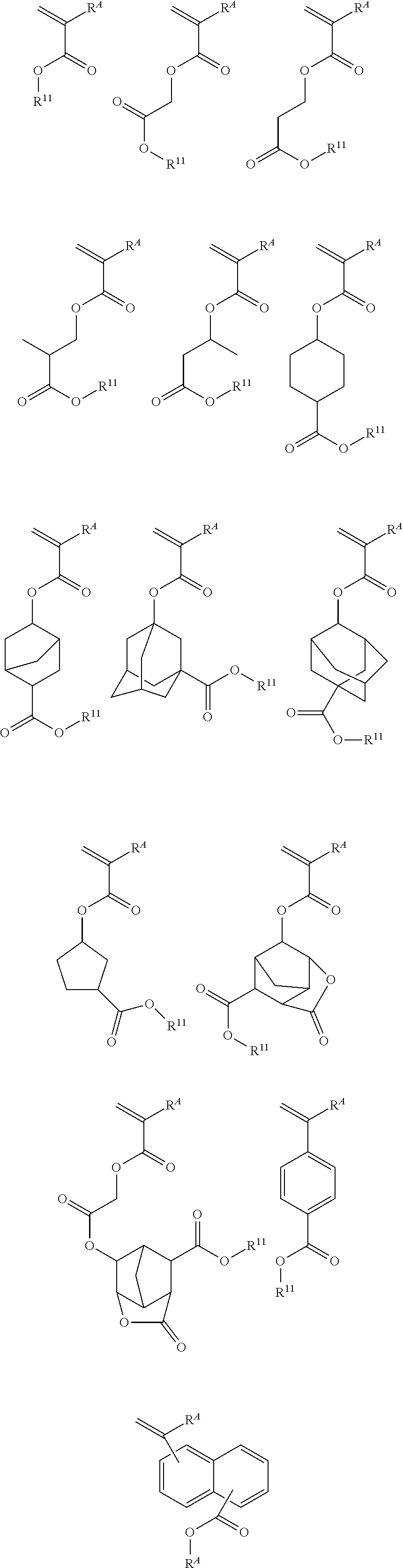

Examples of the monomer from which repeat units a2 are derived are shown below, but not limited thereto. In the following formula, R^{A} and R¹² are as defined above.

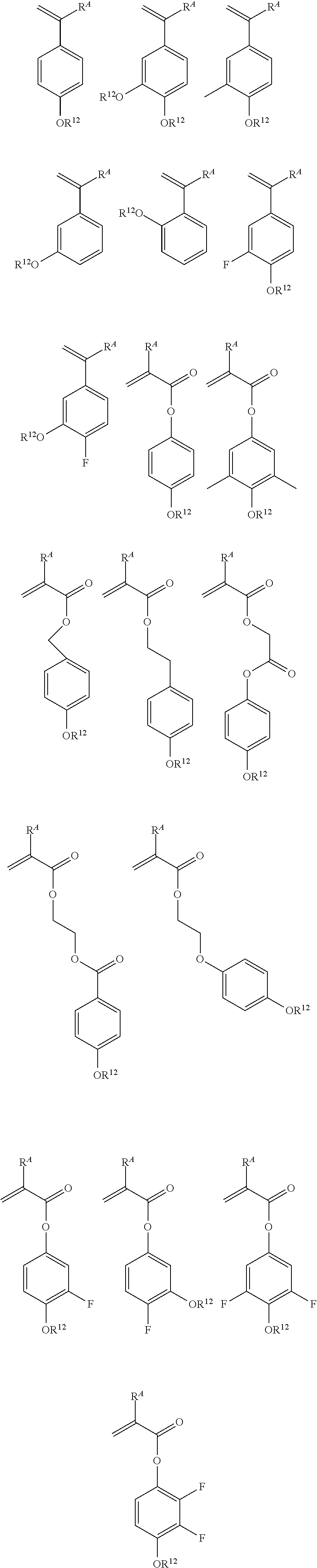

Examples of the acid labile groups represented by R^{4A}, R¹¹, and R¹² in formulae (1), (a1), and (a2) include those groups described in JP-A 2013-80033 and JP-A 2013-83821.

Typical examples of the acid labile group include groups having the following formulae (AL-1) to (AL-3).

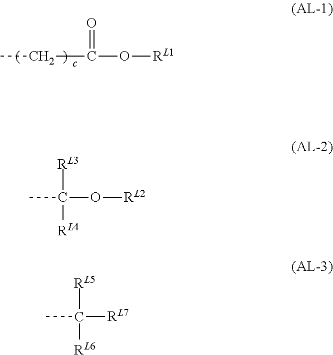

wherein the broken line denotes a point of attachment.

In formulae (AL-1) and (AL-2), R^{L1} and R^{L2} are each independently a C₁-C₄₀ hydrocarbyl group, which may contain a heteroatom such as an oxygen atom, a sulfur atom, a nitrogen atom, or a fluorine atom. The hydrocarbyl group may be saturated or unsaturated and straight, branched, or cyclic. The hydrocarbyl group is preferably a C₁-C₄₀ saturated hydrocarbyl group and more preferably a C₁-C₂₀ saturated hydrocarbyl group.

In formula (AL-1), c is an integer of 0 to 10 and preferably an integer of 1 to 5.

In formula (AL-2). R^{L3} and R^{L4} are each independently a hydrogen atom or a C₁-C₂₀ hydrocarbyl group, which may contain a heteroatom such as an oxygen atom, a sulfur atom, a nitrogen atom, or a fluorine atom. The hydrocarbyl group may be saturated or unsaturated and straight, branched, or cyclic. The hydrocarbyl group is preferably a C₁-C₂₀ saturated hydrocarbyl group. Any two of R^{L2}, R^{L3}, and R^{L4} may bond together to form a C₃-C₂₀ ring with the carbon atom or carbon and oxygen atoms to which they are attached. The ring is preferably a C₄-C₁₆ ring and particularly preferably an alicyclic ring.

In formula (AL-3), R^{L5}, R^{L6}, and R^{L7} are each independently a C₁-C₂₀ hydrocarbyl group, which may contain a heteroatom such as an oxygen atom, a sulfur atom, a nitrogen atom, or a fluorine atom. The hydrocarbyl group may be saturated or unsaturated and straight, branched, or cyclic. The hydrocarbyl group is preferably a C₁-C₂₀ saturated hydrocarbyl group. Any two of R^{L5}, R^{L6}, and R^{L7} may bond together to form a C₃-C₂₀ ring with the carbon atom to which they are attached. The ring is preferably a C₄-C₁₆ ring and particularly preferably an alicyclic ring.

The base polymer may include repeat units b having a phenolic hydroxy group as an adhesive group. Examples of the monomer from which repeat units b are derived are shown below, but not limited thereto. In the following formula, R^{A} is as defined above.

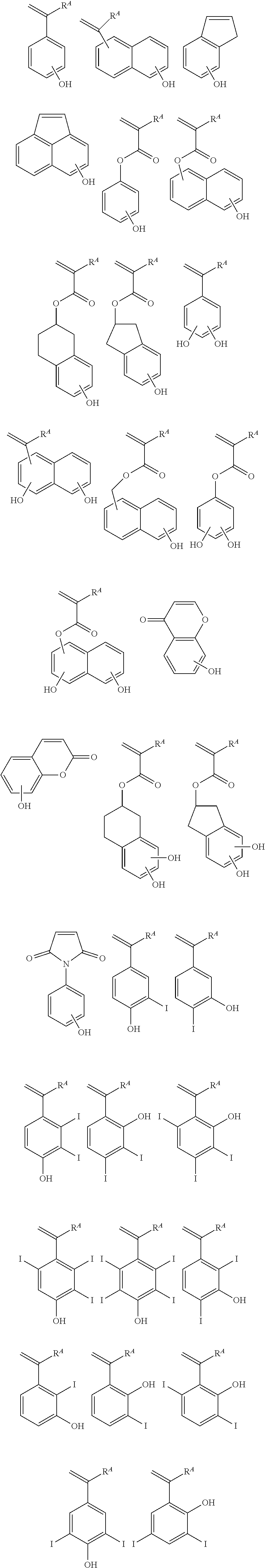

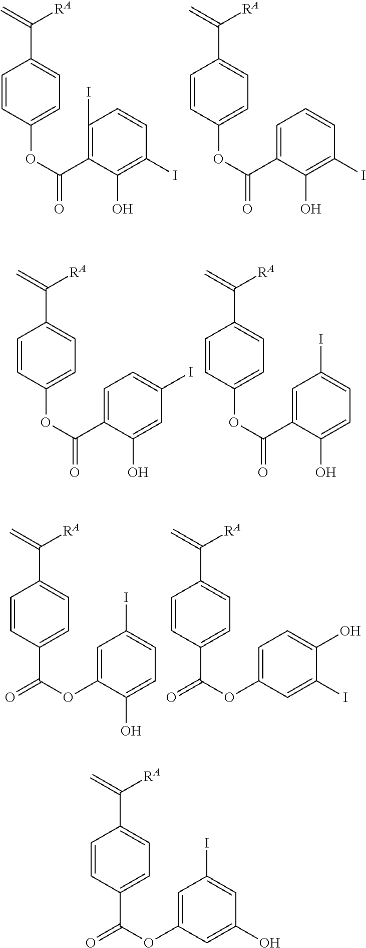

The base polymer may include, as another adhesive group, repeat units c containing a hydroxy group other than the phenolic hydroxy group, a lactone ring, a sultone ring, an ether bond, an ester bond, a sulfonate bond, a carbonyl group, a sulfonyl group, a cyano group, or a carboxy group. Examples of the monomer from which repeat units c are derived are shown below, but not limited thereto. In the following formula, R^{A} is as defined above.

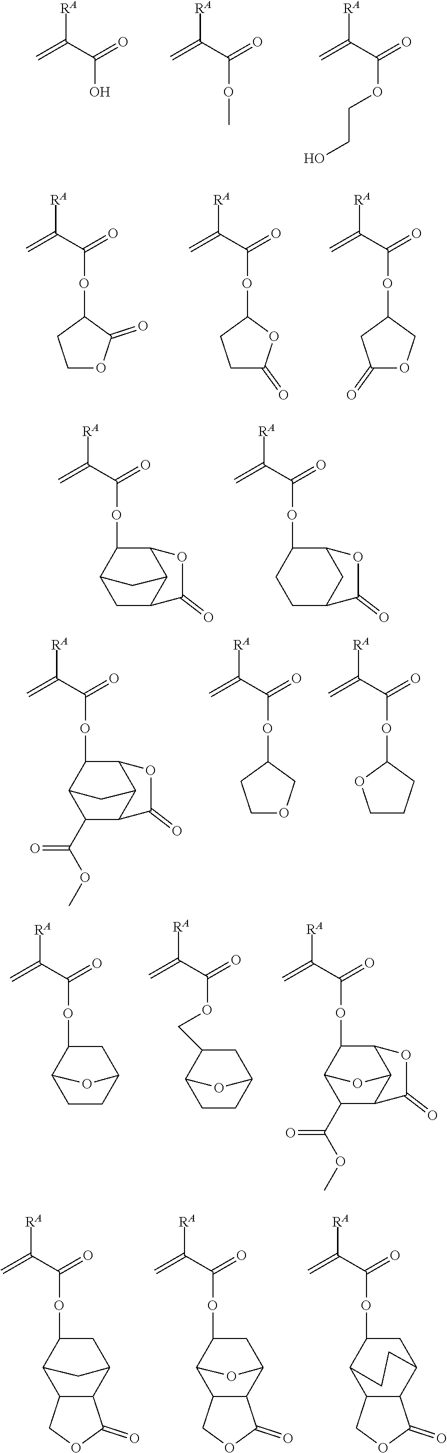

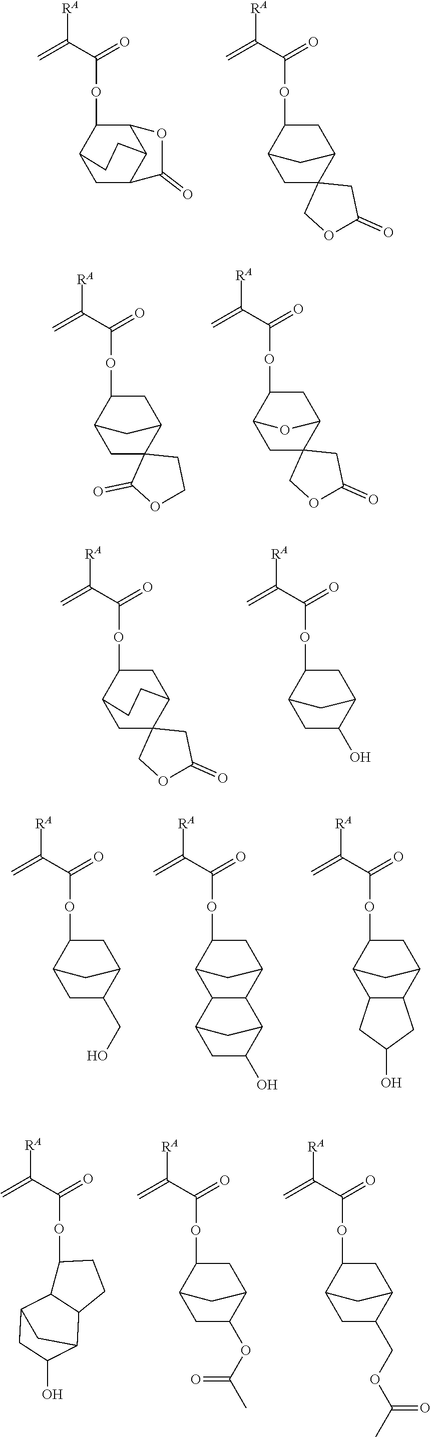

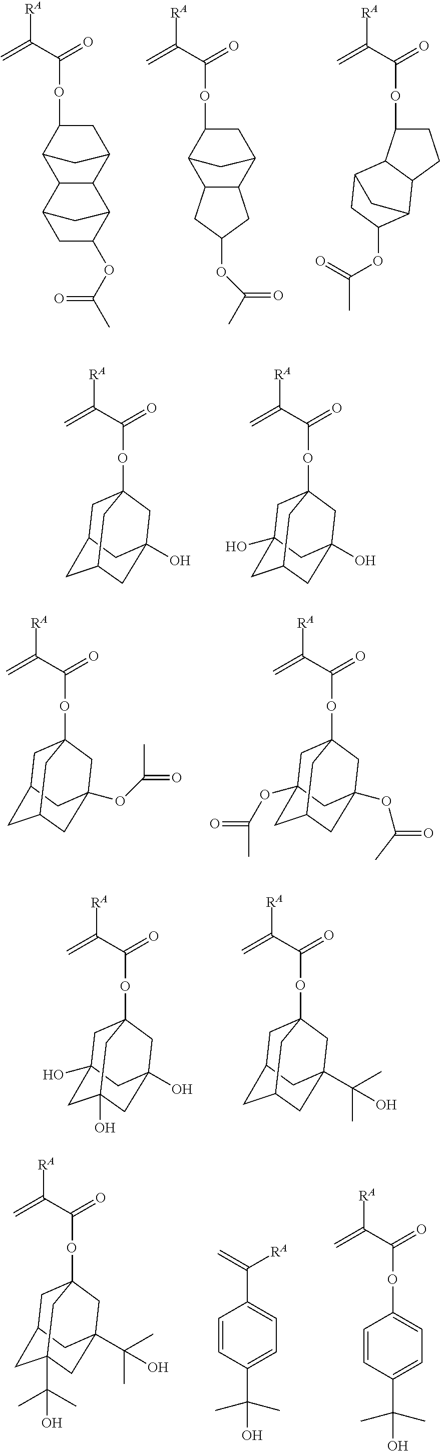

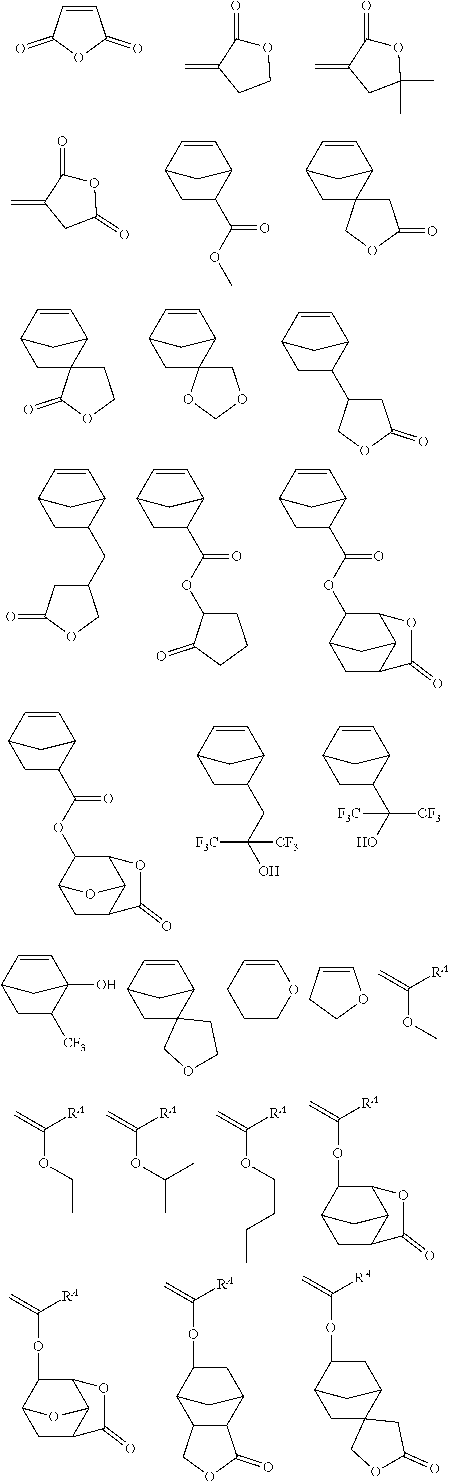

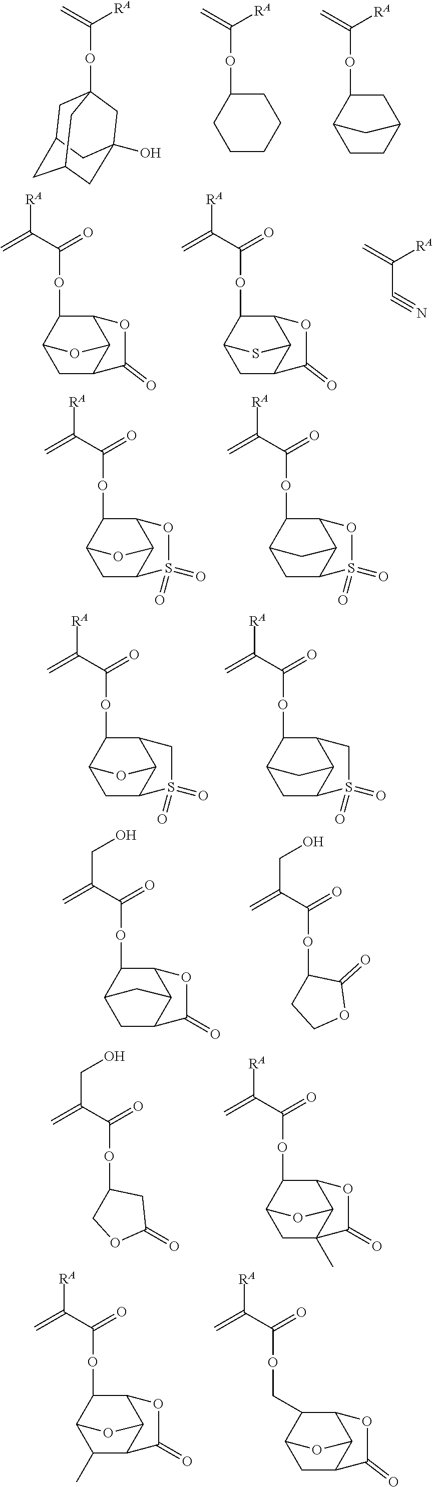

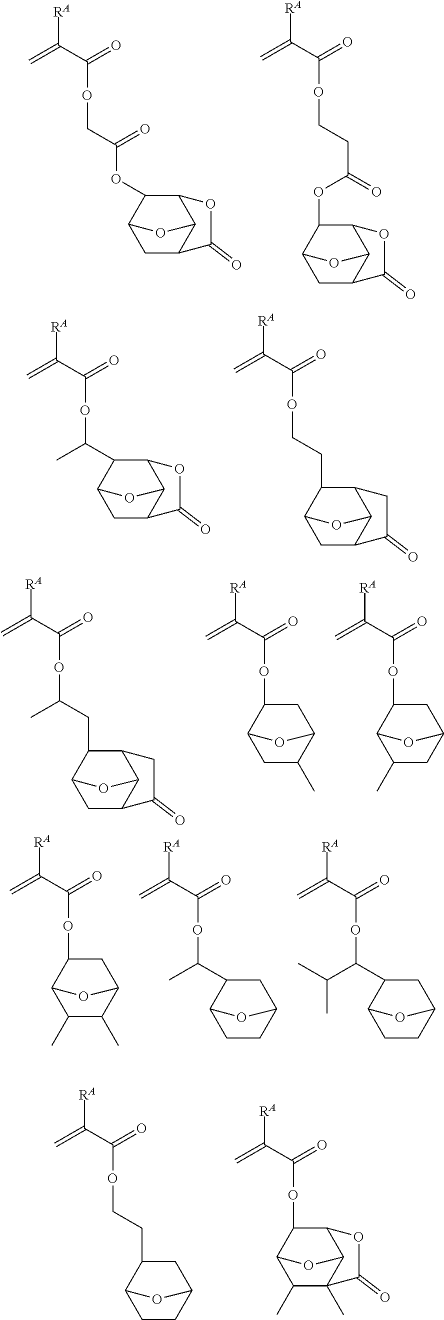

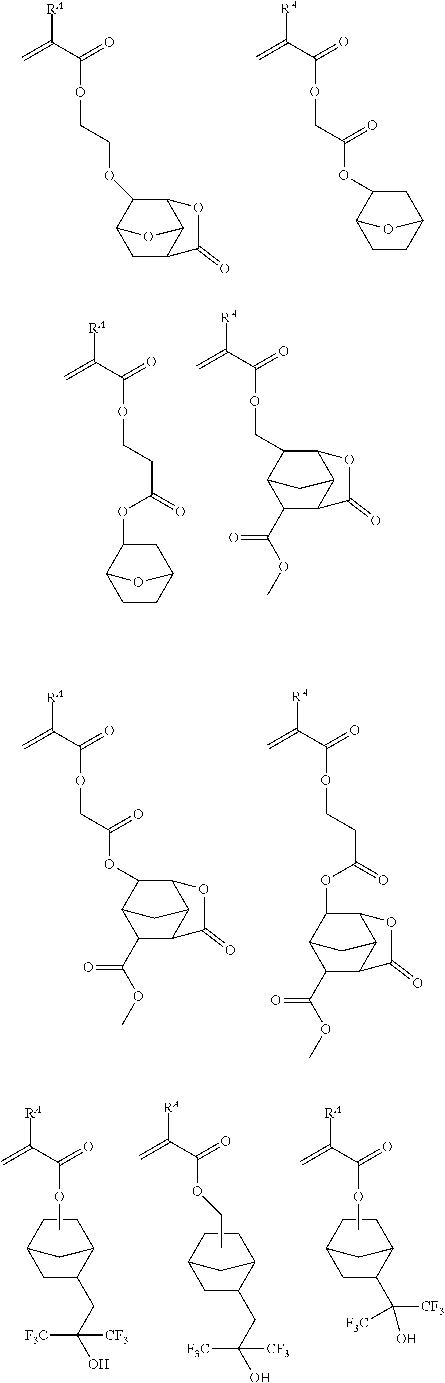

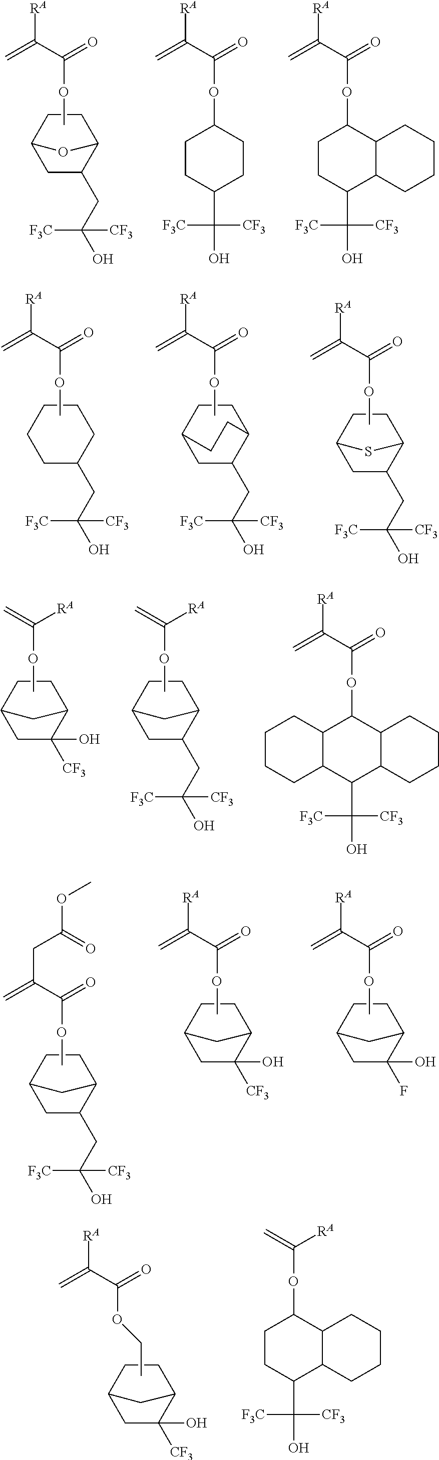

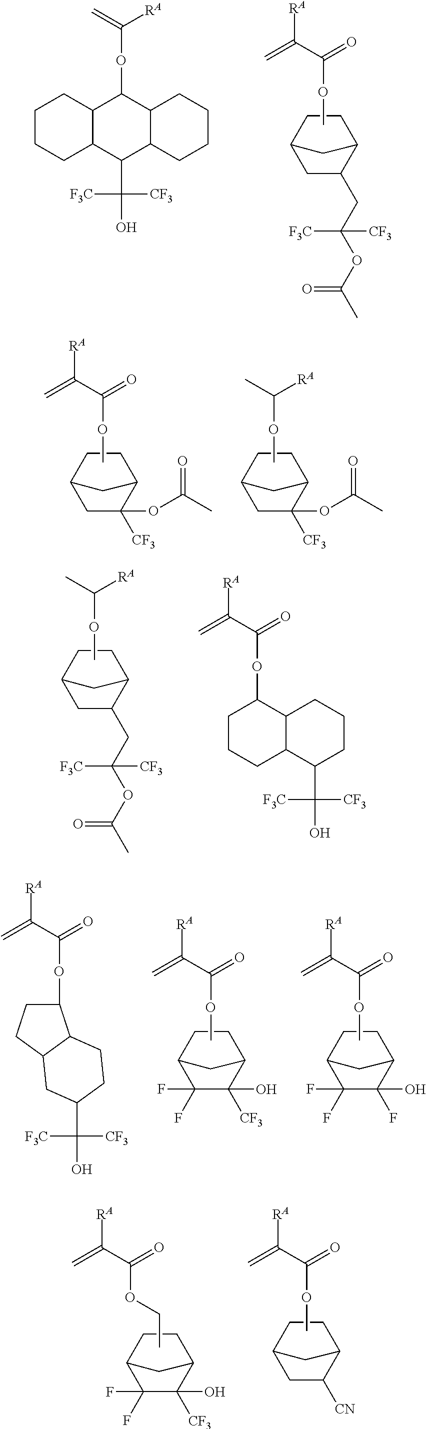

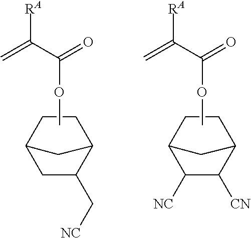

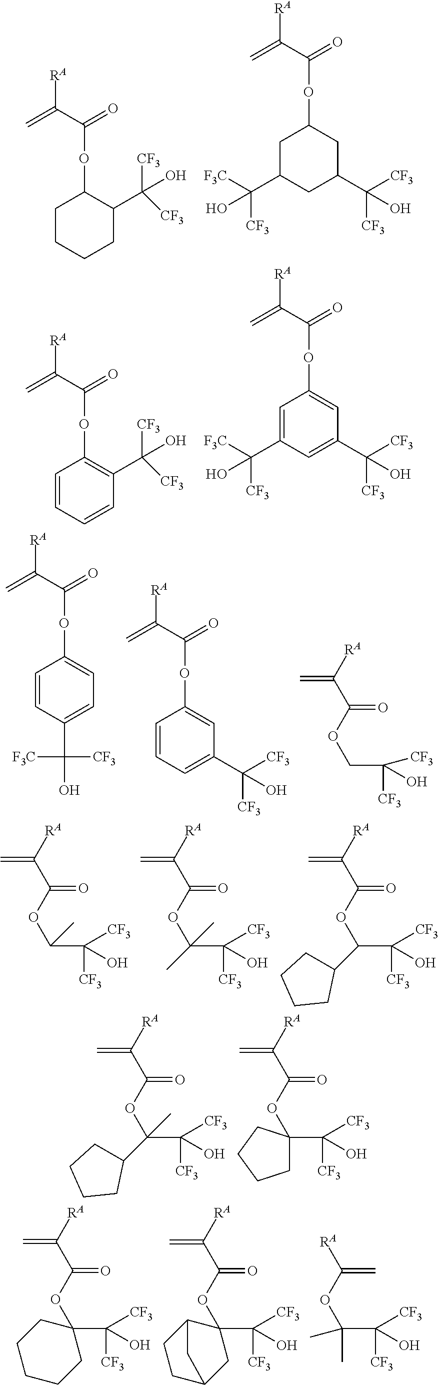

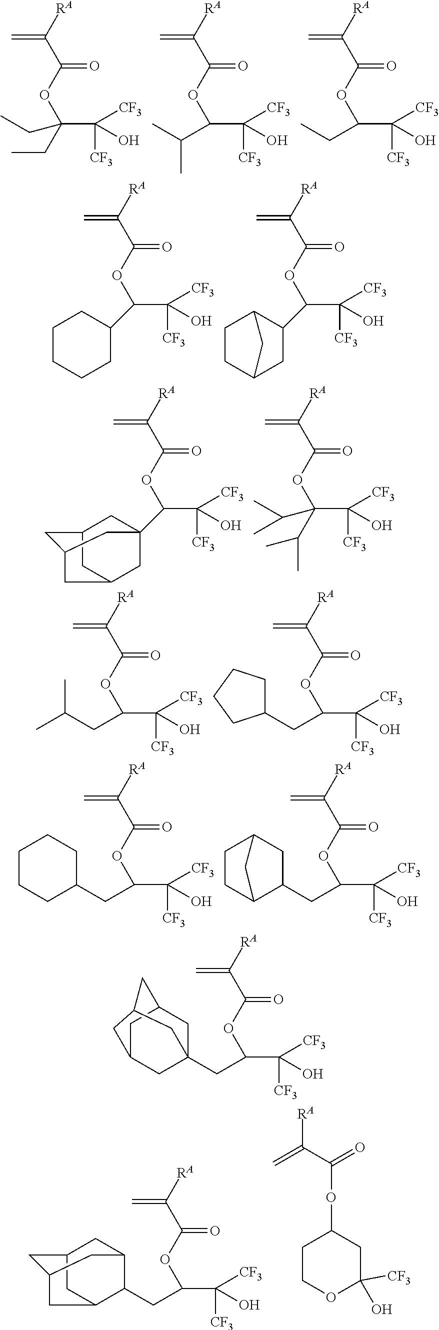

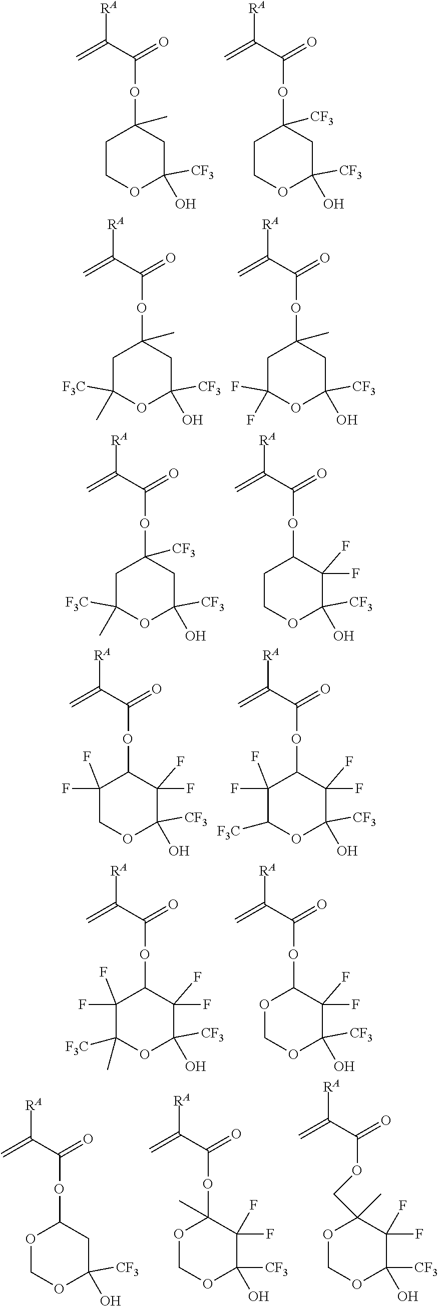

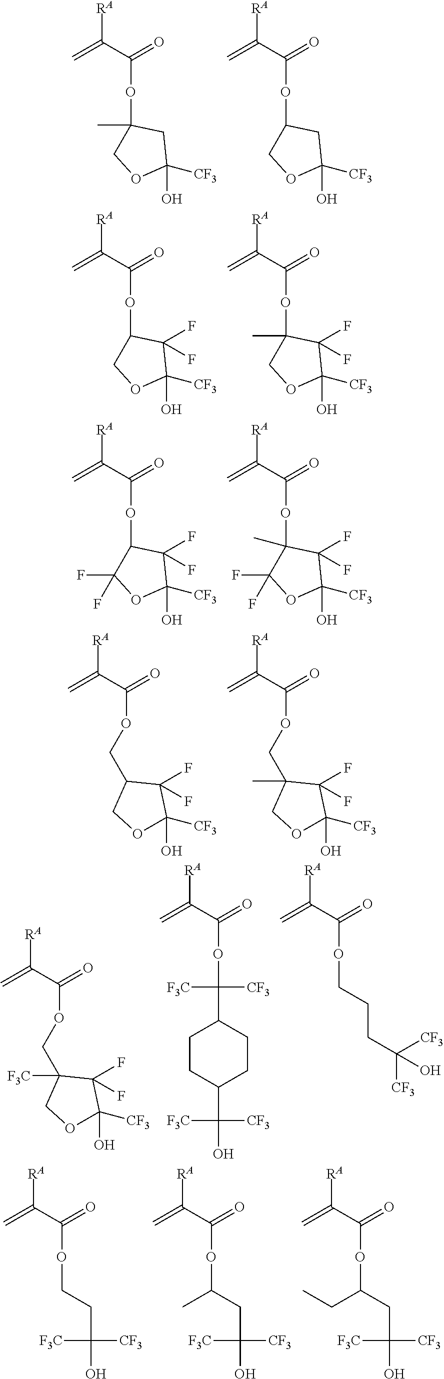

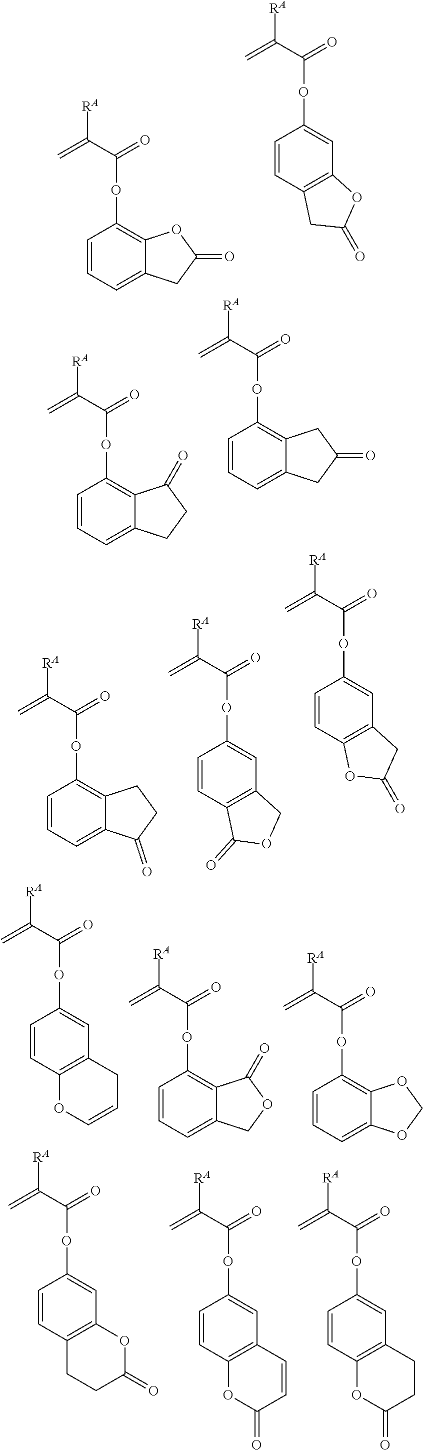

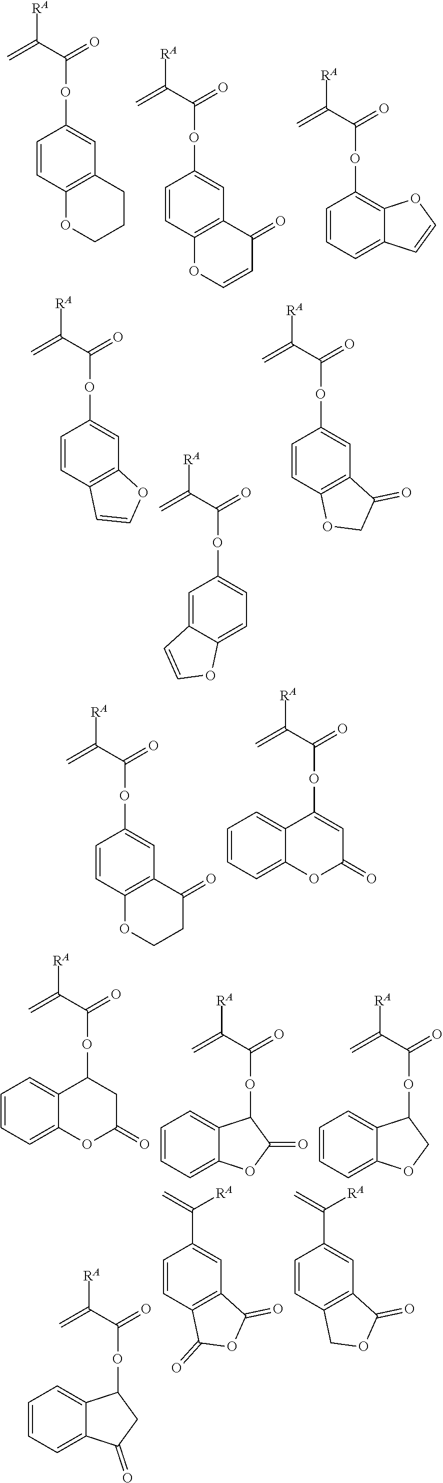

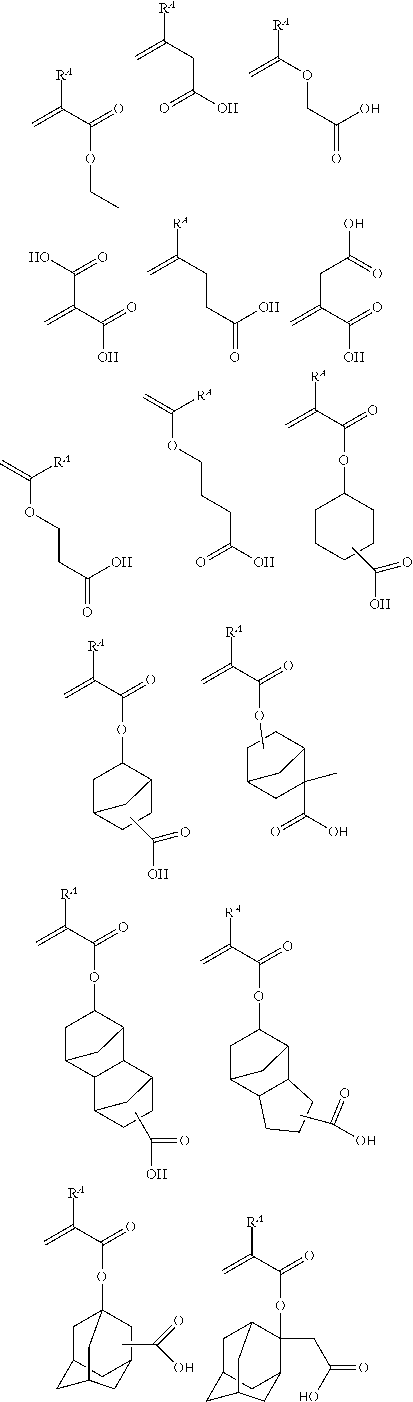

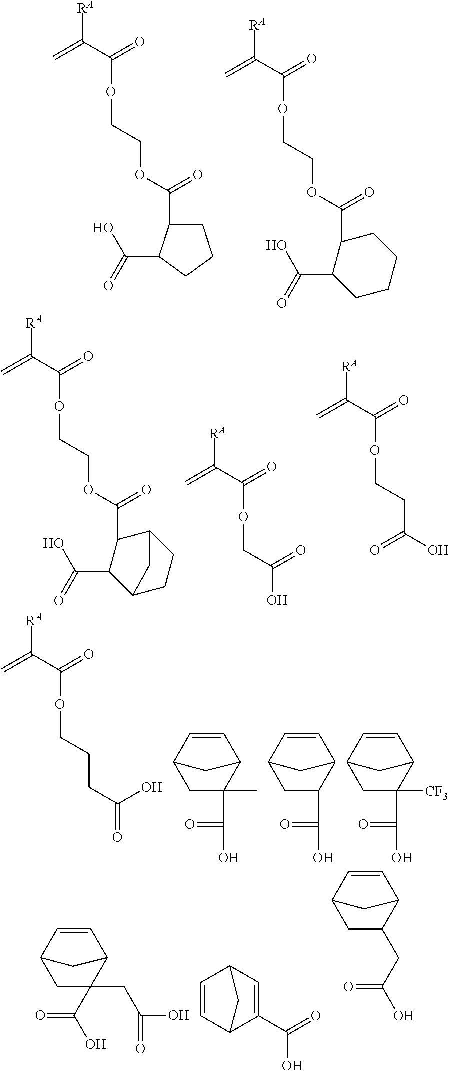

The base polymer may include repeat units d derived from indene, benzofuran, benzothiophene, acenaphthylene, chromone, coumarin, norbornadiene, or derivatives thereof. Examples of the monomer from which repeat units d are derived are shown below, but not limited thereto.

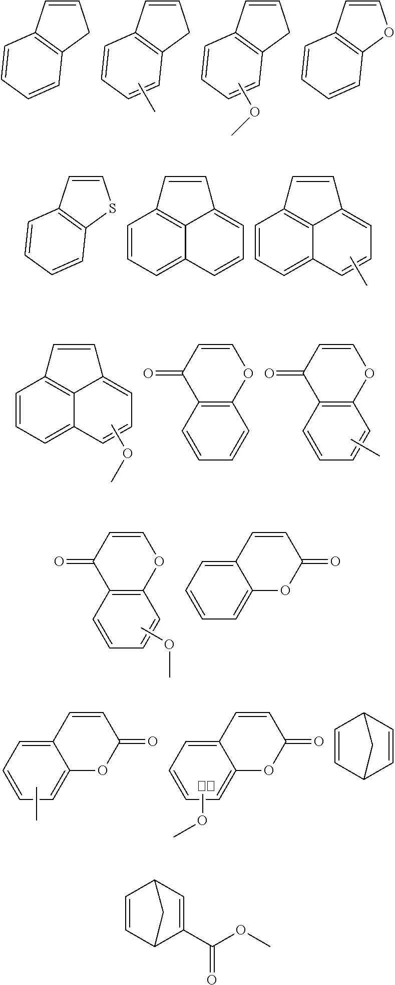

The base polymer may include repeat units e derived from styrene, vinylnaphthalene, vinylanthracene, vinylpyrene, methyleneindene, vinylpyridine, or vinylcarbazole.

The base polymer may include repeat units f derived from an onium salt having a polymerizable unsaturated bond. Examples of the preferable repeat units f include repeat units having the following formula (f1) (also referred to as repeat units f1, hereinafter), repeat units having the following formula (f) (also referred to as repeat units f2, hereinafter), and repeat units having the following formula (f3) (also referred to as repeat units f3, hereinafter). The repeat units f1 to f3 may be used alone or in combination of two or more kinds thereof.

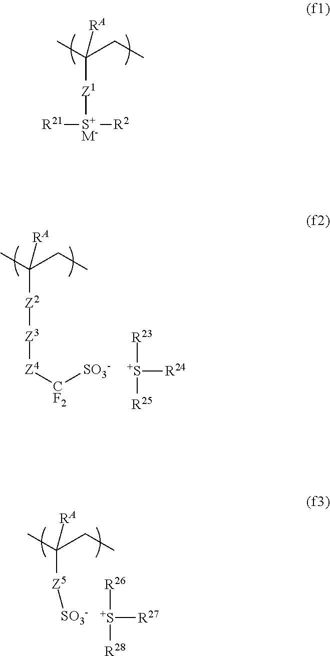

In formulae (f1) to (f3), R^{A} is each independently a hydrogen atom or a methyl group. Z¹ is a single bond, a C₁-C₆ aliphatic hydrocarbylene group, a phenylene group, a naphthylene group, or a C₇-C₁₈ group obtained by combining the foregoing, or —O—Z¹¹—, —C(═O)—O—Z¹¹—, or —C(═O)NH—Z¹¹—. Z¹¹ is a C₁-C₆ aliphatic hydrocarbylene group, a phenylene group, a naphthylene group, or a C₇-C₁₈ group obtained by combining the foregoing, which may contain a carbonyl group, an ester bond, an ether bond, or a hydroxy group. Z² is a single bond or an ester bond. Z³ is a single bond, —Z³¹—C(═O)—O—, —Z³¹—O—, or —Z³¹—O—C(═O)—. Z³¹ is a C₁-C₁₂ aliphatic hydrocarbylene group, a phenylene group, or a C₇-C₁₈ group obtained by combining the foregoing, which may contain a carbonyl group, an ester bond, an ether bond, an iodine atom, or a bromine atom. Z⁴ is a methylene group, a 2,2,2-trifluoro-1,1-ethanediyl group, or a carbonyl group. Z⁵ is a single bond, a methylene group, an ethylene group, a phenylene group, a fluorinated phenylene group, a trifluoromethyl-substituted phenylene group, —O—Z⁵¹—, —C(═O)—O—Z⁵¹—, or —C(═O)—NH—Z⁵¹—. Z⁵¹ is a C₁-C₆ aliphatic hydrocarbylene group, a phenylene group, a fluorinated phenylene group, or a trifluoromethyl-substituted phenylene group, which may contain a carbonyl group, an ester bond, an ether bond, a halogen atom, or a hydroxy group.

In formulae (f1) to (f3), R²¹ to R²⁸ are each independently a halogen atom, or a C₁-C₂₀ hydrocarbyl group which may contain a heteroatom. The hydrocarbyl group may be saturated or unsaturated and straight, branched, or cyclic. Specific examples of the halogen atom and the hydrocarbyl group are as exemplified for the halogen atom and the hydrocarbyl group represented by R¹⁰¹ to R¹⁰⁵ in the description of formulae (3-1) and (3-2) described below. Some or all of the hydrogen atoms in the hydrocarbyl group may be substituted with a group containing a heteroatom such as an oxygen atom, a sulfur atom, a nitrogen atom, or a halogen atom, some of —CH₂— in the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, an ester bond, a sulfonate bond, a carbonate bond, a lactone ring, a sultone ring, a carboxylic anhydride (—C(═O)—O—C(═O)—), a haloalkyl group, or the like. A pair of R²³ and R²⁴ or R²⁶ and R²⁷ may bond together to form a ring with a sulfur atom to which they are attached. In this case, examples of the ring are as exemplified for the ring that R¹⁰¹ and R¹⁰² in the description of formulae (3-1) and (3-2) described below may bond together to form with the sulfur atom to which they are attached.

In formula (f1), M⁻is a non-nucleophilic counter ion. Examples of the non-nucleophilic counter ion include halide ions such as chloride ions and bromide ions; fluoroalkylsulfonate ions such as triflate ions, 1,1,1-trifluoroethanesulfonate ions, and nonafluorobutanesulfonate ions; arylsulfonate ions such as tosylate ions, benzenesulfonate ions, 4-fluorobenzenesulfonate ions, and 1,2,3,4,5-pentafluorobenzenesulfonate ions; alkylsulfonate ions such as mesylate ions and butanesulfonate ions; imide ions such as bis(trifluoromethylsulfonyl)imide ions, bis(perfluoroethylsulfonyl)imide ions, and bis(perfluorobutylsulfonyl)imide ions; and methide ions such as tris(trifluoromethylsulfonyl)methide ions and tris(perfluoroethylsulfonyl)methide ions.

Other examples of the non-nucleophilic counter ion include sulfonate ions having fluorine substituted at α-position as represented by the following formula (f1-1) and sulfonate ions having fluorine substituted at α-position and trifluoromethyl at β-position as represented by the following formula (f1-2).

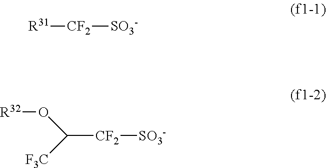

In formula (f1-1), R³¹ is a hydrogen atom or a C₁-C₂₀ hydrocarbyl group which may contain an ether bond, an ester bond, a carbonyl group, a lactone ring, or a fluorine atom. The hydrocarbyl group may be saturated or unsaturated and straight, branched, or cyclic. Specific examples thereof are as exemplified for the hydrocarbyl group represented by R^{id} in formula (3A′) described below.

In formula (f1-2), R³² is a hydrogen atom, or a C₁-C₁₀ hydrocarbyl group or C₆-C₂₀ hydrocarbylcarbonyl group, which may contain an ether bond, an ester bond, a carbonyl group, or a lactone ring. The hydrocarbyl moiety of the hydrocarbyl group and the hydrocarbylcarbonyl group may be saturated or unsaturated and straight, branched, or cyclic. Specific examples thereof are as exemplified for the hydrocarbyl group represented by R^{fa1} in formula (3A′) described below.

Examples of the cation of the monomer from which repeat units f1 are derived are shown below, but not limited thereto. In the following formula, R^{A} is as defined above.

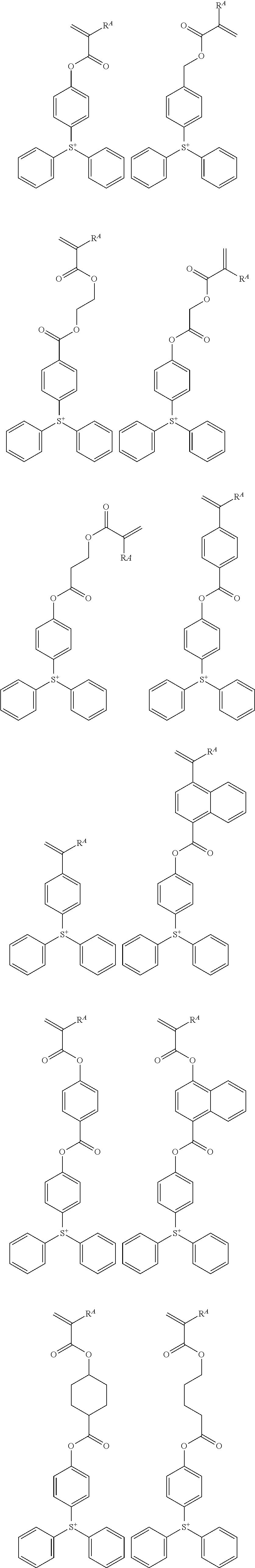

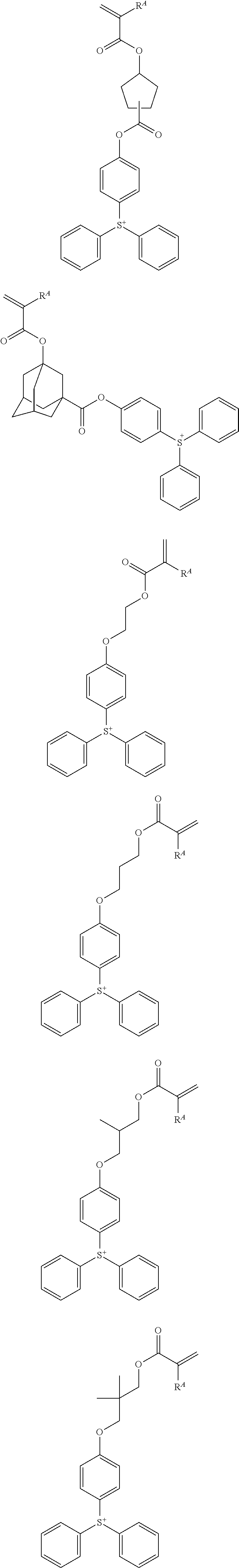

Examples of the cation of the monomer salt from which repeat units f2 or f3 are derived are exemplified for the sulfonium cation having formula (1) and the cation of the sulfonium salt having formula (3-1) described below.

Examples of the anion of the monomer from which repeat units 12 are derived are shown below, but not limited thereto. In the following formula, R^{A} is as defined above.

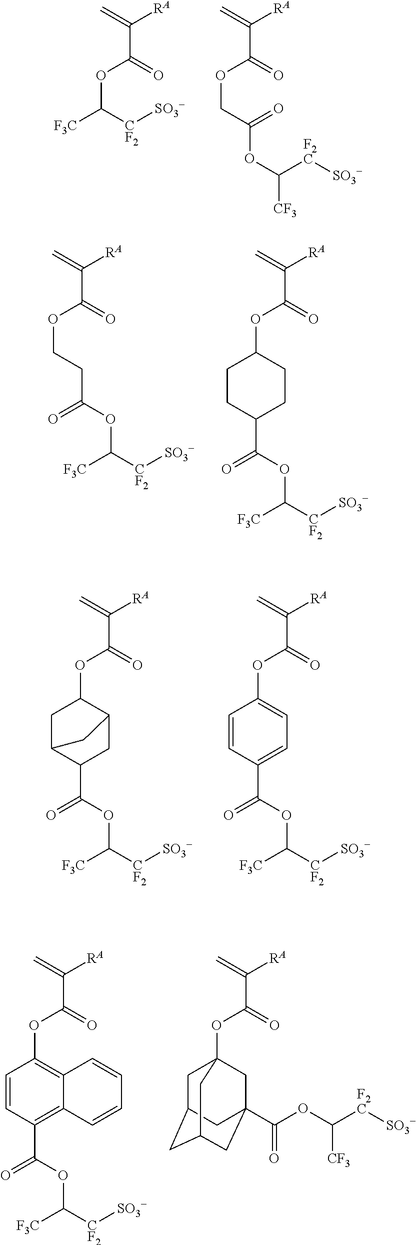

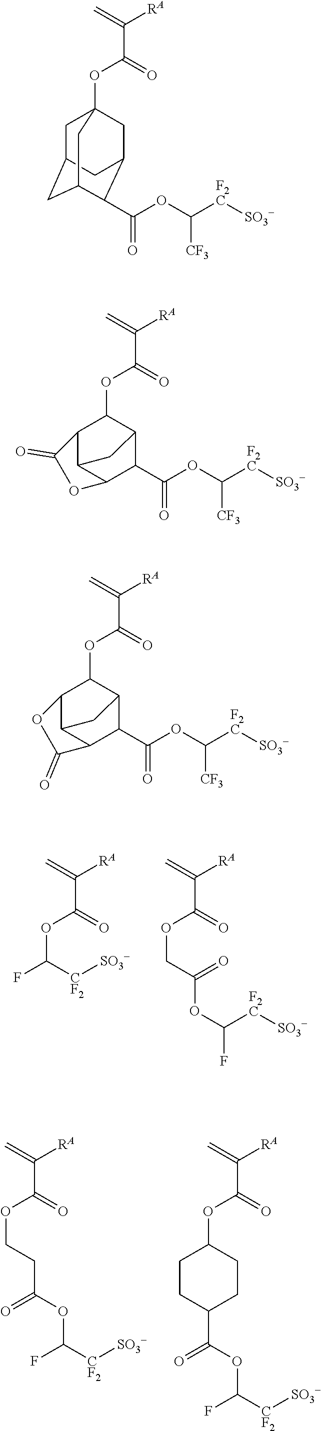

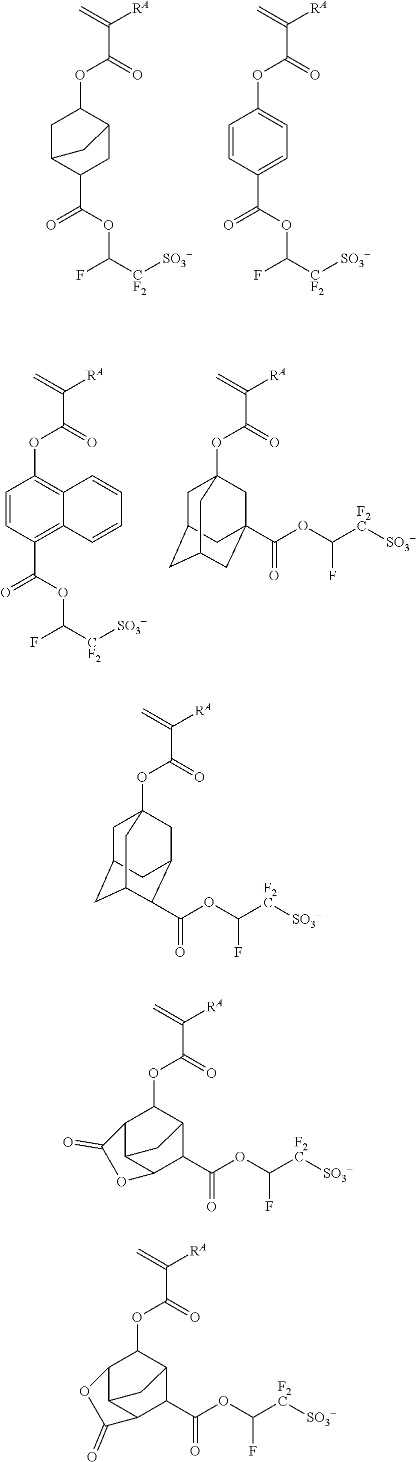

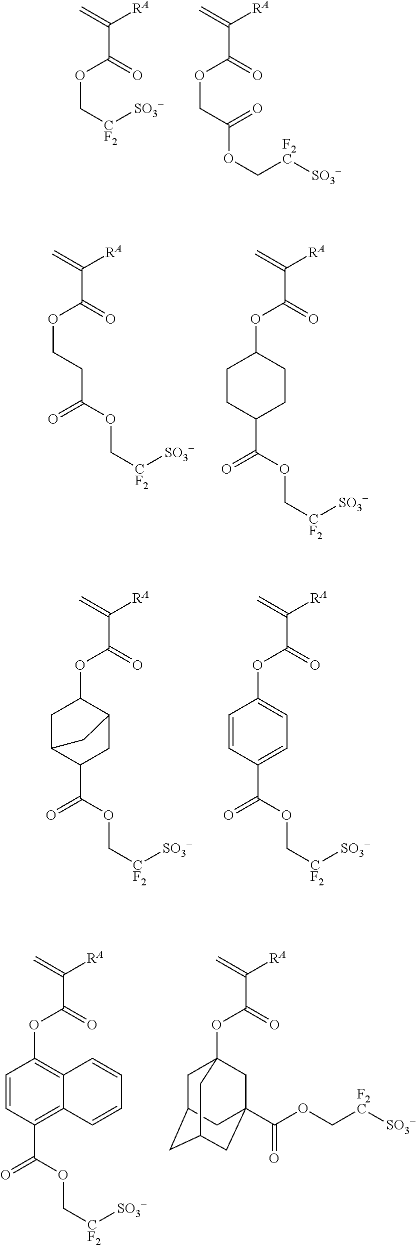

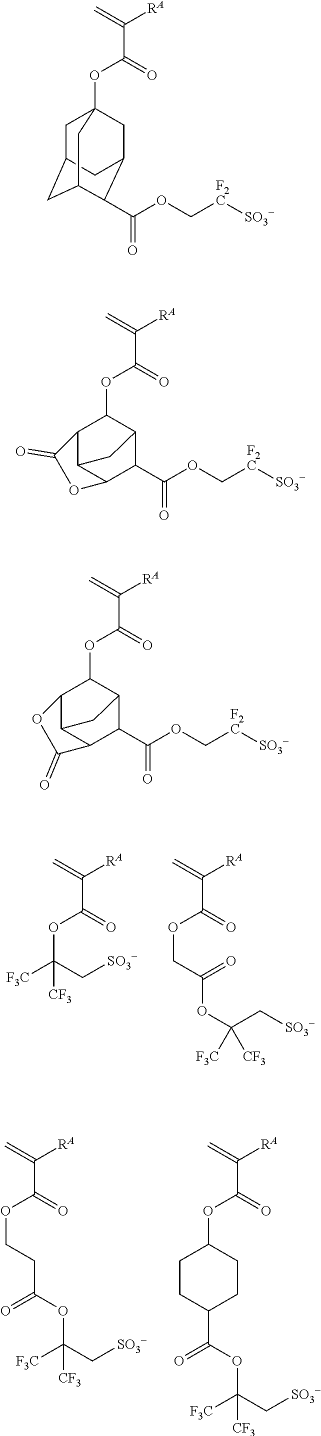

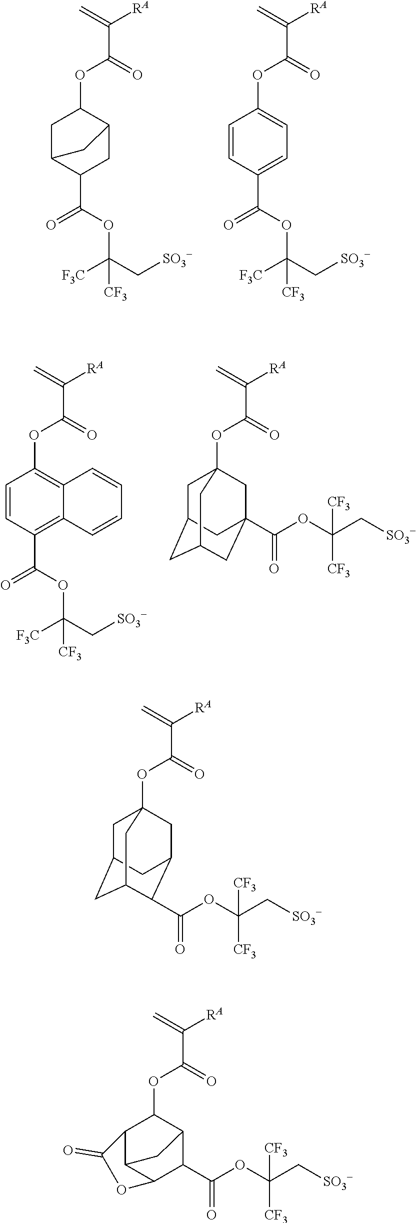

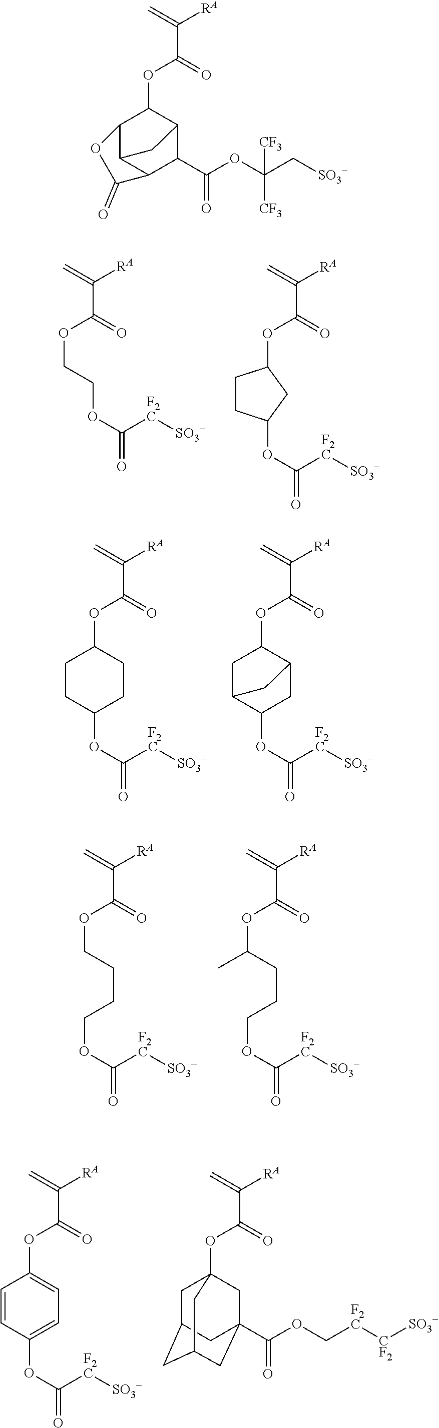

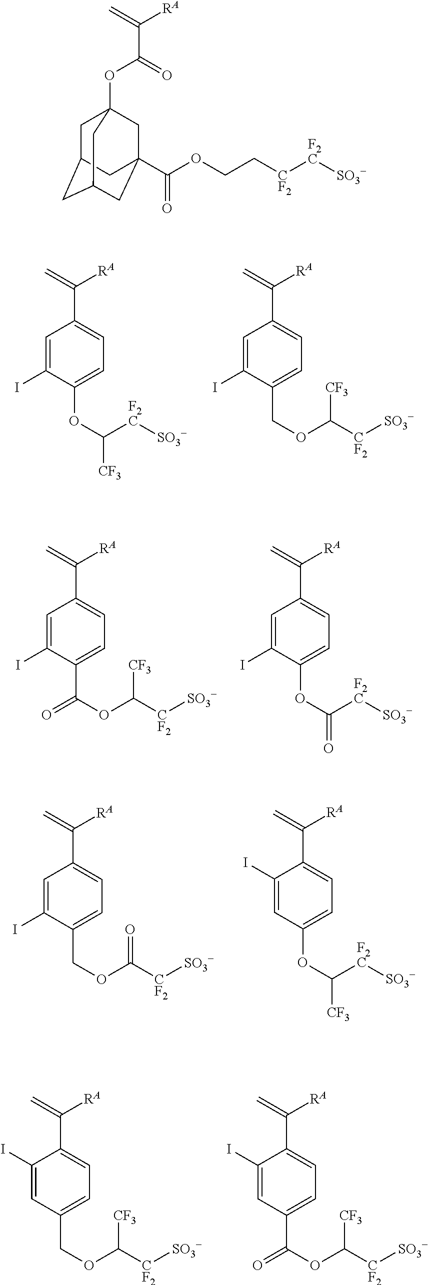

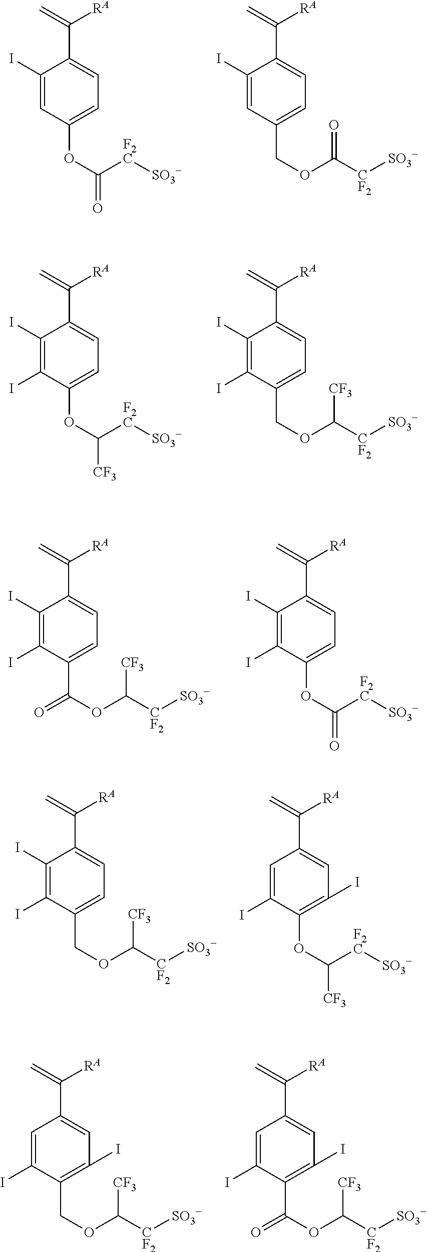

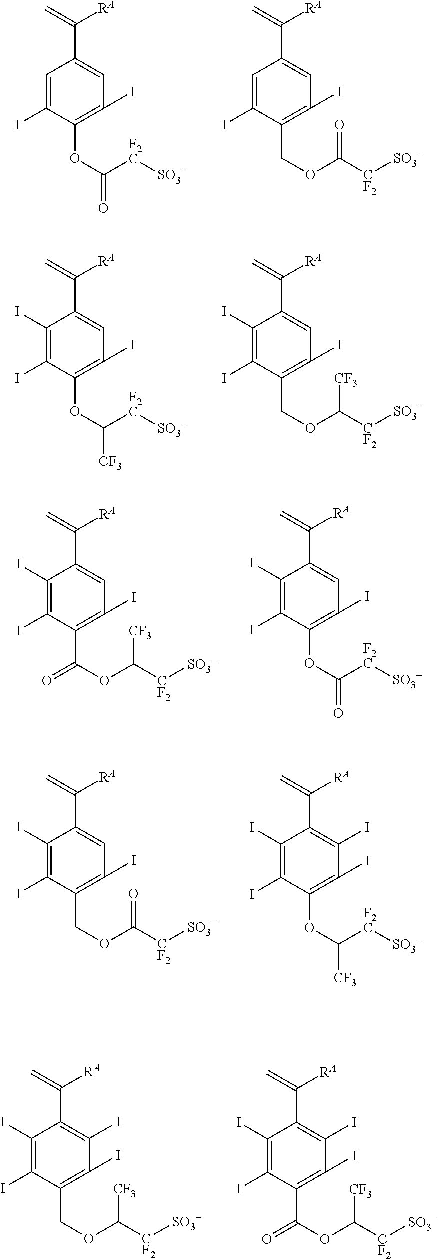

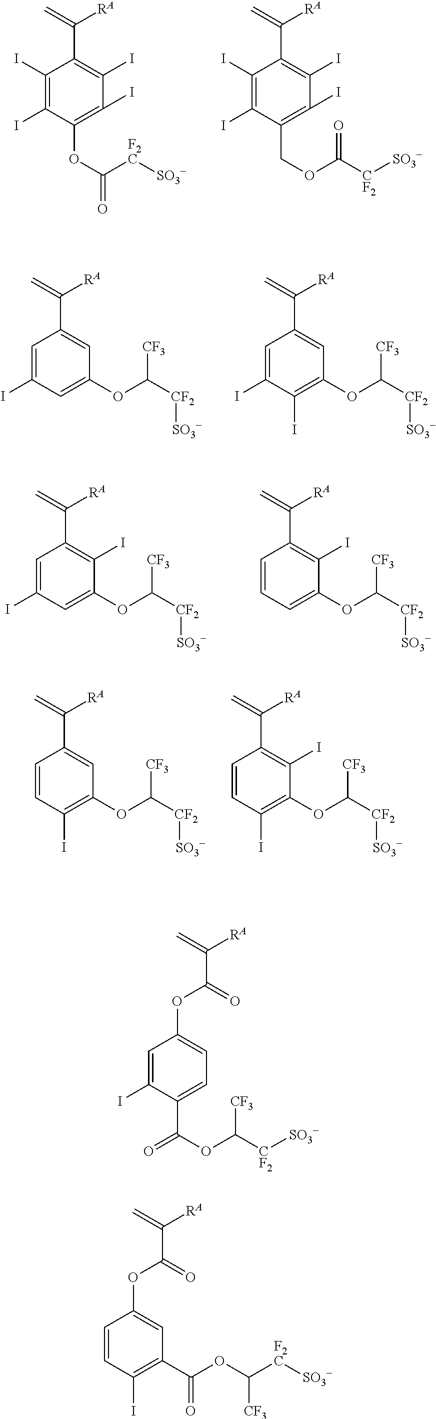

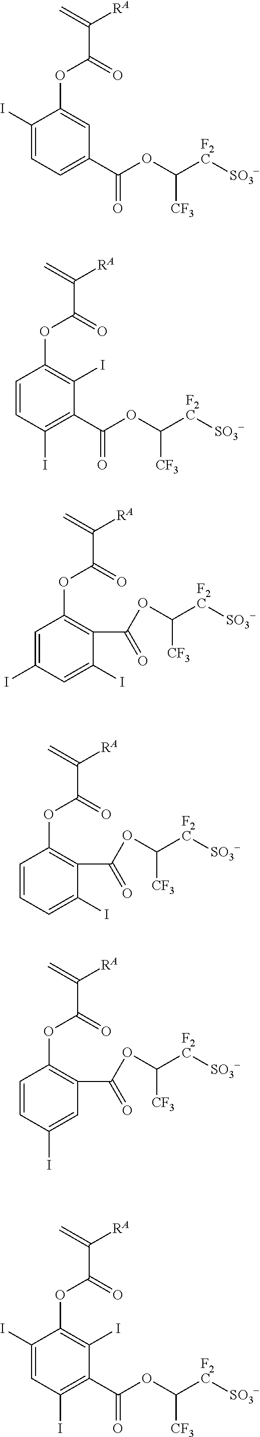

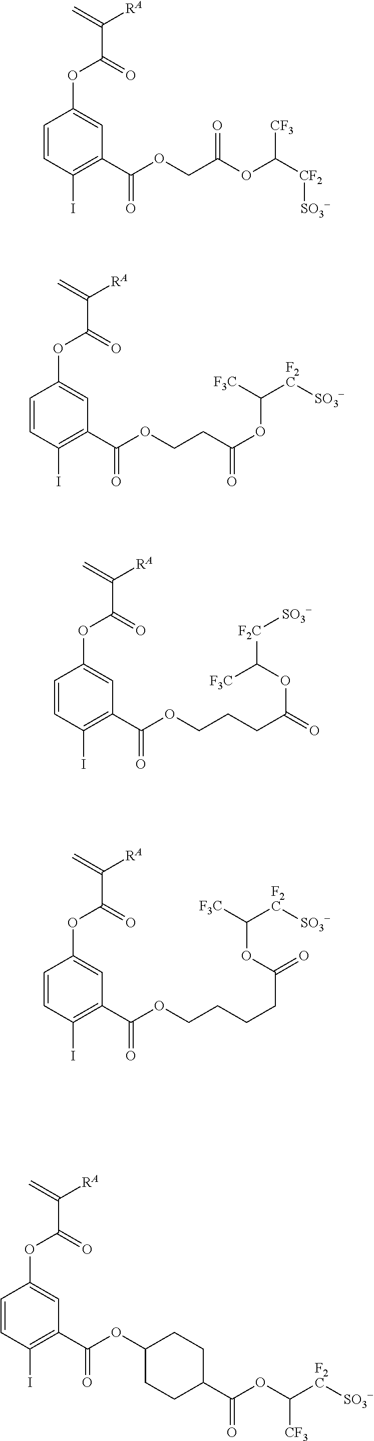

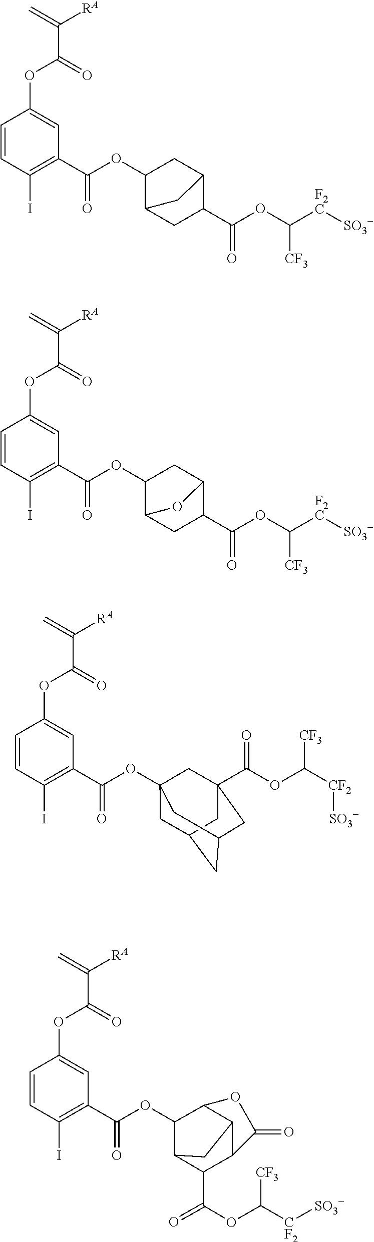

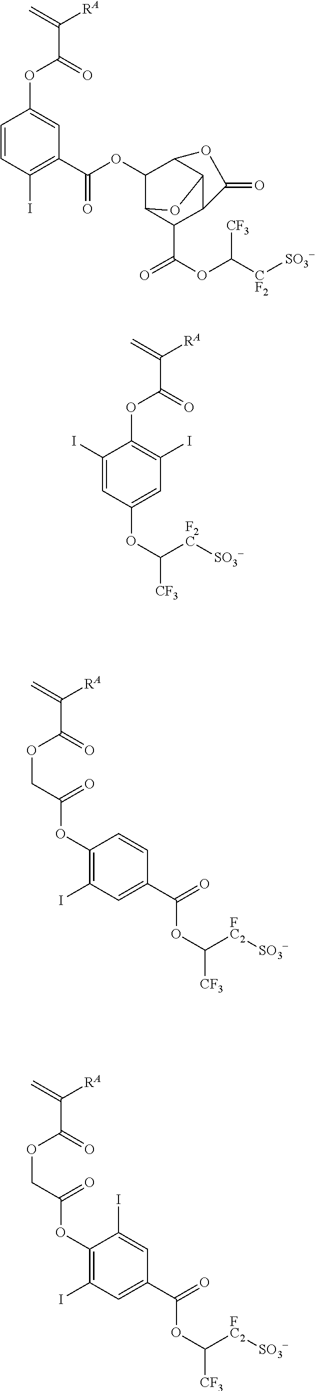

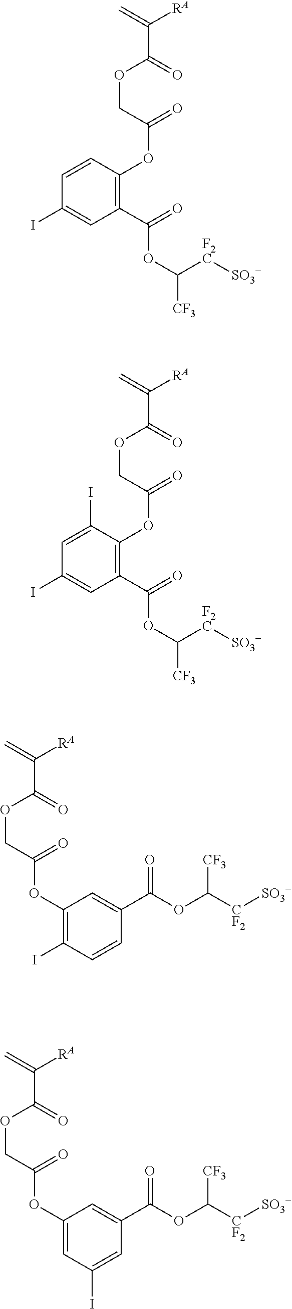

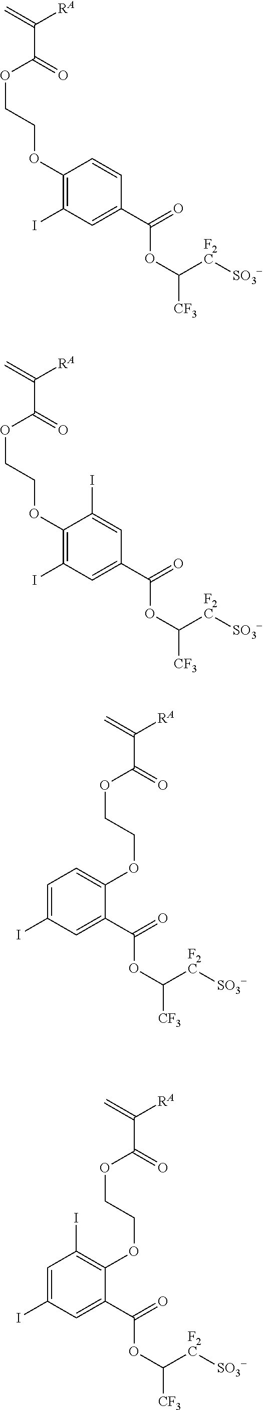

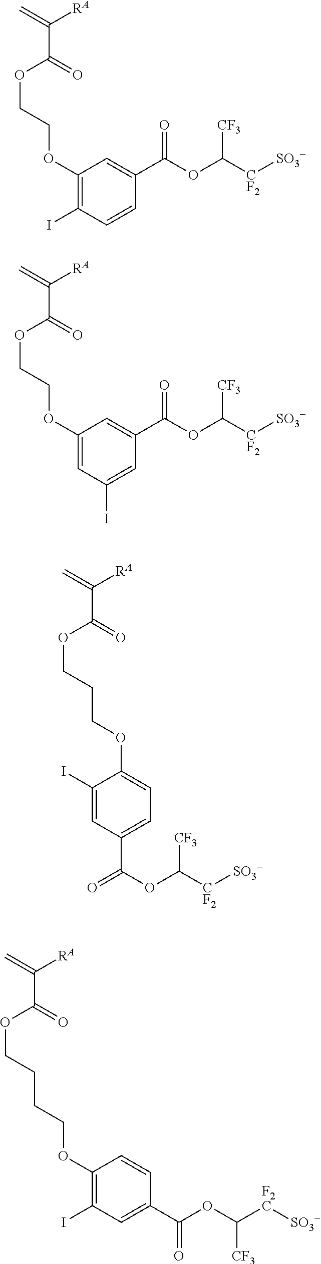

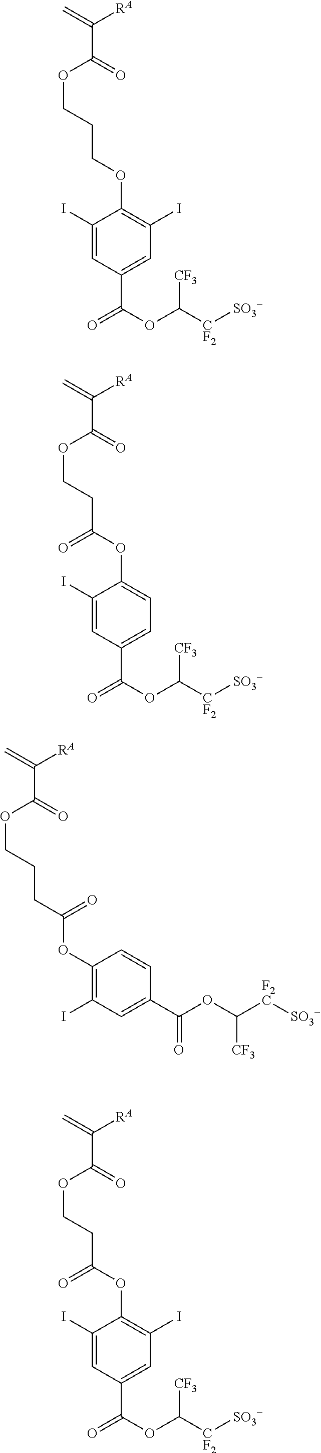

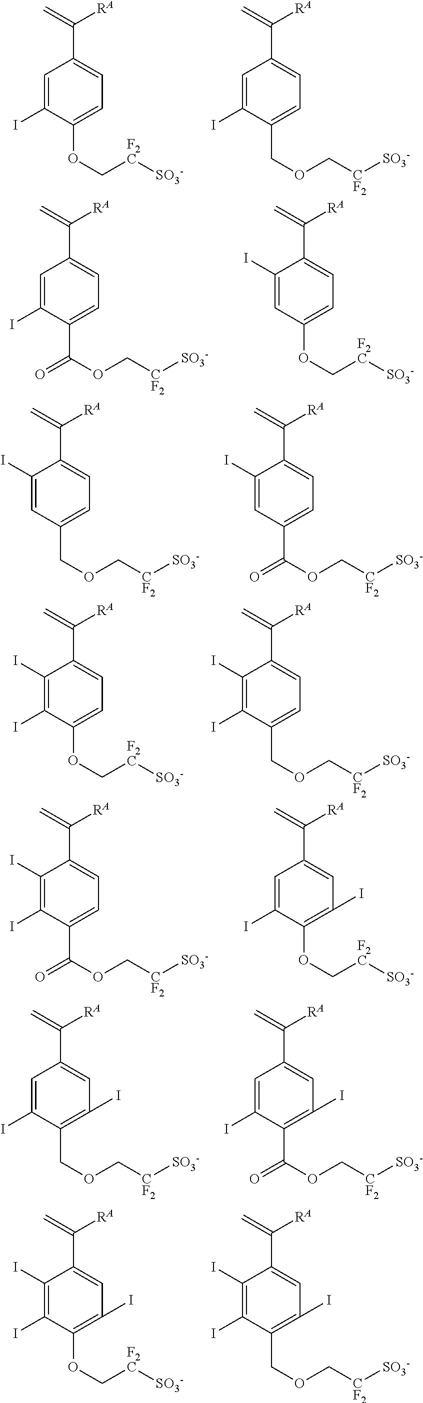

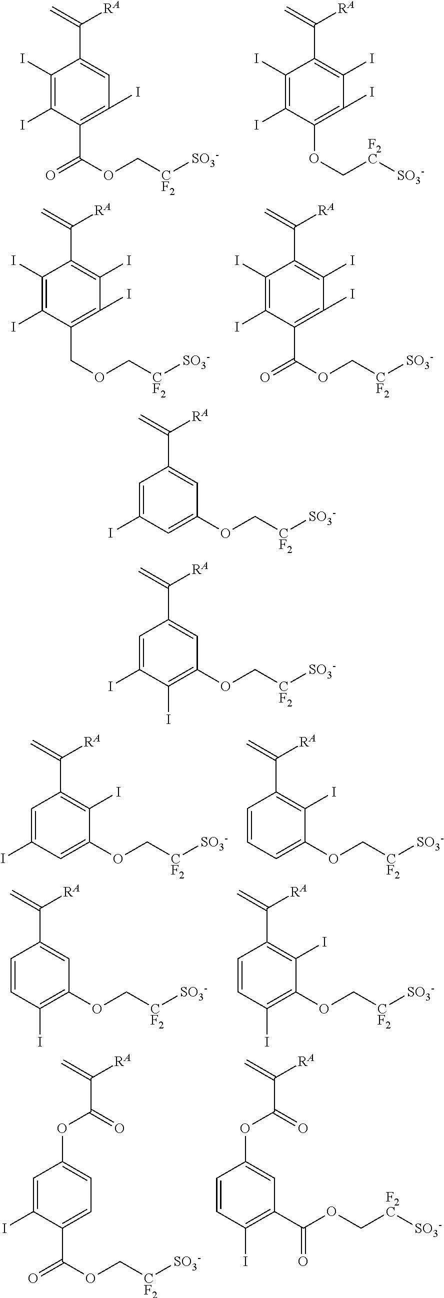

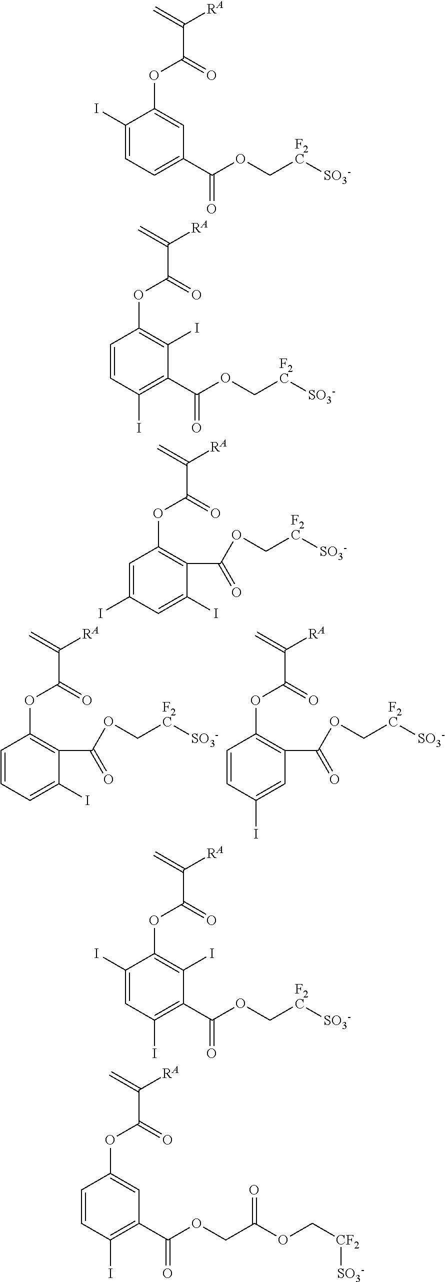

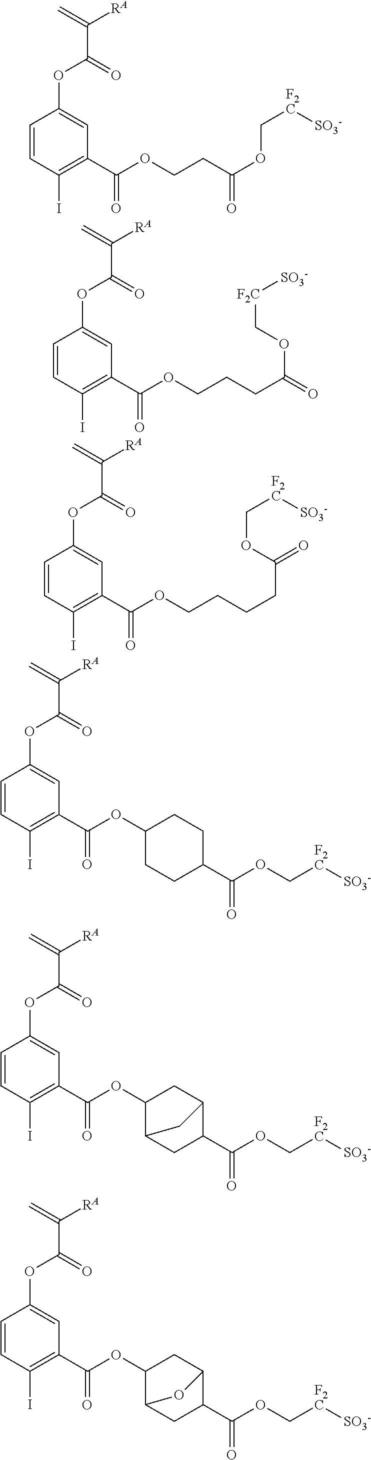

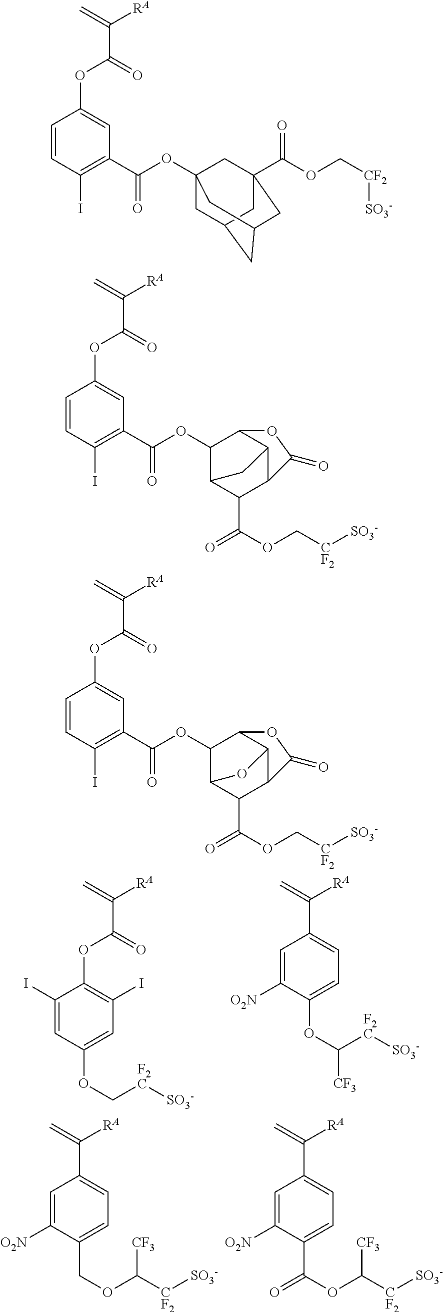

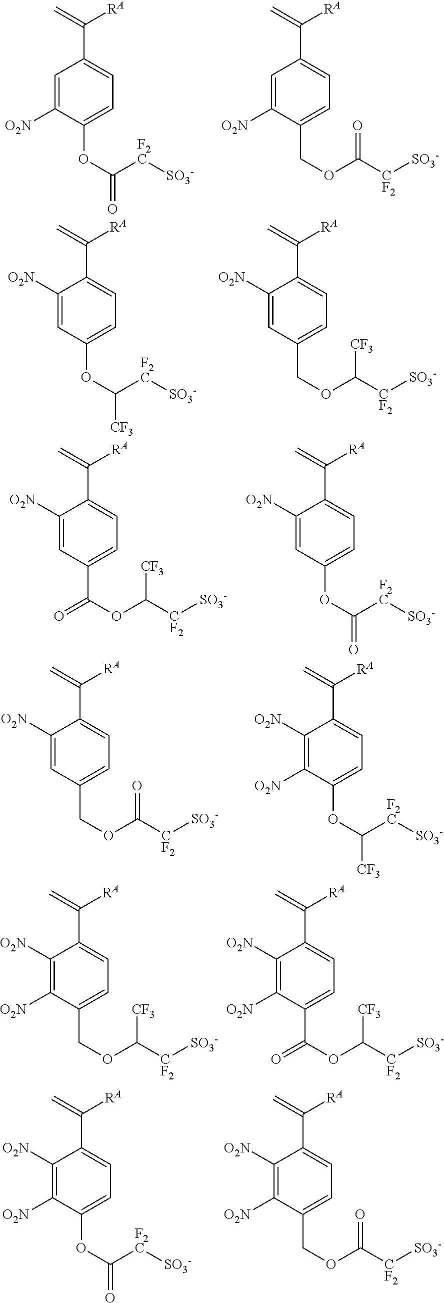

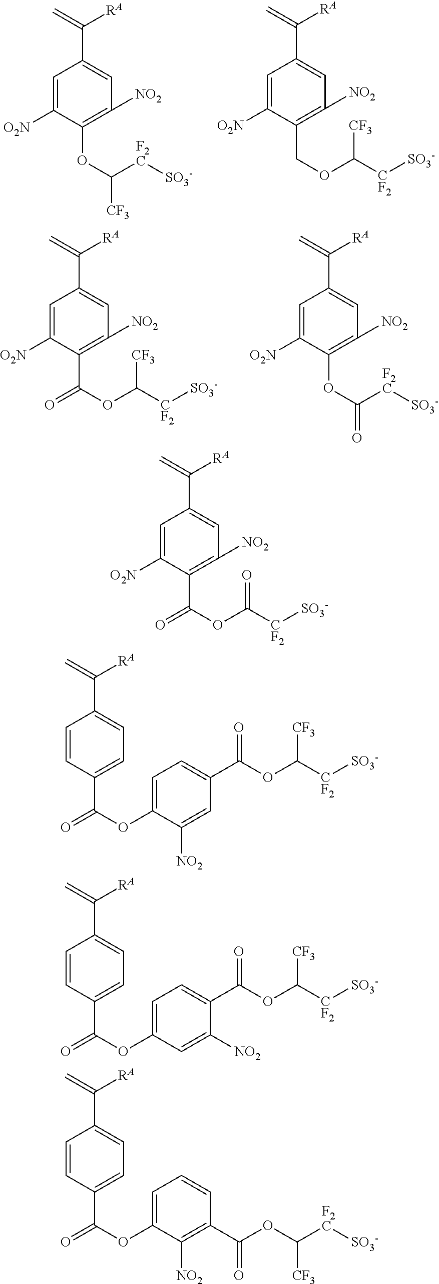

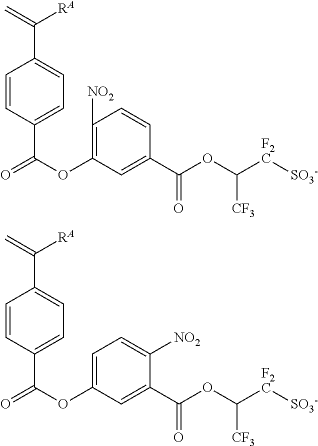

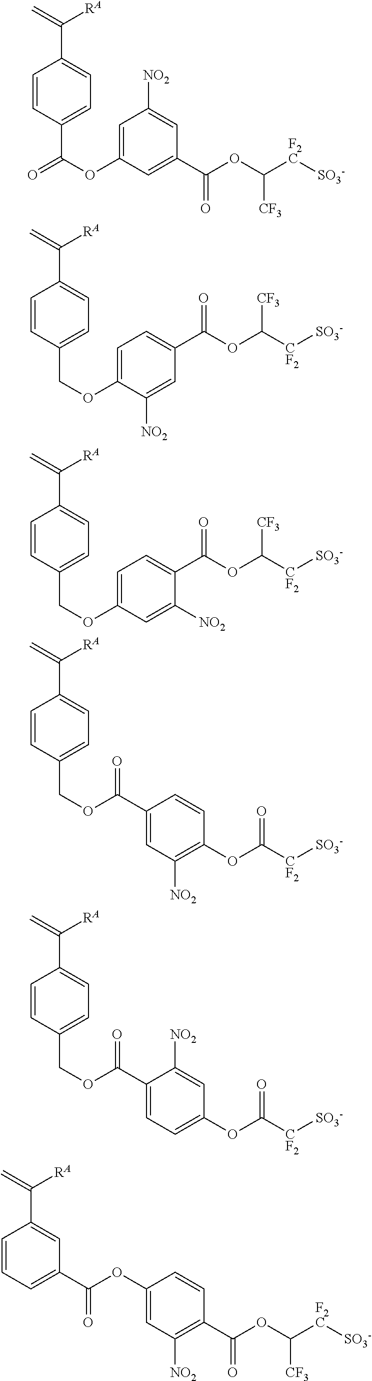

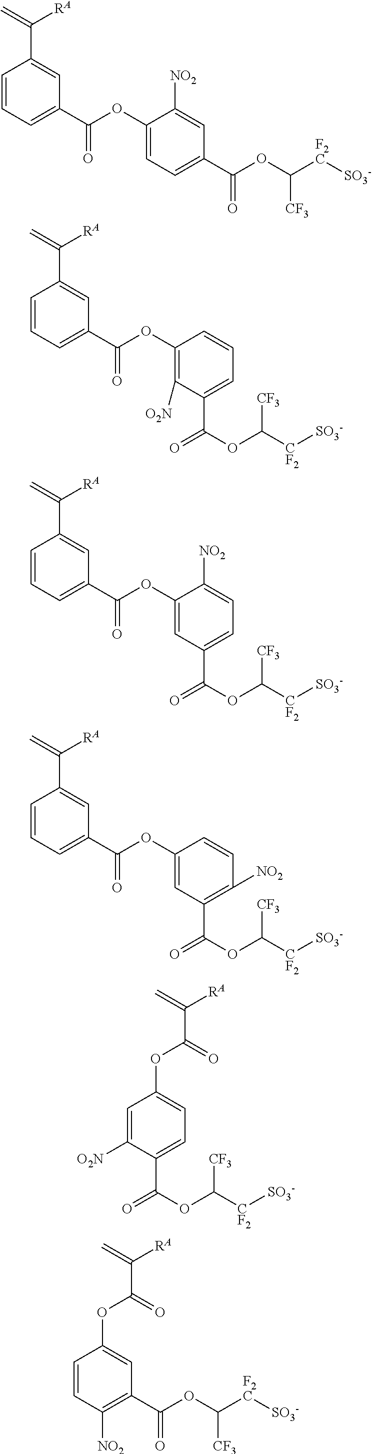

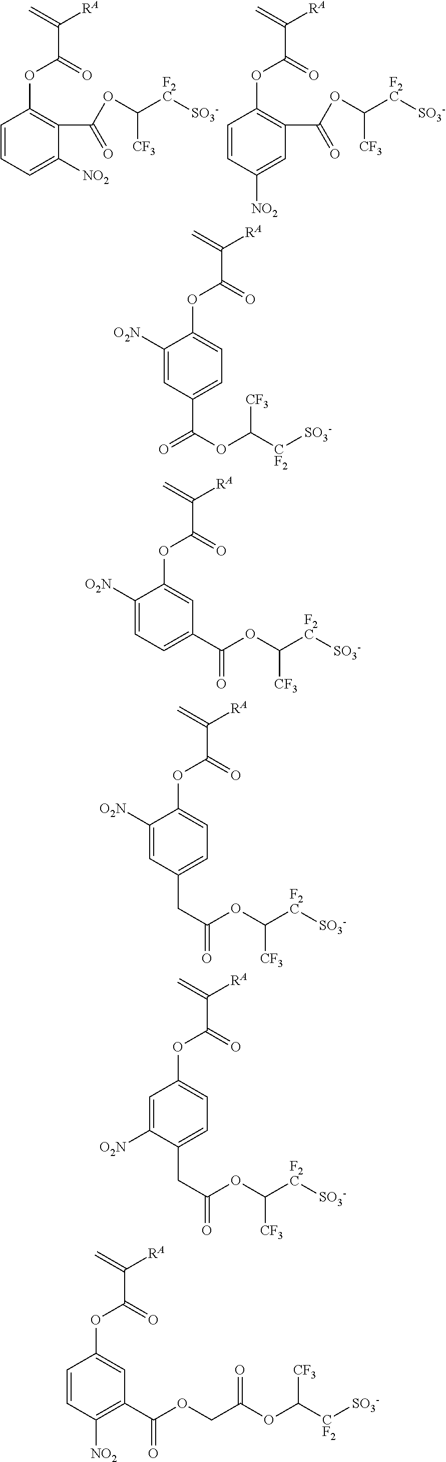

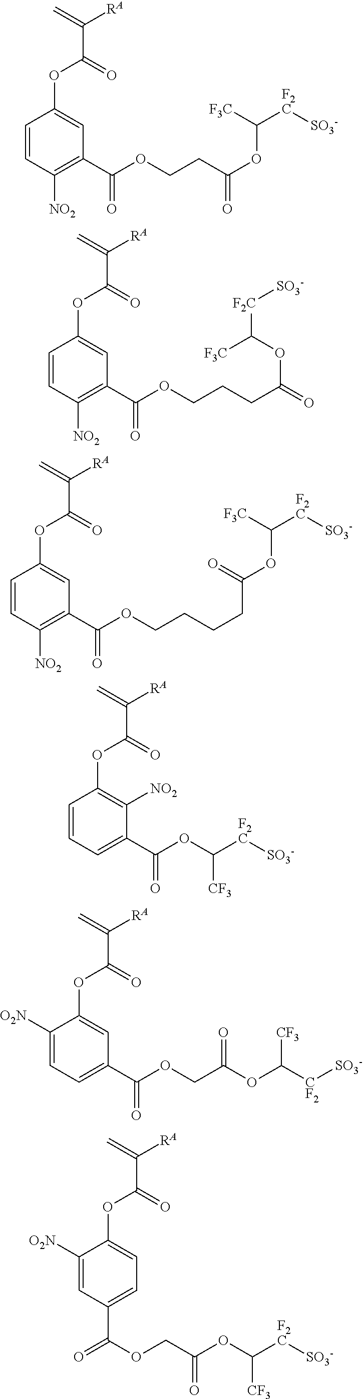

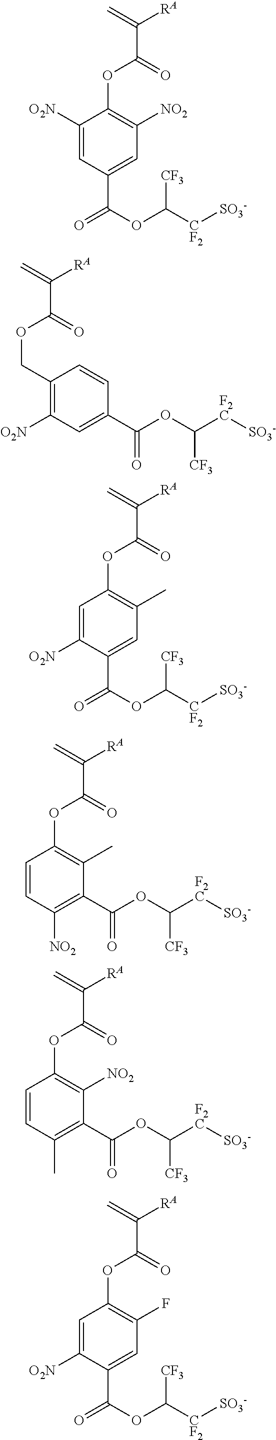

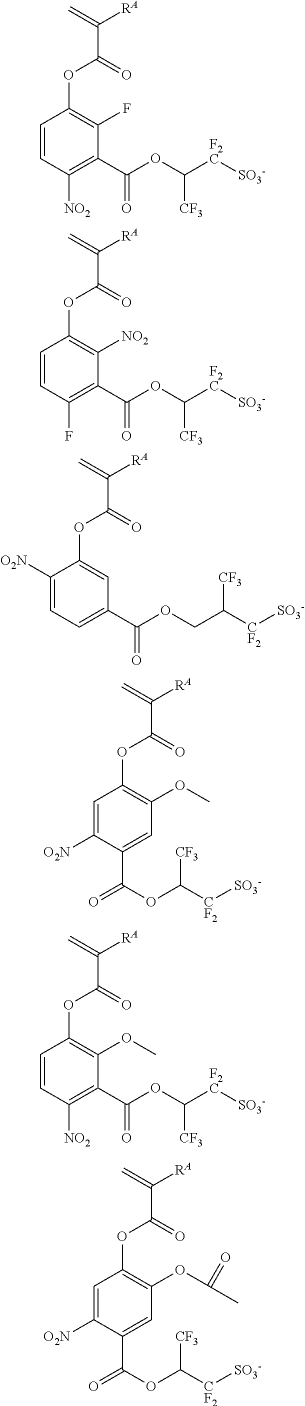

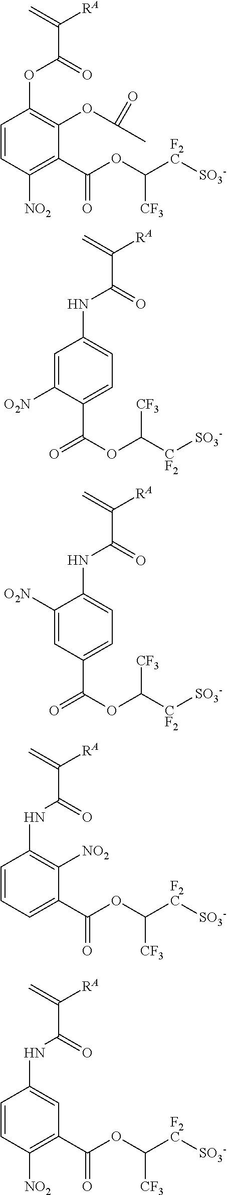

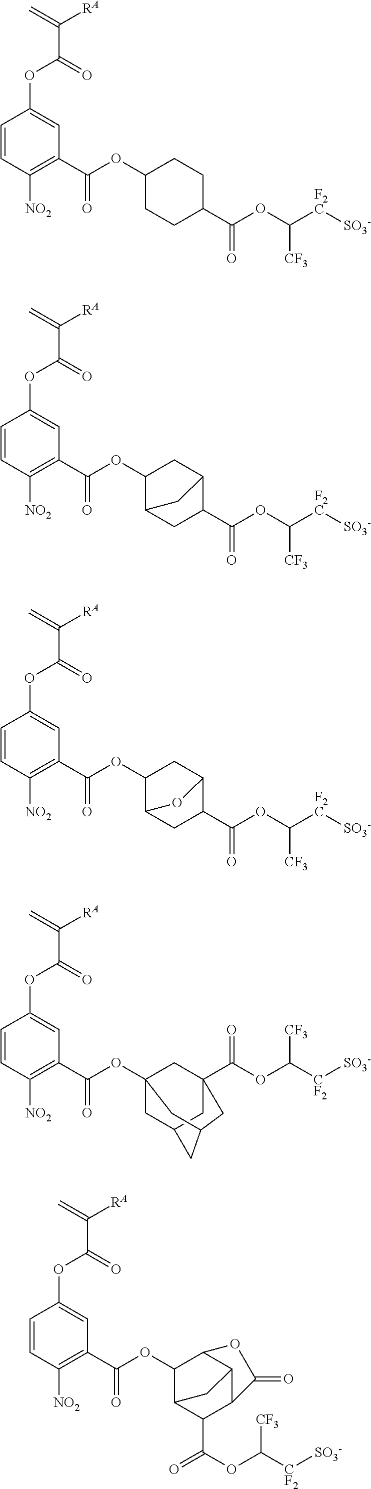

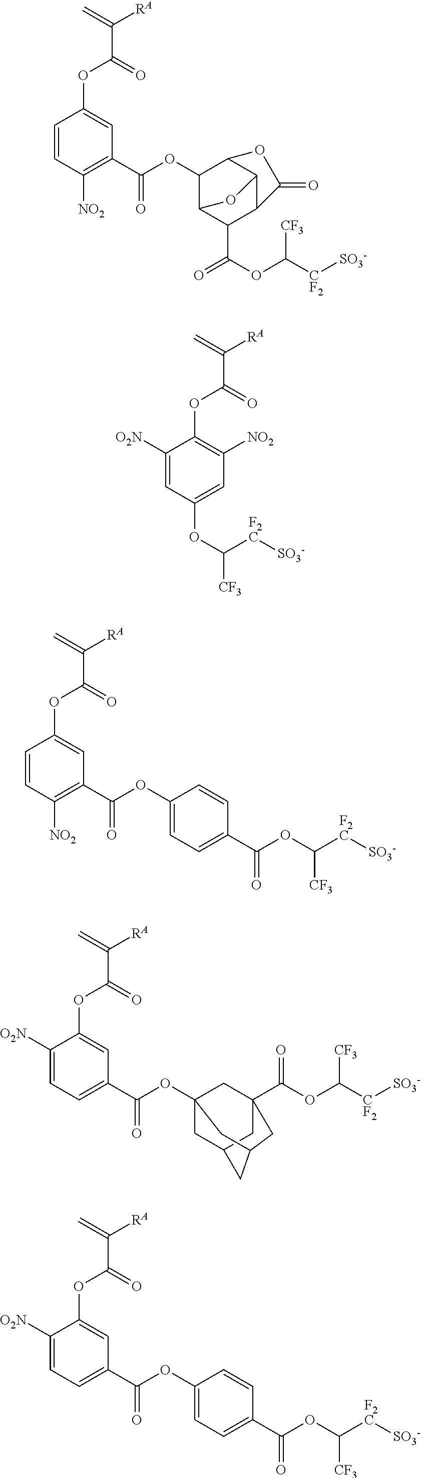

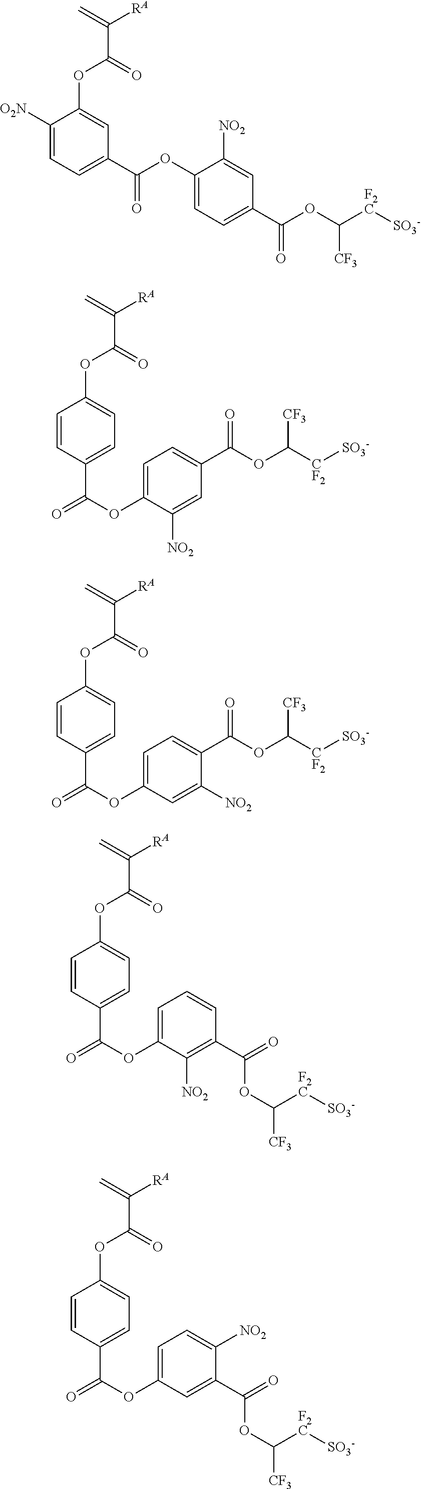

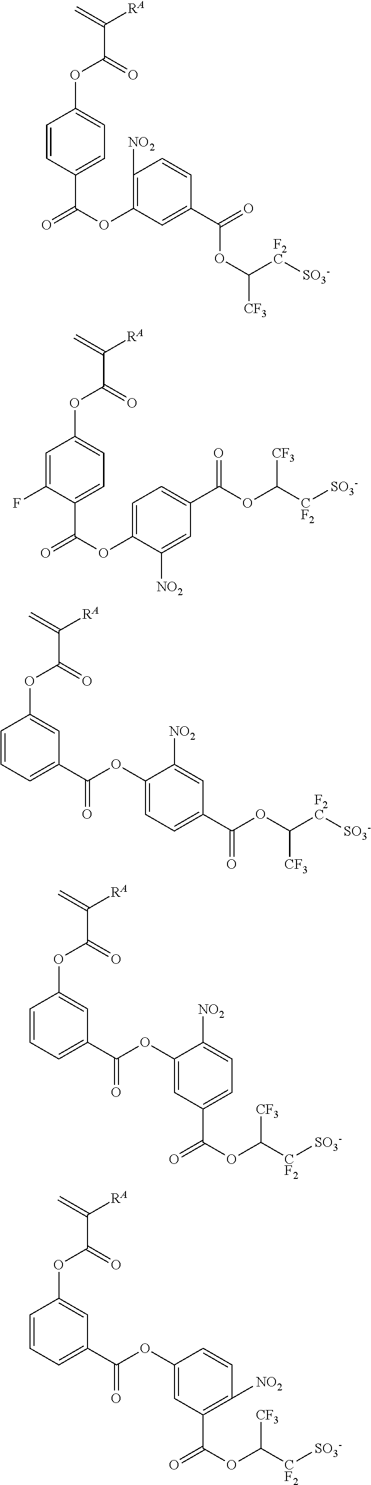

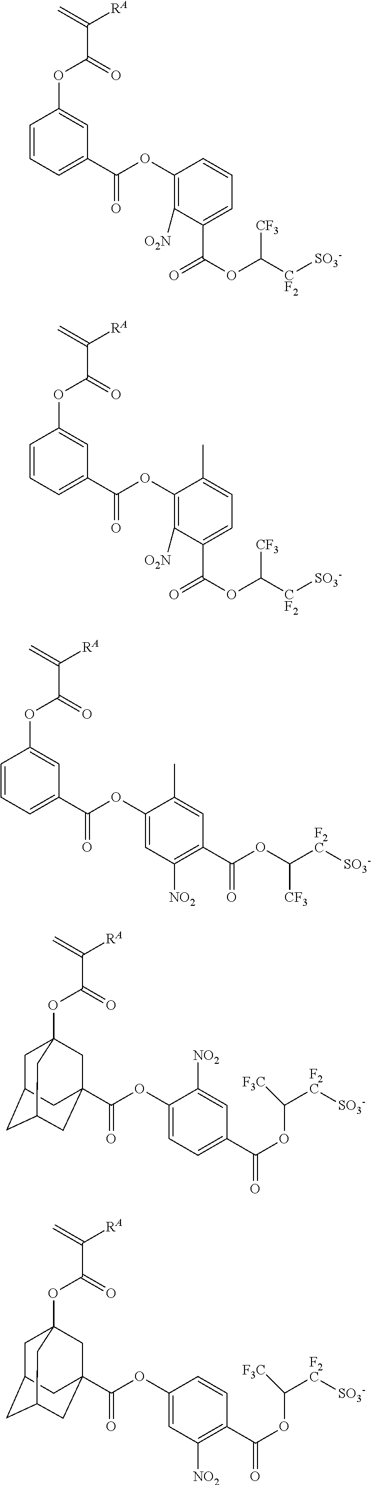

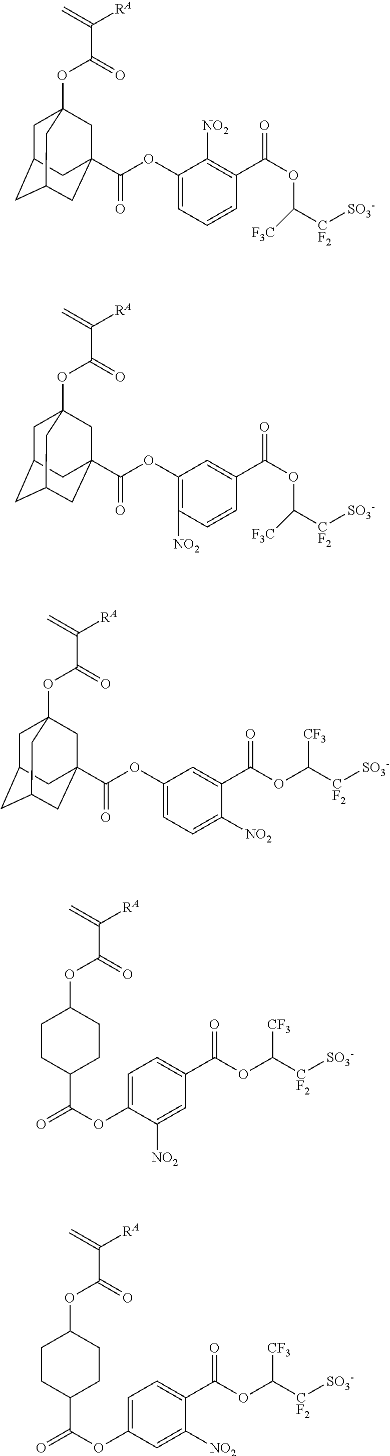

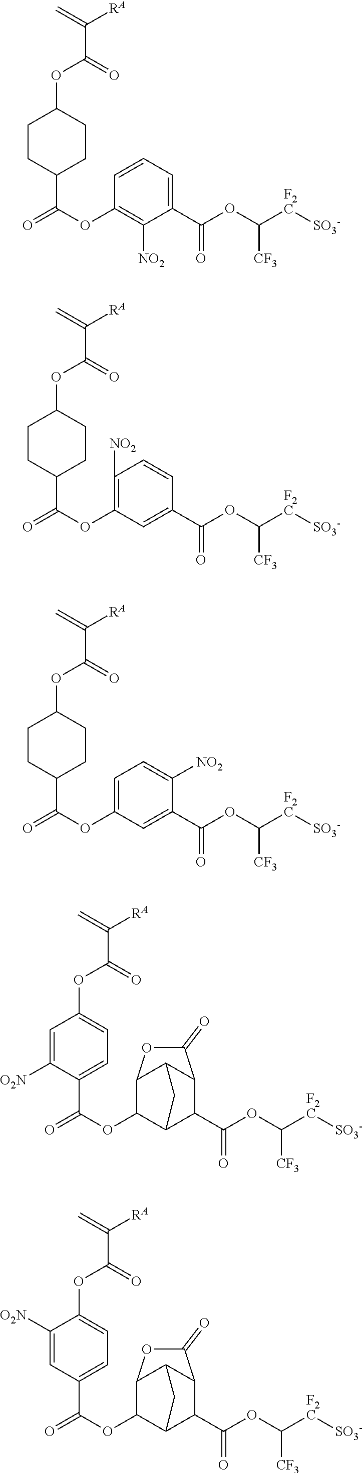

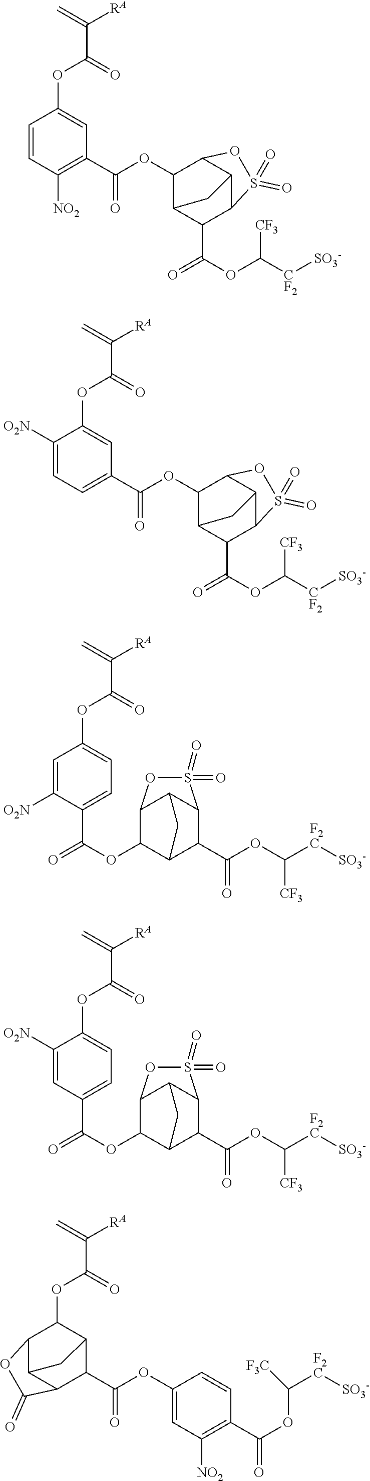

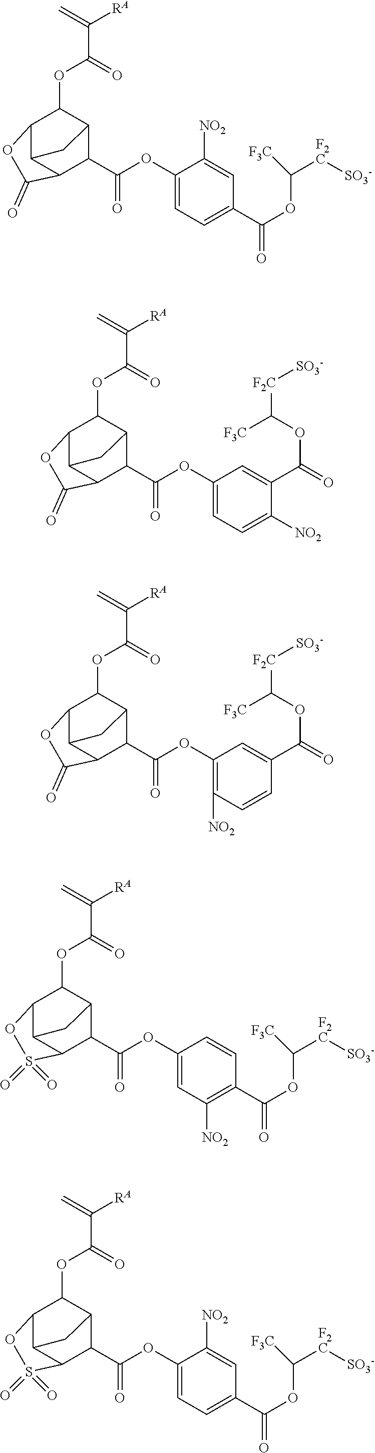

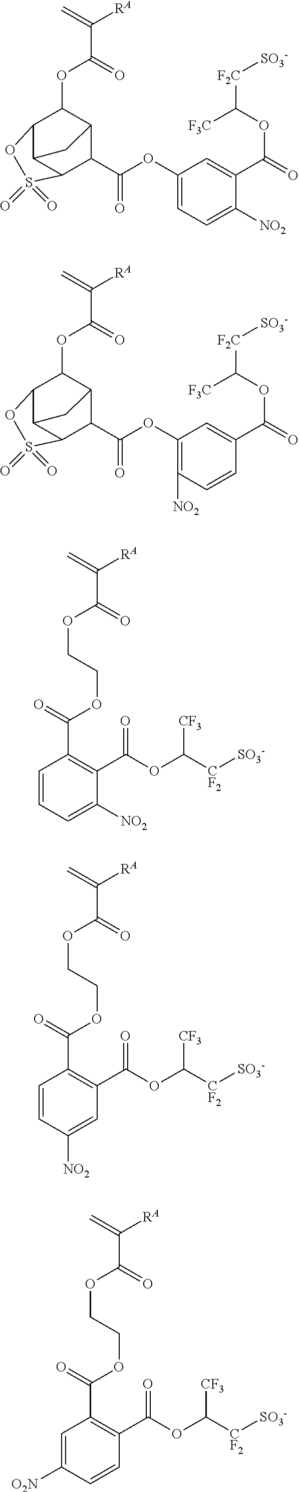

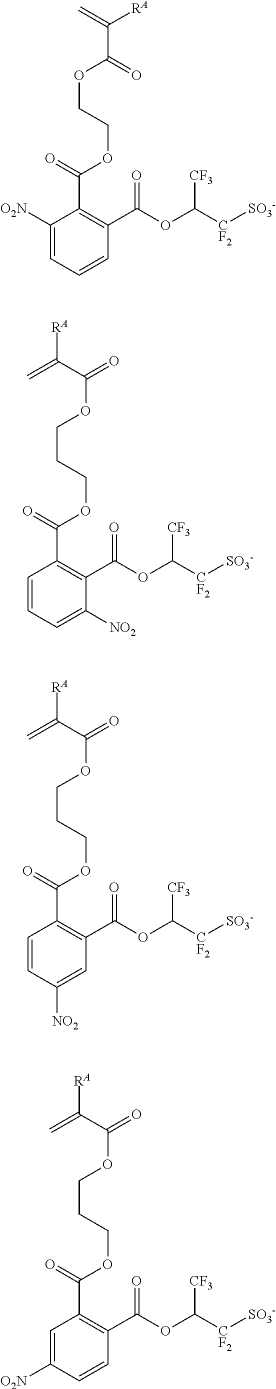

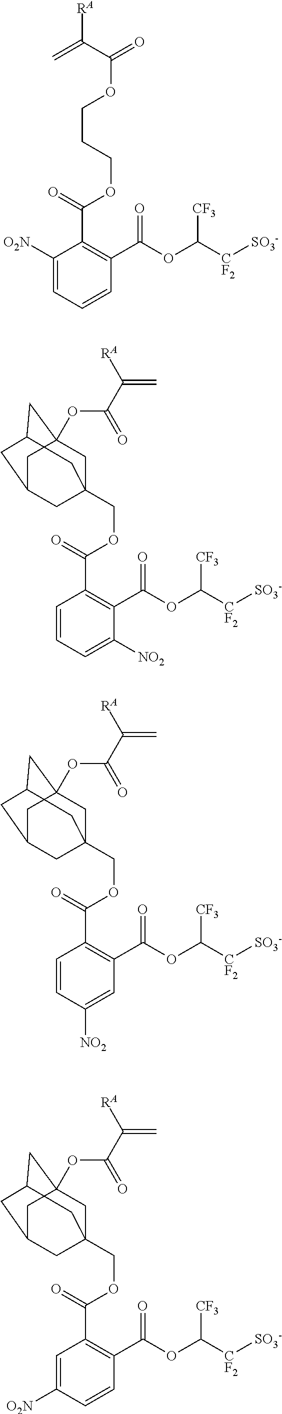

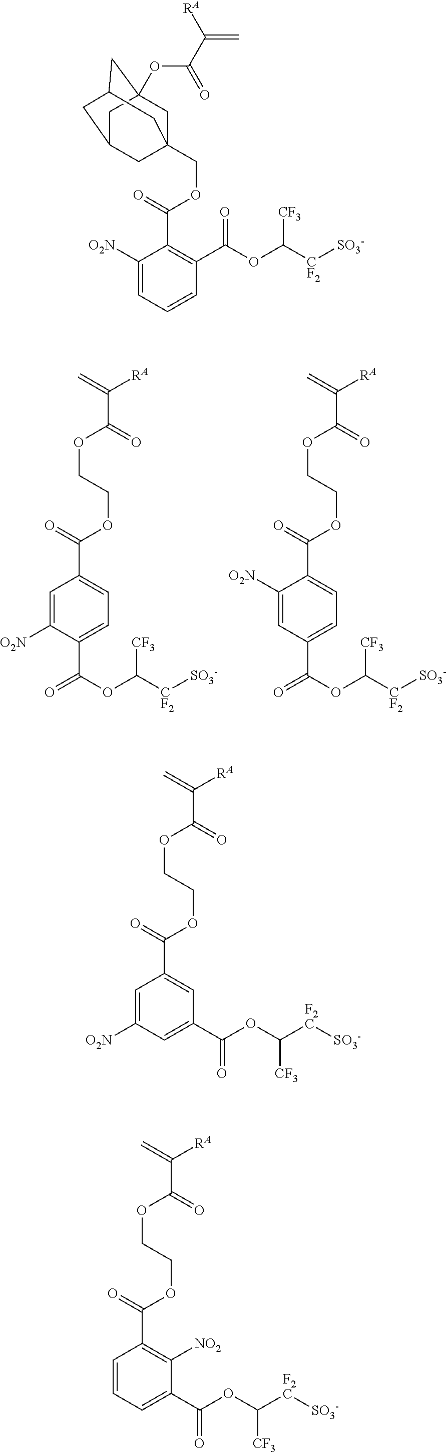

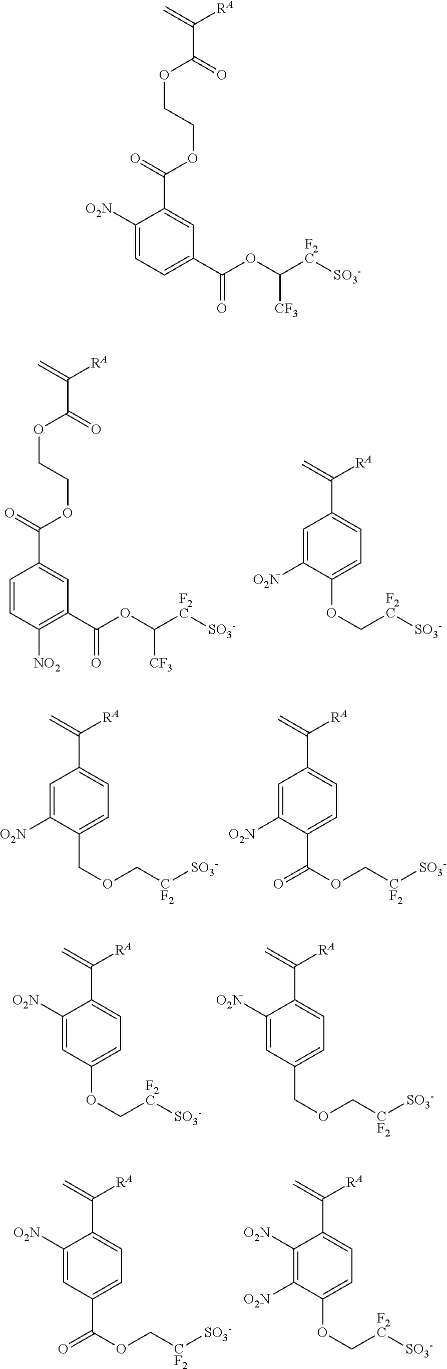

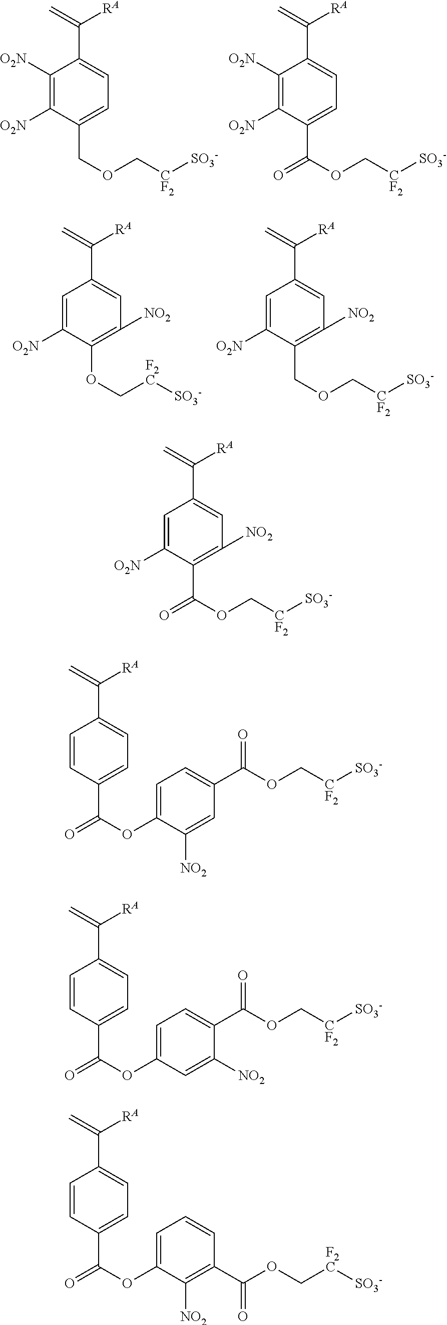

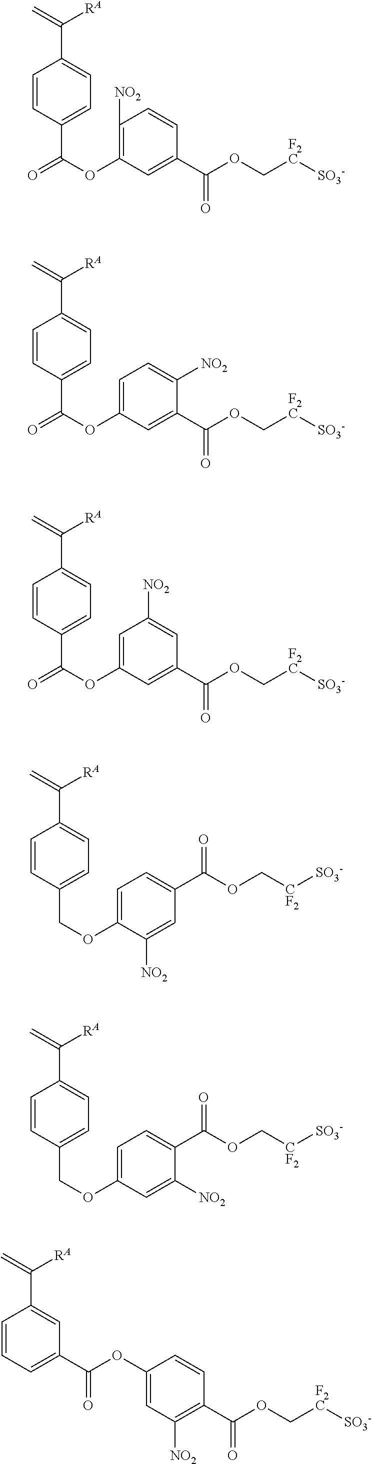

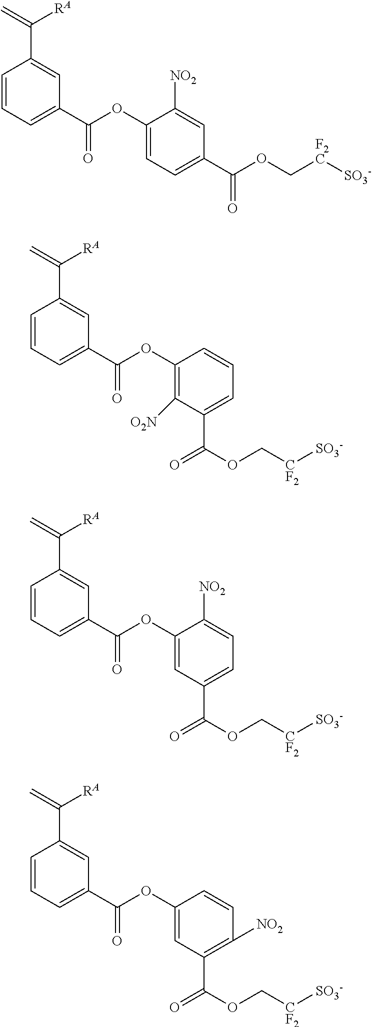

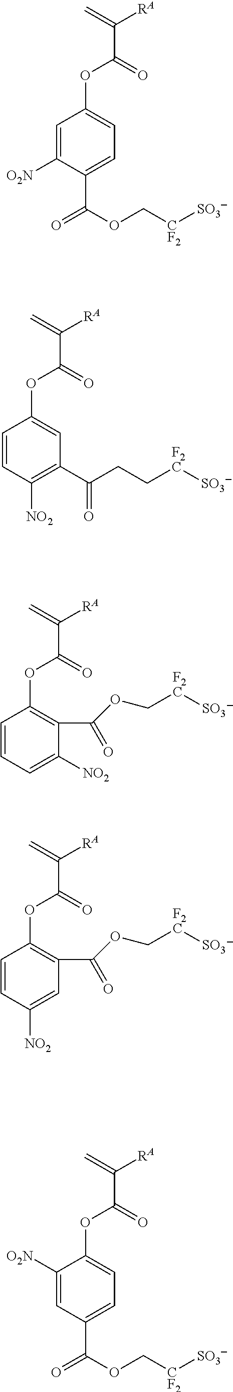

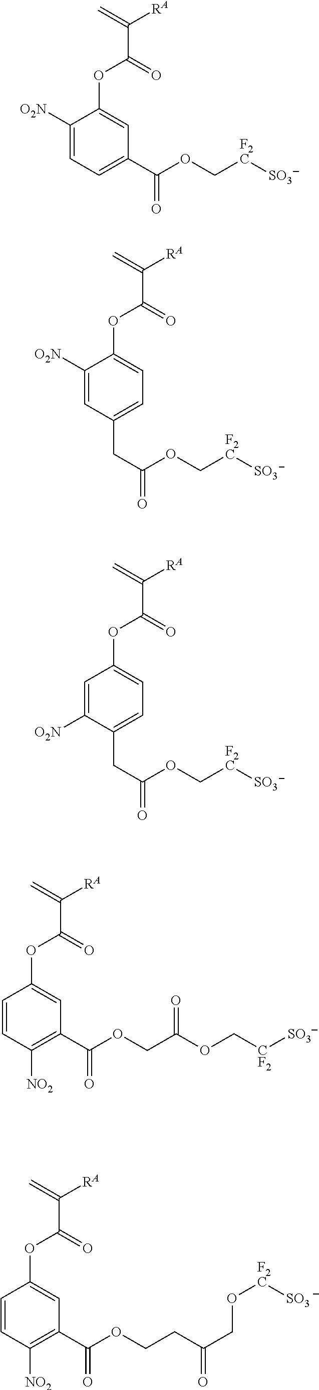

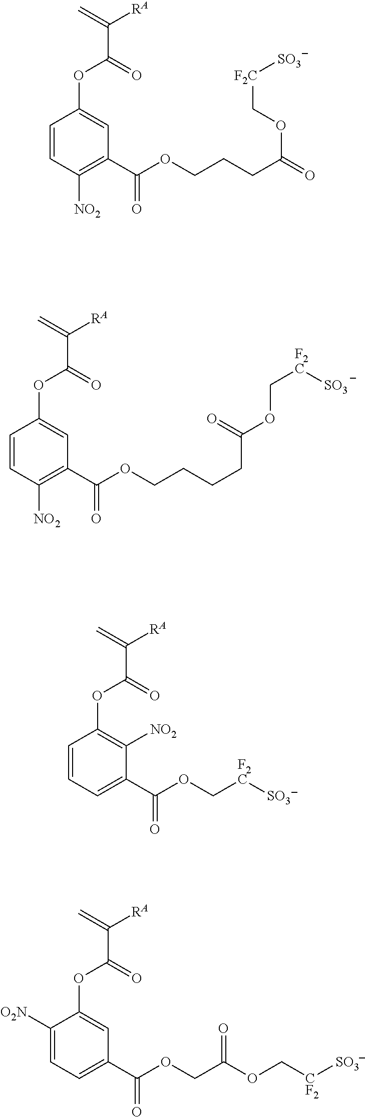

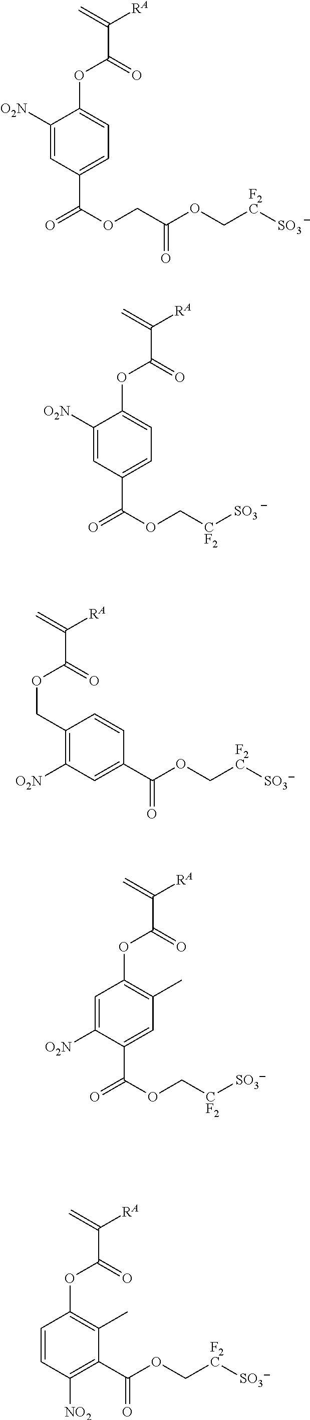

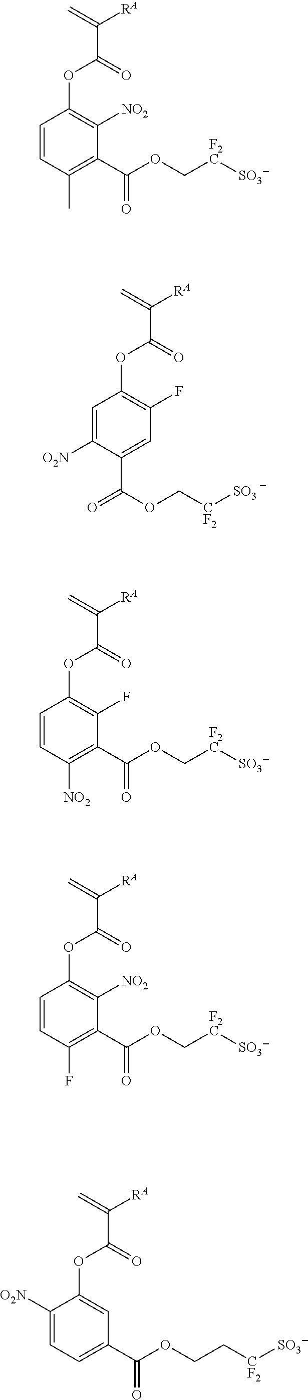

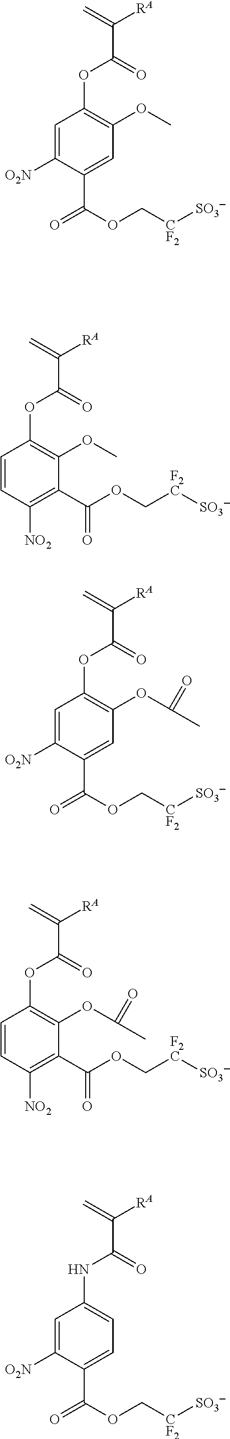

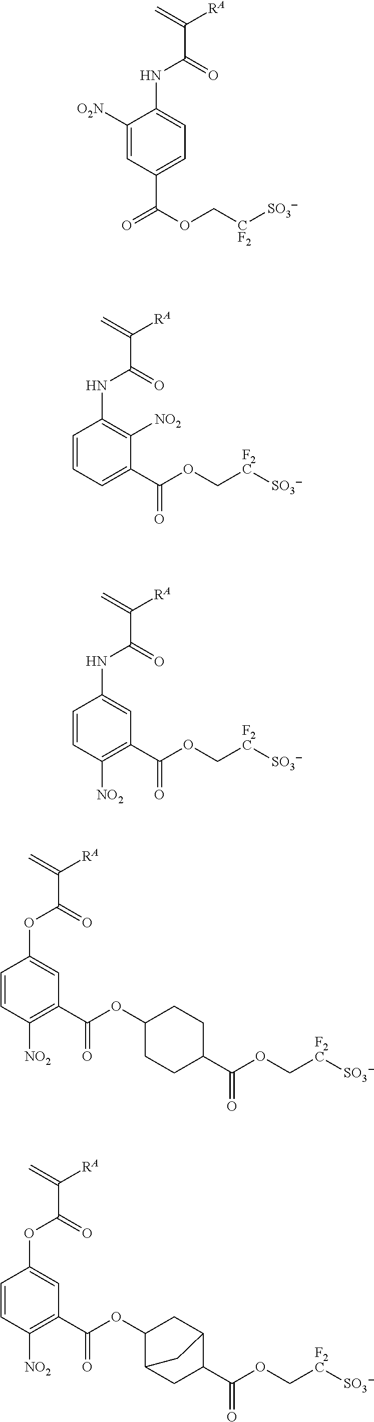

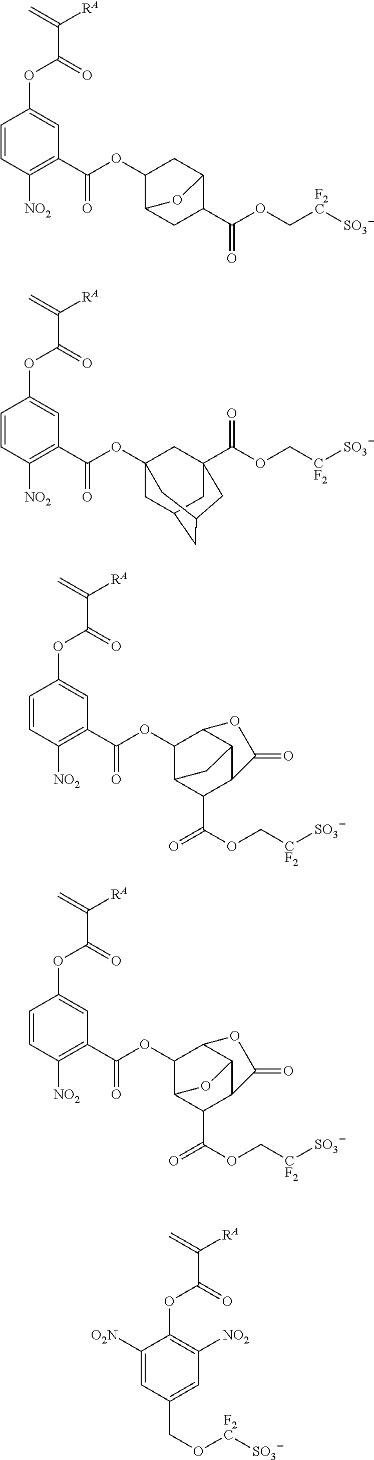

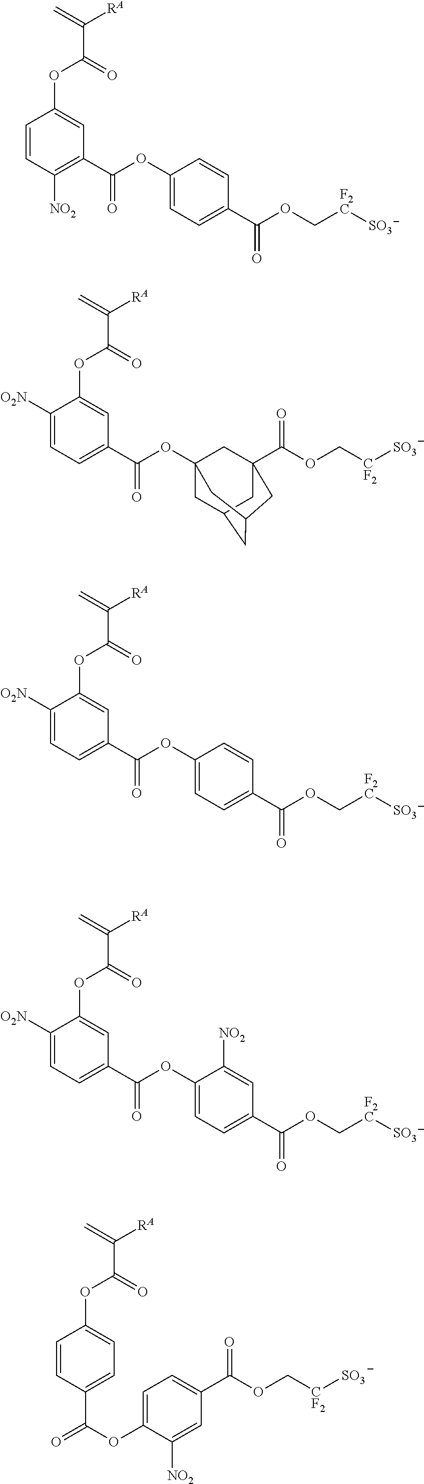

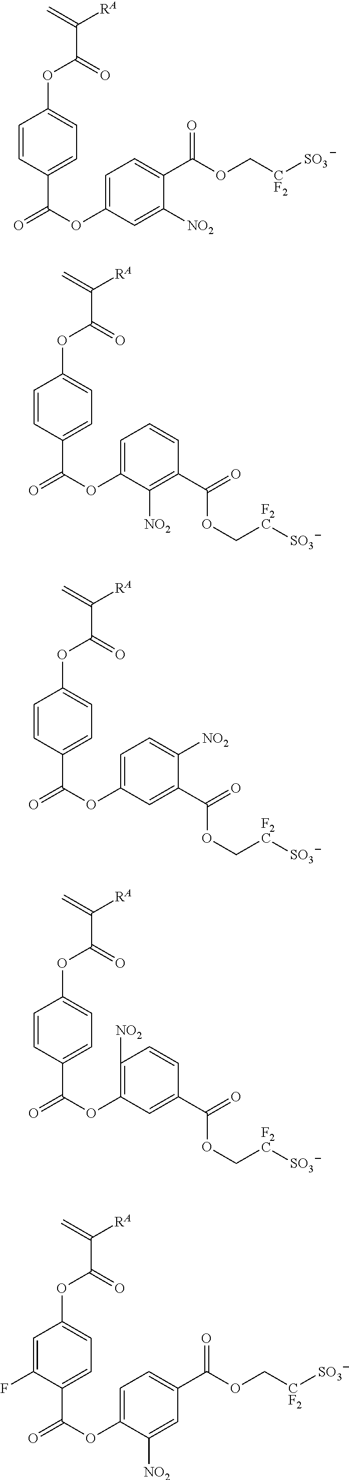

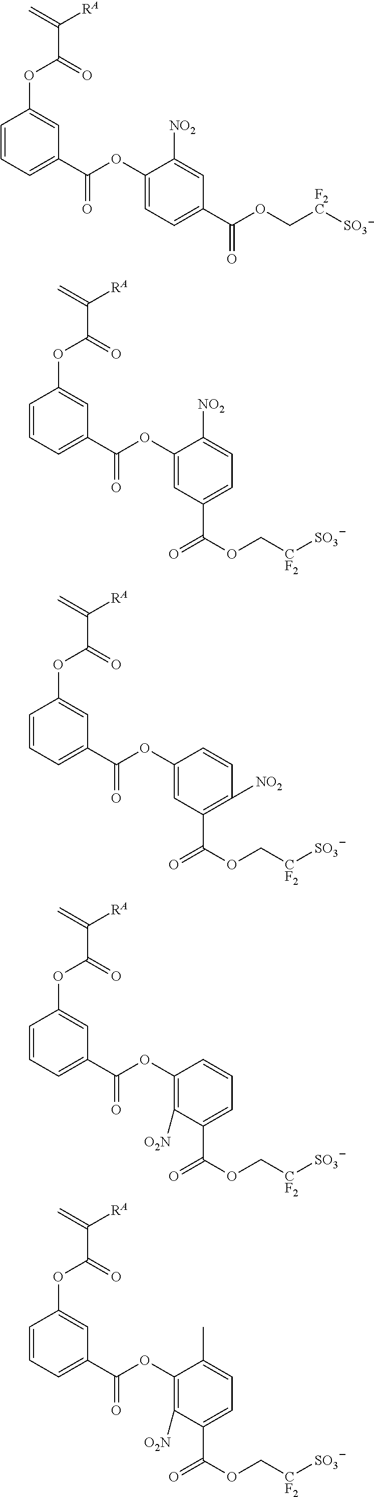

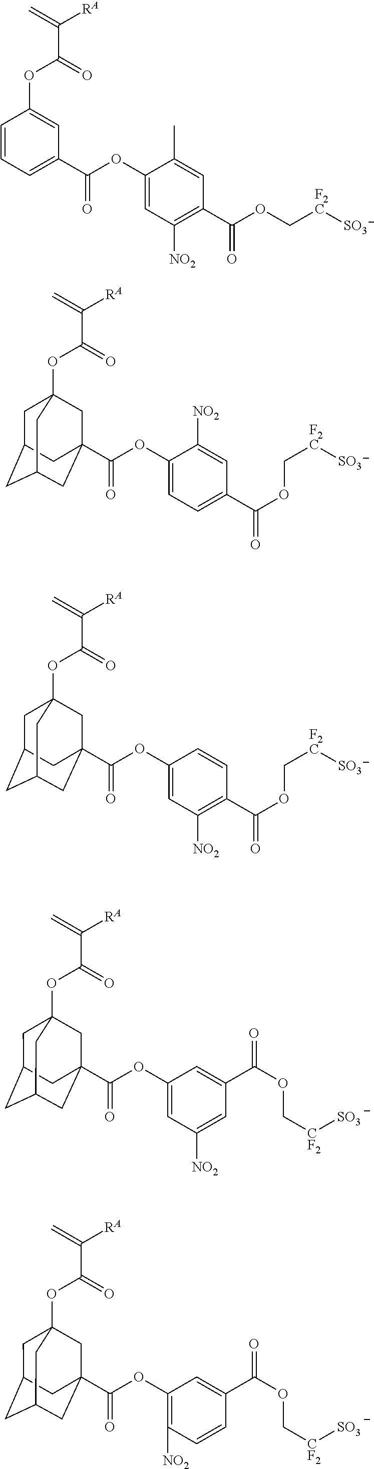

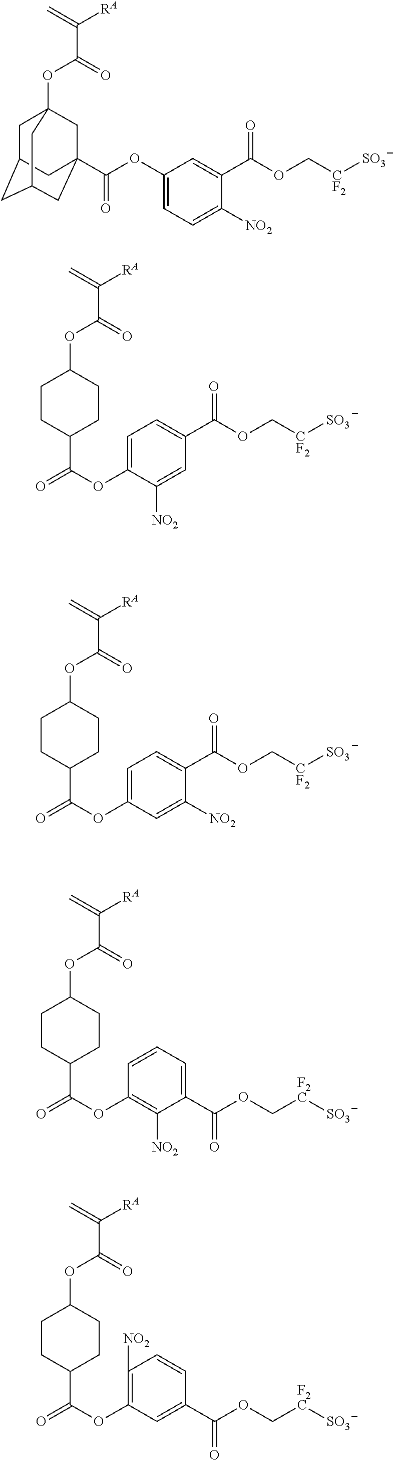

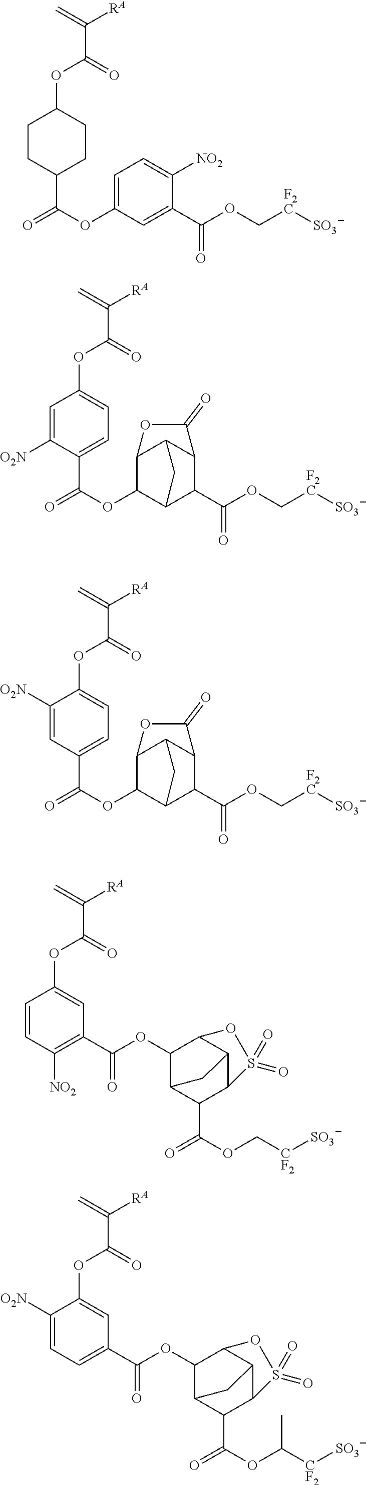

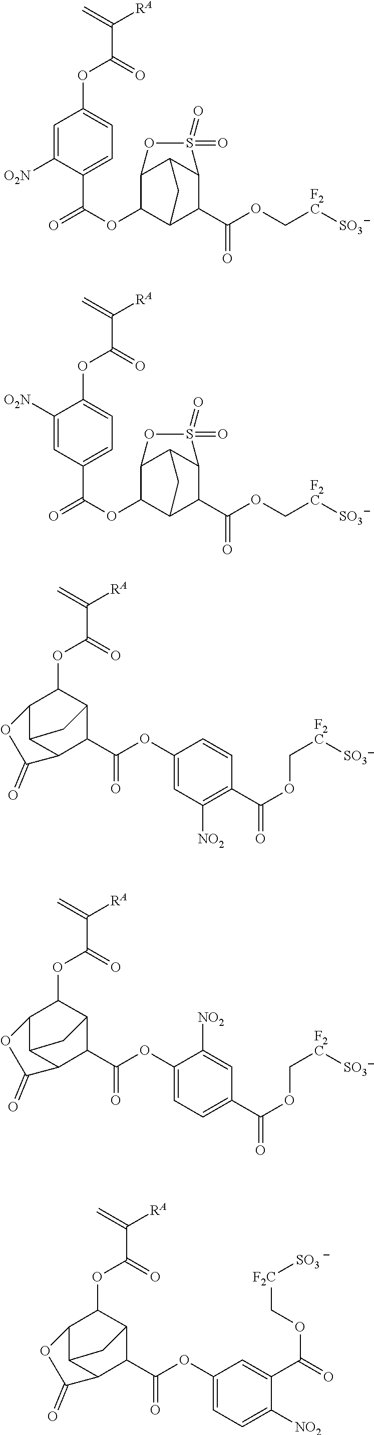

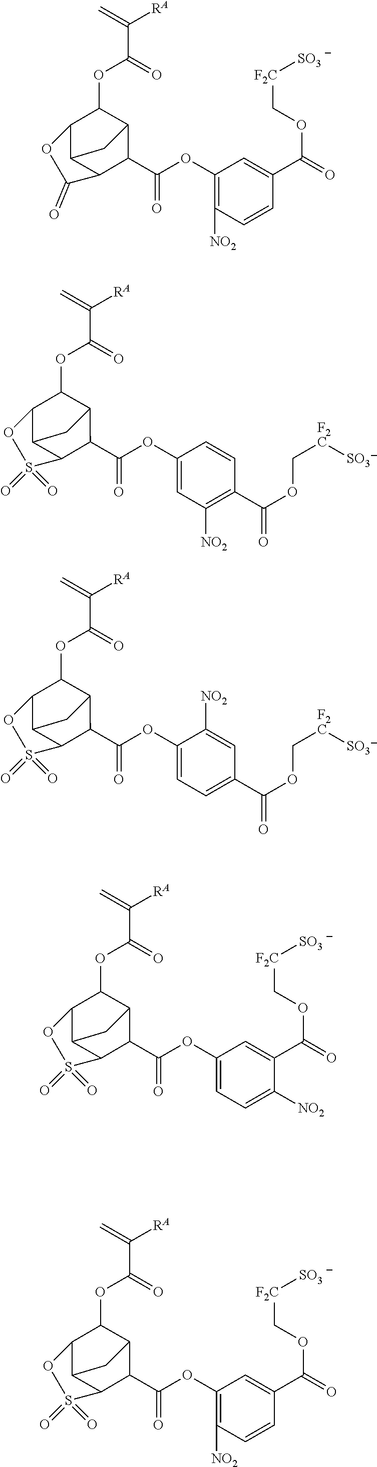

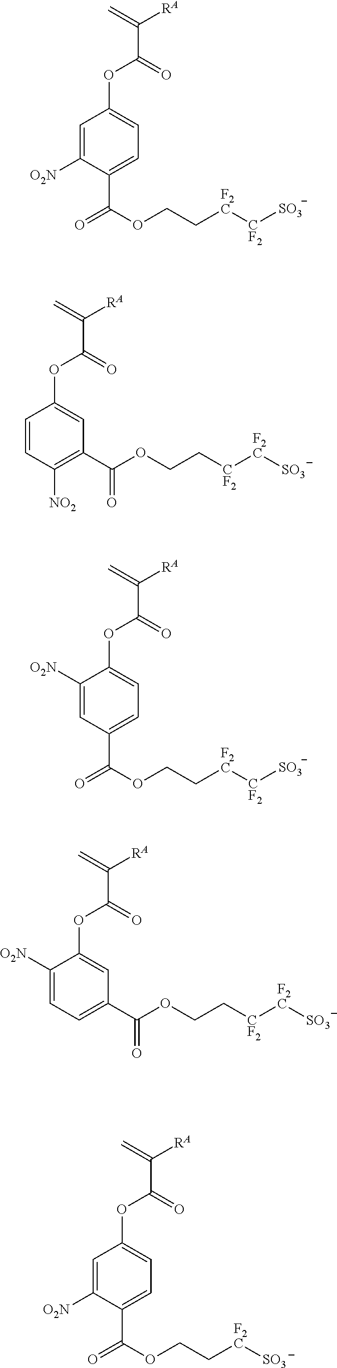

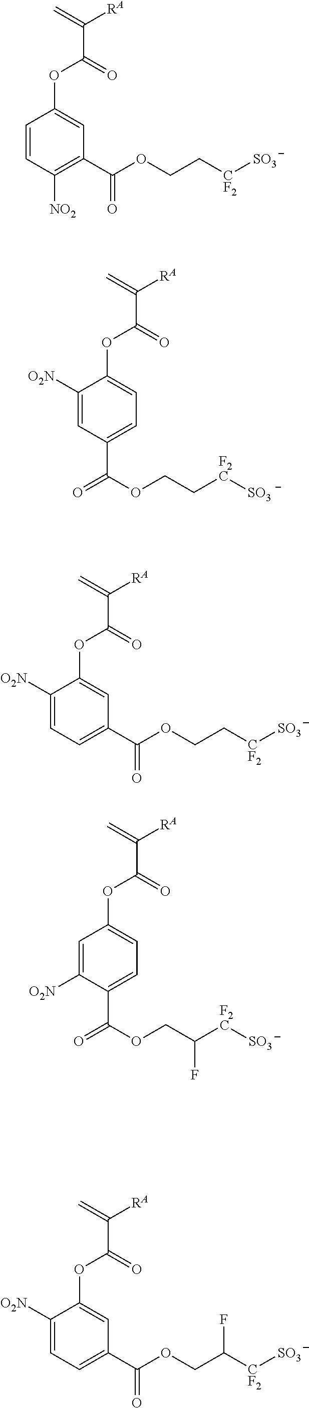

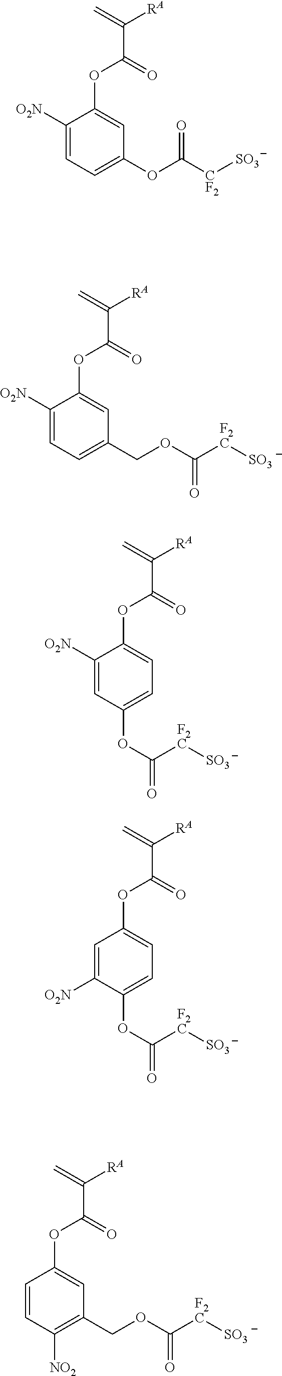

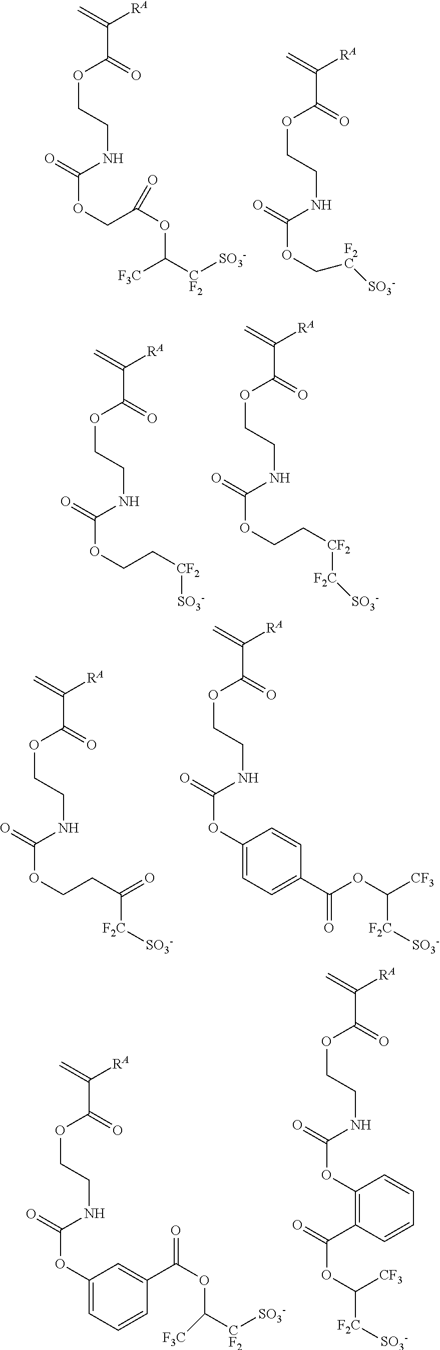

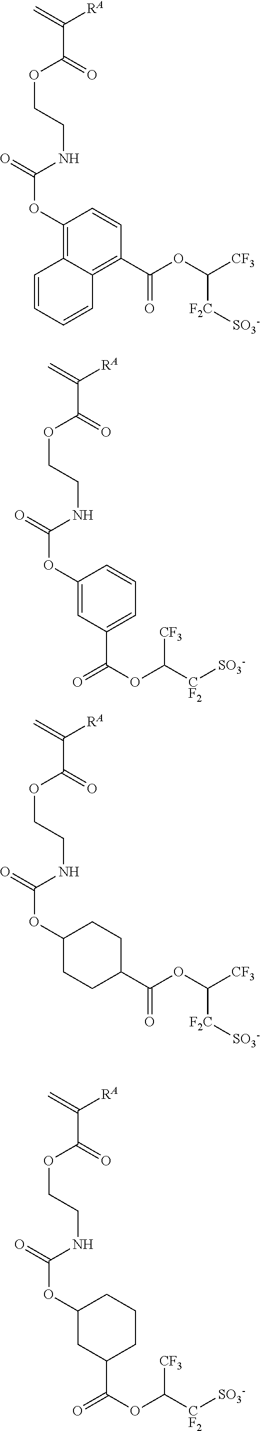

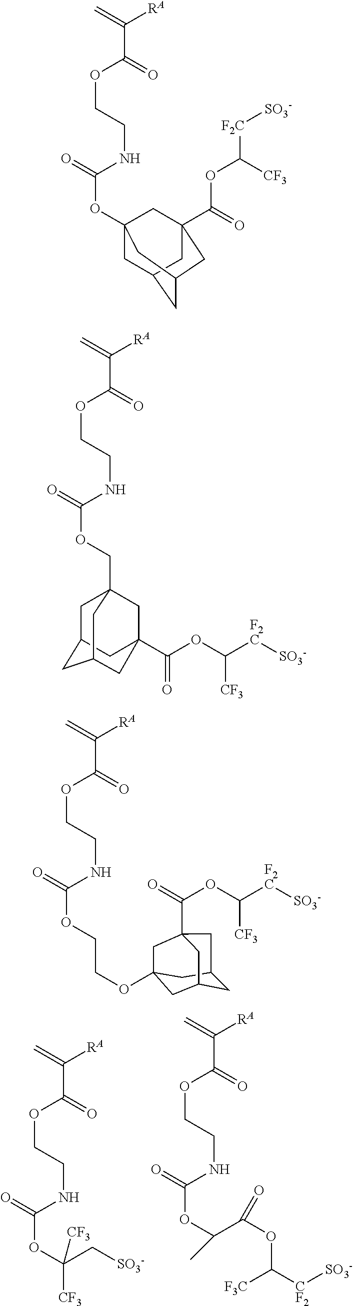

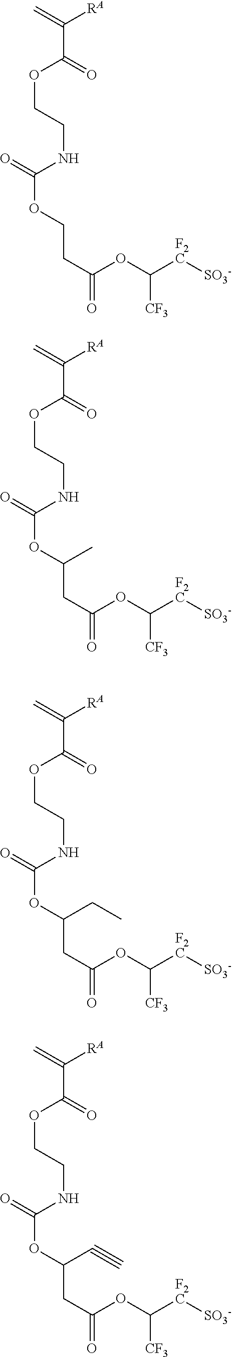

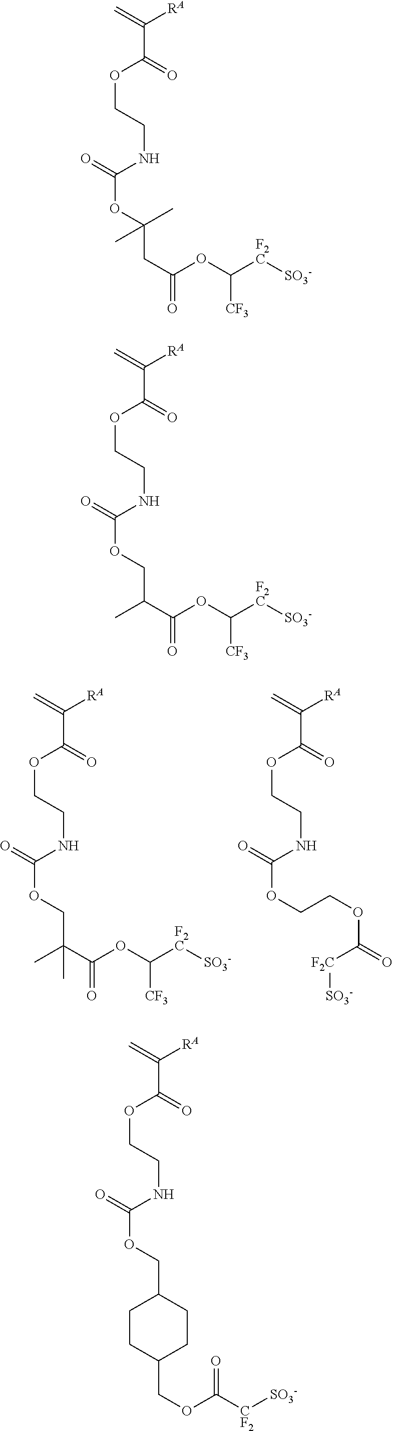

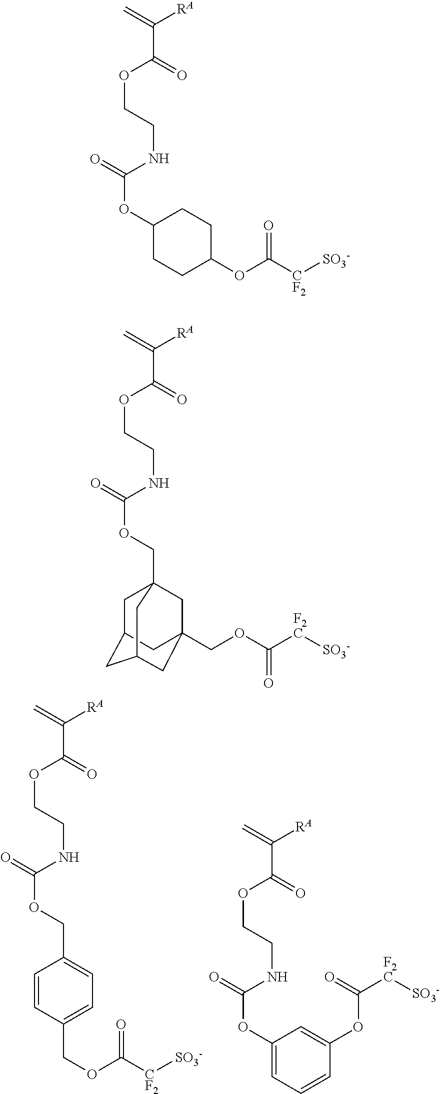

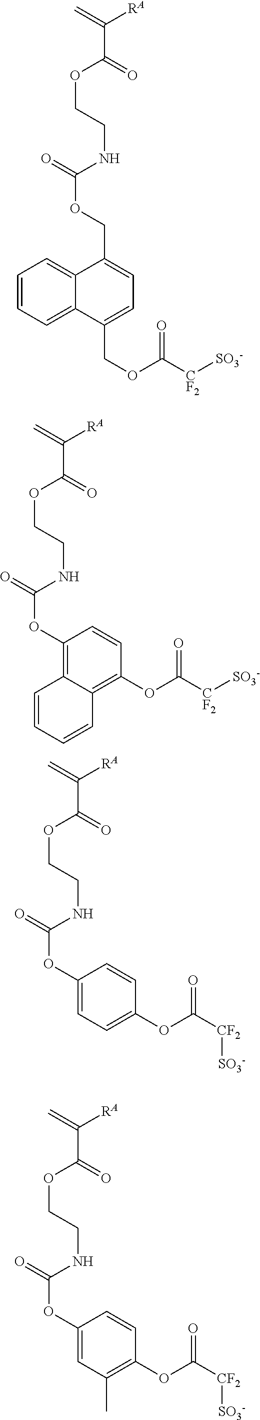

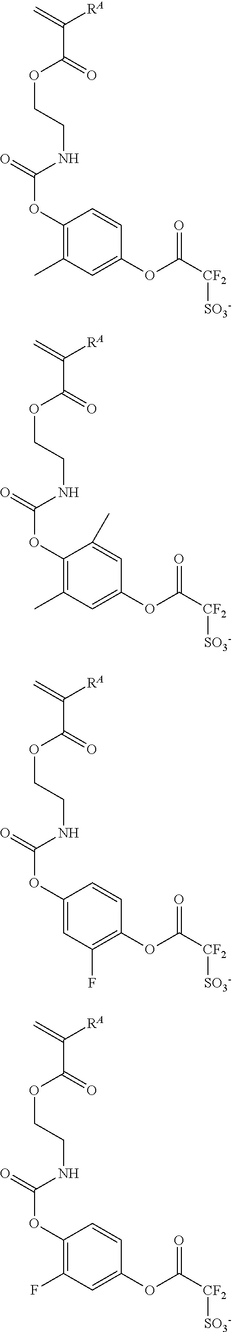

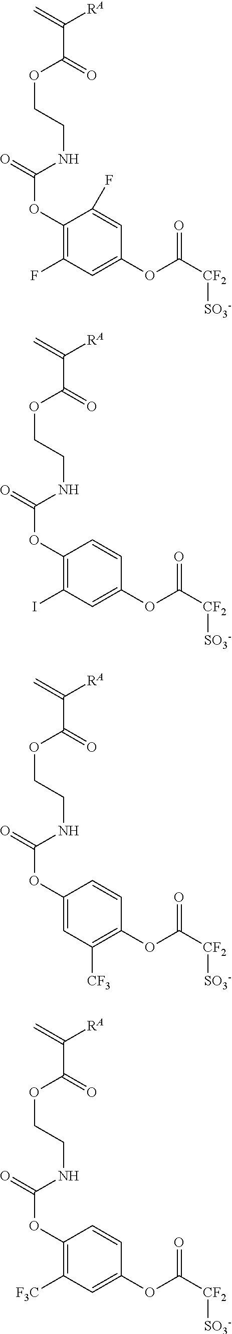

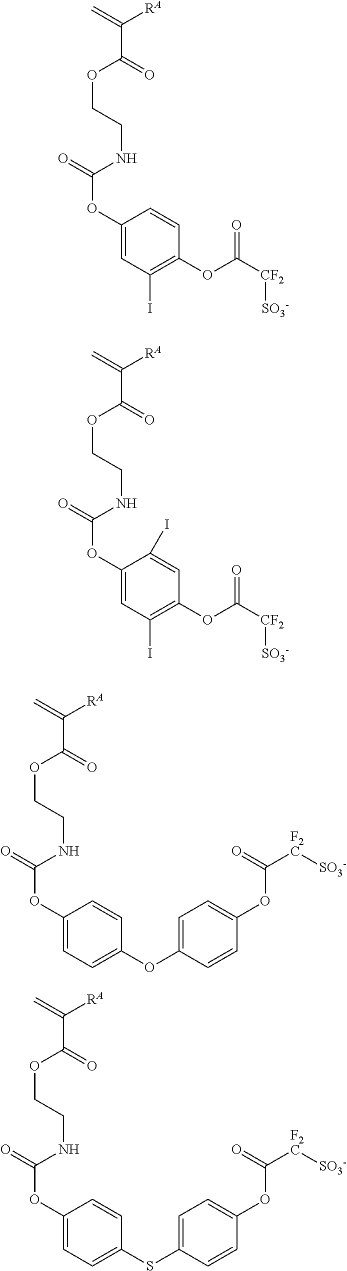

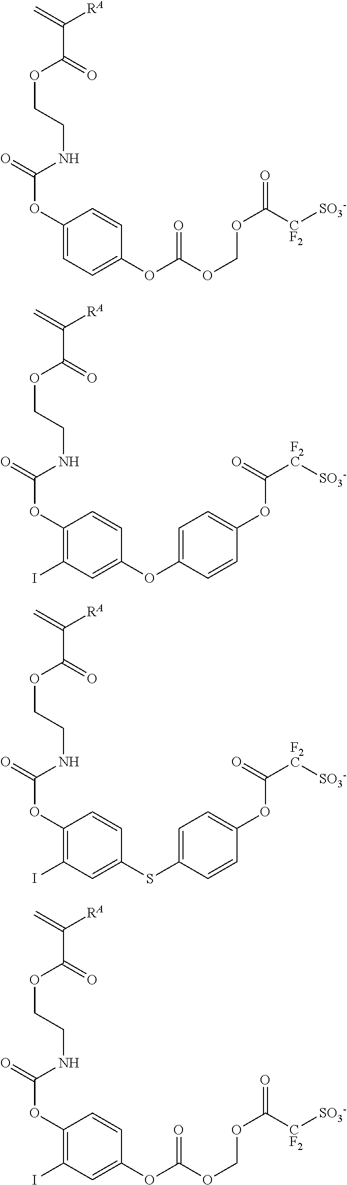

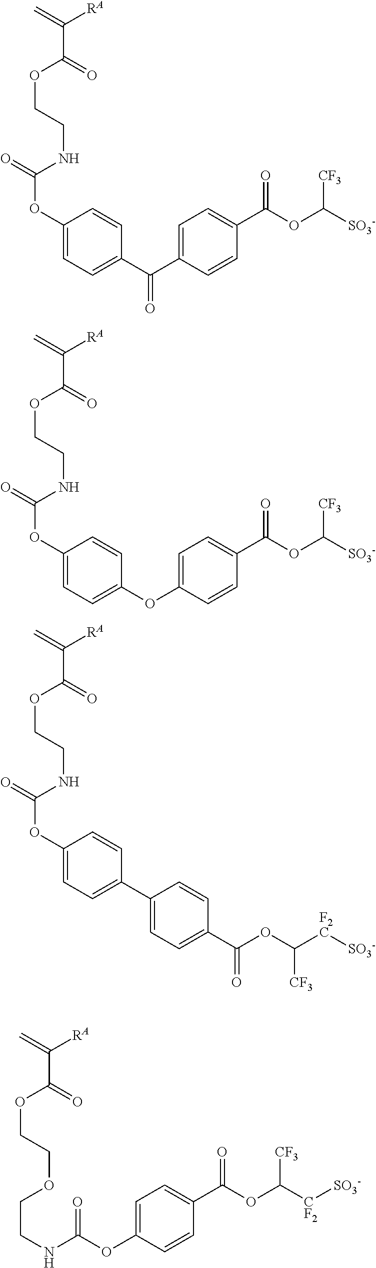

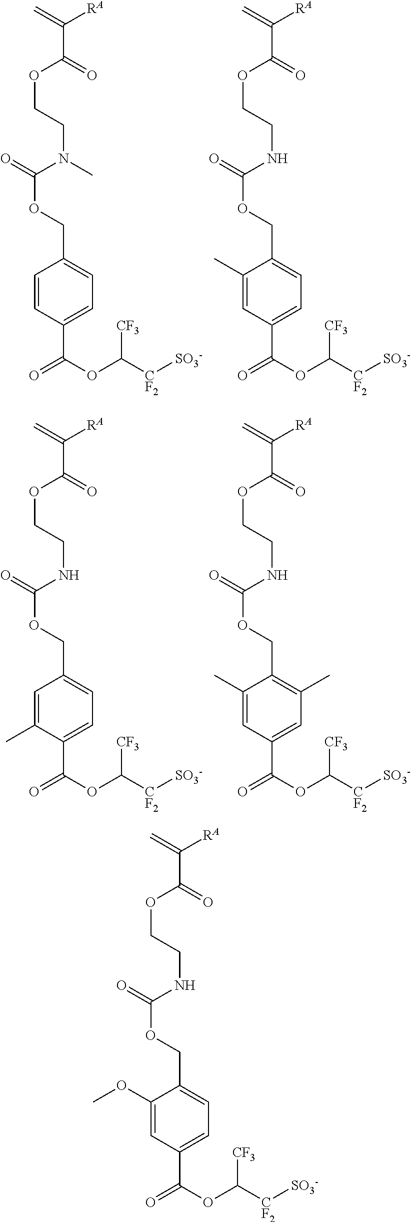

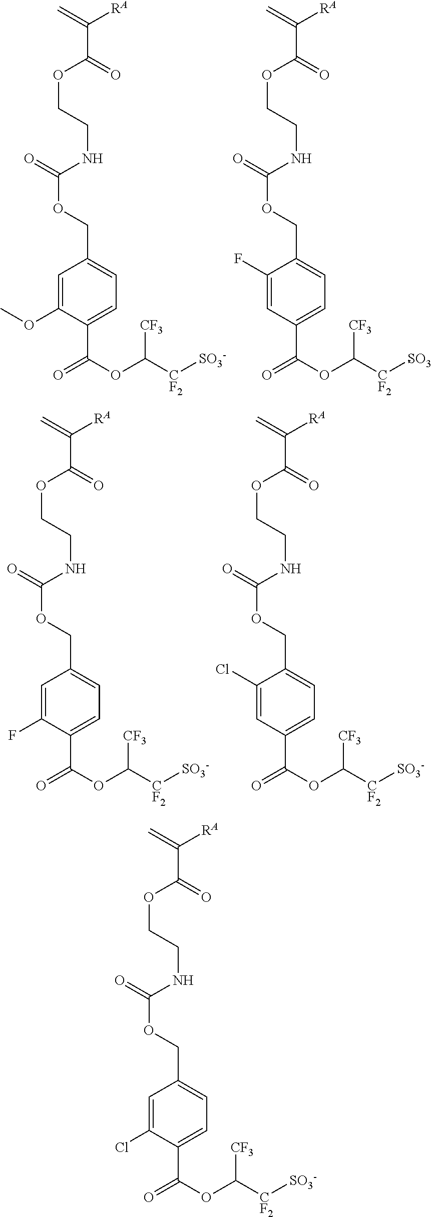

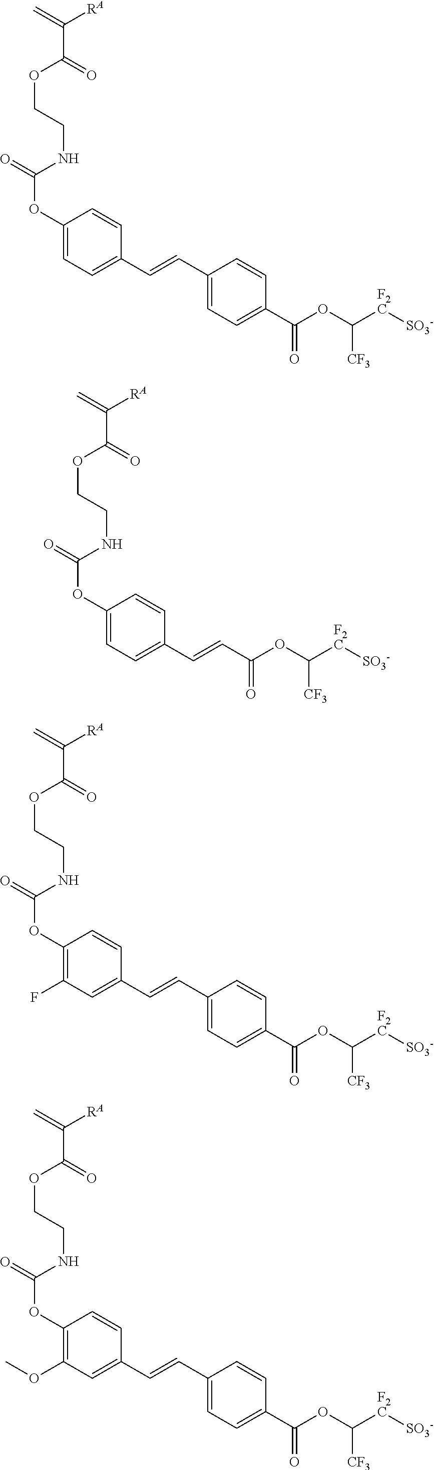

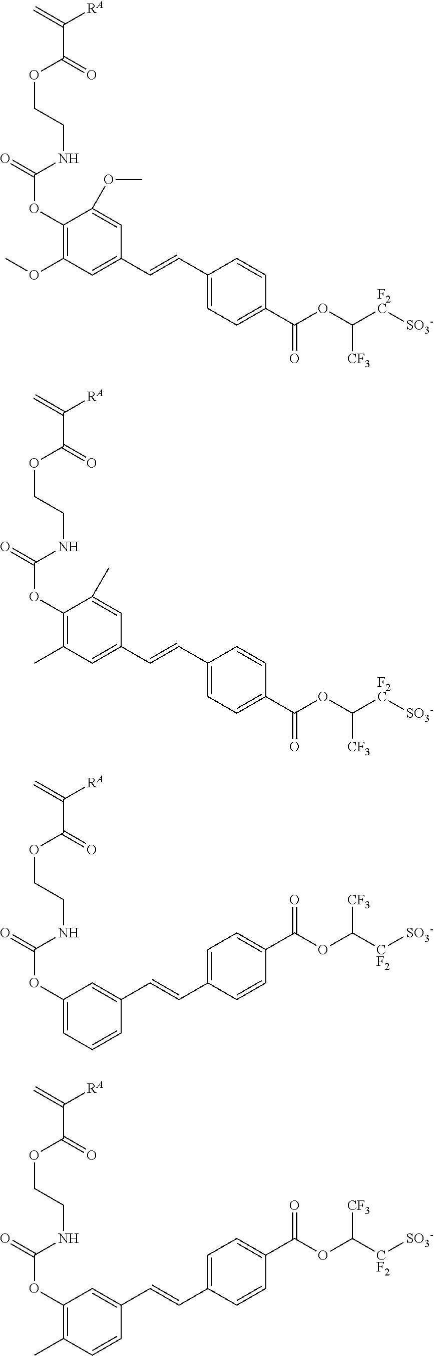

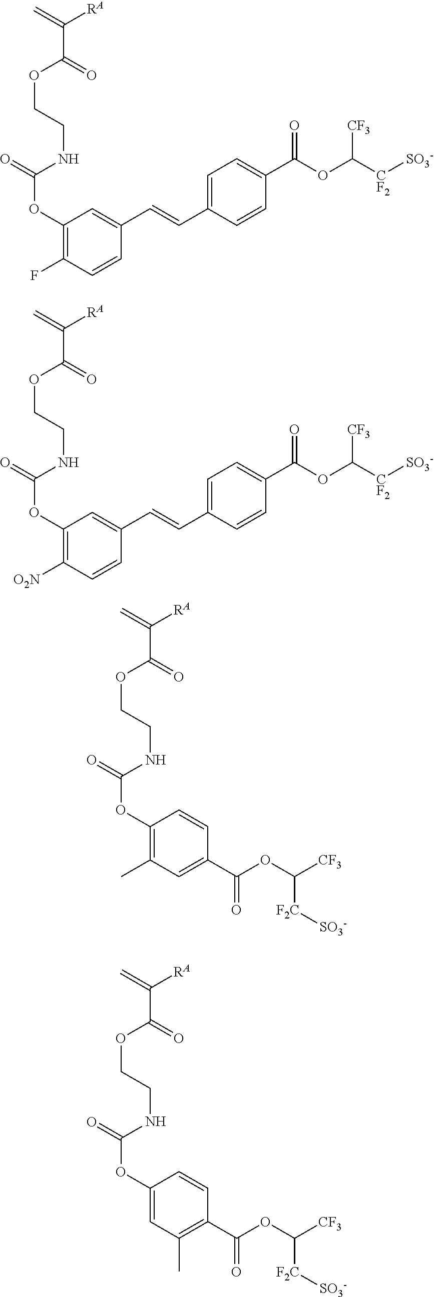

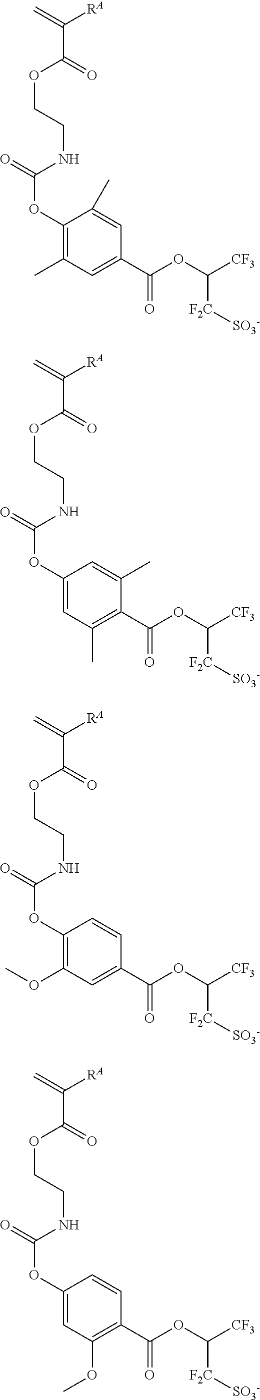

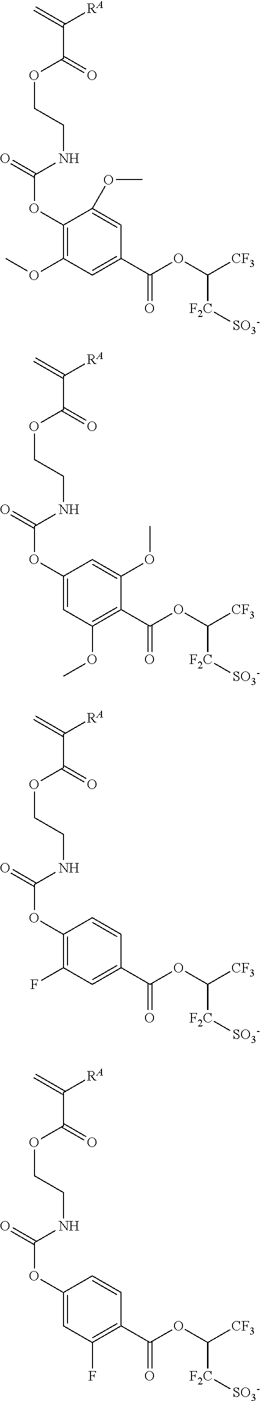

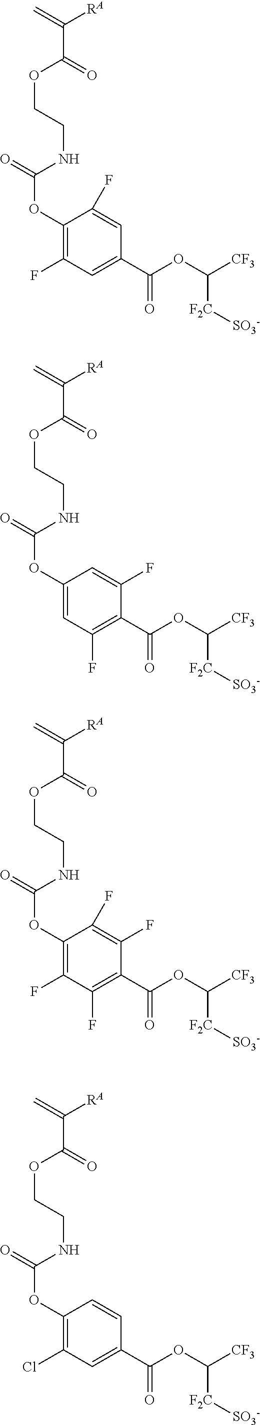

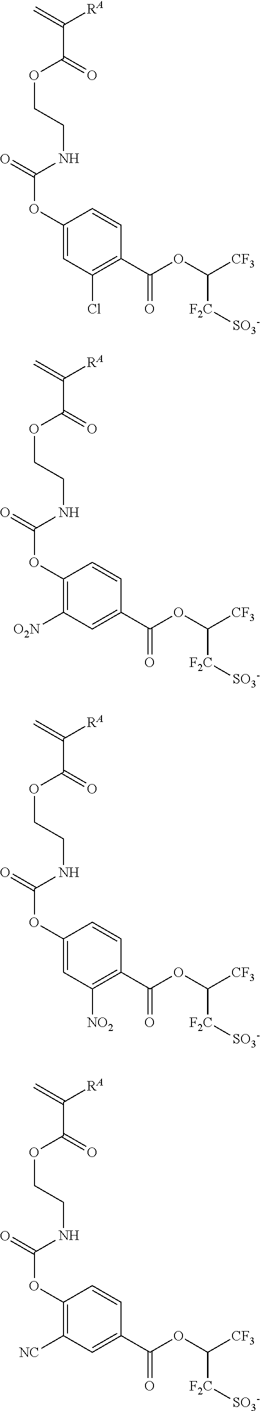

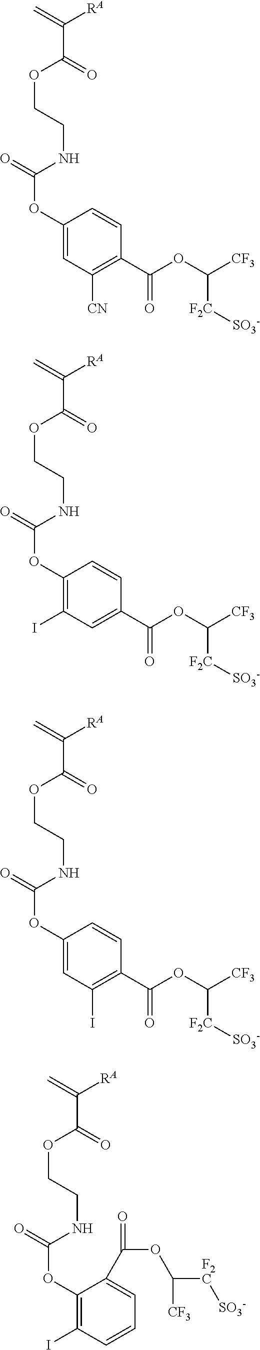

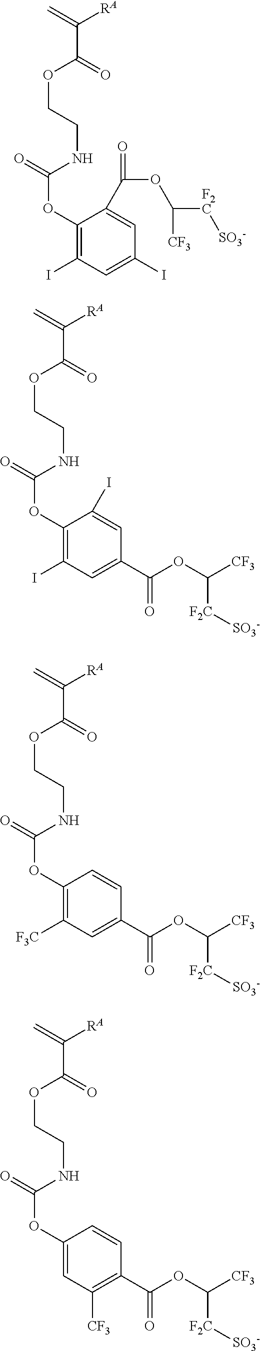

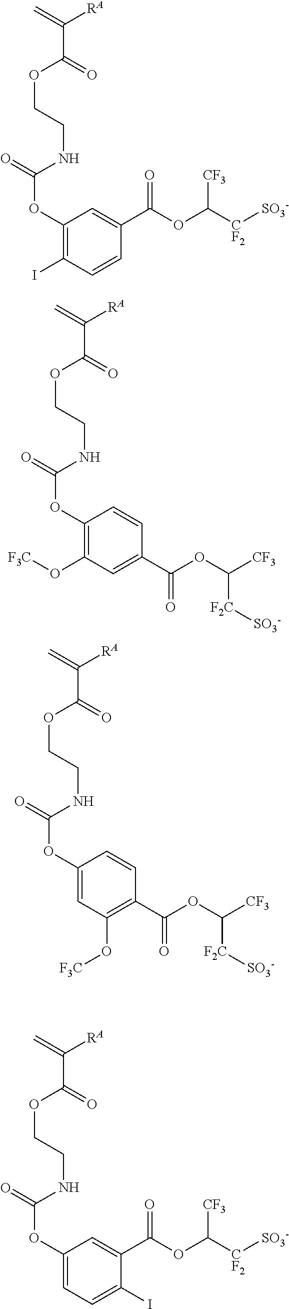

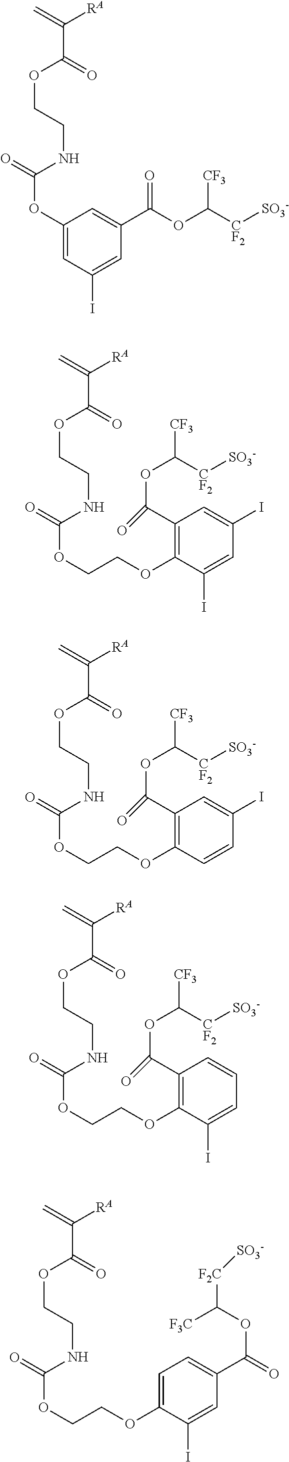

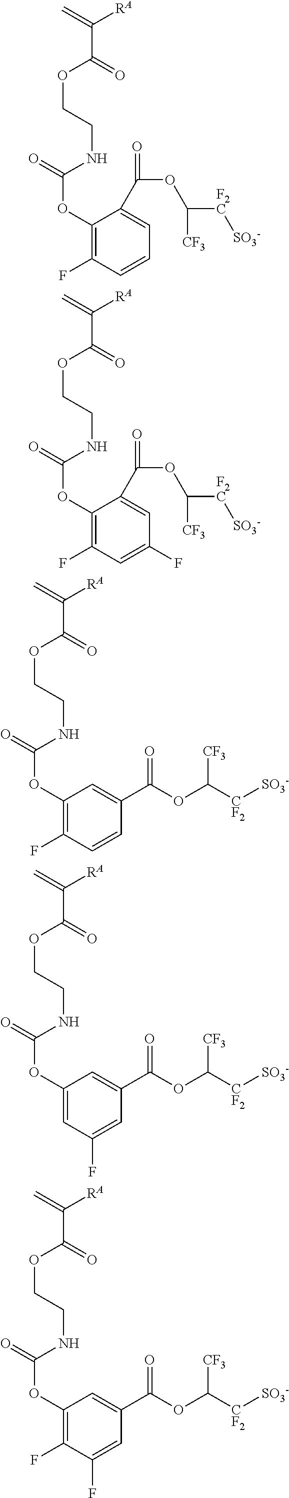

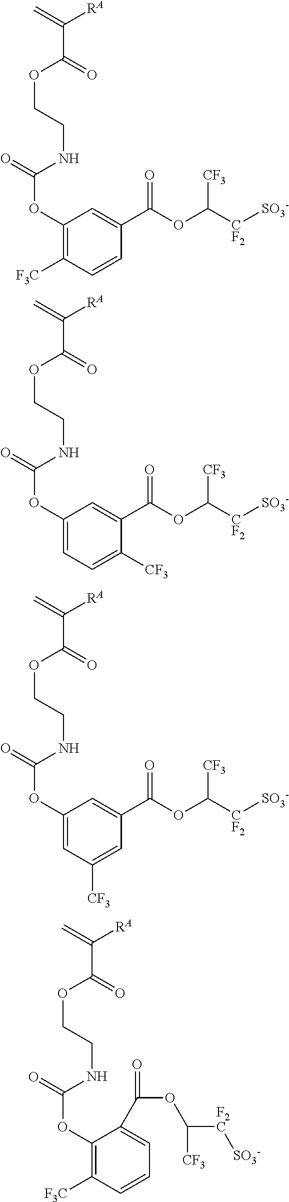

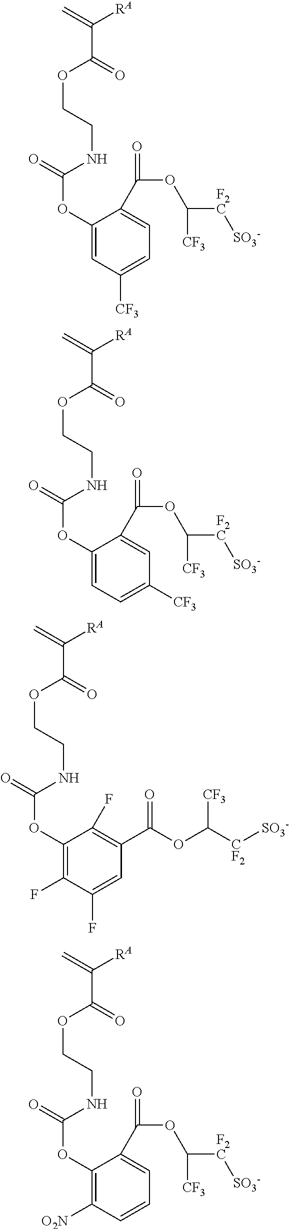

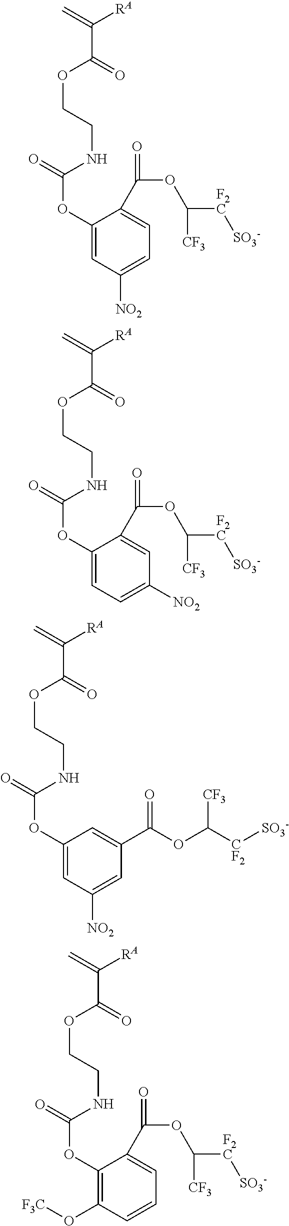

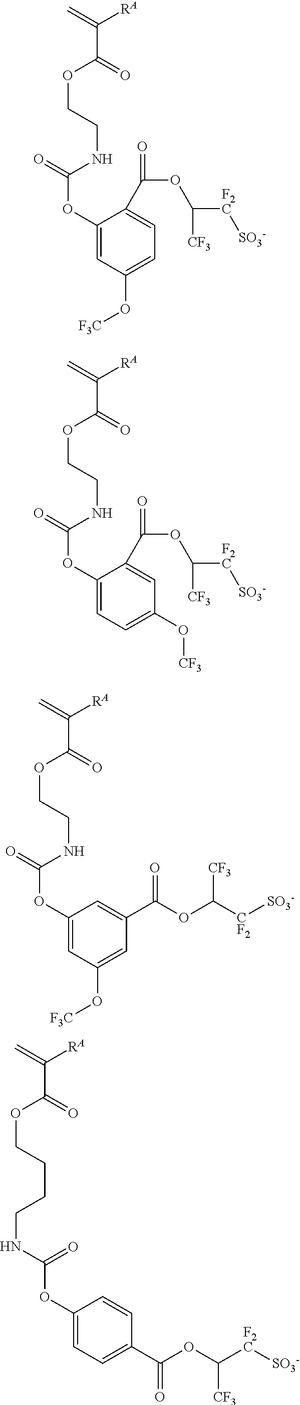

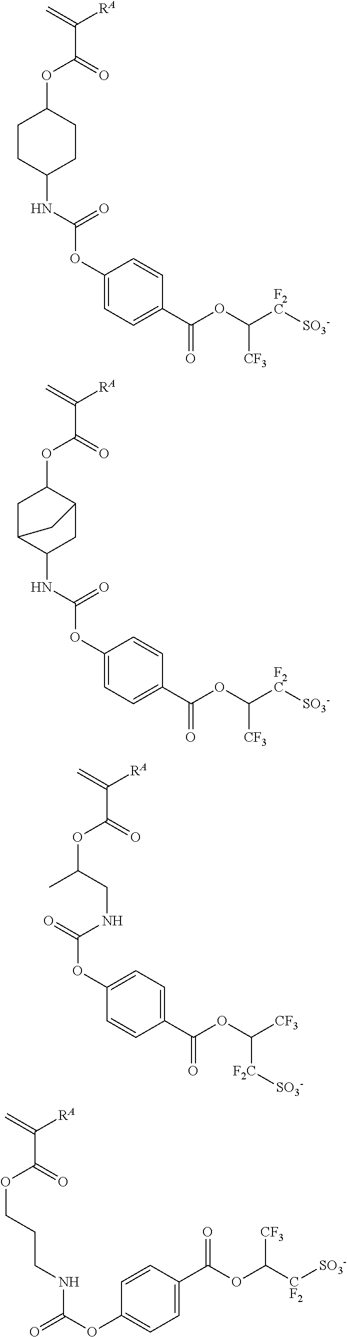

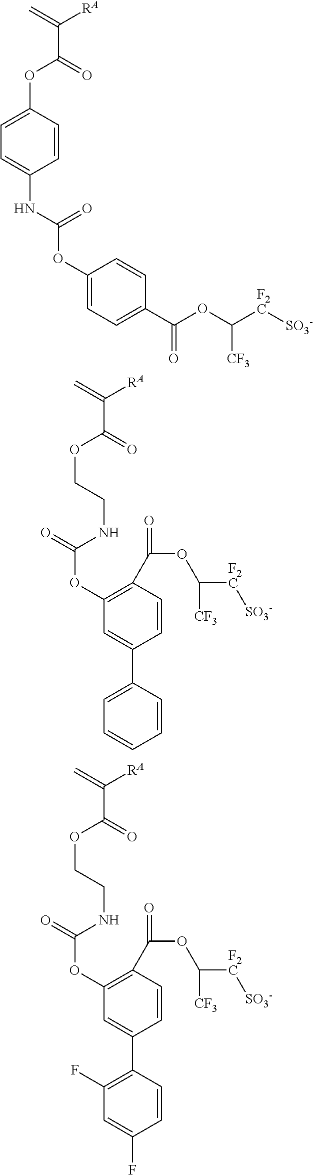

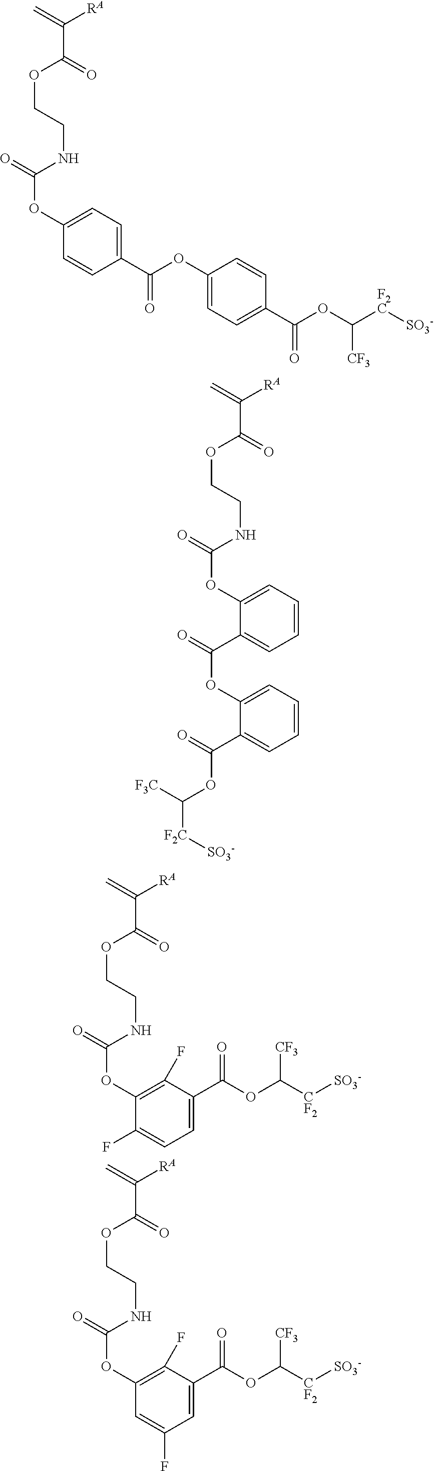

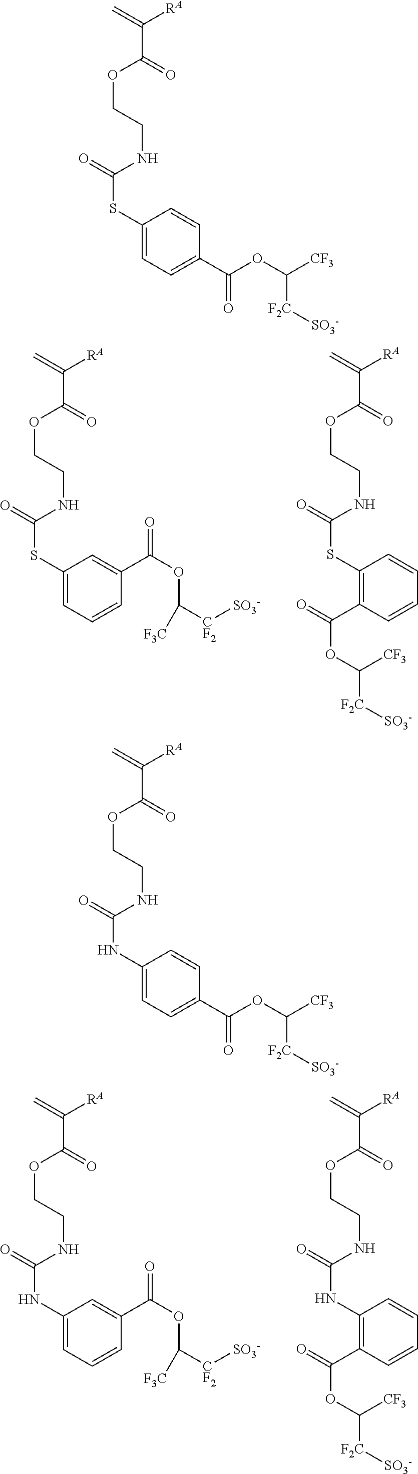

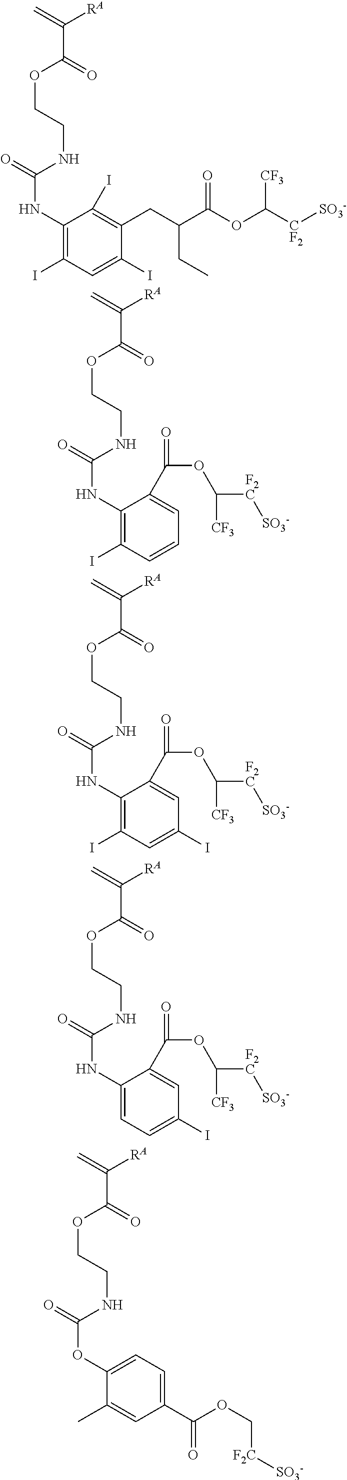

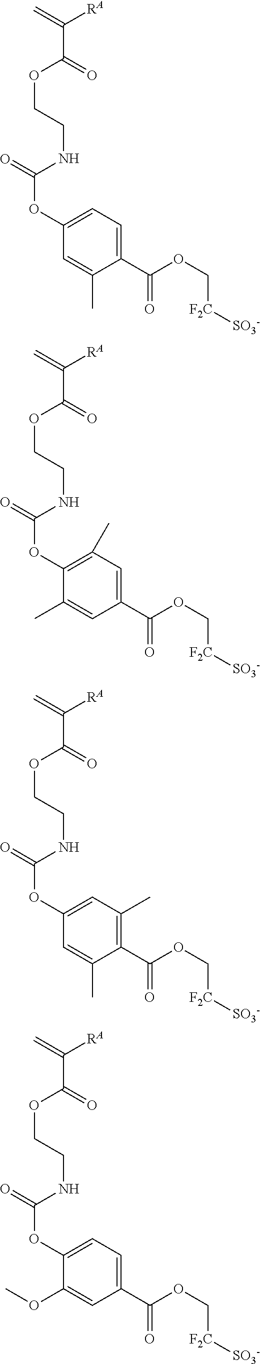

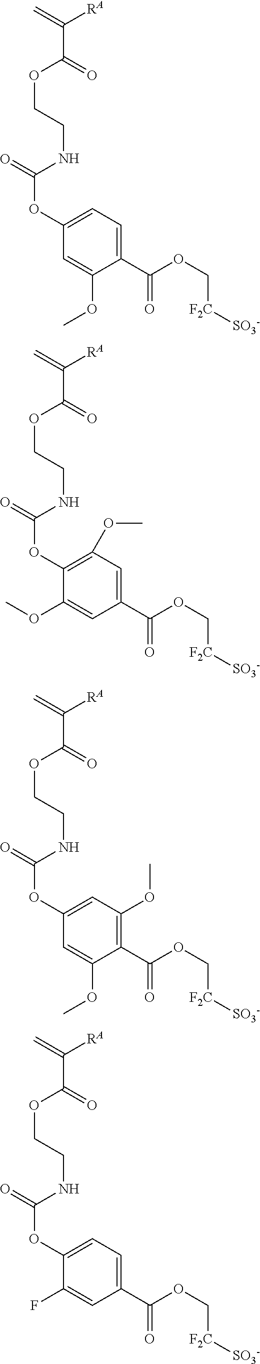

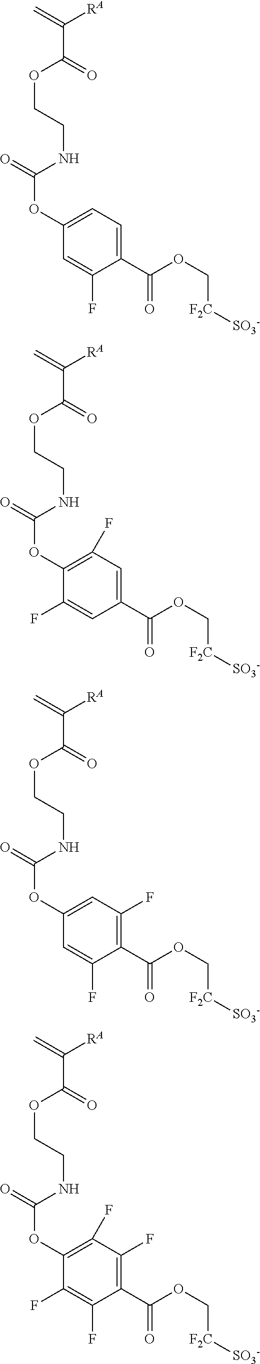

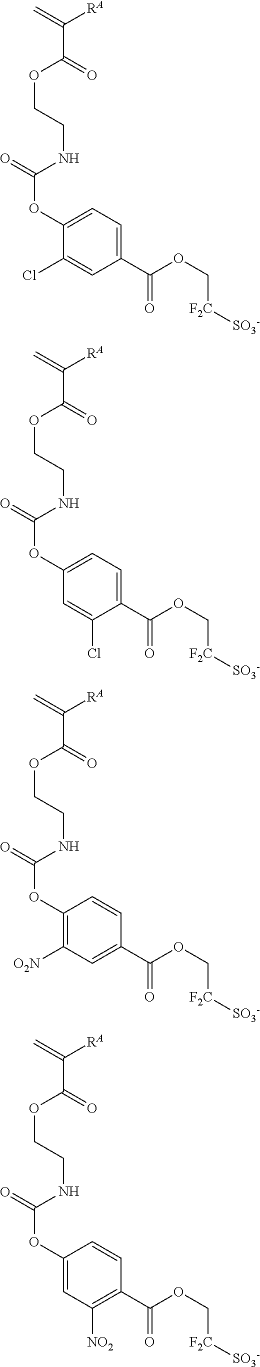

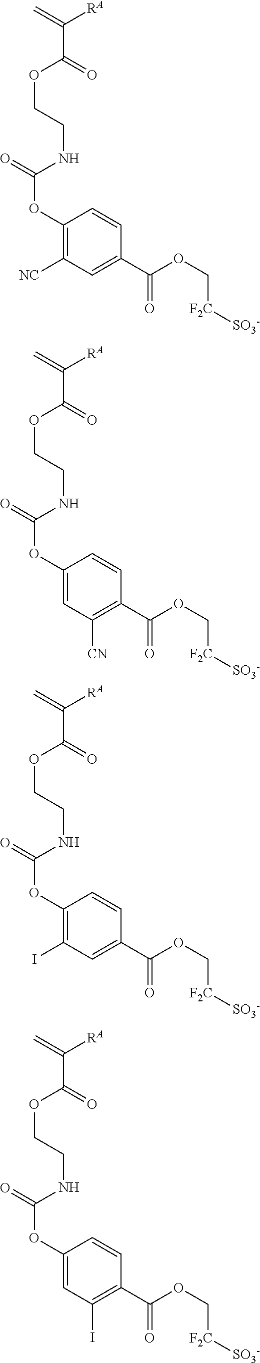

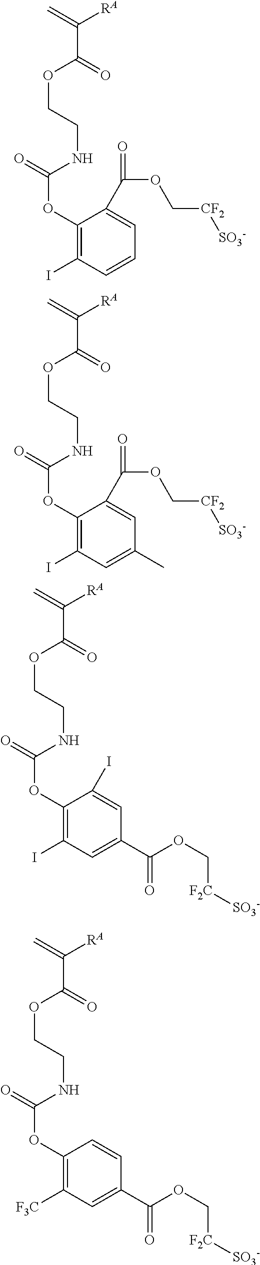

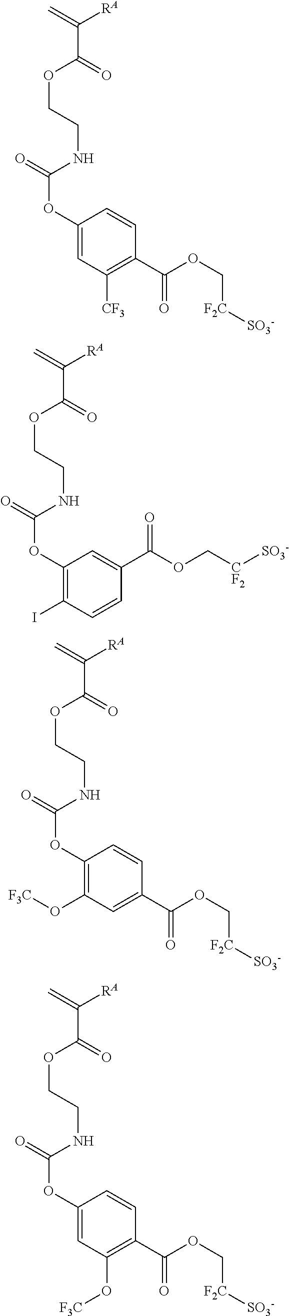

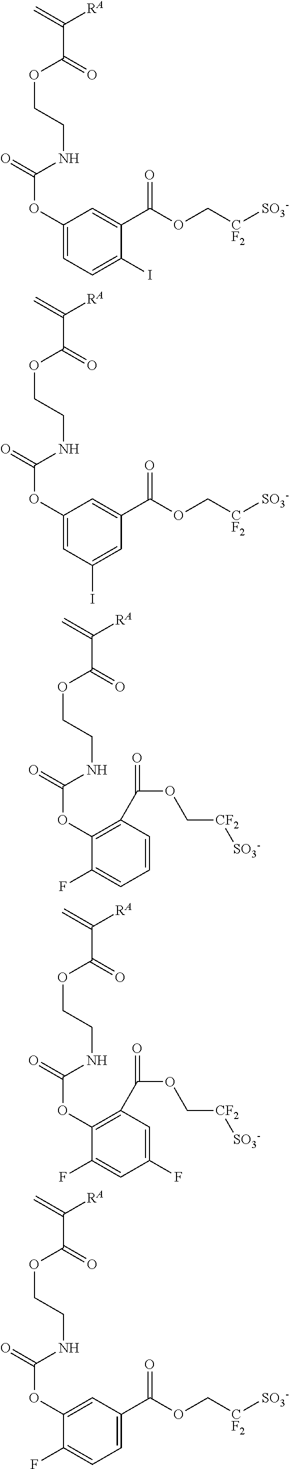

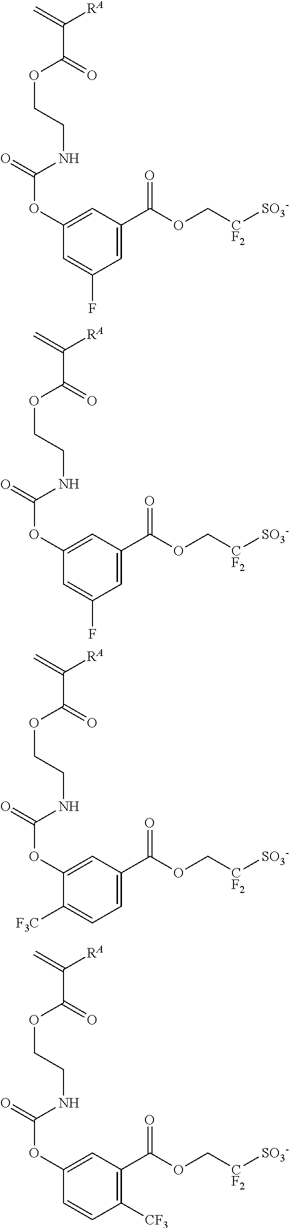

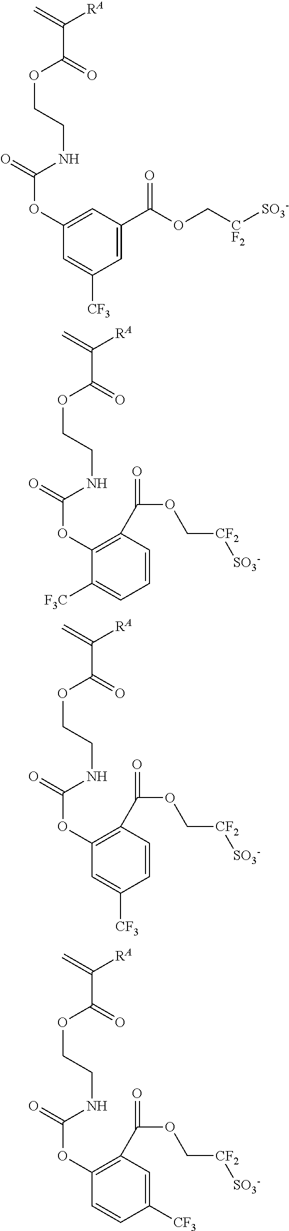

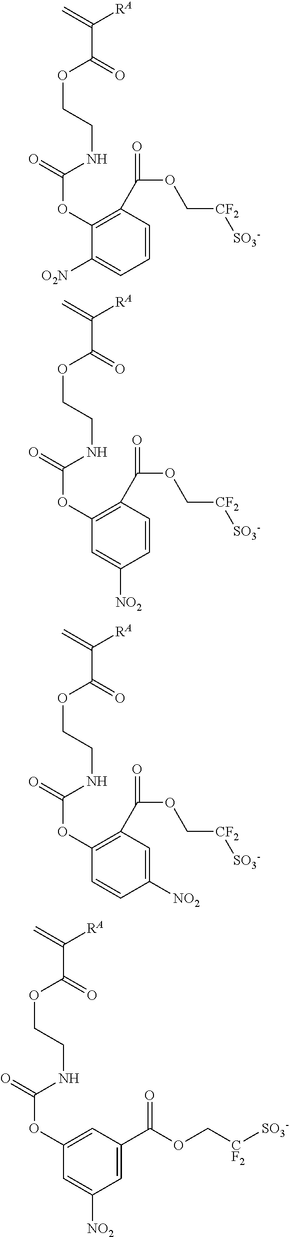

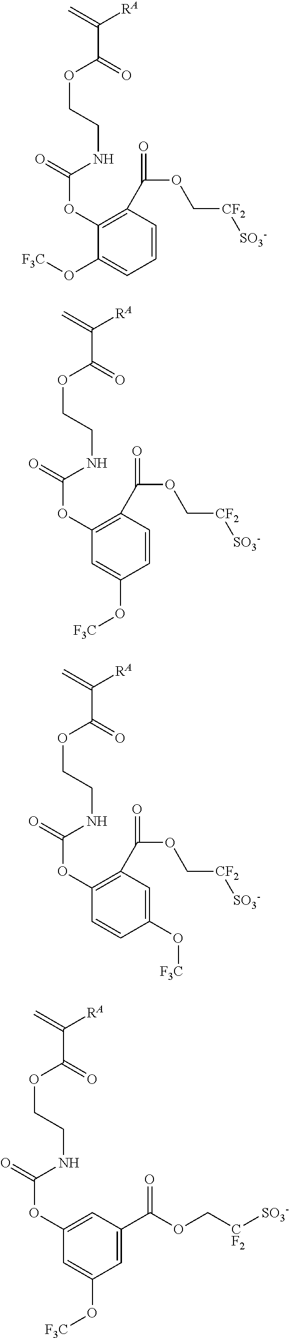

Examples of the anion of the monomer from which repeat units f3 are derived are shown below, but not limited thereto. In the following formula, R^{A} is as defined above.

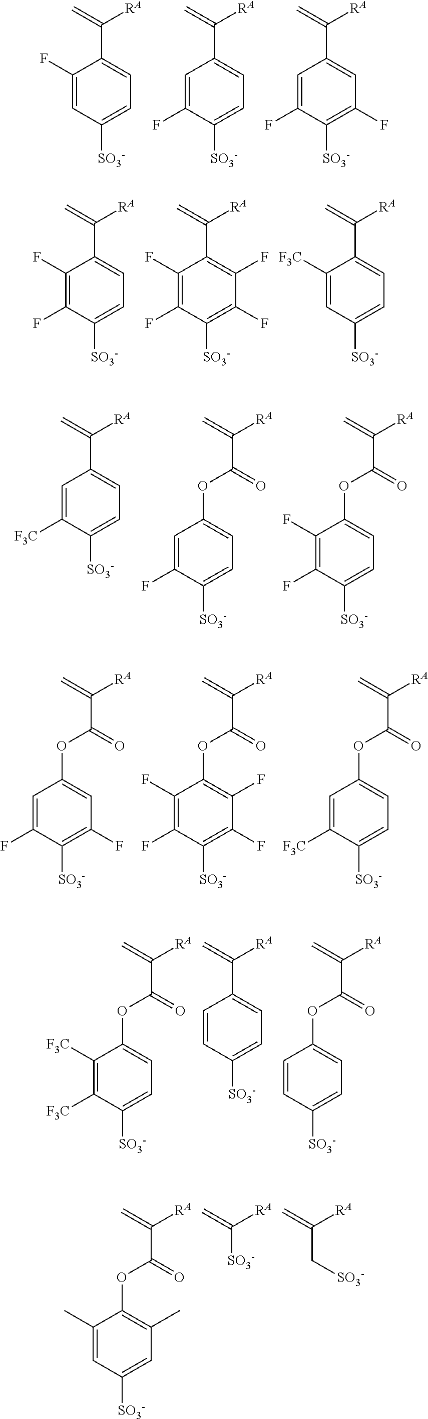

The repeat units f1 to f3 have an acid generator function. The attachment of an acid generator to the polymer main chain is effective in restraining acid diffusion, thereby preventing a reduction of resolution due to blur by acid diffusion. LWR or CDU is improved since the acid generator is uniformly distributed. In the case of using the base polymer including the repeat units f, the blending of an acid generator of addition type described below may be omitted.

In the base polymer, a fraction of repeat units a1, a2, b, c, d, e, f1, f2, and f3 is: preferably 0≤a1≤0.9, 0≤a2≤0.9, 0≤a1+a2≤0.9, 0≤b≤0.9, 0≤c≤0.9, 0≤d≤0.5, 0≤e≤0.5, 0≤f1≤0.5, 0≤f2≤0.5, 0≤f3≤0.5, and 0≤f1+f2+f3≤0.5; more preferably 0≤a1≤0.8, 0≤a2≤0.8, 0≤a1+a2≤0.8, 0≤b≤0.8, 0≤c≤0.8, 0≤d≤0.4, 0≤e≤0.4, 0≤f1≤0.4, 0≤f2≤0.4, 0≤f3≤0.4, and 0≤f1+f2+f3≤0.4; and further preferably 0≤a1≤0.7, 0≤a2≤0.7, 0≤a1+a2≤0.7, 0≤b≤0.7, 0≤c≤0.7, 0≤d≤0.3, 0≤e≤0.3, 0≤f1≤0.3, 0≤f2≤0.3, 0≤f3≤0.3, and 0≤f1+f2+f3≤0.3. Provided that a1+a2+b+c+d+f1+f2+f3+e=1.0.

Examples of the method for synthesizing the base polymer include a method in which monomers from which the foregoing repeat units are derived are heated in an organic solvent with a radical polymerization initiator added thereto to perform polymerization.

Examples of the organic solvent used in the polymerization include toluene, benzene, tetrahydrofuran (THF), diethyl ether, and dioxane. Examples of the polymerization initiator include 2,2′-azobisisobutyronitrile (AIBN), 2,2′-azobis(2,4-dimethylvaleronitrile), dimethyl-2,2-azobis(2-methylpropionate), benzoyl peroxide, and lauroyl peroxide. The temperature during polymerization is preferably 50 to 80° C. The reaction time is preferably 2 to 100 hours and more preferably 5 to 20 hours.

In the case of copolymerizing a monomer containing a hydroxy group, the hydroxy group may be substituted with an acetal group susceptible to deprotection with an acid such as an ethoxyethoxy group during polymerization, and then deprotected by a weak acid and water, or may be substituted with an acetyl group, a formyl group, a pivaloyl group, or the like, and then alkaline hydrolysis may be performed after polymerization.

When hydroxystyrene or hydroxyvinylnaphthalene is copolymerized, acetoxystyrene or acetoxyvinylnaphthalene may be used instead of hydroxystyrene or hydroxyvinylnaphthalene, and after polymerization, the acetoxy group may be deprotected by the alkaline hydrolysis, thereby converting the polymer product to hydroxystyrene or hydroxyvinylnaphthalene.

As a base during the alkaline hydrolysis, aqueous ammonia, triethylamine, or the like can be used. The reaction temperature is preferably −20 to 100° C. and more preferably 0 to 60° C. The reaction time is preferably 0.2 to 100 hours and more preferably 0.5 to 20 hours.

The weight average molecular weight (Mw) of the base polymer in terms of polystyrene by gel permeation chromatography (GPC) using THE as a solvent is preferably 1000 to 500000 and more preferably 2000 to 30000. If the Mw is in the above range, the heat resistance of the resist film and the solubility of the resist film in an alkaline developer are favorable.

If a base polymer has a wide molecular weight distribution (Mw/Mn) is wide in the base polymer, since a low-molecular-weight or high-molecular-weight polymer is present, there is a possibility that foreign matter is observed on the pattern or pattern profile is degraded after exposure. Since the influences of Mw and Mw/Mn become stronger as the pattern rule becomes finer, the Mw/Mn of the base polymer preferably has narrow dispersity of 1.0 to 2.0, especially 1.0 to 1.5, in order to obtain a resist composition suitable for micropatterning to a small feature size.

The base polymer may contain two or more polymers which differ in compositional ratio, Mw. or Mw/Mn.

Acid Generator

The resist composition of the present invention may comprise an acid generator capable of generating a strong acid (also referred to as acid generator of addition type, hereinafter). As used herein, the term “strong acid” refers to a compound having a sufficient acidity to induce deprotection reaction of an acid labile group on the base polymer in the case of a chemically amplified positive resist composition, or a compound having a sufficient acidity to induce acid catalyzed polarity switch reaction or crosslinking reaction in the case of a chemically amplified negative resist composition. By containing such an acid generator, the sulfonium salt functions as a quencher, and the resist composition of the present invention can function as a chemically amplified positive resist composition or a chemically amplified negative resist composition.

Examples of the acid generator include a compound (photoacid generator) capable of generating an acid in response to actinic ray or radiation. Although the photoacid generator may be any compound capable of generating an acid upon exposure to high-energy radiation, those compounds capable of generating sulfonic acid, imide acid, or methide acid are preferred. Suitable photoacid generators include sulfonium salts, iodonium salts, sulfonyldiazomethane, N-sulfonyloxyimide, and oxime-O-sulfonate acid generators. Specific examples of the photoacid generator include those described in JP-A 2008-111103, paragraphs [0122] to [0142].

As the photoacid generator, sulfonium salts having the following formula (3-1) and iodonium salts having the following formula (3-2) can also be suitably used.

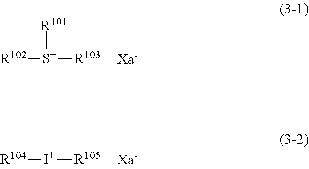

In formulae (3-1) to (3-2), R¹⁰¹ to R¹⁰⁵ are each independently a halogen atom, or a C₁-C₂₀ hydrocarbyl group which may contain a heteroatom.

Examples of the halogen atom represented by R¹⁰¹ to R¹⁰⁵ include a fluorine atom, a chlorine atom, a bromine atom, and an iodine atom.

The C₁-C₂₀ hydrocarbyl group represented by R¹⁰¹ to R¹⁰⁵ may be saturated or unsaturated and straight, branched, or cyclic. Specific examples thereof include C₁-C₂₀ alkyl groups such as a methyl group, an ethyl group, a n-propyl group, an isopropyl group, a n-butyl group, an isobutyl group, a sec-butyl group, a tert-butyl group, a n-pentyl group, a n-hexyl group, a n-octyl group, a n-nonyl group, a n-decyl group, an undecyl group, a dodecyl group, a tridecyl group, a tetradecyl group, a pentadecyl group, a heptadecyl group, an octadecyl group, a nonadecyl group, and an icosyl group; C₃-C₂₀ cyclic saturated hydrocarbyl groups such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; C₂-C₂₀ alkenyl groups such as a vinyl group, a propenyl group, a butenyl group, and a hexenyl group; C₂-C₂₀ alkynyl groups such as an ethynyl group, a propynyl group, and a butynyl group; C₃-C₂₀ cyclic unsaturated aliphatic hydrocarbyl groups such as a cyclohexenyl group and a norbornenyl group; C₆-C₂₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, a naphthyl group, a methylnaphthyl group, an ethylnaphthyl group, a n-propylnaphthyl group, an isopropylnaphthyl group, a n-butylnaphthyl group, an isobutylnaphthyl group, a sec-butylnaphthyl group, and a tert-butylnaphthyl group; C₇-C₂₀ aralkyl groups such as a benzyl group and a phenethyl group; and groups obtained by combining these.

Some or all of the hydrogen atoms in the hydrocarbyl group may be substituted with a group containing a heteroatom such as an oxygen atom, a sulfur atom, a nitrogen atom, or a halogen atom, some of —CH₂— in the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a mercapto group, a carbonyl group, an ether bond, an ester bond, a sulfonate bond, a carbonate bond, a lactone ring, a sultone ring, a carboxylic anhydride (—C(═O)—O—C(═O)—), a haloalkyl group, or the like.

A pair of R¹⁰¹ and R¹⁰² may bond together to form a ring with a sulfur atom to which they are attached. In this case, the ring preferably has the following structure.

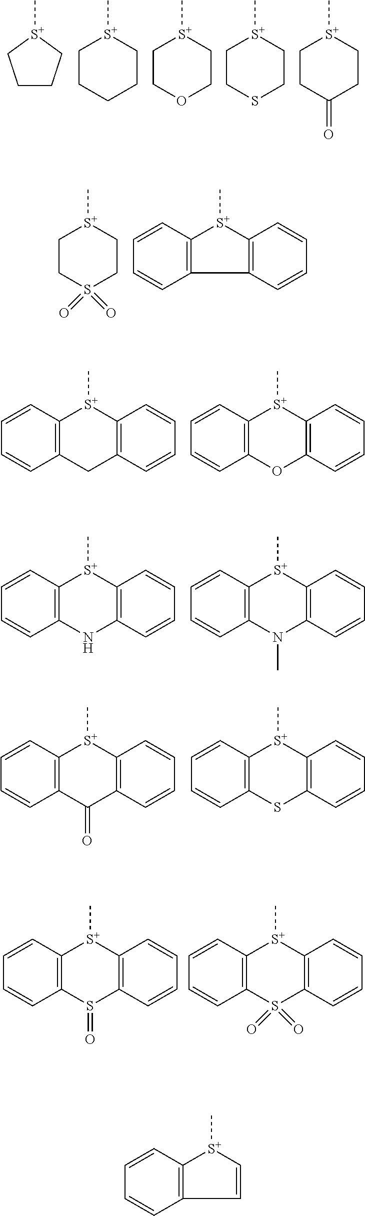

wherein the broken line denotes a point of attachment to R^{103.}

Examples of the cation of the sulfonium salt having formula (3-1) are derived are shown below, but not limited thereto.

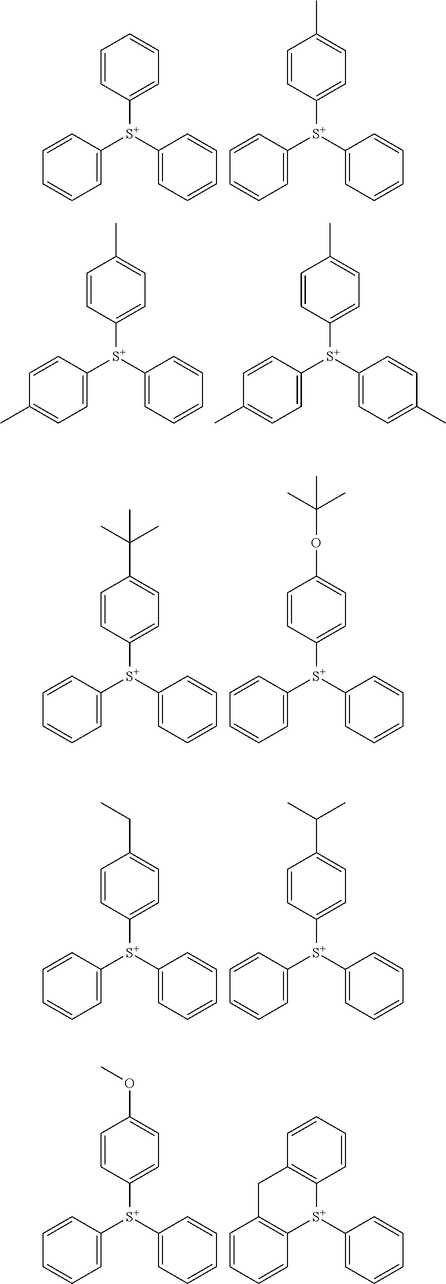

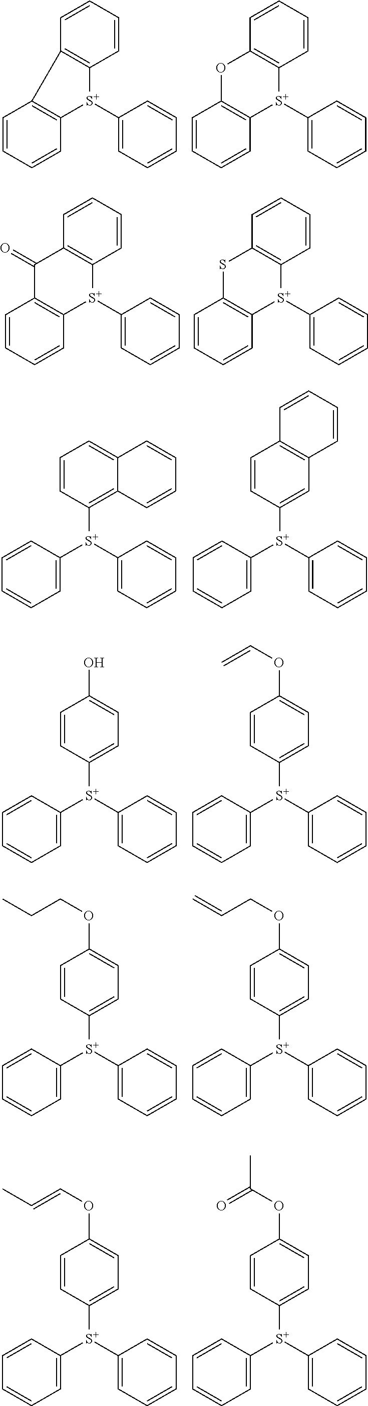

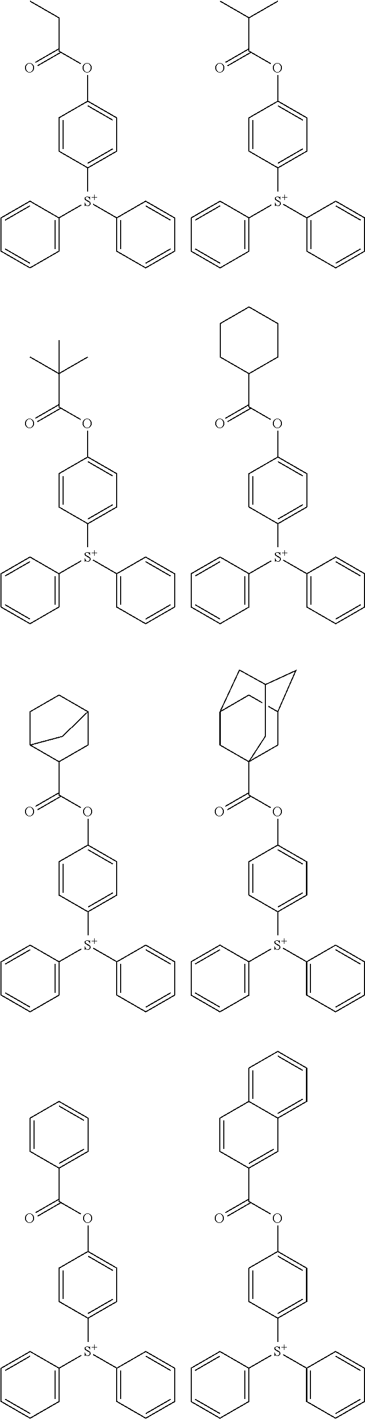

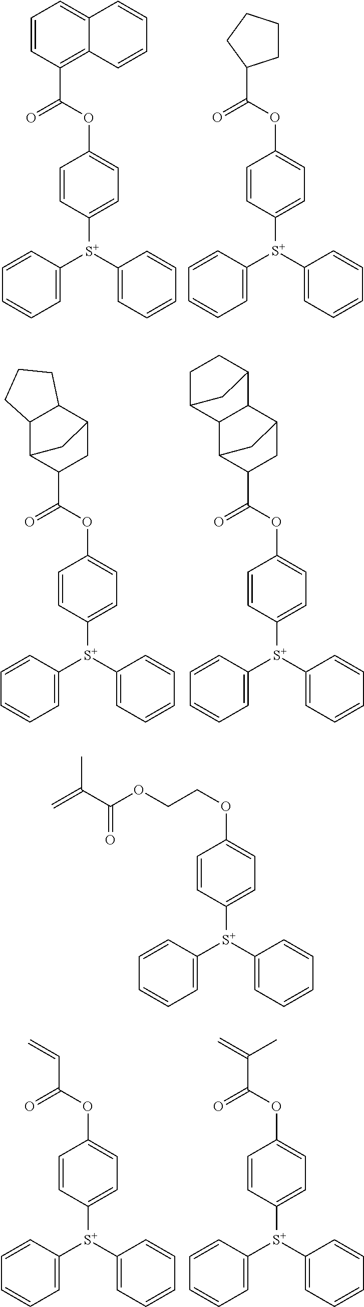

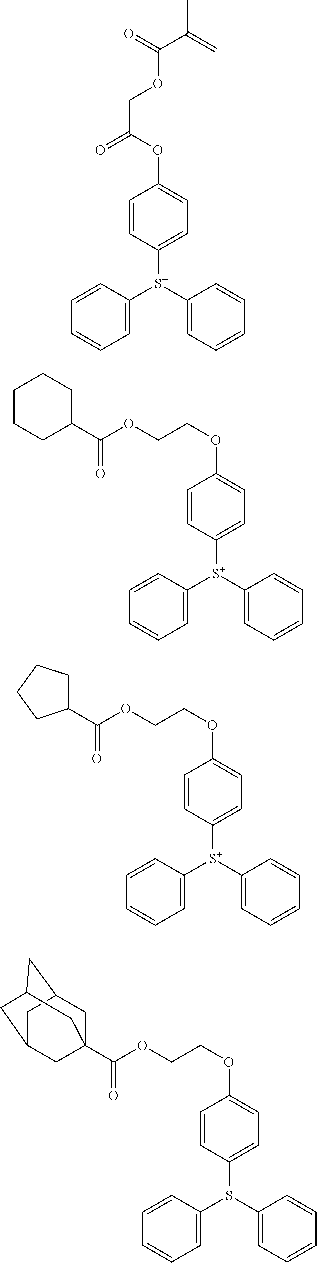 [SMILES: C=C(C)C(=O)OCC(=O)Oc1ccc([S+](c2ccccc2)c2ccccc2)cc1 ; O=C(OCCOc1ccc([S+](c2ccccc2)c2ccccc2)cc1)C1CCCCC1 ; O=C(OCCOc1ccc([S+](c2ccccc2)c2ccccc2)cc1)C1CCCC1 ; O=C(OCCOc1ccc([S+](c2ccccc2)c2ccccc2)cc1)C12CC3CC(CC(C3)C1)C2]

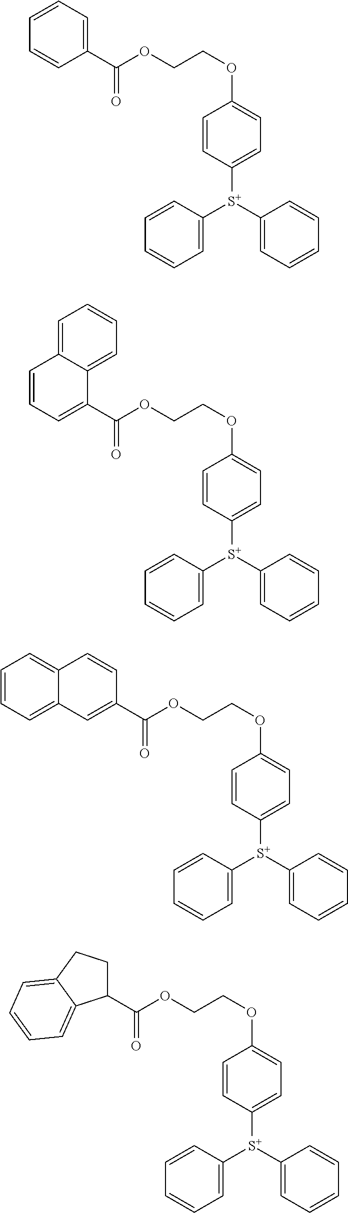 [SMILES: O=C(OCCOc1ccc([S+](c2ccccc2)c2ccccc2)cc1)c1ccccc1 ; O=C(OCCOc1ccc([S+](c2ccccc2)c2ccccc2)cc1)c1cccc2ccccc12 ; O=C(OCCOc1ccc([S+](c2ccccc2)c2ccccc2)cc1)c1ccc2ccccc2c1 ; O=C(OCCOc1ccc([S+](c2ccccc2)c2ccccc2)cc1)C1CCc2ccccc21]

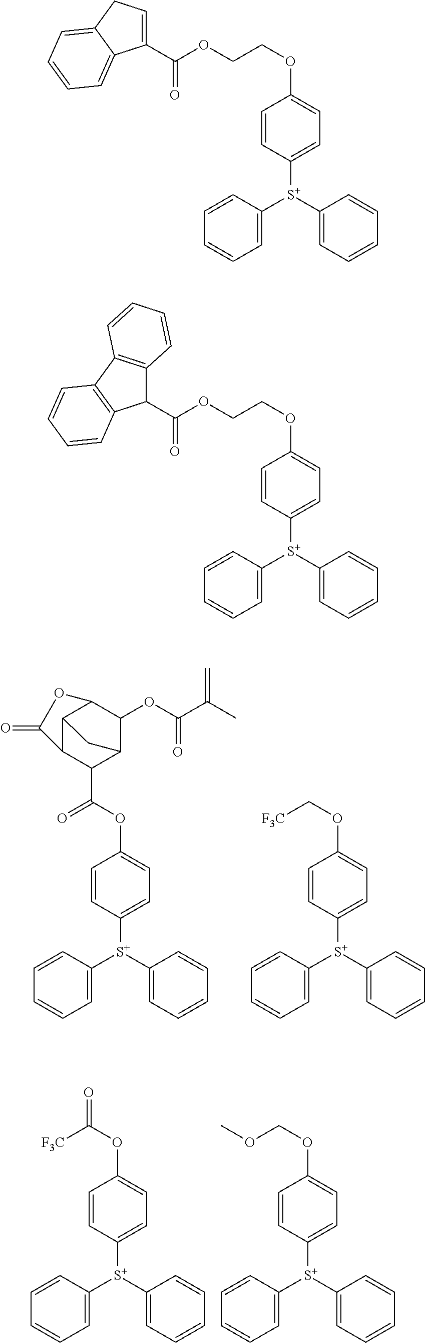 [SMILES: O=C(OCCOc1ccc([S+](c2ccccc2)c2ccccc2)cc1)C1=CCc2ccccc21 ; O=C(OCCOc1ccc([S+](c2ccccc2)c2ccccc2)cc1)C1c2ccccc2-c2ccccc21 ; C=C(C)C(=O)OC1C2CC3C1OC(=O)C3C2C(=O)Oc1ccc([S+](c2ccccc2)c2ccccc2)cc1 ; FC(F)(F)COc1ccc([S+](c2ccccc2)c2ccccc2)cc1 ; O=C(Oc1ccc([S+](c2ccccc2)c2ccccc2)cc1)C(F)(F)F ; COCOc1ccc([S+](c2ccccc2)c2ccccc2)cc1]

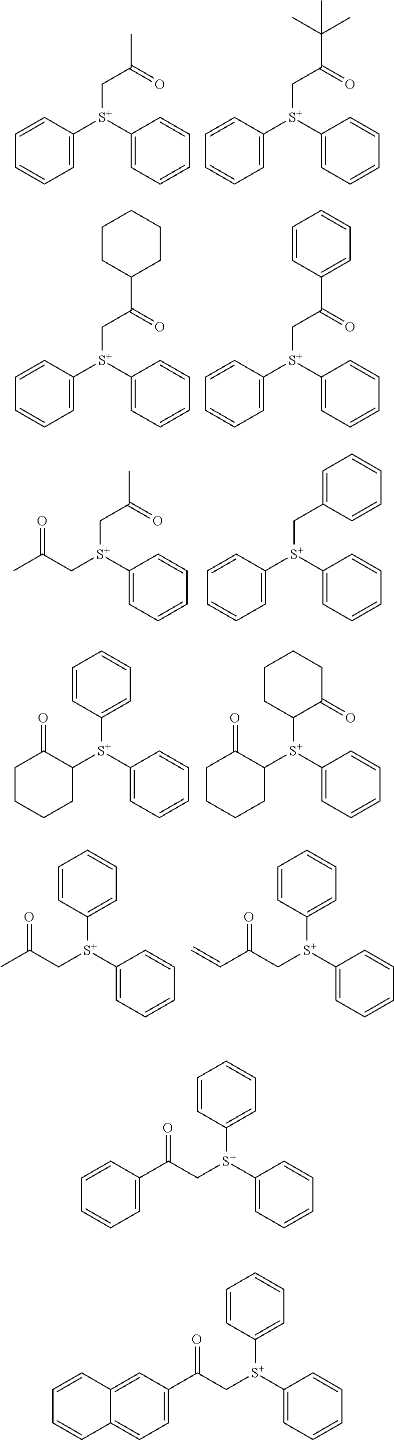

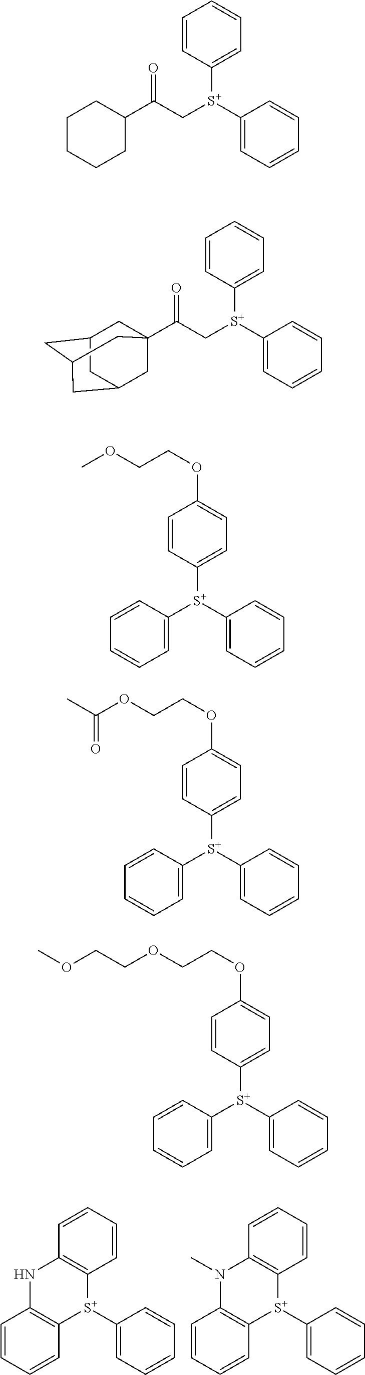

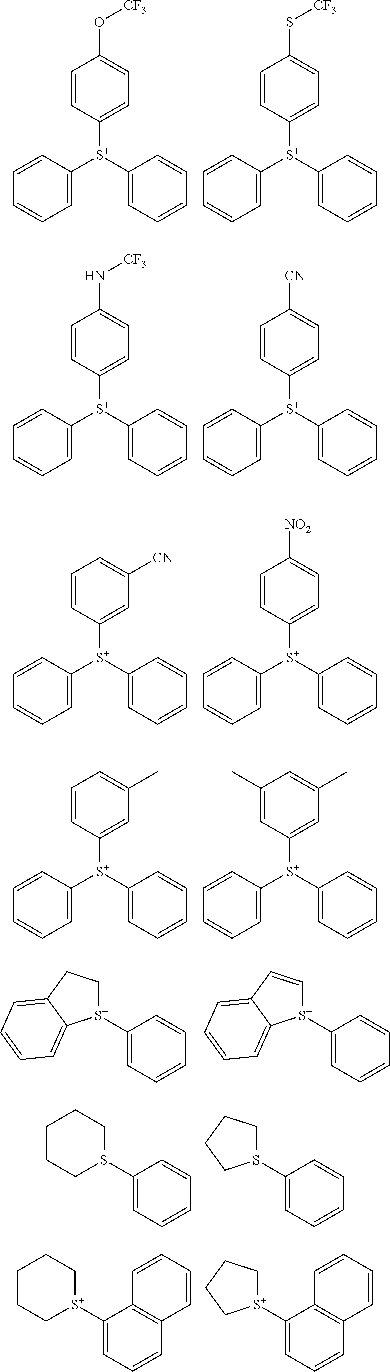

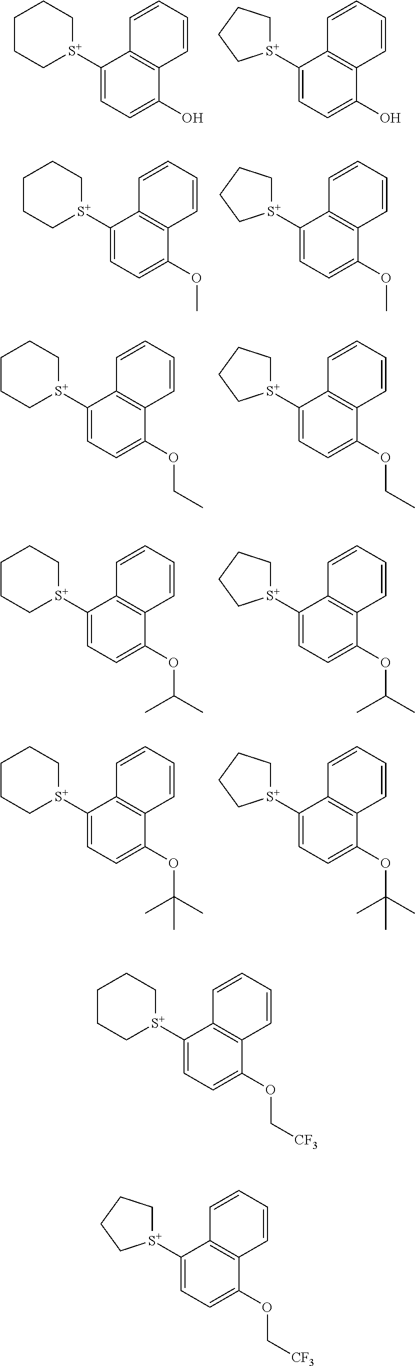

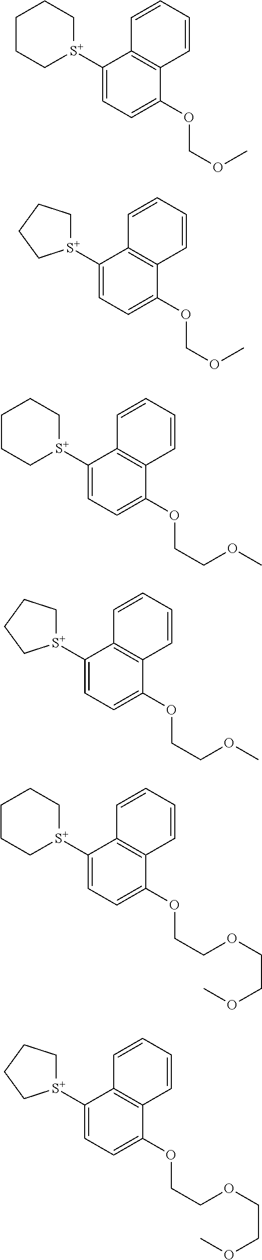 [SMILES: COCOc1ccc([S+]2CCCCC2)c2ccccc12 ; COCOc1ccc([S+]2CCCC2)c2ccccc12 ; COCCOc1ccc([S+]2CCCCC2)c2ccccc12 ; COCCOc1ccc([S+]2CCCC2)c2ccccc12 ; COCCOCCOc1ccc([S+]2CCCCC2)c2ccccc12 ; COCCOCCOc1ccc([S+]2CCCC2)c2ccccc12]

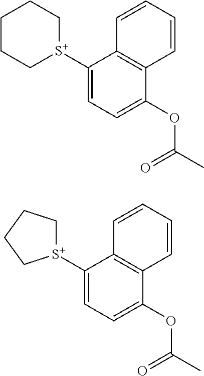 [SMILES: CC(=O)Oc1ccc([S+]2CCCCC2)c2ccccc12 ; CC(=O)Oc1ccc([S+]2CCCC2)c2ccccc12]

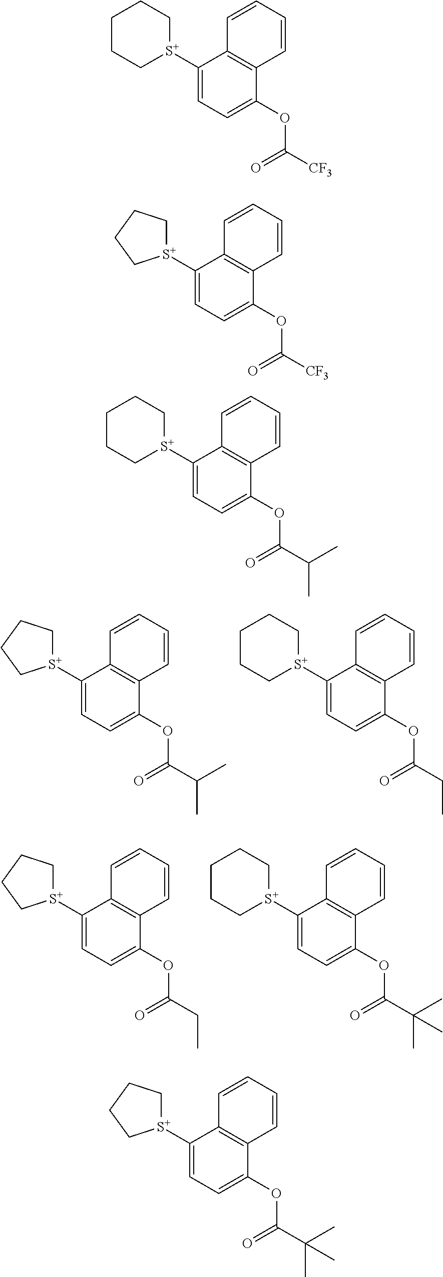

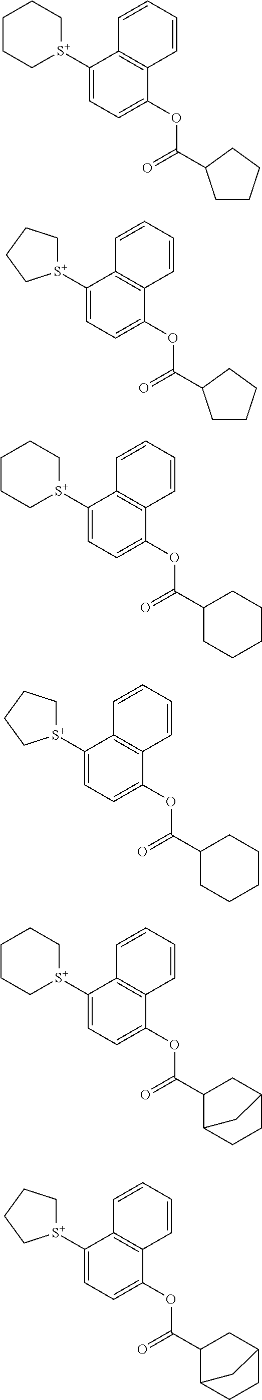 [SMILES: O=C(Oc1ccc([S+]2CCCCC2)c2ccccc12)C1CCCC1 ; O=C(Oc1ccc([S+]2CCCC2)c2ccccc12)C1CCCC1 ; O=C(Oc1ccc([S+]2CCCCC2)c2ccccc12)C1CCCCC1 ; O=C(Oc1ccc([S+]2CCCC2)c2ccccc12)C1CCCCC1 ; O=C(Oc1ccc([S+]2CCCCC2)c2ccccc12)C1CC2CCC1C2 ; O=C(Oc1ccc([S+]2CCCC2)c2ccccc12)C1CC2CCC1C2]

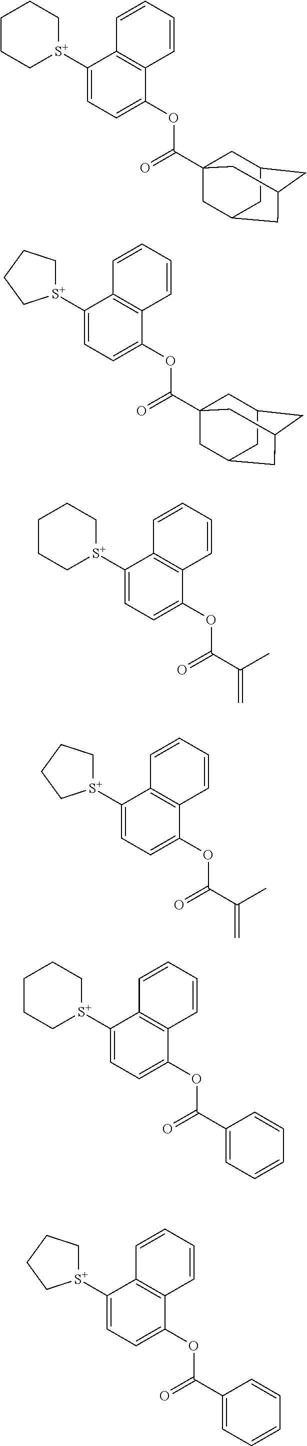 [SMILES: O=C(Oc1ccc([S+]2CCCCC2)c2ccccc12)C12CC3CC(CC(C3)C1)C2 ; O=C(Oc1ccc([S+]2CCCC2)c2ccccc12)C12CC3CC(CC(C3)C1)C2 ; C=C(C)C(=O)Oc1ccc([S+]2CCCCC2)c2ccccc12 ; C=C(C)C(=O)Oc1ccc([S+]2CCCC2)c2ccccc12 ; O=C(Oc1ccc([S+]2CCCCC2)c2ccccc12)c1ccccc1 ; O=C(Oc1ccc([S+]2CCCC2)c2ccccc12)c1ccccc1]

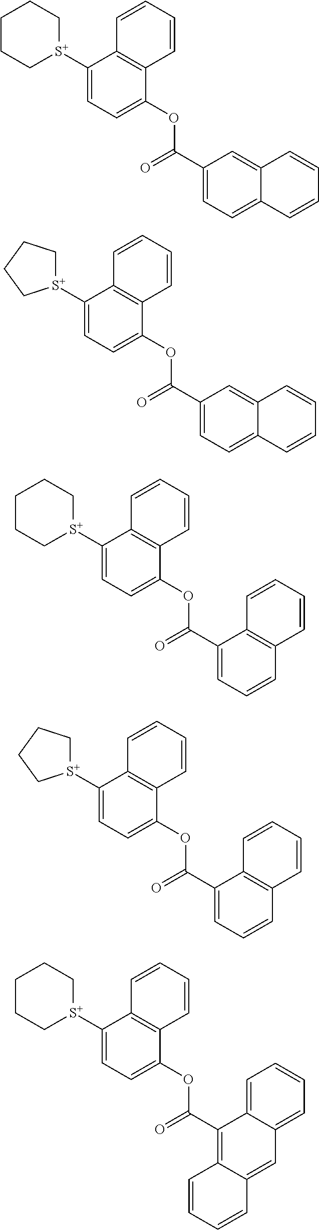 [SMILES: O=C(Oc1ccc([S+]2CCCCC2)c2ccccc12)c1ccc2ccccc2c1 ; O=C(Oc1ccc([S+]2CCCC2)c2ccccc12)c1ccc2ccccc2c1 ; O=C(Oc1ccc([S+]2CCCCC2)c2ccccc12)c1cccc2ccccc12 ; O=C(Oc1ccc([S+]2CCCC2)c2ccccc12)c1cccc2ccccc12 ; O=C(Oc1ccc([S+]2CCCCC2)c2ccccc12)c1c2ccccc2cc2ccccc12]

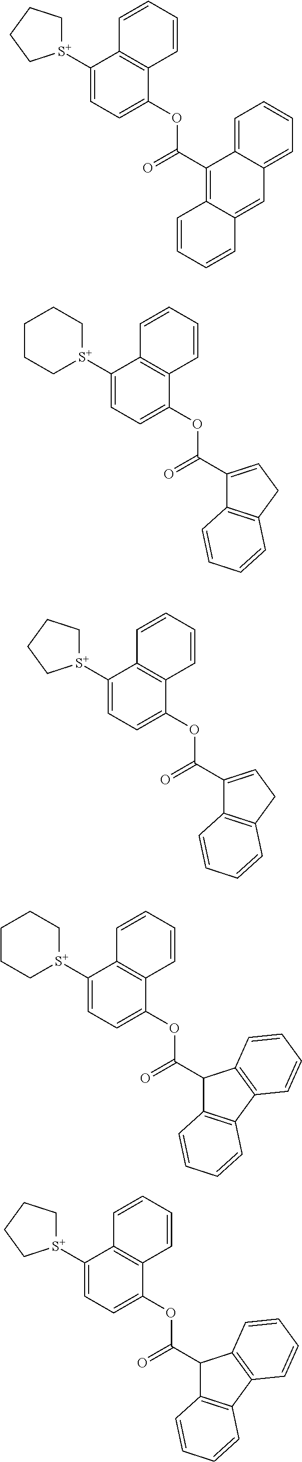 [SMILES: O=C(Oc1ccc([S+]2CCCC2)c2ccccc12)c1c2ccccc2cc2ccccc12 ; O=C(Oc1ccc([S+]2CCCCC2)c2ccccc12)C1=CCc2ccccc21 ; O=C(Oc1ccc([S+]2CCCC2)c2ccccc12)C1=CCc2ccccc21 ; O=C(Oc1ccc([S+]2CCCCC2)c2ccccc12)C1c2ccccc2-c2ccccc21 ; O=C(Oc1ccc([S+]2CCCC2)c2ccccc12)C1c2ccccc2-c2ccccc21]

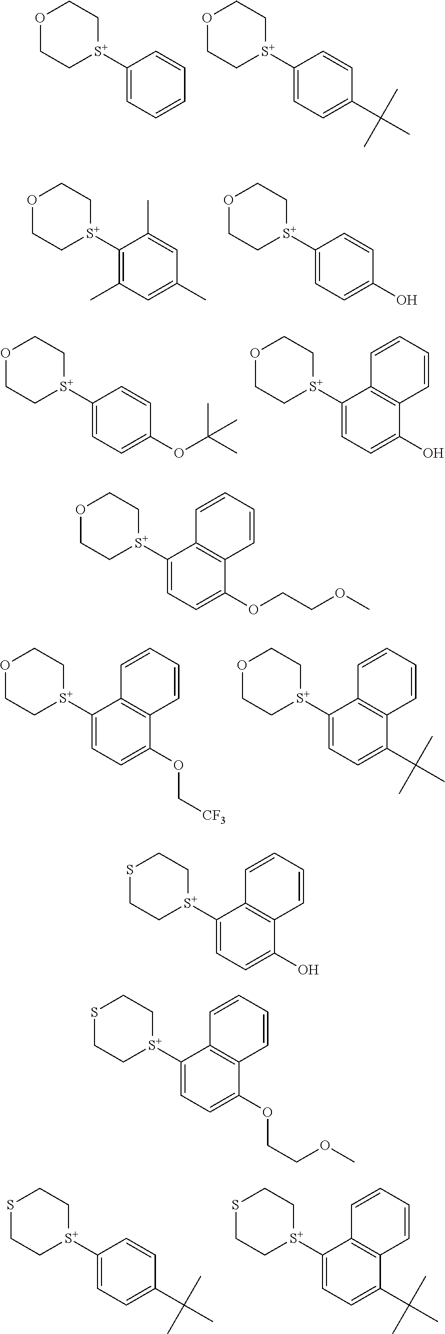

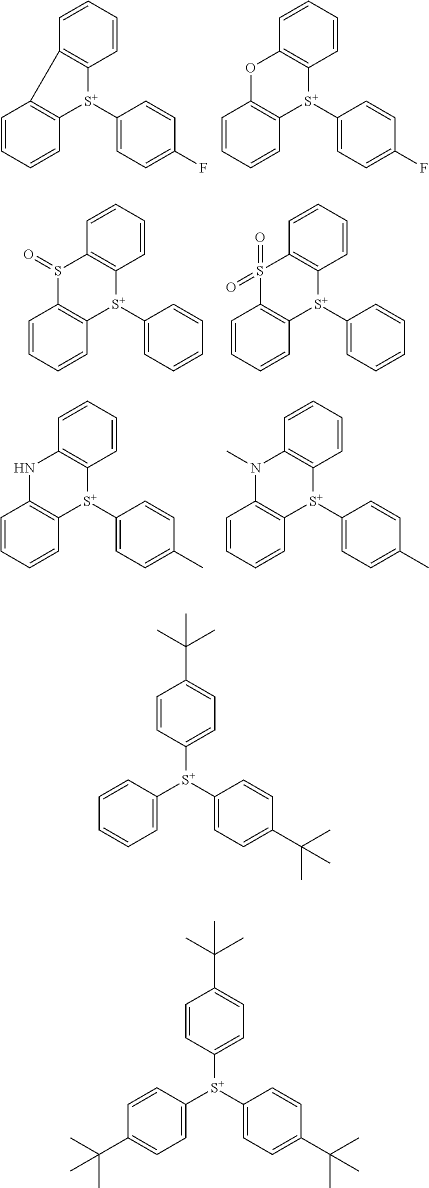

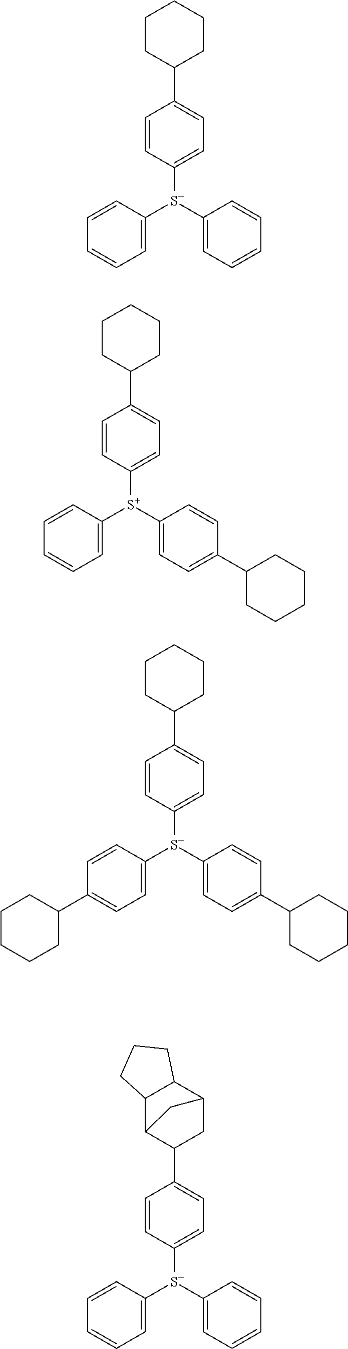 [SMILES: c1ccc([S+](c2ccccc2)c2ccc(C3CCCCC3)cc2)cc1 ; c1ccc([S+](c2ccc(C3CCCCC3)cc2)c2ccc(C3CCCCC3)cc2)cc1 ; c1cc([S+](c2ccc(C3CCCCC3)cc2)c2ccc(C3CCCCC3)cc2)ccc1C1CCCCC1 ; c1ccc([S+](c2ccccc2)c2ccc(C3CC4CC3C3CCCC43)cc2)cc1]

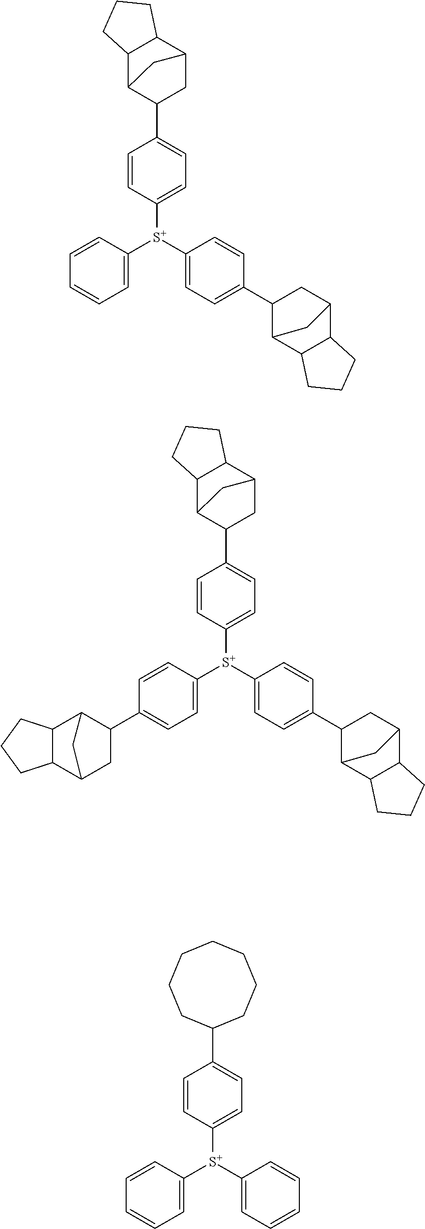 [SMILES: c1ccc([S+](c2ccc(C3CC4CC3C3CCCC43)cc2)c2ccc(C3CC4CC3C3CCCC43)cc2)cc1 ; c1cc([S+](c2ccc(C3CC4CC3C3CCCC43)cc2)c2ccc(C3CC4CC3C3CCCC43)cc2)ccc1C1CC2CC1C1CCCC21 ; c1ccc([S+](c2ccccc2)c2ccc(C3CCCCCCC3)cc2)cc1]

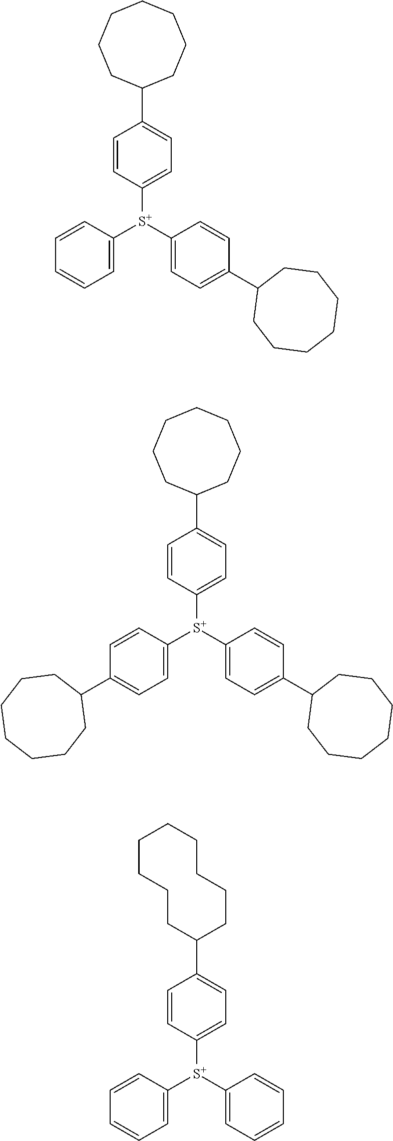 [SMILES: c1ccc([S+](c2ccc(C3CCCCCCC3)cc2)c2ccc(C3CCCCCCC3)cc2)cc1 ; c1cc([S+](c2ccc(C3CCCCCCC3)cc2)c2ccc(C3CCCCCCC3)cc2)ccc1C1CCCCCCC1 ; c1ccc([S+](c2ccccc2)c2ccc(C3CCCCCCCCC3)cc2)cc1]

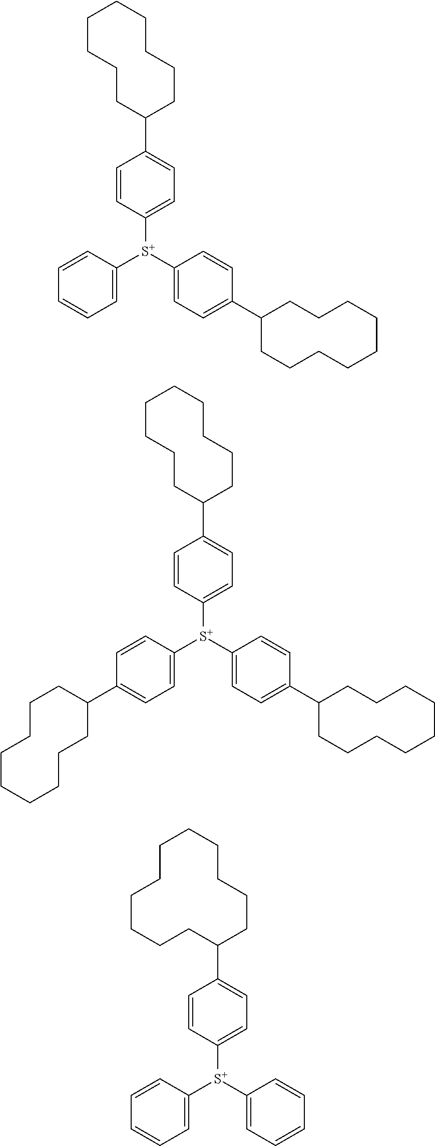 [SMILES: c1ccc([S+](c2ccc(C3CCCCCCCCC3)cc2)c2ccc(C3CCCCCCCCC3)cc2)cc1 ; c1cc([S+](c2ccc(C3CCCCCCCCC3)cc2)c2ccc(C3CCCCCCCCC3)cc2)ccc1C1CCCCCCCCC1 ; c1ccc([S+](c2ccccc2)c2ccc(C3CCCCCCCCCCC3)cc2)cc1]

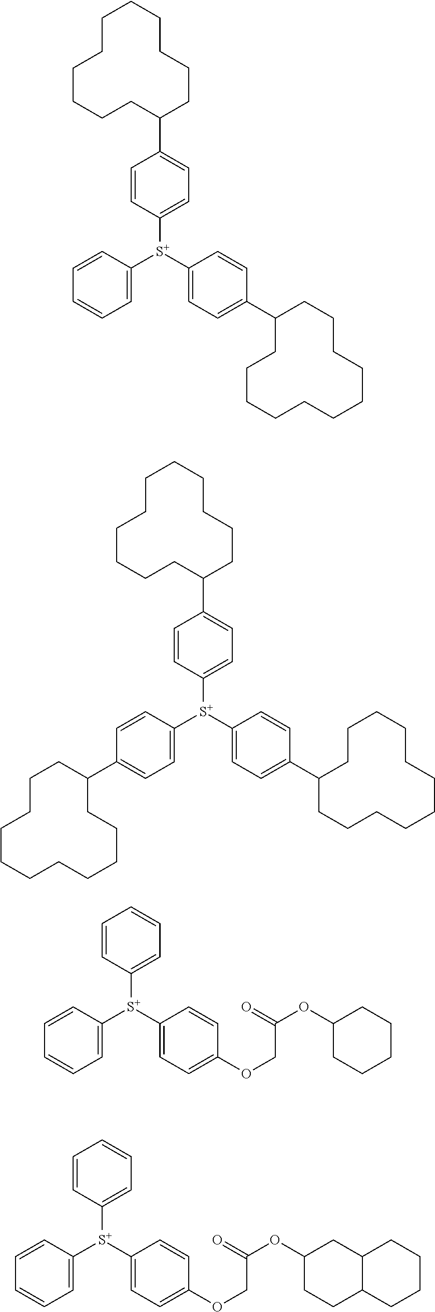 [SMILES: c1ccc([S+](c2ccc(C3CCCCCCCCCCC3)cc2)c2ccc(C3CCCCCCCCCCC3)cc2)cc1 ; c1cc([S+](c2ccc(C3CCCCCCCCCCC3)cc2)c2ccc(C3CCCCCCCCCCC3)cc2)ccc1C1CCCCCCCCCCC1 ; O=C(COc1ccc([S+](c2ccccc2)c2ccccc2)cc1)OC1CCCCC1 ; O=C(COc1ccc([S+](c2ccccc2)c2ccccc2)cc1)OC1CCC2CCCCC2C1]

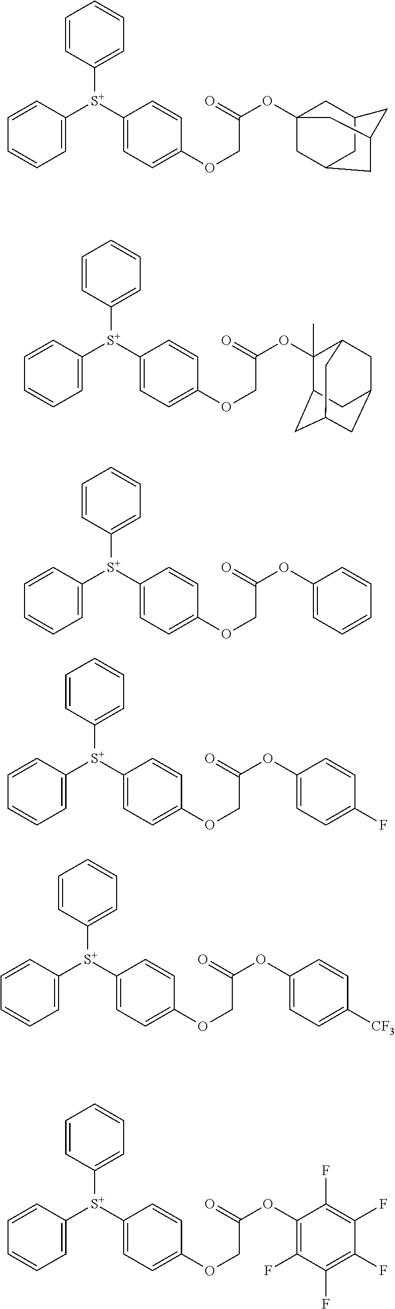 [SMILES: O=C(COc1ccc([S+](c2ccccc2)c2ccccc2)cc1)OC12CC3CC(CC(C3)C1)C2 ; CC1(OC(=O)COc2ccc([S+](c3ccccc3)c3ccccc3)cc2)C2CC3CC(C2)CC1C3 ; O=C(COc1ccc([S+](c2ccccc2)c2ccccc2)cc1)Oc1ccccc1 ; O=C(COc1ccc([S+](c2ccccc2)c2ccccc2)cc1)Oc1ccc(F)cc1 ; O=C(COc1ccc([S+](c2ccccc2)c2ccccc2)cc1)Oc1ccc(C(F)(F)F)cc1 ; O=C(COc1ccc([S+](c2ccccc2)c2ccccc2)cc1)Oc1c(F)c(F)c(F)c(F)c1F]

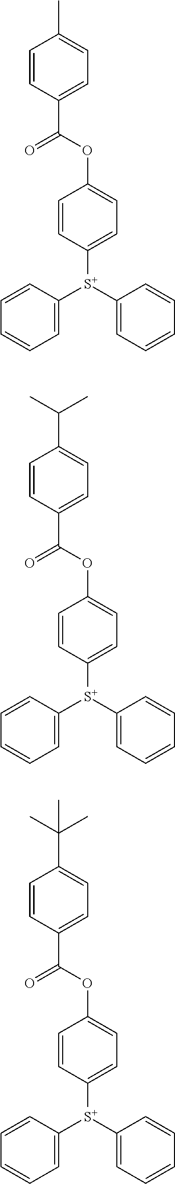 [SMILES: Cc1ccc(C(=O)Oc2ccc([S+](c3ccccc3)c3ccccc3)cc2)cc1 ; CC(C)c1ccc(C(=O)Oc2ccc([S+](c3ccccc3)c3ccccc3)cc2)cc1 ; CC(C)(C)c1ccc(C(=O)Oc2ccc([S+](c3ccccc3)c3ccccc3)cc2)cc1]

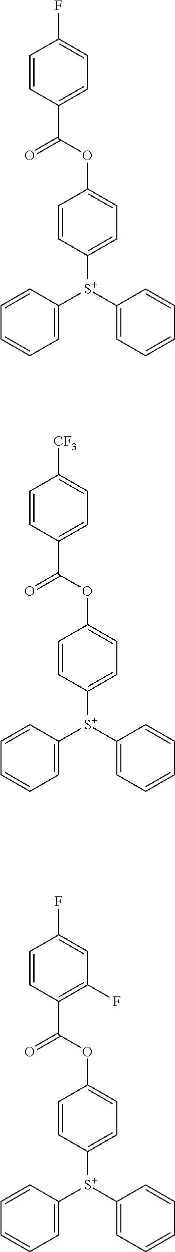 [SMILES: O=C(Oc1ccc([S+](c2ccccc2)c2ccccc2)cc1)c1ccc(F)cc1 ; O=C(Oc1ccc([S+](c2ccccc2)c2ccccc2)cc1)c1ccc(C(F)(F)F)cc1 ; O=C(Oc1ccc([S+](c2ccccc2)c2ccccc2)cc1)c1ccc(F)cc1F]

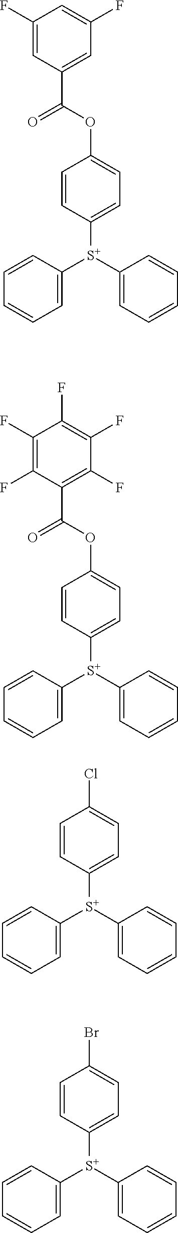 [SMILES: O=C(Oc1ccc([S+](c2ccccc2)c2ccccc2)cc1)c1cc(F)cc(F)c1 ; O=C(Oc1ccc([S+](c2ccccc2)c2ccccc2)cc1)c1c(F)c(F)c(F)c(F)c1F ; Clc1ccc([S+](c2ccccc2)c2ccccc2)cc1 ; Brc1ccc([S+](c2ccccc2)c2ccccc2)cc1]

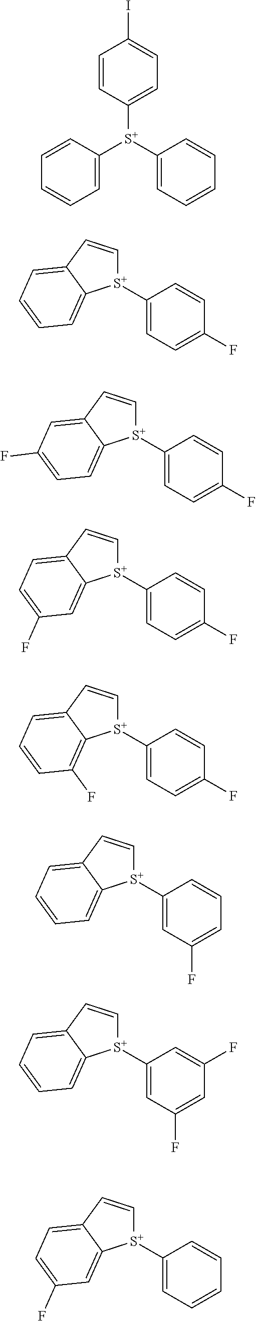

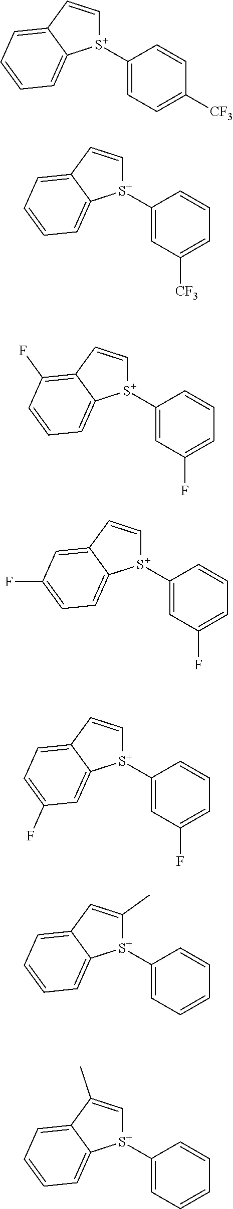

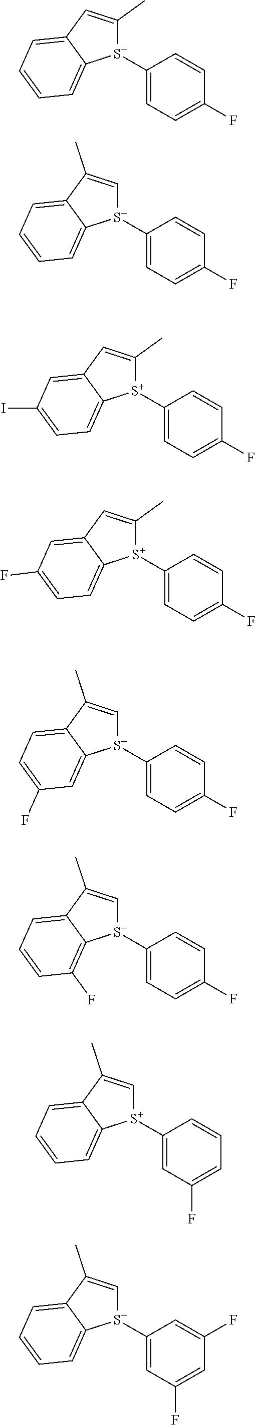

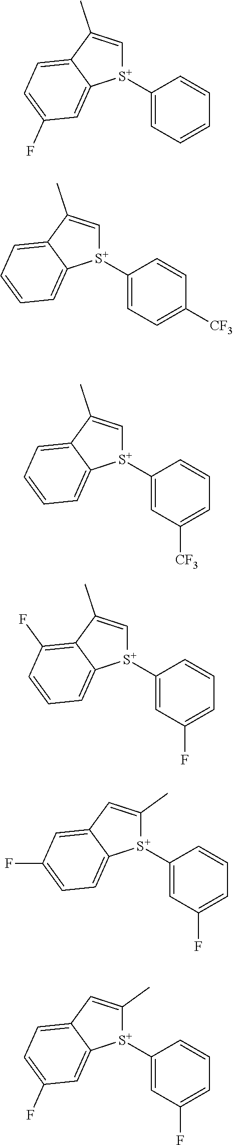 [SMILES: Cc1c[s+](-c2ccccc2)c2cc(F)ccc12 ; Cc1c[s+](-c2ccc(C(F)(F)F)cc2)c2ccccc12 ; Cc1c[s+](-c2cccc(C(F)(F)F)c2)c2ccccc12 ; Cc1c[s+](-c2cccc(F)c2)c2cccc(F)c12 ; Cc1cc2cc(F)ccc2[s+]1-c1cccc(F)c1 ; Cc1cc2ccc(F)cc2[s+]1-c1cccc(F)c1]

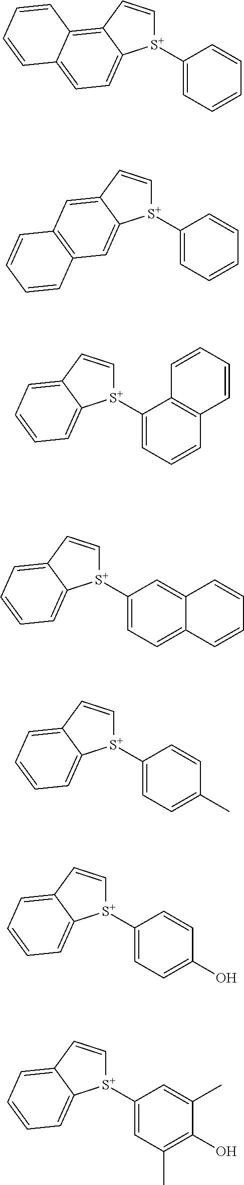

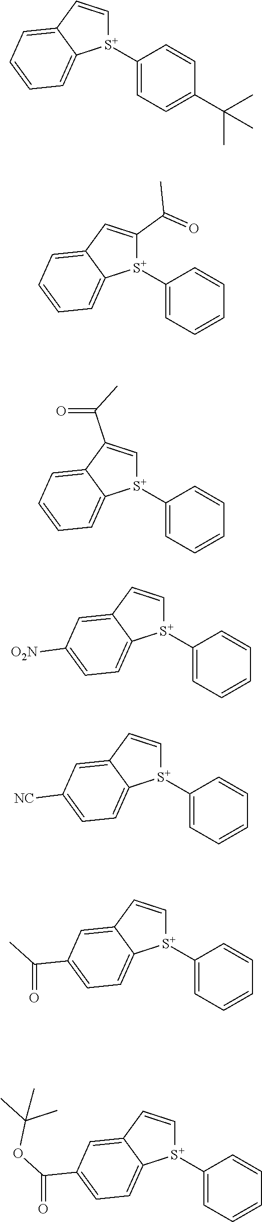

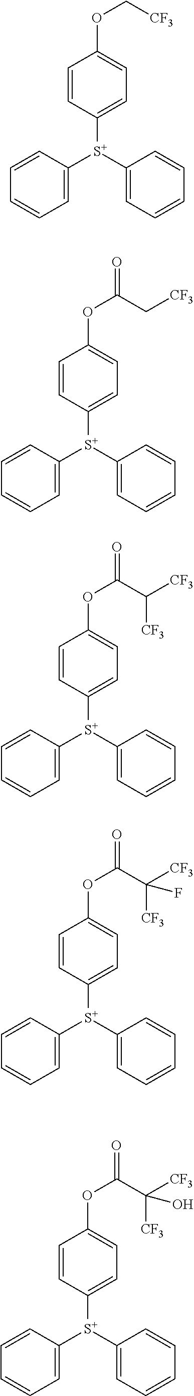 [SMILES: FC(F)(F)COc1ccc([S+](c2ccccc2)c2ccccc2)cc1 ; O=C(CC(F)(F)F)Oc1ccc([S+](c2ccccc2)c2ccccc2)cc1 ; O=C(Oc1ccc([S+](c2ccccc2)c2ccccc2)cc1)C(C(F)(F)F)C(F)(F)F ; O=C(Oc1ccc([S+](c2ccccc2)c2ccccc2)cc1)C(F)(C(F)(F)F)C(F)(F)F ; O=C(Oc1ccc([S+](c2ccccc2)c2ccccc2)cc1)C(O)(C(F)(F)F)C(F)(F)F]

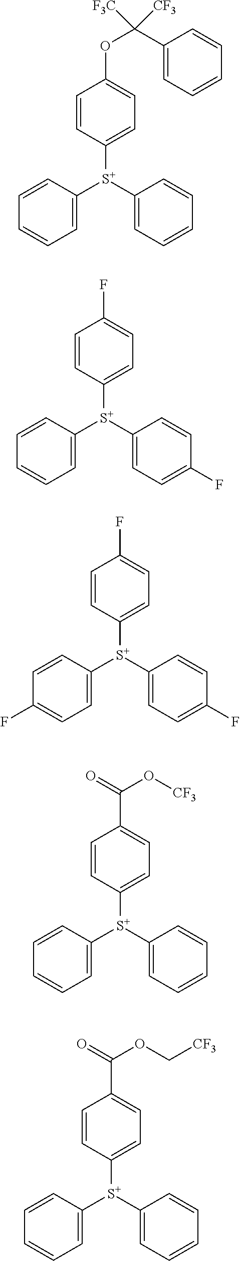 [SMILES: FC(F)(F)C(Oc1ccc([S+](c2ccccc2)c2ccccc2)cc1)(c1ccccc1)C(F)(F)F ; Fc1ccc([S+](c2ccccc2)c2ccc(F)cc2)cc1 ; Fc1ccc([S+](c2ccc(F)cc2)c2ccc(F)cc2)cc1 ; O=C(OC(F)(F)F)c1ccc([S+](c2ccccc2)c2ccccc2)cc1 ; O=C(OCC(F)(F)F)c1ccc([S+](c2ccccc2)c2ccccc2)cc1]

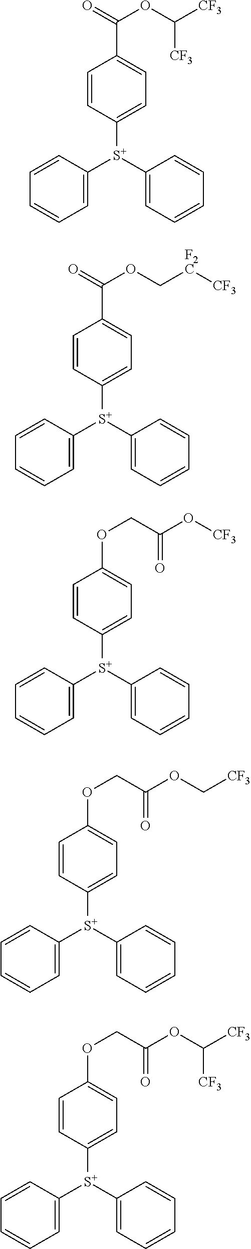 [SMILES: O=C(OC(C(F)(F)F)C(F)(F)F)c1ccc([S+](c2ccccc2)c2ccccc2)cc1 ; O=C(OCC(F)(F)C(F)(F)F)c1ccc([S+](c2ccccc2)c2ccccc2)cc1 ; O=C(COc1ccc([S+](c2ccccc2)c2ccccc2)cc1)OC(F)(F)F ; O=C(COc1ccc([S+](c2ccccc2)c2ccccc2)cc1)OCC(F)(F)F ; O=C(COc1ccc([S+](c2ccccc2)c2ccccc2)cc1)OC(C(F)(F)F)C(F)(F)F]

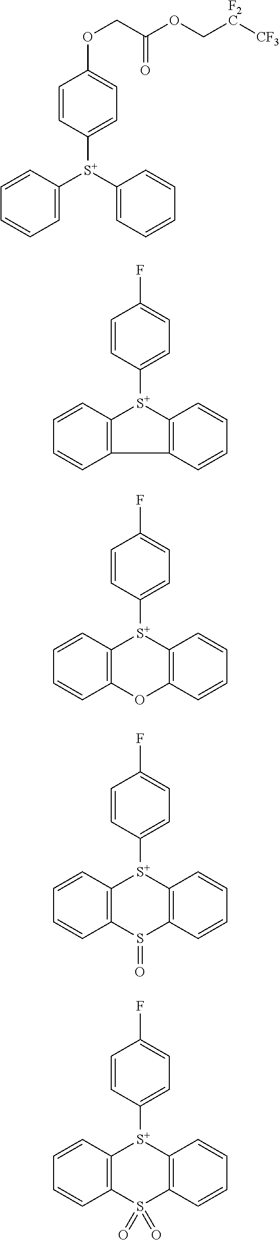 [SMILES: O=C(COc1ccc([S+](c2ccccc2)c2ccccc2)cc1)OCC(F)(F)C(F)(F)F ; Fc1ccc(-[s+]2c3ccccc3c3ccccc32)cc1 ; Fc1ccc([S+]2c3ccccc3Oc3ccccc32)cc1 ; O=S1c2ccccc2[S+](c2ccc(F)cc2)c2ccccc21 ; O=S1(=O)c2ccccc2[S+](c2ccc(F)cc2)c2ccccc21]

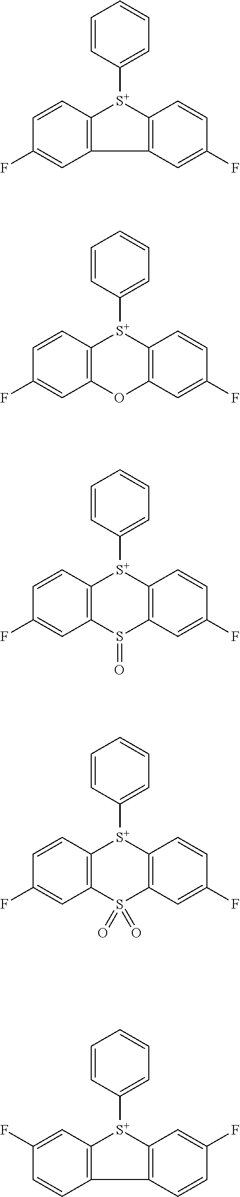 [SMILES: Fc1ccc2c(c1)c1cc(F)ccc1[s+]2-c1ccccc1 ; Fc1ccc2c(c1)Oc1cc(F)ccc1[S+]2c1ccccc1 ; O=S1c2cc(F)ccc2[S+](c2ccccc2)c2ccc(F)cc21 ; O=S1(=O)c2cc(F)ccc2[S+](c2ccccc2)c2ccc(F)cc21 ; Fc1ccc2c3ccc(F)cc3[s+](-c3ccccc3)c2c1]

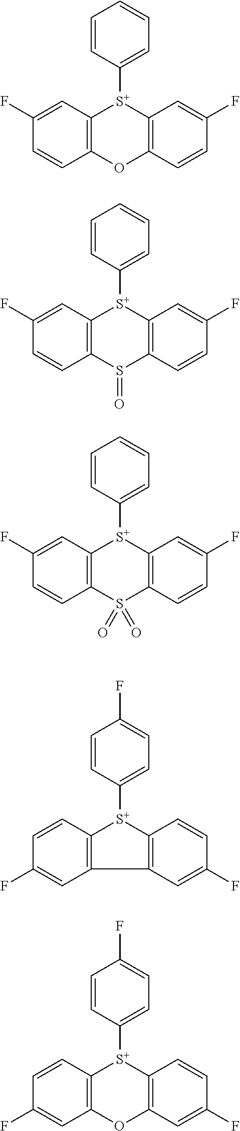 [SMILES: Fc1ccc2c(c1)[S+](c1ccccc1)c1cc(F)ccc1O2 ; O=S1c2ccc(F)cc2[S+](c2ccccc2)c2cc(F)ccc21 ; O=S1(=O)c2ccc(F)cc2[S+](c2ccccc2)c2cc(F)ccc21 ; Fc1ccc(-[s+]2c3ccc(F)cc3c3cc(F)ccc32)cc1 ; Fc1ccc([S+]2c3ccc(F)cc3Oc3cc(F)ccc32)cc1]

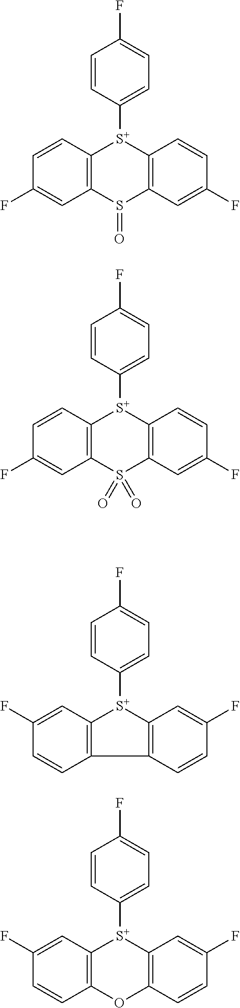 [SMILES: O=S1c2cc(F)ccc2[S+](c2ccc(F)cc2)c2ccc(F)cc21 ; O=S1(=O)c2cc(F)ccc2[S+](c2ccc(F)cc2)c2ccc(F)cc21 ; Fc1ccc(-[s+]2c3cc(F)ccc3c3ccc(F)cc32)cc1 ; Fc1ccc([S+]2c3cc(F)ccc3Oc3ccc(F)cc32)cc1]

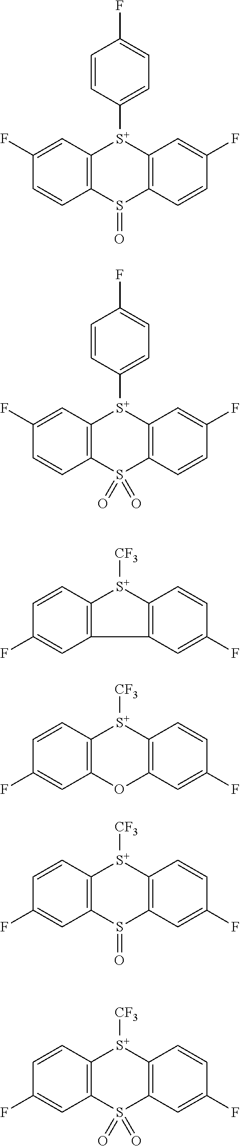 [SMILES: O=S1c2ccc(F)cc2[S+](c2ccc(F)cc2)c2cc(F)ccc21 ; O=S1(=O)c2ccc(F)cc2[S+](c2ccc(F)cc2)c2cc(F)ccc21 ; Fc1ccc2c(c1)c1cc(F)ccc1[s+]2C(F)(F)F ; Fc1ccc2c(c1)Oc1cc(F)ccc1[S+]2C(F)(F)F ; O=S1c2cc(F)ccc2[S+](C(F)(F)F)c2ccc(F)cc21 ; O=S1(=O)c2cc(F)ccc2[S+](C(F)(F)F)c2ccc(F)cc21]

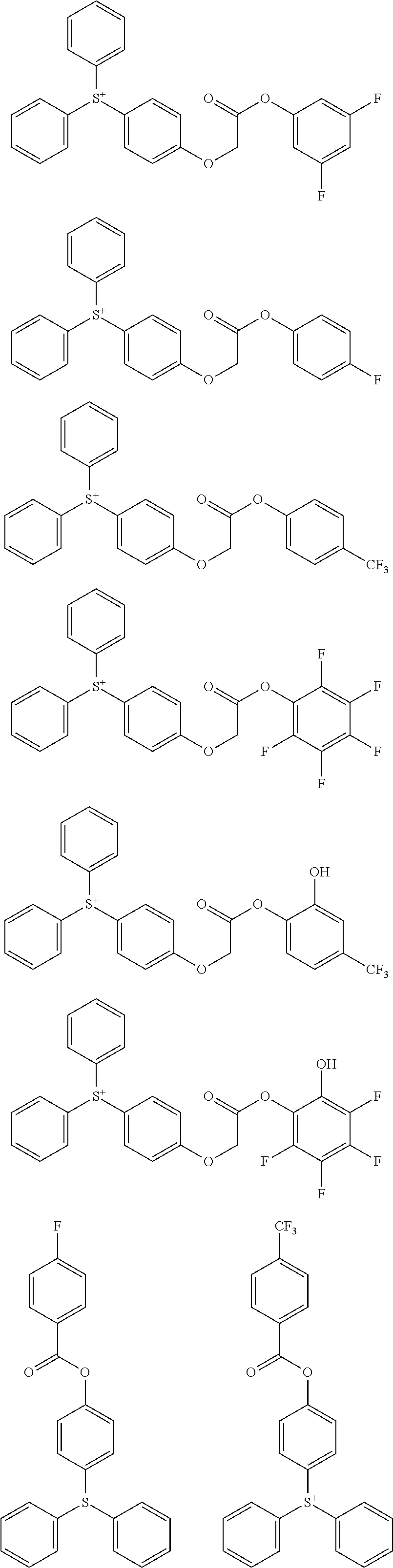

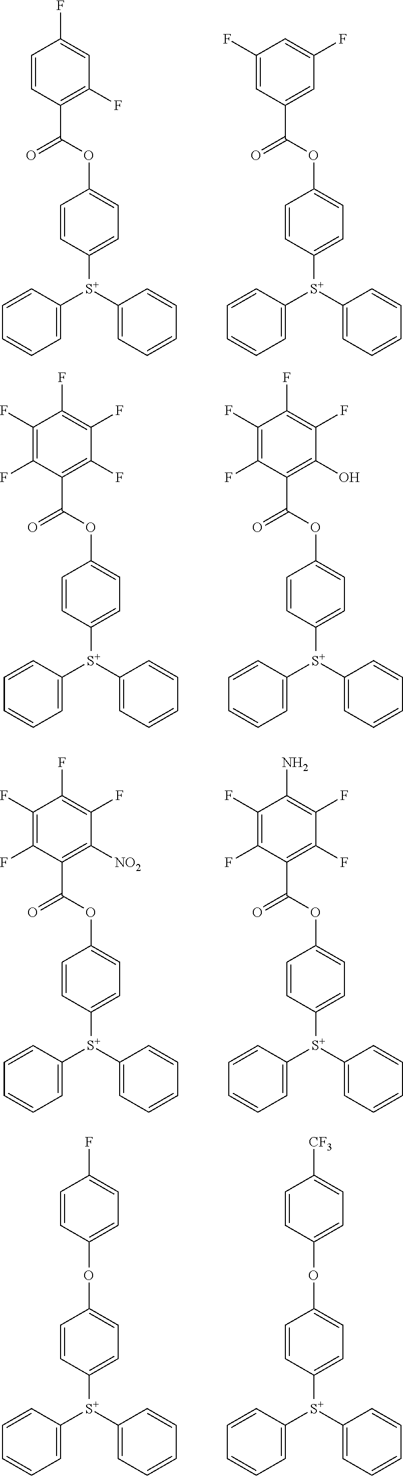

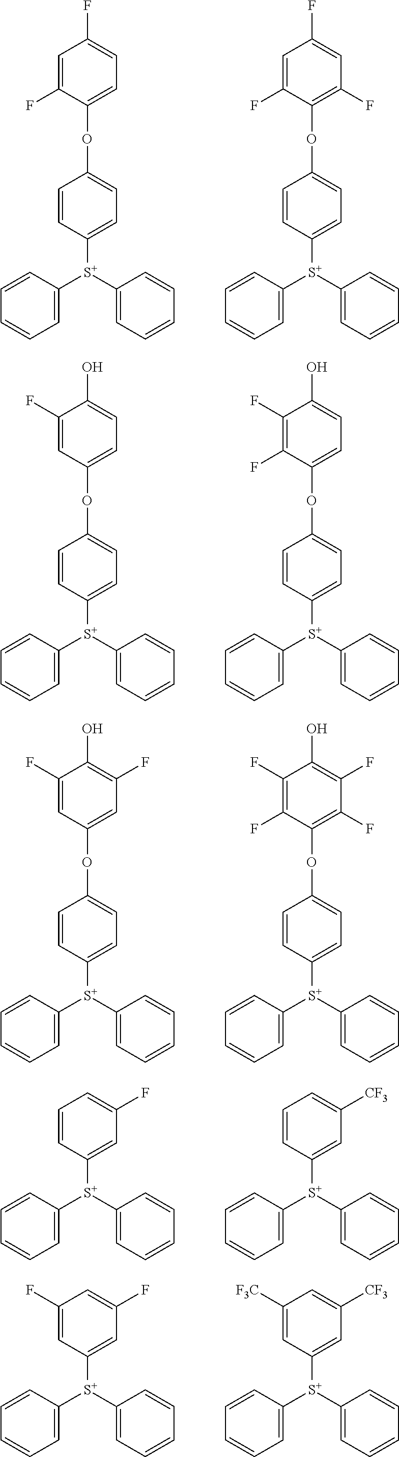

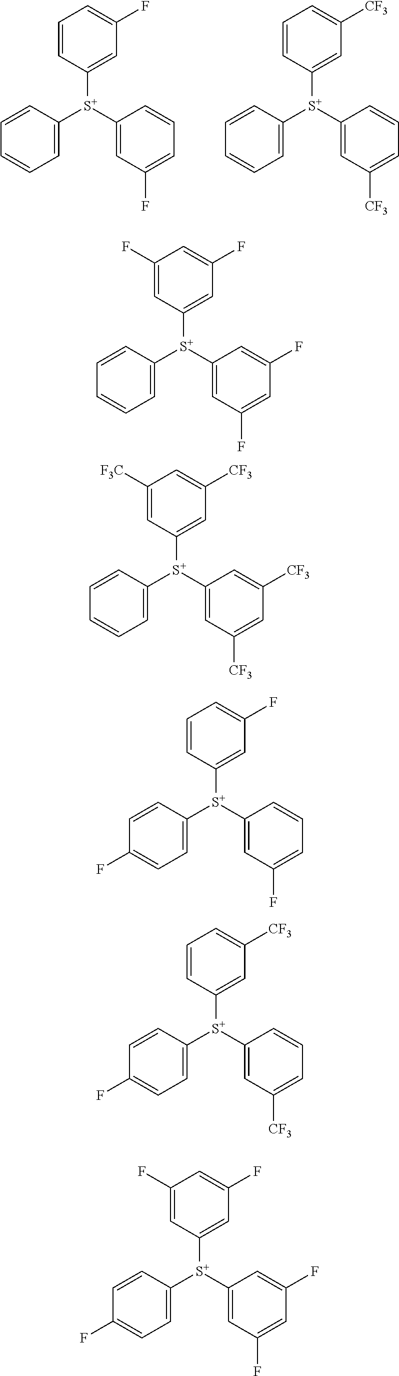

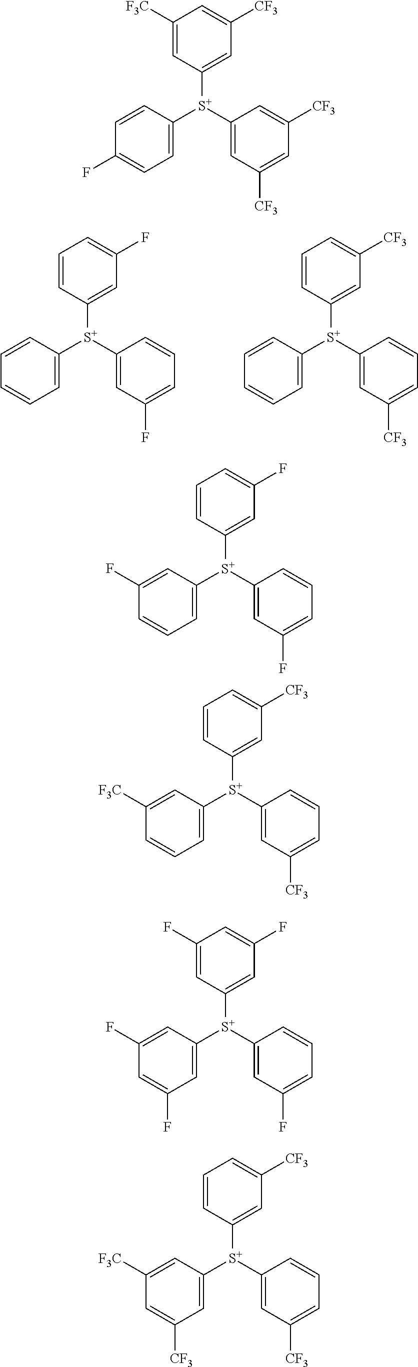

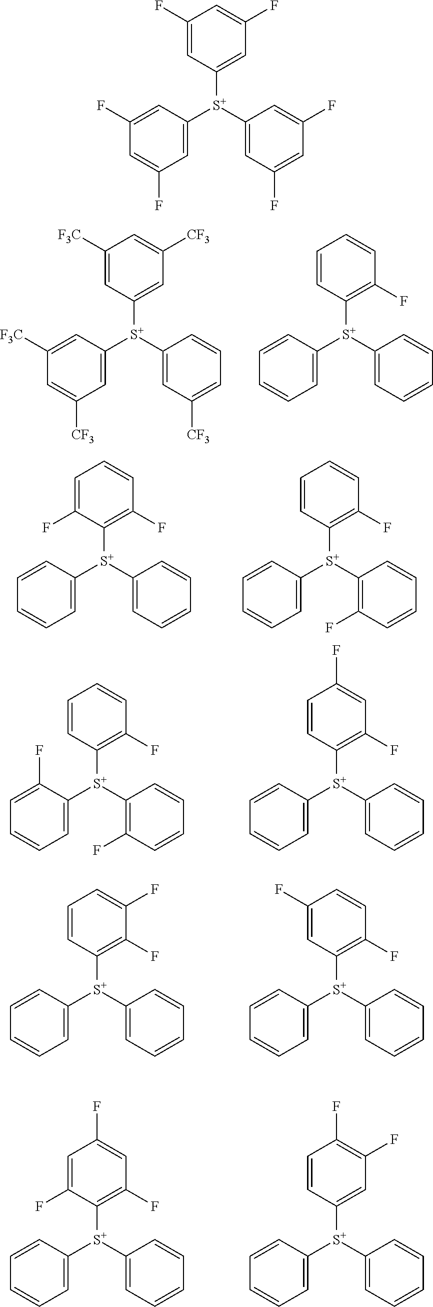

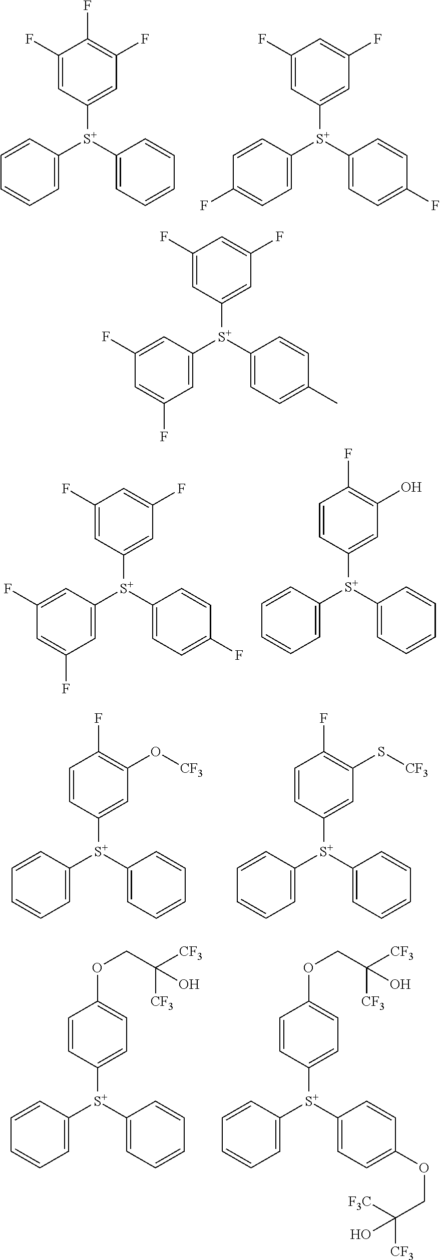

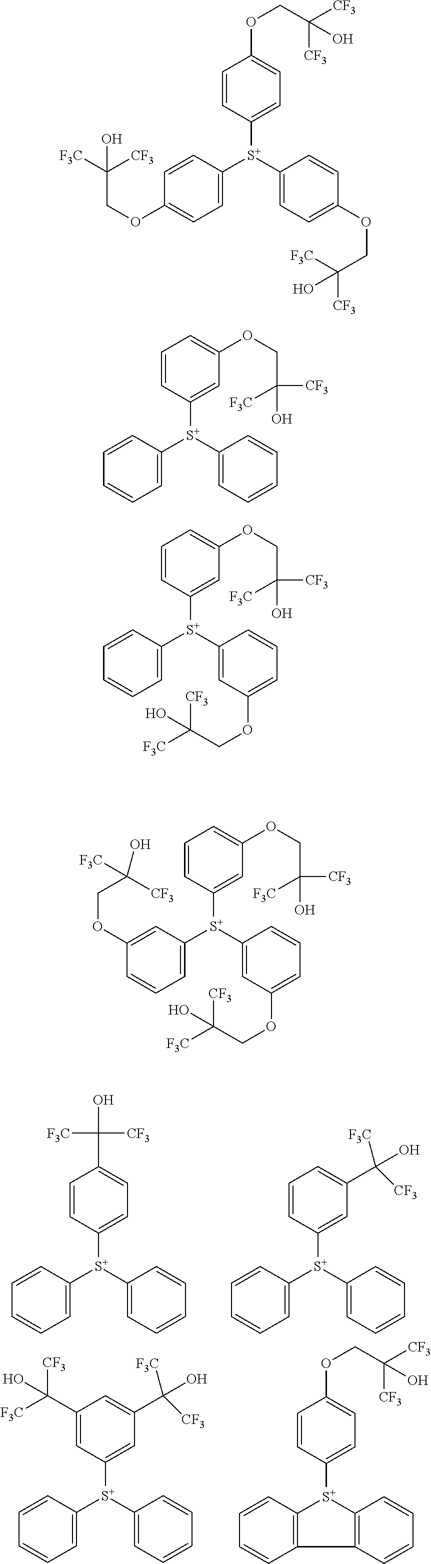

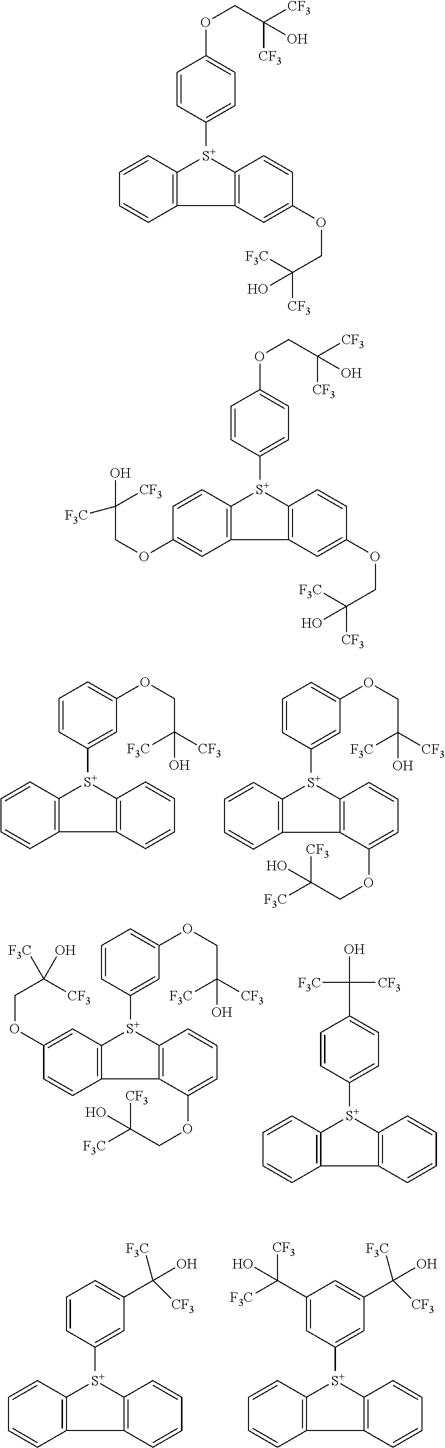

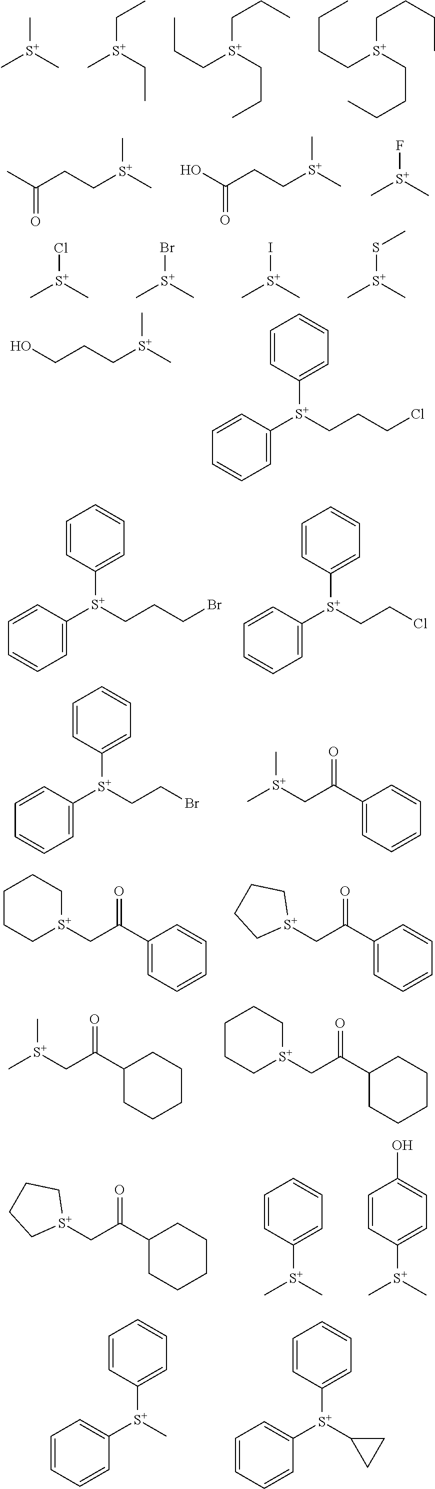

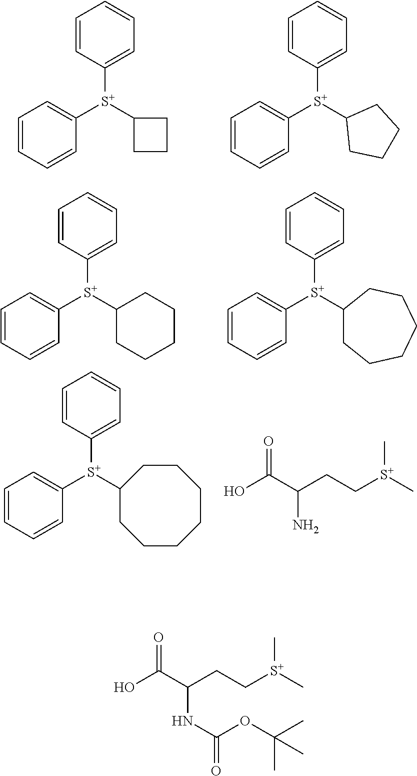

As the cation of the sulfonium salt having formula (3-1), the cation having the formula (1) can also be used.

Examples of the cation of the iodonium salt having formula (3-2) are derived are shown below, but not limited thereto.

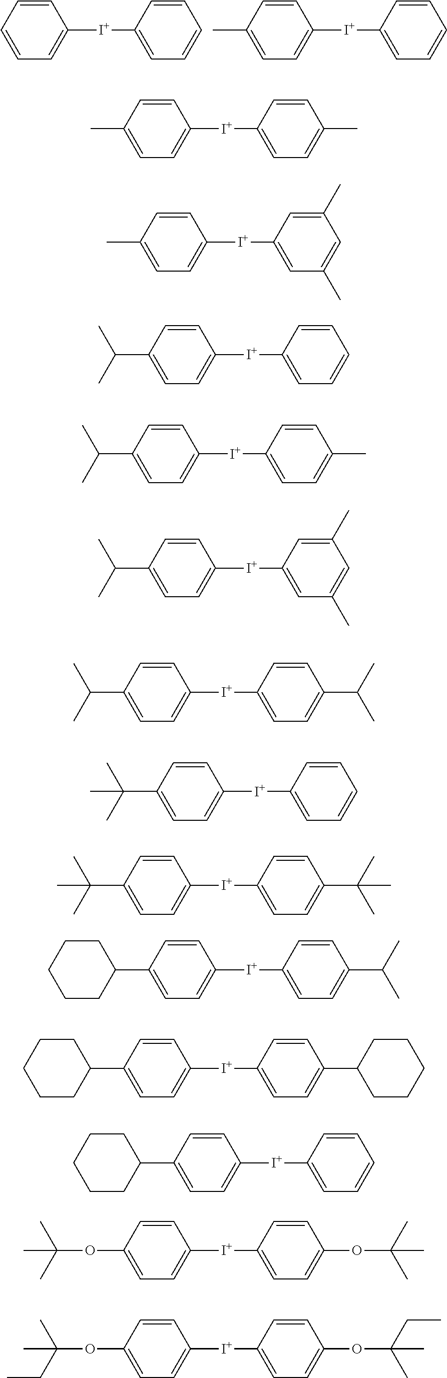

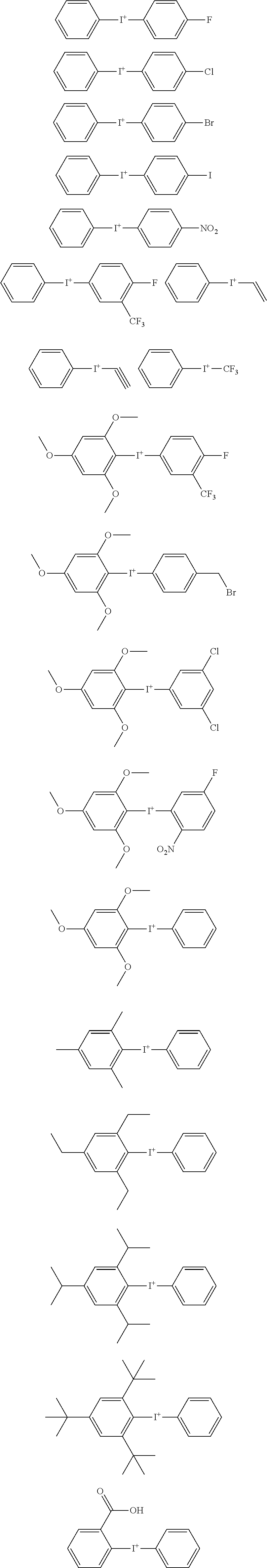

In formulae (3-1) and (3-2), Xa⁻is an anion selected from the following formulae (3A) to (3D).

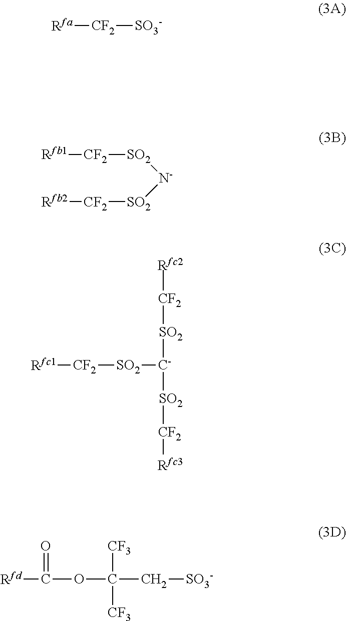

In formula (3A), R^{fa} is a fluorine atom, or a C₁-C₄₀ hydrocarbyl group which may contain a heteroatom. The hydrocarbyl group may be saturated or unsaturated and straight, branched, or cyclic. Specific examples thereof are as exemplified for the hydrocarbyl group represented by R^{fa1} in formula (3A′) described below.

The anion having formula (3A) preferably has the following formula (3A′).

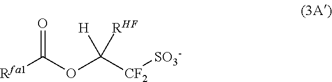

In formula (3A′), R^{HF} is a hydrogen atom or a trifluoromethyl group and preferably a trifluoromethyl group. R^{fa1} is a C₁-C₃₈ hydrocarbyl group which may contain a heteroatom. The heteroatom is preferably an oxygen atom, a nitrogen atom, a sulfur atom, a halogen atom, or the like, and more preferably an oxygen atom. The hydrocarbyl group is particularly preferably a C₆-C₃₀ hydrocarbyl group from the viewpoint of obtaining a high resolution in fine pattern formation.

The hydrocarbyl group represented by R^{fa1} may be saturated or unsaturated and straight, branched, or cyclic. Specific examples thereof include C₁-C₃₈ alkyl groups such as a methyl group, an ethyl group, a n-propyl group, an isopropyl group, a n-butyl group, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosanyl group; C₃-C₃₈ cyclic saturated hydrocarbyl groups such as a cyclopentyl group, a cyclohexyl group, a 1-adamantyl group, a 2-adamantyl group, a 1-adamantylmethyl group, a norbornyl group, a norbornylmethyl group, a tricyclodecyl group, a tetracyclododecyl group, a tetracyclododecylmethyl group, and a dicyclohexylmethyl group; C₂-C₃₈ unsaturated aliphatic hydrocarbyl groups such as an allyl group and a 3-cyclohexenyl group; C₆-C₃₈ aryl groups such as a phenyl group, a 1-naphthyl group, and a 2-naphthyl group; C₇-C₃₈ aralkyl groups such as a benzyl group and a diphenylmethyl group; and groups obtained by combining these.

Some or all of the hydrogen atoms in the hydrocarbyl group may be substituted with a group containing a heteroatom such as an oxygen atom, a sulfur atom, a nitrogen atom, or a halogen atom, some of —CH₂— in the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, au ester bond, a sulfonate bond, a carbonate bond, a lactone ring, a sultone ring, a carboxylic anhydride (—C(═O)—O—C(═O)—), a haloalkyl group, or the like. Examples of the heteroatom-containing hydrocarbyl group include a tetrahydrofuryl group, a methoxymethyl group, an ethoxymethyl group, a methylthiomethyl group, an acetamidomethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group.

With respect to the synthesis of the sulfonium salt having an anion of formula (3A′), reference is made to JP-A 2007-145797, JP-A 2008-106045, JP-A 2009-7327, JP-A 2009-258695, and the like. Also useful are the sulfonium salts described in JP-A 2010-215608, JP-A 2012-41320, JP-A 2012-106986, JP-A 2012-153644, and the like.

Examples of the anion having formula (3A) are as exemplified for the anion having formula (1A) in JP-A 2018-197853.

In formula (3B), R^{fb1} and R^{fb2} are each independently a fluorine atom, or a C₁-C₄₀ hydrocarbyl group which may contain a heteroatom. The hydrocarbyl group may be saturated or unsaturated and straight, branched, or cyclic. Specific examples thereof are as exemplified above for the hydrocarbyl group represented by R^{fa1} in formula (3A′). Preferably, R^{fb1} and R^{fb2} each are a fluorine atom or a straight C₁-C₄ fluorinated alkyl group. A pair of R^{fb1} and R^{fb2} may bond together to form a ring with the group (—CF₂—SO₂—N⁻—SO₂—CF₂—) to which they are attached, and in this case, the group obtained by bonding the pair of R^{fb1} and R^{fb2} to each other is preferably a fluorinated ethylene group or a fluorinated propylene group.

In formula (3C), R^{fc1}, R^{fc2}, and R^{fc3} are each independently a fluorine atom, or a C₁-C₄₀ hydrocarbyl group which may contain a heteroatom. The hydrocarbyl group may be saturated or unsaturated and straight, branched, or cyclic. Specific examples thereof are as exemplified above for the hydrocarbyl group represented by R^{fa1} in formula (3A′). Preferably, R^{fc1}, R^{fc2}, and R^{fc3} each are a fluorine atom or a straight C₁-C₄ fluorinated alkyl group. A pair of R^{fc1} and R^{fc2} may bond together to form a ring with the group (—CF₂—SO₂—C⁻—SO₂—CF₂—) to which they are attached, and in this case, the group obtained by bonding the pair of R^{fc1} and R^{fc2} to each other is preferably a fluorinated ethylene group or a fluorinated propylene group.

In formula (3D), R^{f1} is a C₁-C₄₀ hydrocarbyl group which may contain a heteroatom. The hydrocarbyl group may be saturated or unsaturated and straight, branched, or cyclic. Specific examples thereof are as exemplified above for the hydrocarbyl group represented by R^{fa1} in formula (1A′).

With respect to the synthesis of the sulfonium salt having an anion of formula (3D), reference is made to JP-A 2010-215608 and JP-A 2014-133723.

Examples of the anion having formula (3D) are as exemplified for the anion having formula (1D) in JP-A 2018-197853.

The photoacid generator having the anion of formula (3D) has a sufficient acidity to cleave acid labile groups in the base polymer because it is free of a fluorine atom at α-position of the sulfo group, but has two trifluoromethyl groups at β-position. Thus, it can be used as a photoacid generator.

As the photoacid generator, compounds having the following formula (4) can also be suitably used.

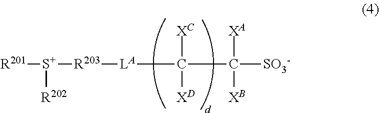

In formula (4), R²⁰¹ and R²⁰² are each independently a halogen atom, or a C₁-C₃₀ hydrocarbyl group which may contain a heteroatom. R²⁰³ is a C₁-C₃₀ hydrocarbylene group which may contain a heteroatom. Any two of R²⁰¹, R²⁰², and R²⁰³ may bond together to form a ring with the sulfur atom to which they are attached. In this case, examples of the ring are as exemplified above for the ring that R¹⁰¹ and R¹⁰² in the description of formula (3-1) may bond together to form with the sulfur atom to which they are attached.

The hydrocarbyl group represented by R²⁰¹ and R²⁰² may be saturated or unsaturated and straight, branched, or cyclic. Specific examples thereof include C₁-C₃₀ alkyl groups such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group, and a n-decyl group; C₃-C₃₀ cyclic saturated hydrocarbyl groups such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, an oxanorbornyl group, a tricyclo[5.2.1.0^{2,6}] decyl group, and an adamantyl group; C₆-C₃₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, a naphthyl group, a methylnaphthyl group, an ethylnaphthyl group, a n-propylnaphthyl group, an isopropylnaphthyl group, a n-butylnaphthyl group, an isobutylnaphthyl group, a sec-butylnaphthyl group, a tert-butylnaphthyl group, and an anthracenyl group; and groups obtained by combining these. Some or all of the hydrogen atoms in the hydrocarbyl group may be substituted with a group containing a heteroatom such as an oxygen atom, a sulfur atom, a nitrogen atom, or a halogen atom, some of —CH₂— in the hydrocarbyl group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, an ester bond, a sulfonate bond, a carbonate bond, a lactone ring, a sultone ring, a carboxylic anhydride (—C(═O)—O—C(═O)—), a haloalkyl group, or the like.

The hydrocarbylene group represented by R²⁰³ may be saturated or unsaturated and straight, branched, or cyclic. Specific examples thereof include C₁-C₃₀ alkanediyl groups such as a methanediyl group, an ethane-1,1-diyl group, an ethane-1,2-diyl group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, and a heptadecane-1,17-diyl group; C₃-C₃₀ cyclic saturated hydrocarbylene groups such as a cyclopentanediyl group, a cyclohexanediyl group, a norbornanediyl group, and an adamantanediyl group; C₆-C₃₀ arylene groups such as a phenylene group, a methylphenylene group, an ethylphenylene group, a n-propylphenylene group, an isopropylphenylene group, a n-butylphenylene group, an isobutylphenylene group, a sec-butylphenylene group, a tert-butylphenylene group, a naphthylene group, a methylnaphthylene group, an ethylnaphthylene group, a n-propylnaphthylene group, an isopropylnaphthylene group, a n-butylnaphthylene group, an isobutylnaphthylene group, a sec-butylnaphthylene group, and a tert-butylnaphthylene group; and groups obtained by combining these. Some or all of the hydrogen atoms in the hydrocarbylene group may be substituted with a group containing a heteroatom such as an oxygen atom, a sulfur atom, a nitrogen atom, or a halogen atom, some of —CH₂— in the hydrocarbylene group may be substituted with a group containing a heteroatom such as an oxygen atom, a sulfur atom, or a nitrogen atom, so that the group may contain a hydroxy group, a fluorine atom, a chlorine atom, a bromine atom, an iodine atom, a cyano group, a nitro group, a carbonyl group, an ether bond, an ester bond, a sulfonate bond, a carbonate bond, a lactone ring, a sultone ring, a carboxylic anhydride (—C(═O)—O—C(═O)—), a haloalkyl group, or the like. The heteroatom is preferably an oxygen atom.

In formula (4), L^{A} is a single bond, an ether bond, or a C₁-C₂₀ hydrocarbylene group which may contain a heteroatom. The hydrocarbylene group may be saturated or unsaturated and straight, branched, or cyclic. Specific examples thereof are as exemplified above for the hydrocarbylene group represented by R^{203.}

In formula (4), X^{A}, X^{B}, X^{c}, and X^{D} are each independently a hydrogen atom, a fluorine atom, or a trifluoromethyl group. Provided that at least one of X^{A}, X^{B}, X^{C}, and X^{D} is a fluorine atom or a trifluoromethyl group.

In formula (4), d is an integer of 0 to 3.

The photoacid generator having formula (4) preferably has the following formula (4′).

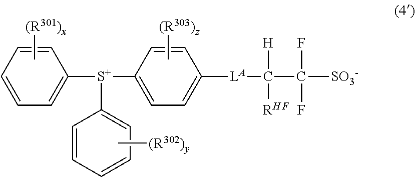

In formula (4′), L^{A} is as defined above. R^{HF} is a hydrogen atom or a trifluoromethyl group and preferably a trifluoromethyl group. R³⁰¹, R³⁰², and R³⁰³ are each independently a hydrogen atom, or a C₁-C₂₀ hydrocarbyl group which may contain a heteroatom. The hydrocarbyl group may be saturated or unsaturated and straight, branched, or cyclic. Specific examples thereof are as exemplified above for the hydrocarbyl group represented by R^{fa1} in formula (3A′). x and y are each independently an integer of 0 to 5, and z is an integer of 0 to 4.

Examples of the photoacid generator having formula (4) are as exemplified for the photoacid generator having formula (2) in JP-A 2017-26980.

Of the foregoing photoacid generators, those having an anion of formula (3A′) or (3D) are particularly preferred because of reduced acid diffusion and high solubility in the solvent. Those having formula (4′) are particularly preferred because of extremely reduced acid diffusion.

As the photoacid generator, a sulfonium or iodonium salt having an anion containing an iodized or brominated aromatic ring can also be used. Examples of such a salt include those having the following formula (5-1) or (5-2).

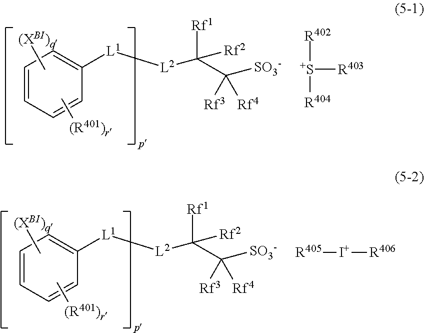

In formulae (5-1) and (5-2), p′ is an integer satisfying 1≤p′≤3. q′ and r′ are integers satisfying 1≤q′≤5, 0≤r′≤3, and 1≤q′+r′≤5. q′ is preferably an integer satisfying 1≤q′≤3 and more preferably 2 or 3. r′ is preferably an integer satisfying 0≤r′≤2.

In formulae (5-1) and (5-2), X^{BI} is an iodine atom or a bromine atom, and may be the same or different when p′ and/or q′ is 2 or more.

In formulae (5-1) and (5-2), L¹ is a single bond, an ether bond, an ester bond, or a C₁-C₆ saturated hydrocarbylene group which may contain an ether bond or an ester bond. The saturated hydrocarbylene group may be straight, branched, or cyclic.

In formulae (5-1) and (5-2), L² is a single bond or a C₁-C₂₀ divalent linking group when p′ is 1, and a C₁-C₂₀ (p′+1)-valent linking group which may contain an oxygen atom, a sulfur atom, or a nitrogen atom when p′ is 2 or 3.

In formulae (5-1) and (5-2), R⁴⁰¹ is a hydroxy group, a carboxy group, a fluorine atom, a chlorine atom, a bromine atom, an amino group, a C₁-C₂₀ hydrocarbyl group, C₁-C₂₀ hydrocarbyloxy group, C₂-C₂₀ hydrocarbylcarbonyl group, C₂-C₂₀ hydrocarbyloxycarbonyl group, C₂-C₂₀ hydrocarbylcarbonyloxy group, or C₁-C₂₀ hydrocarbylsulfonyloxy group, which may contain a fluorine atom, a chlorine atom, a bromine atom, a hydroxy group, an amino group, or an ether bond, or —N(R^{401A})(R^{401B)}, —N(R^{401C})—C(═O)—R^{401D}, or —N(R⁴⁰¹C)—C(═O)—O—R^{401D}. R^{401A} and R^{401B} are each independently a hydrogen atom or a C₁-C₆ saturated hydrocarbyl group. R^{401C} is a hydrogen atom or a C₁-C₆ saturated hydrocarbyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. R^{401D} is a C₁-C₁₆ aliphatic hydrocarbyl group, a C₆-C₁₄ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group. The aliphatic hydrocarbyl group may be saturated or unsaturated and straight, branched, or cyclic. The hydrocarbyl group, the hydrocarbyloxy group, the hydrocarbyloxycarbonyl group, the hydrocarbylcarbonyl group, and the hydrocarbylcarbonyloxy group may be straight, branched, or cyclic. When p′ and/or r′ is 2 or more, respective R⁴⁰¹ may be the same as or different from each other.

Of these, R⁴⁰¹ is preferably a hydroxy group, —N(R^{401C}—C(═O)—R^{401D}, —N(R^{401C})—C(═O)—O—R^{401D}, a fluorine atom, a chlorine atom, a bromine atom, a methyl group, a methoxy group, or the like.

In formulae (5-1) and (5-2), Rf¹ to Rf⁴ are each independently a hydrogen atom, a fluorine atom, or a trifluoromethyl group, and at least one of Rf¹ to Rf⁴ is a fluorine atom or a trifluoromethyl group. Rf¹ and Rf², taken together, may form a carbonyl group. Preferably, both Rf³ and Rf⁴ are a fluorine atom.

In formulae (5-1) to (5-2), R⁴⁰² to R⁴⁰⁶ are each independently a halogen atom, or a C₁-C₂₀ hydrocarbyl group which may contain a heteroatom. The hydrocarbyl group may be saturated or unsaturated and straight, branched, or cyclic. Specific examples thereof are as exemplified above for the hydrocarbyl group represented by R¹⁰¹ to R¹⁰⁵ in the description of formulae (3-1) and (3-2). Some or all of the hydrogen atoms in the hydrocarbyl group may be substituted with a hydroxy group, a carboxy group, a halogen atom, a cyano group, a nitro group, a mercapto group, a sultone ring, a sulfo group, or a sulfonium salt-containing group, and some of —CH₂— in the hydrocarbyl group may be substituted with an ether bond, an ester bond, a carbonyl group, an amide bond, a carbonate bond, or a sulfonate bond. A pair of R⁴⁰² and R⁴⁰³ may bond together to form a ring with a sulfur atom to which they are attached. In this case, examples of the ring are as exemplified above for the ring that R¹⁰¹ and R¹⁰² in the description of formula (3-1) may bond together to form with the sulfur atom to which they are attached.

Examples of the cation of the sulfonium salt having formula (5-1) are exemplified above for the cation of the sulfonium salt having formula (3-1). Examples of the cation of the iodonium salt having formula (3-2) are exemplified above for the cation of the iodonium salt having formula (3-2).

Examples of the anion of the onium salt having formula (5-1) or (5-2) are derived are shown below, but not limited thereto. In the following formula, X^{Br} is as defined above.

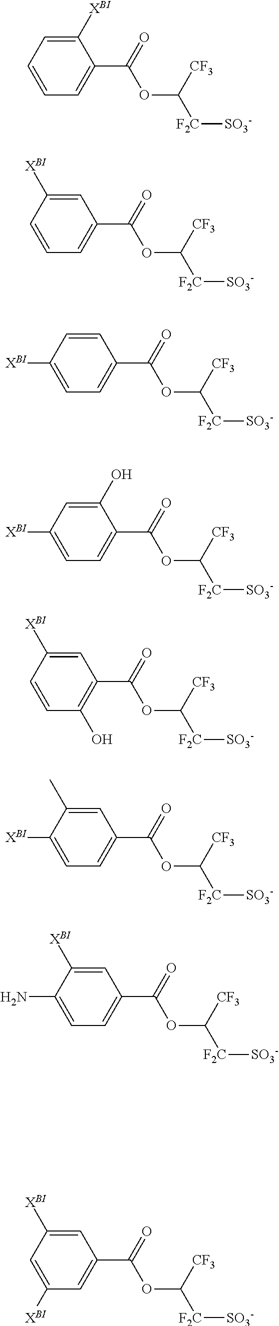

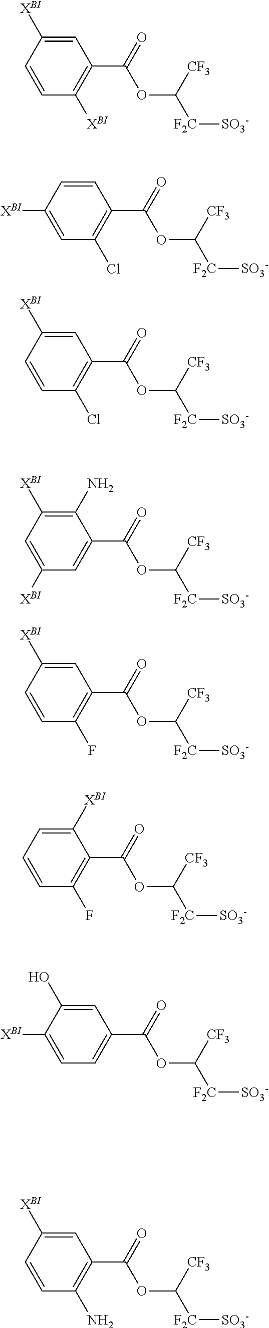

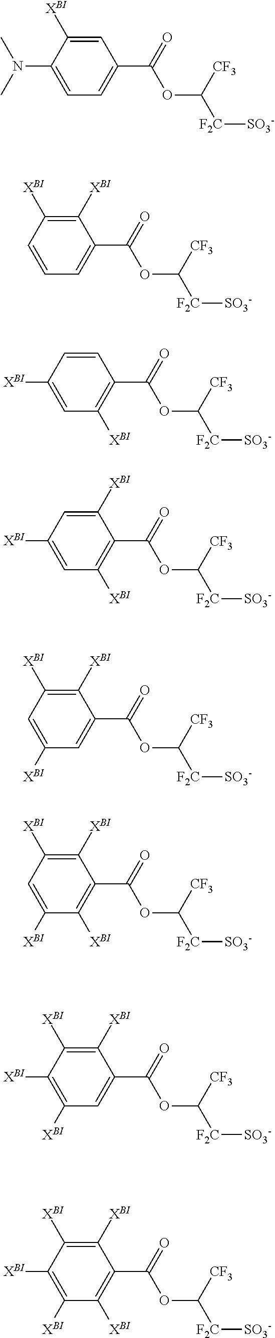

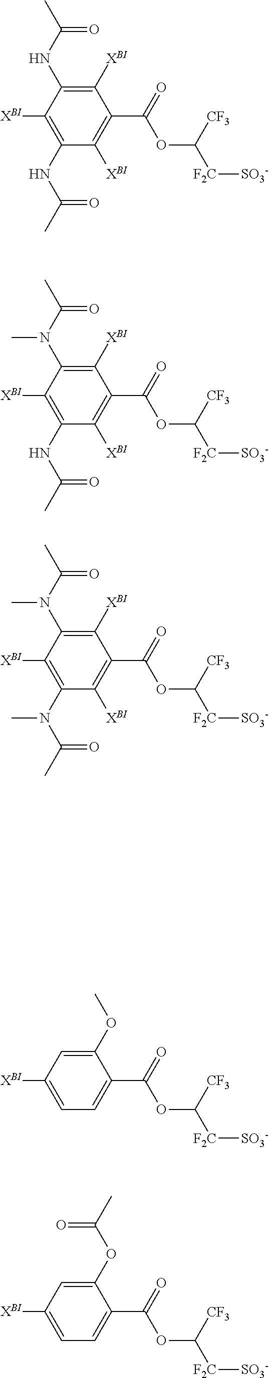

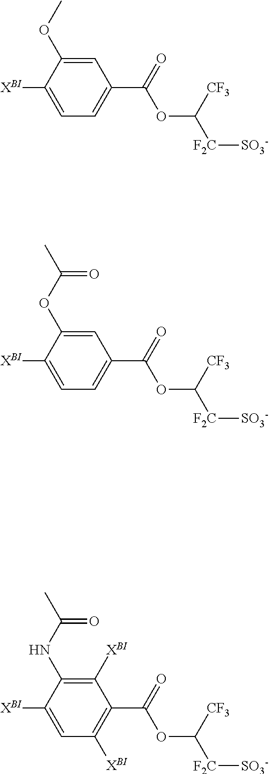

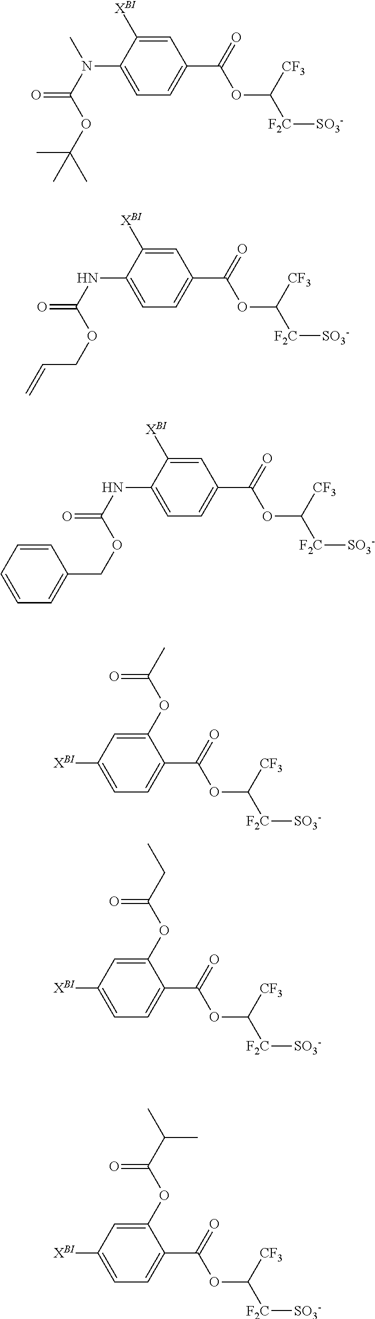

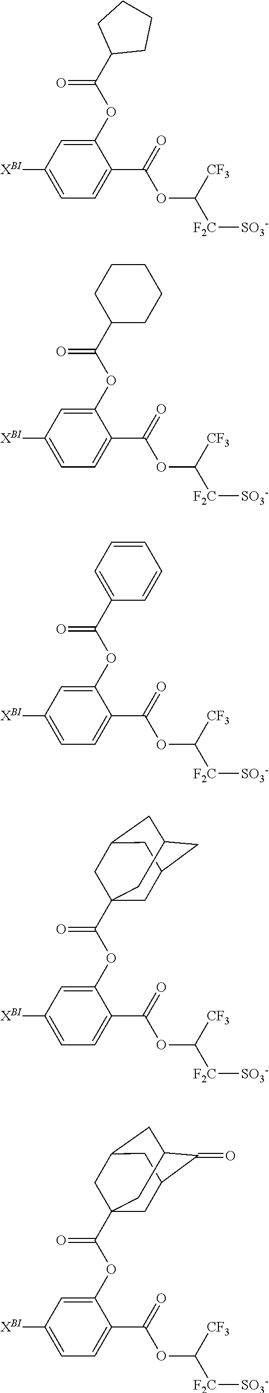

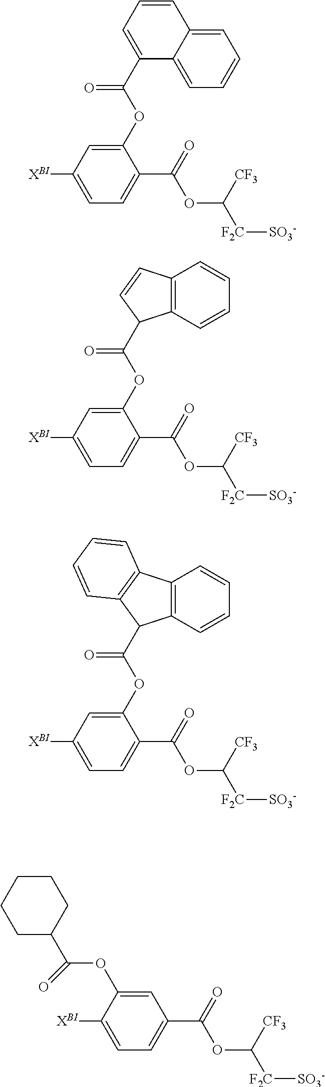

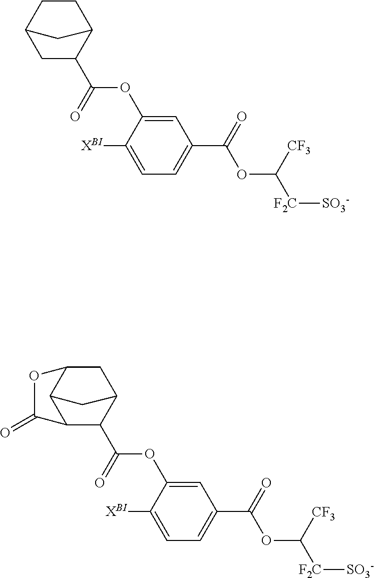

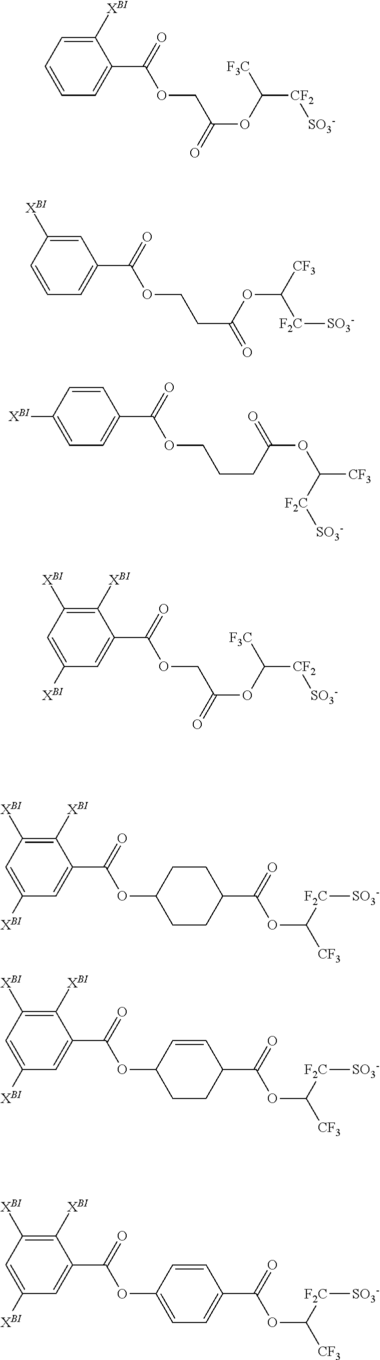

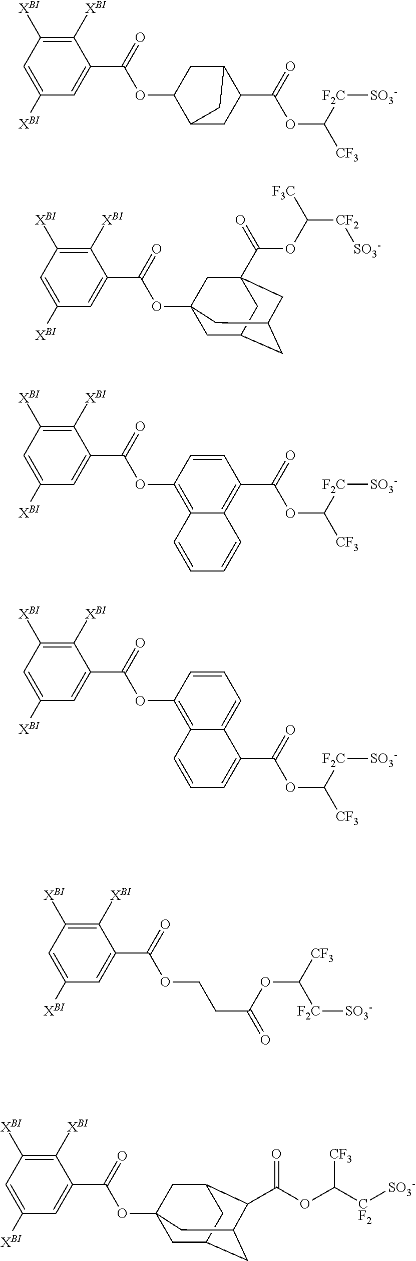

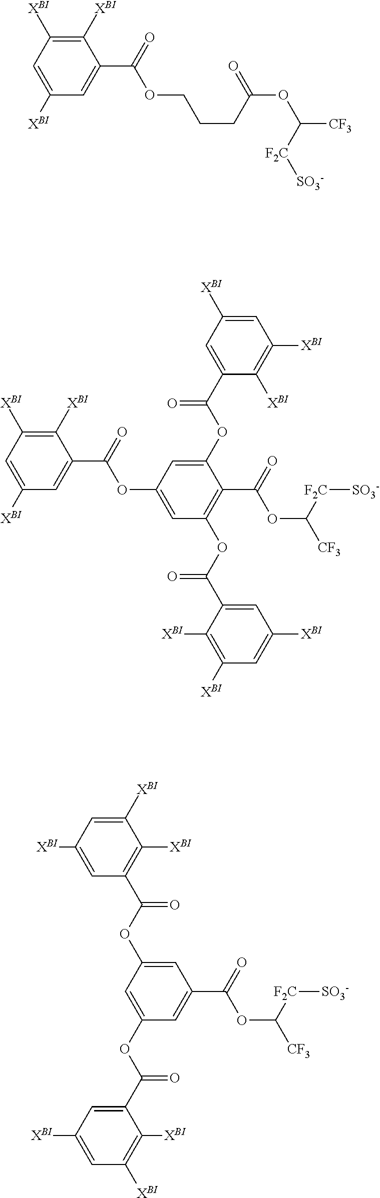

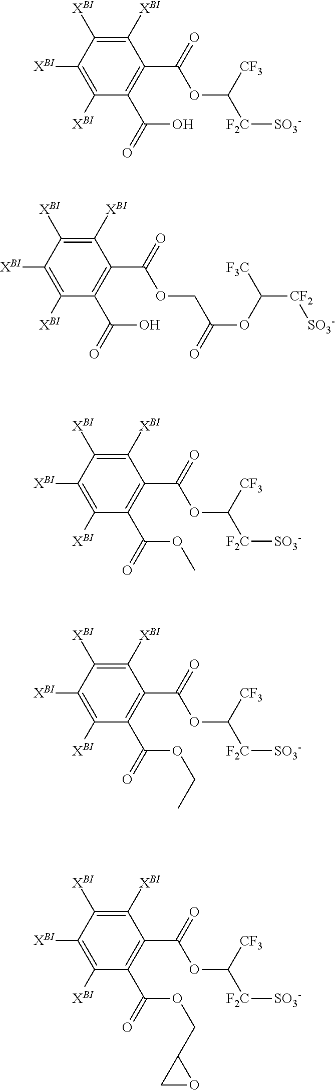

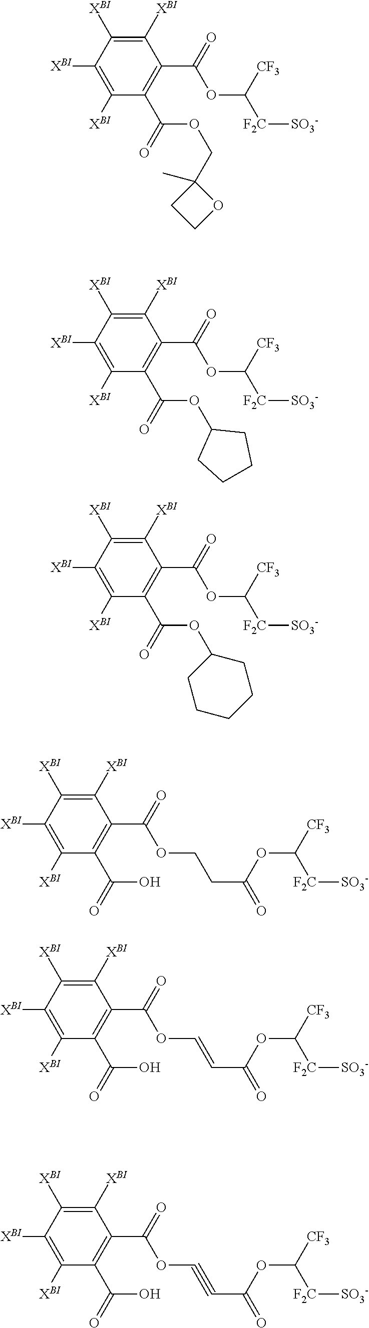

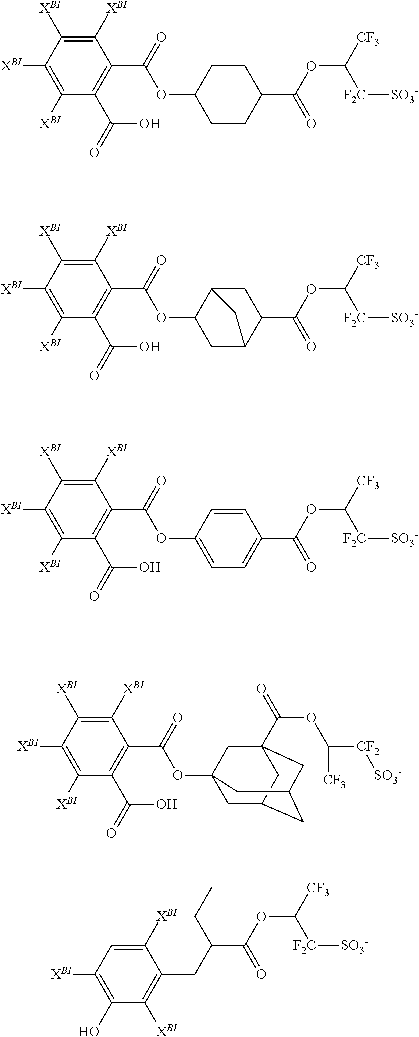

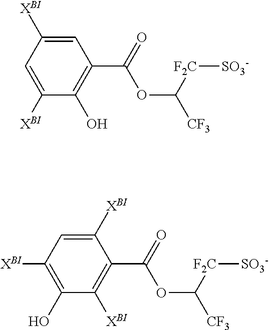

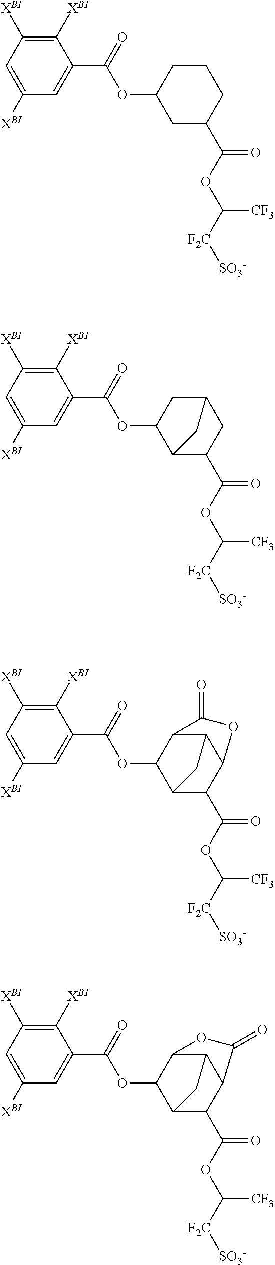

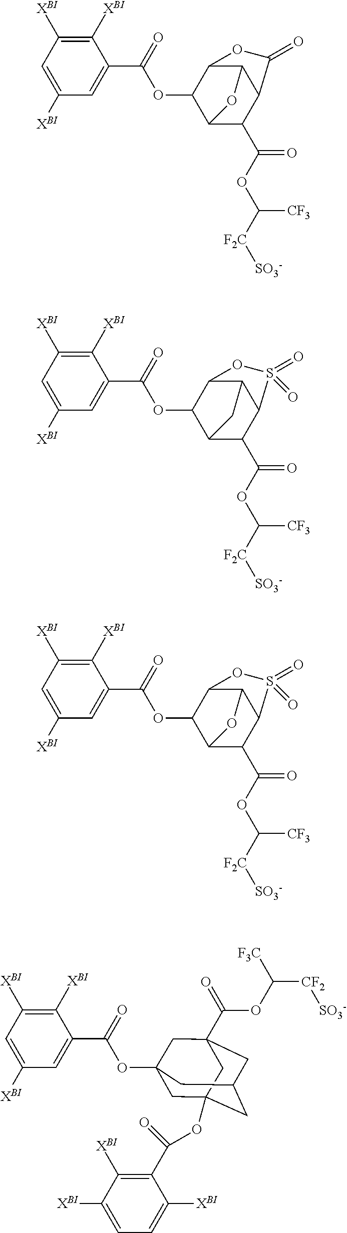

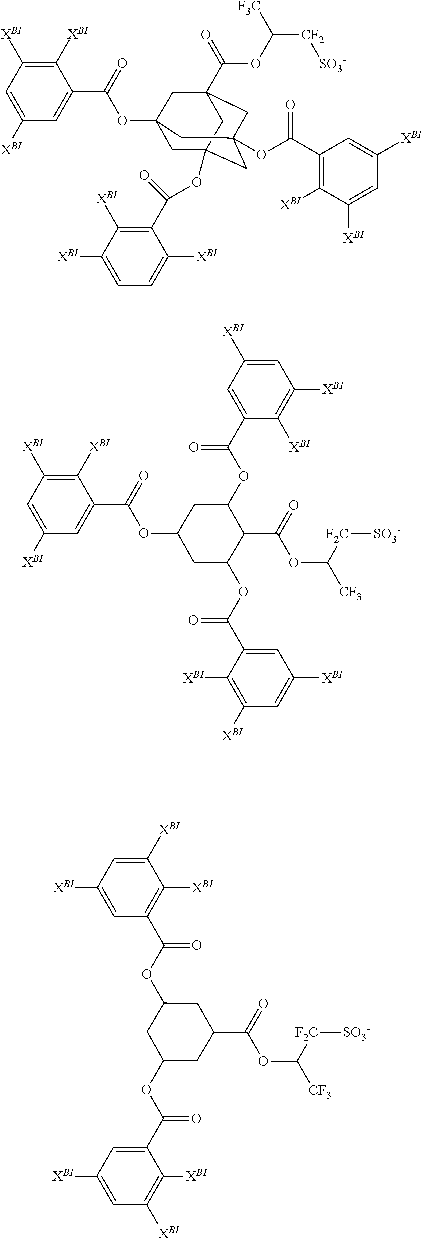

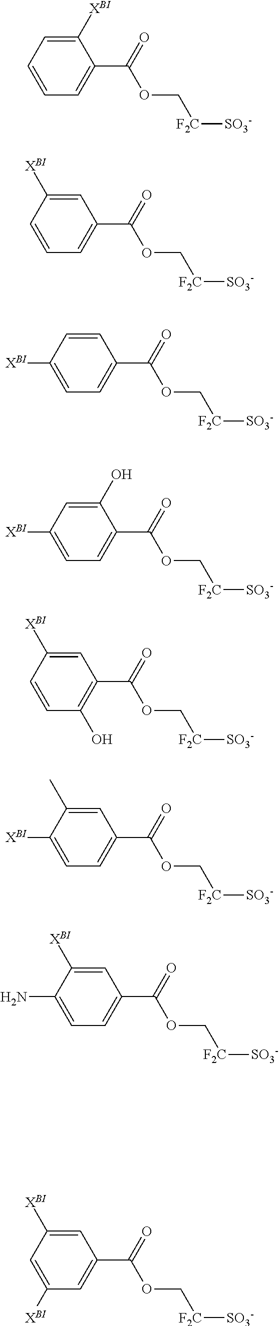

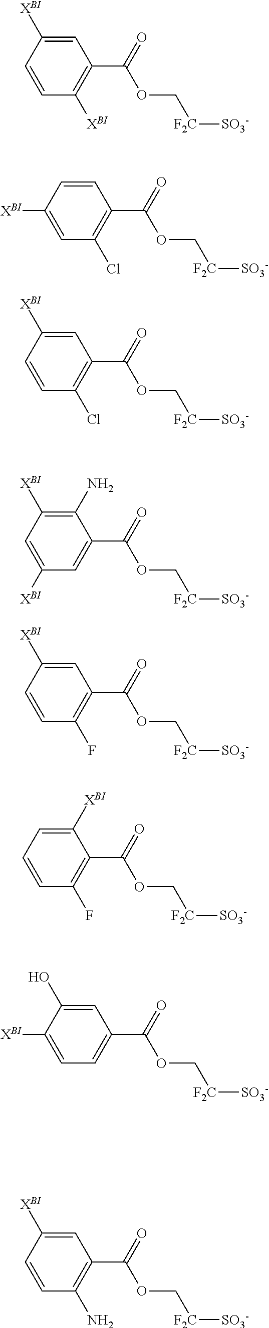

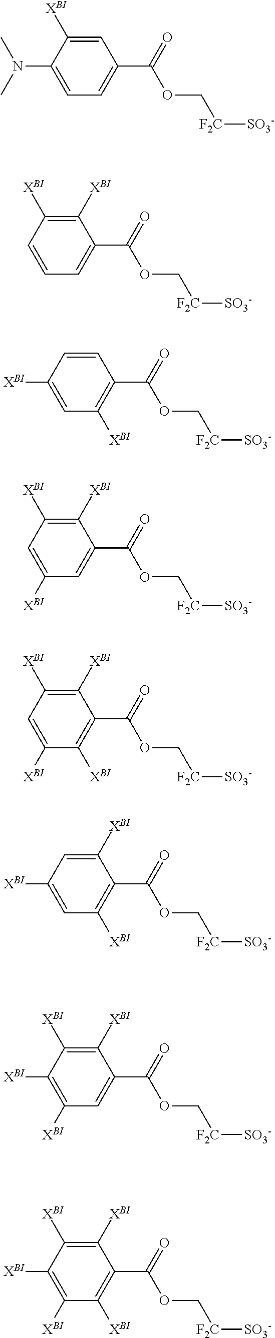

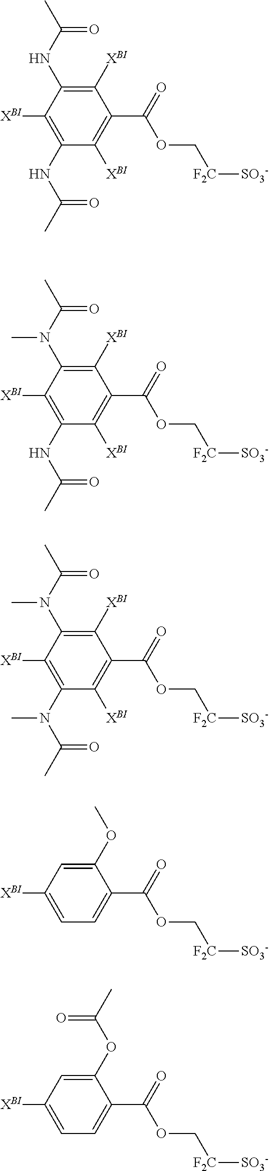

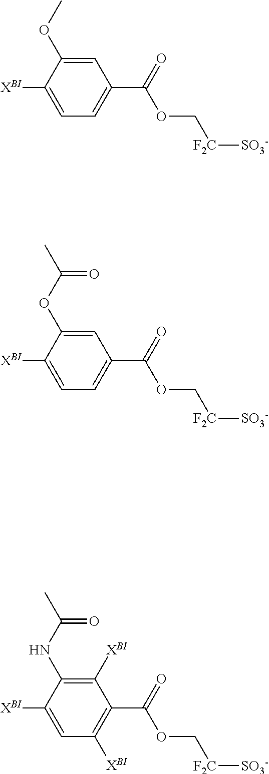

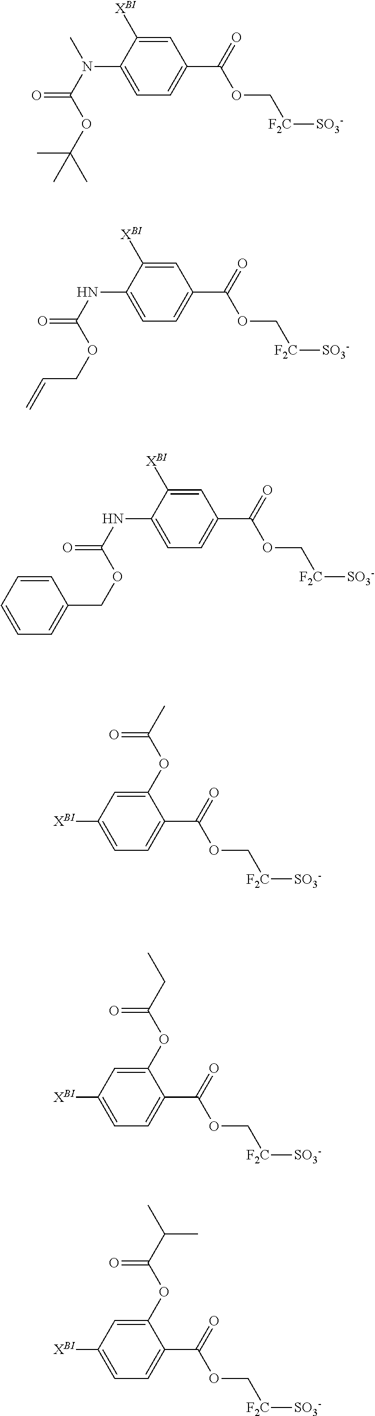

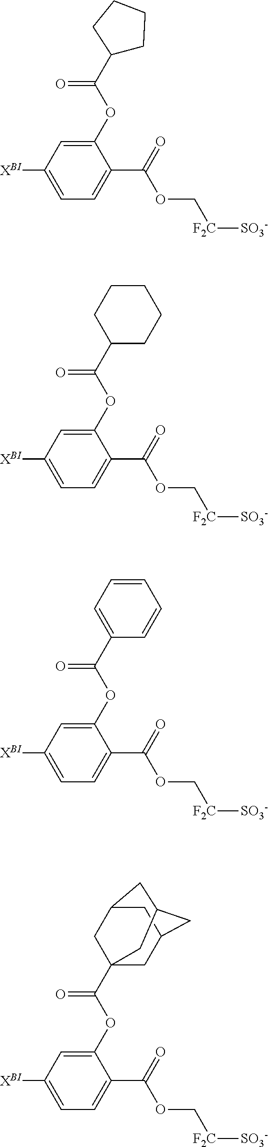

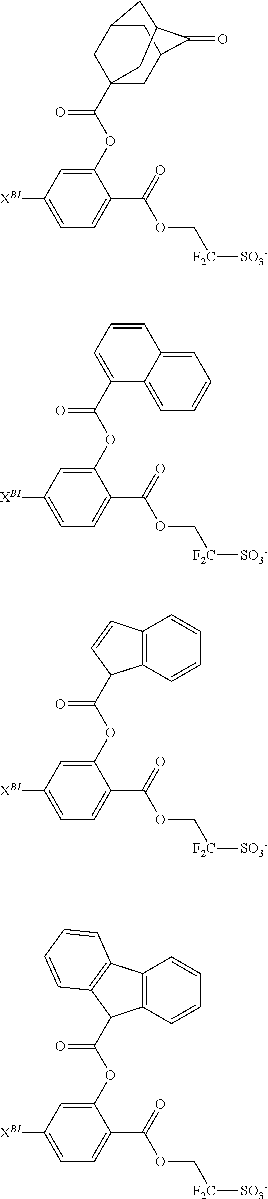

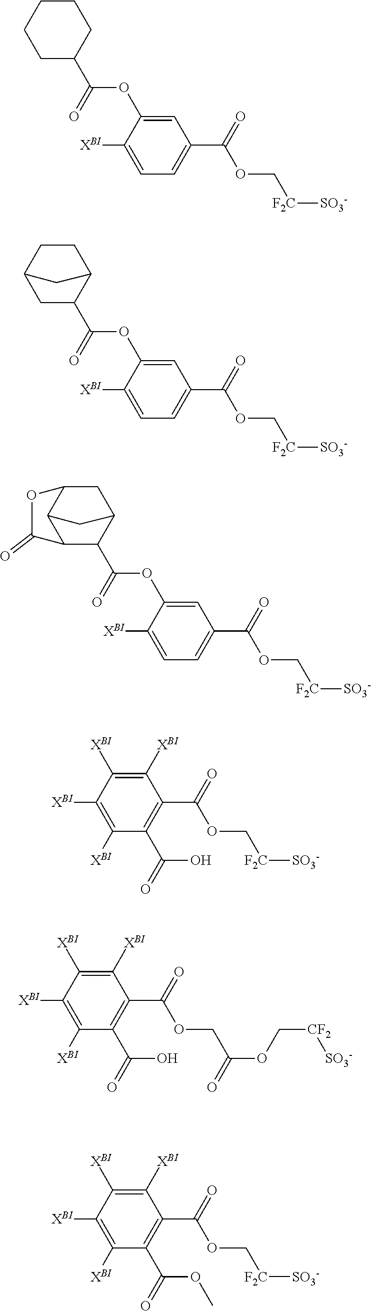

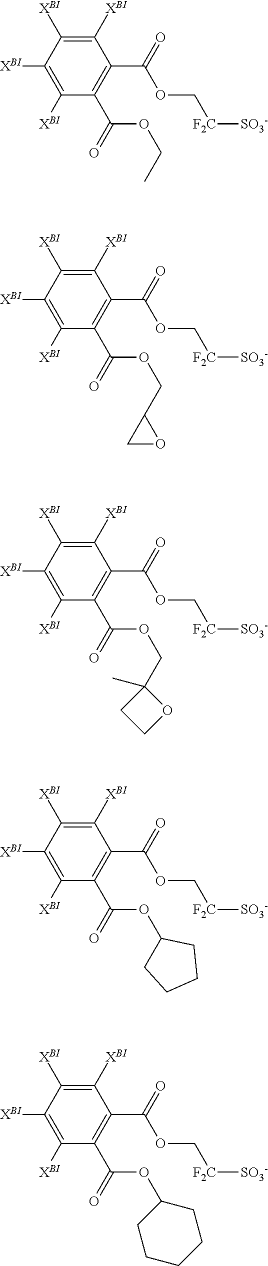

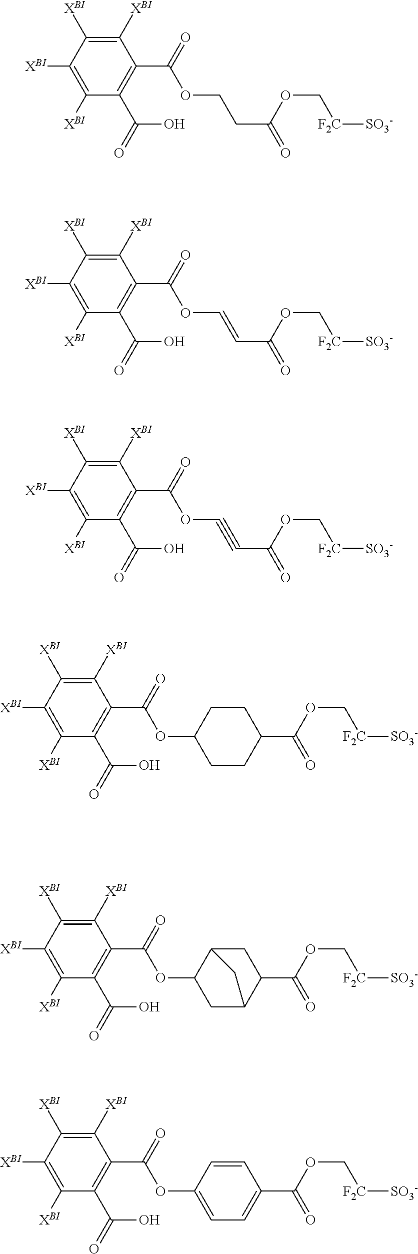

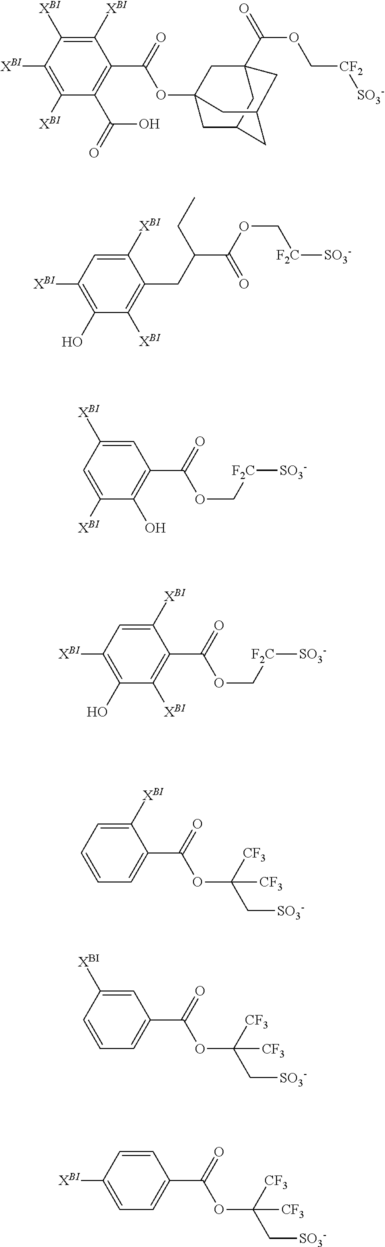

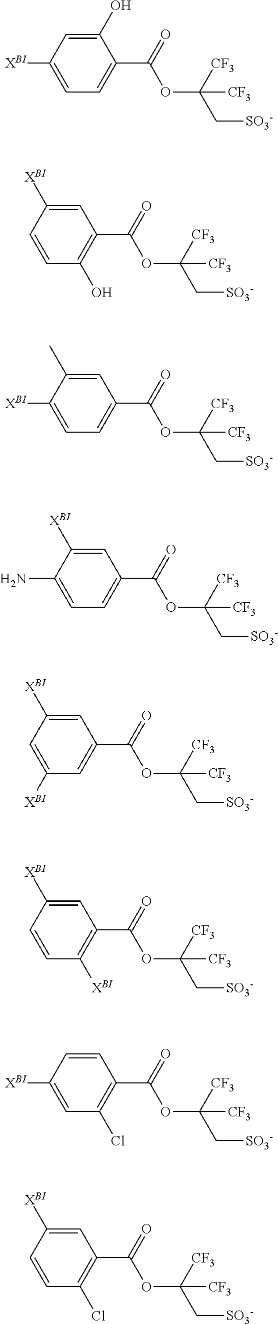

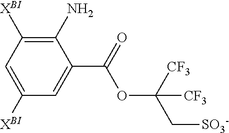

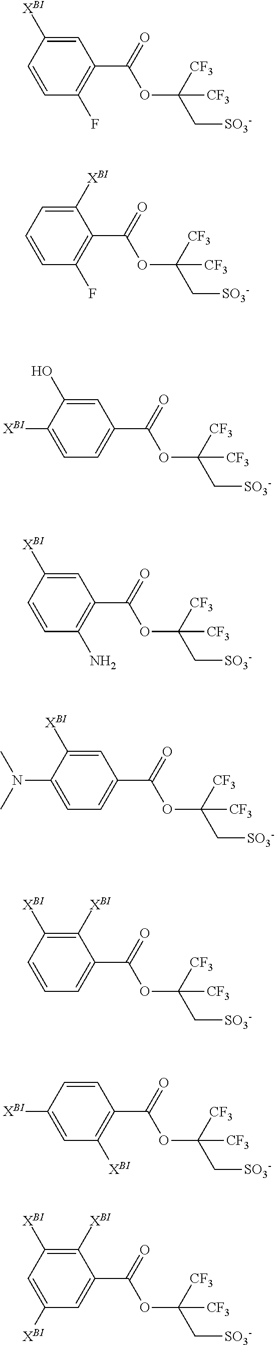

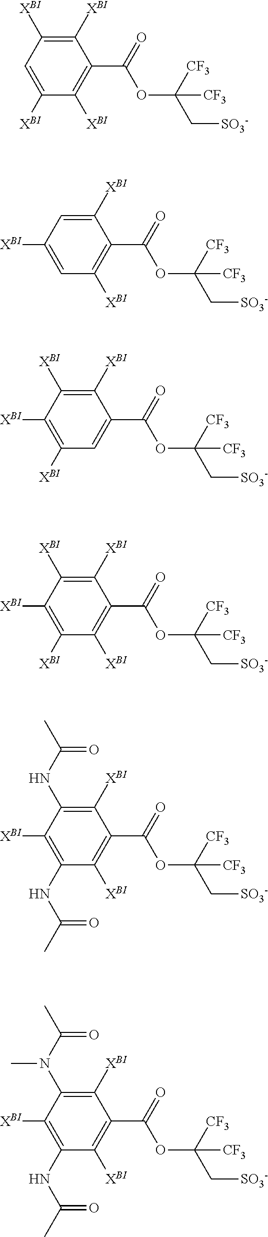

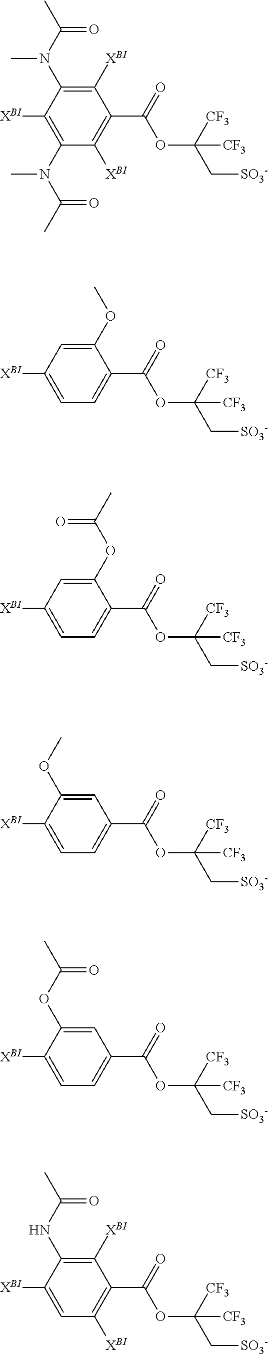

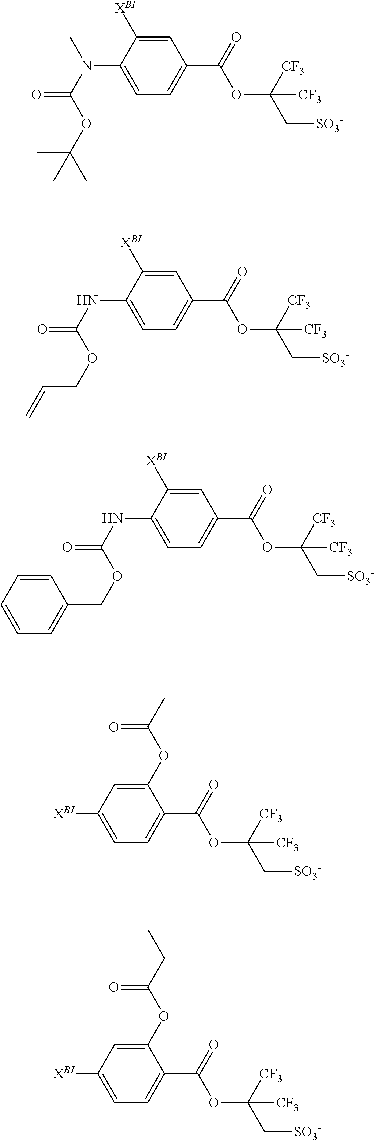

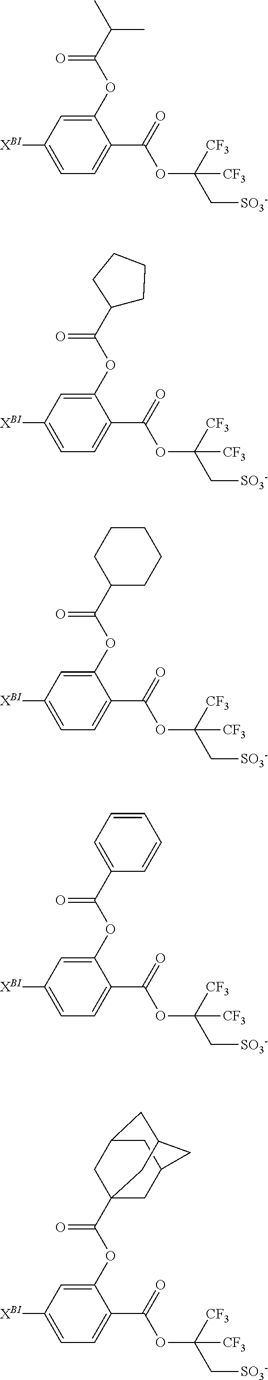

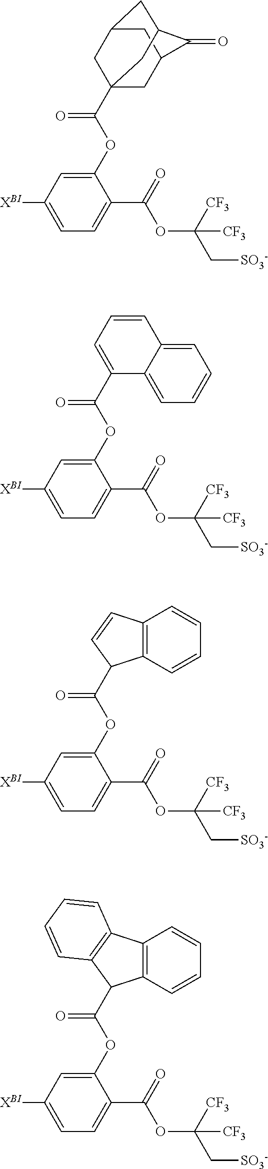

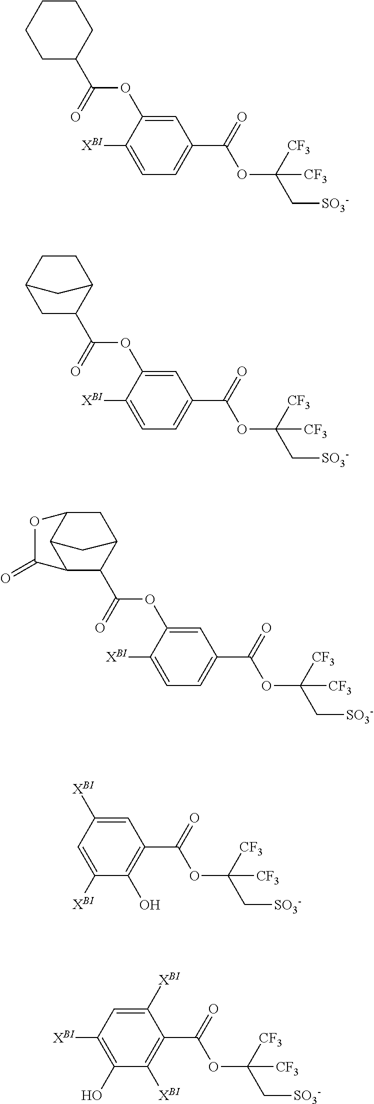

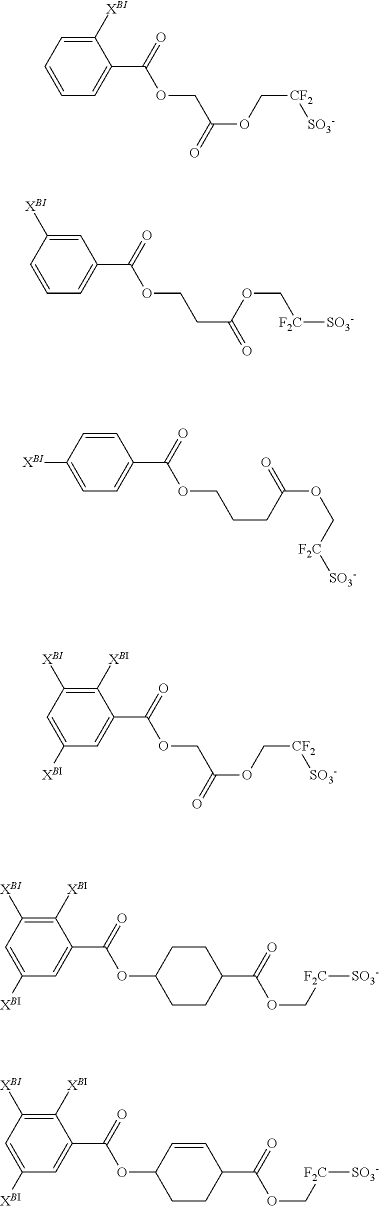

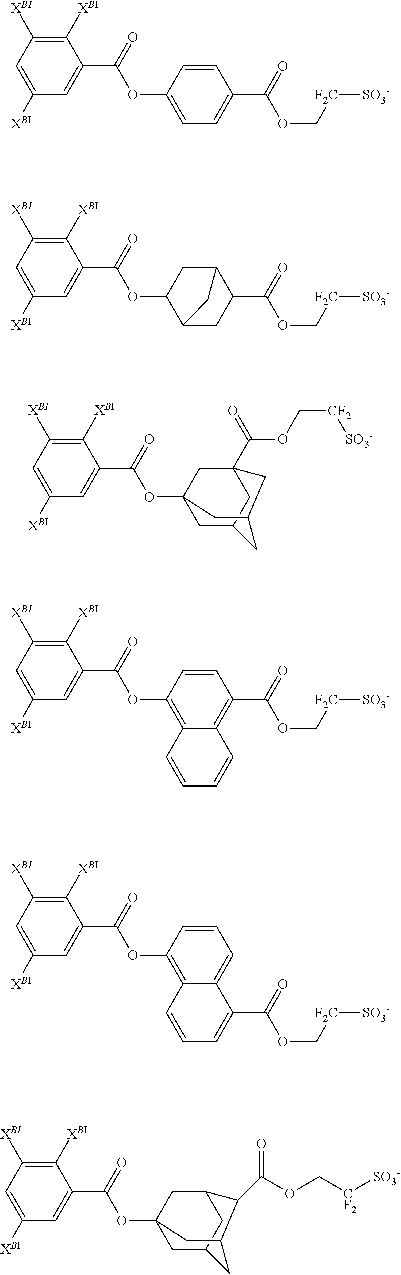

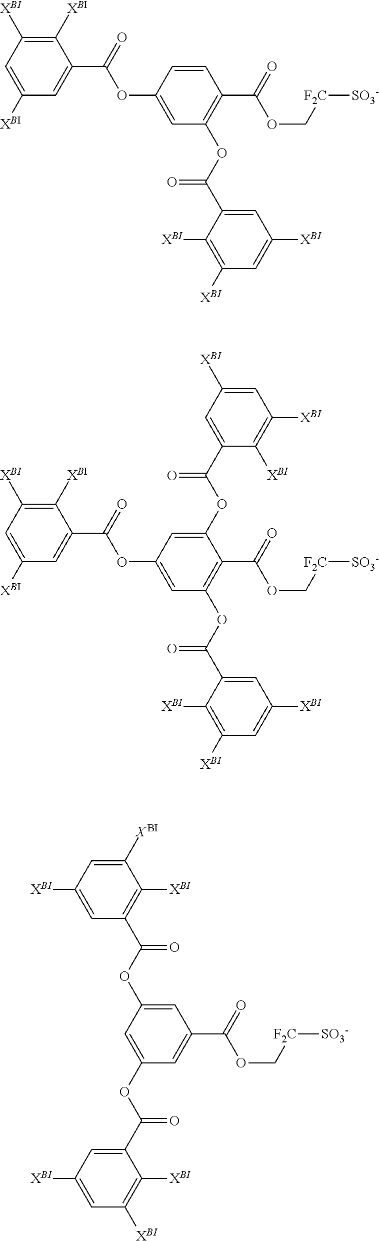

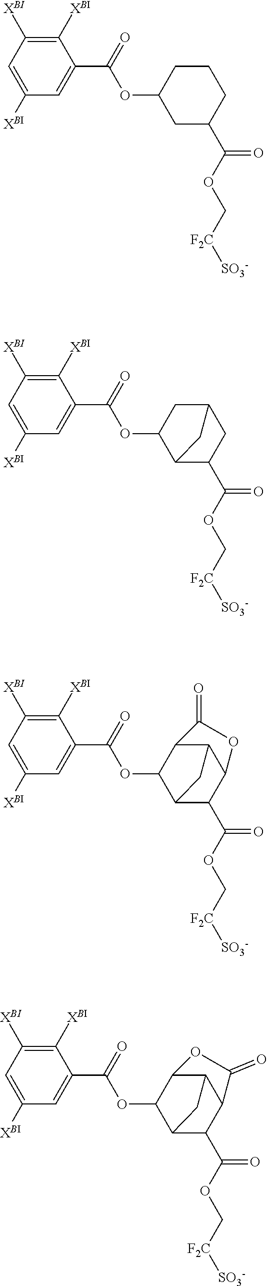

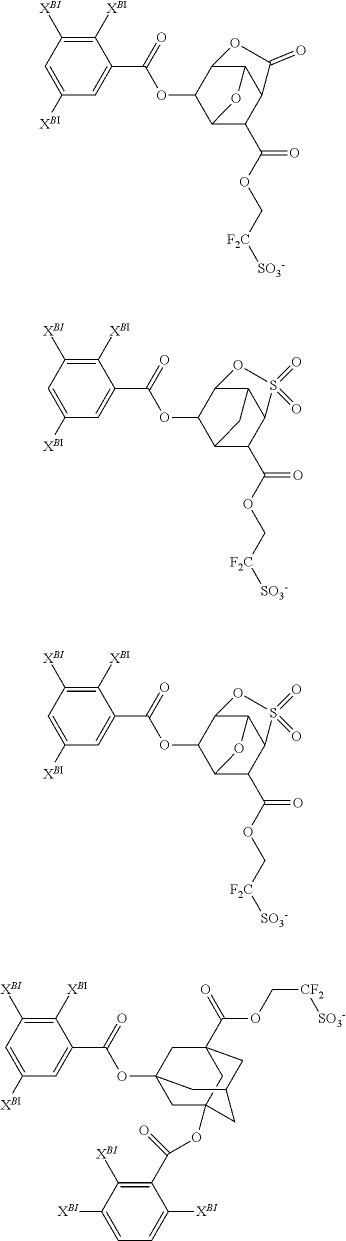

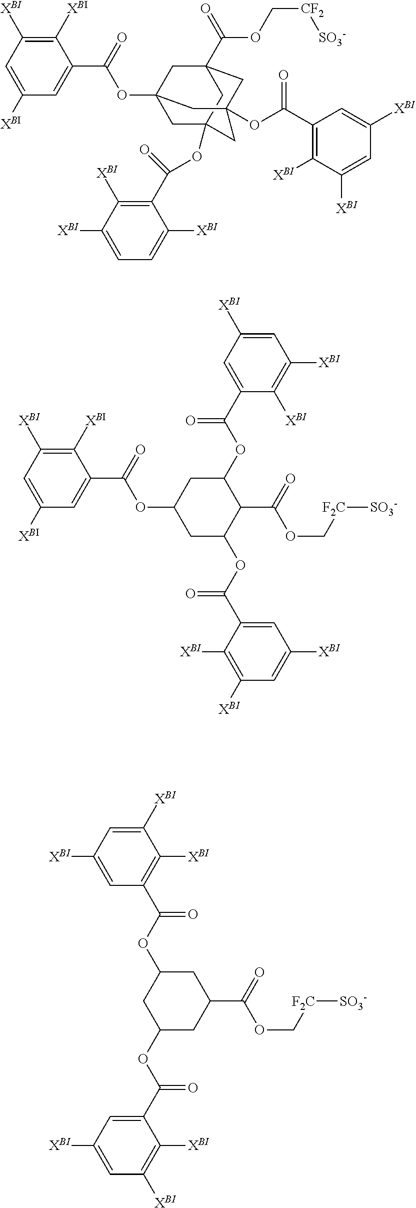

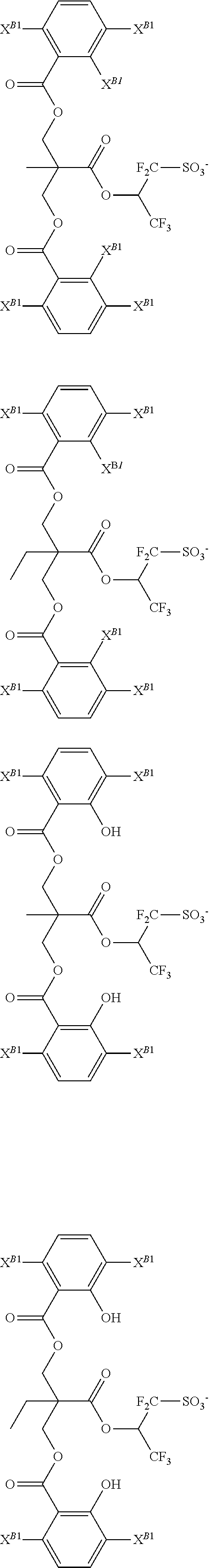

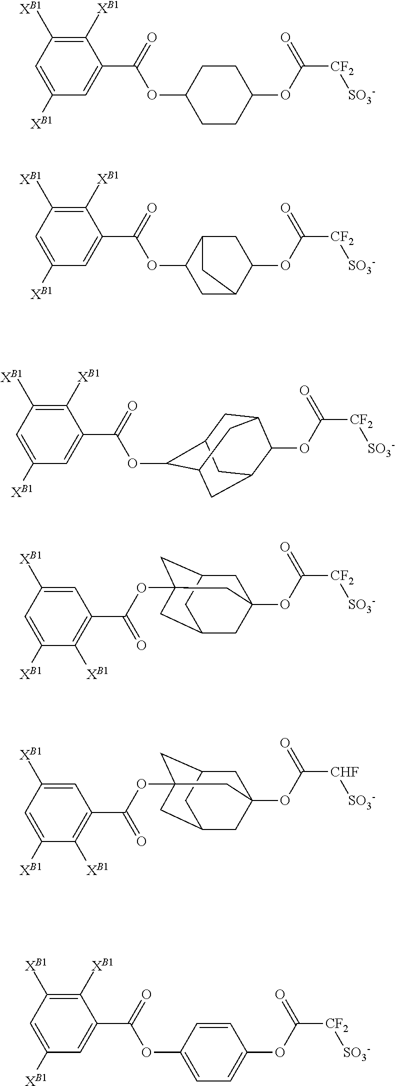

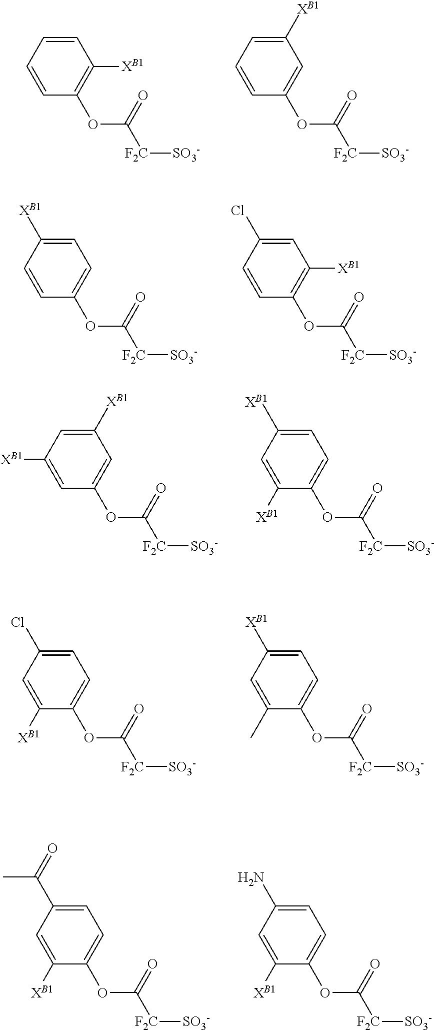

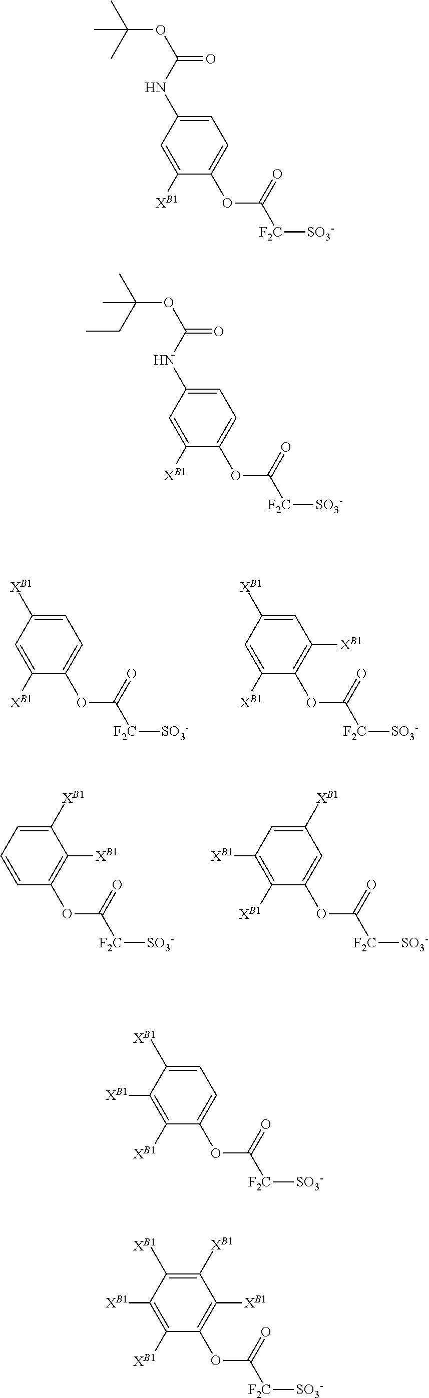

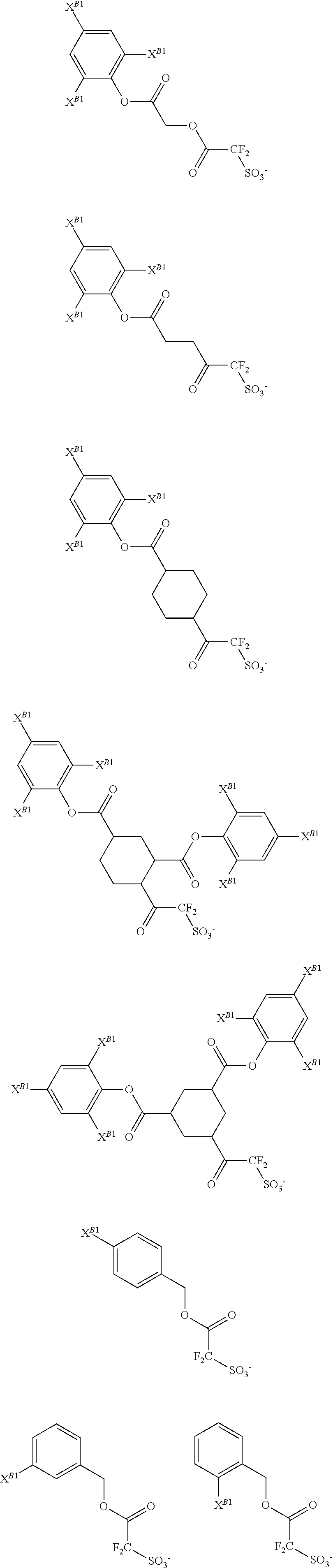

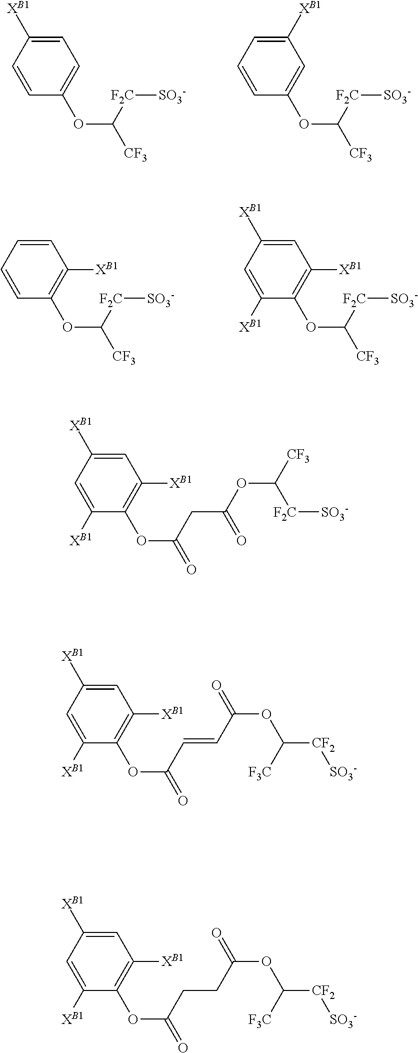

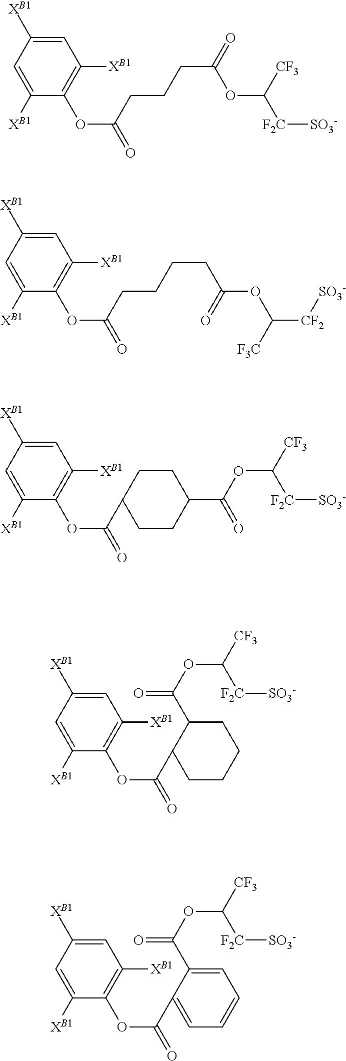

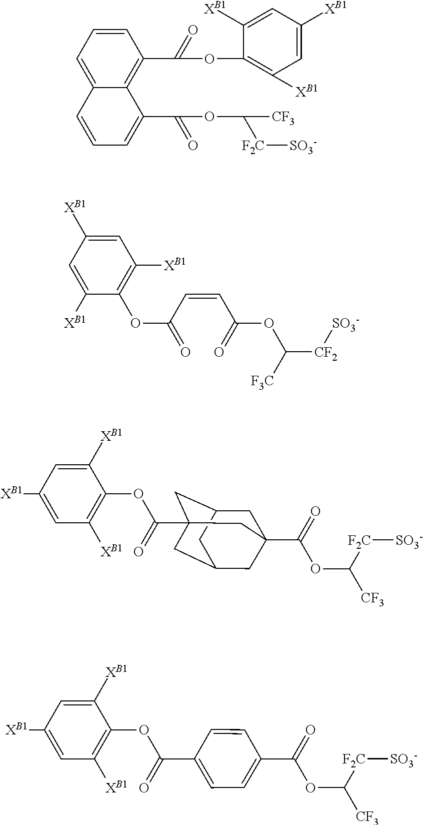

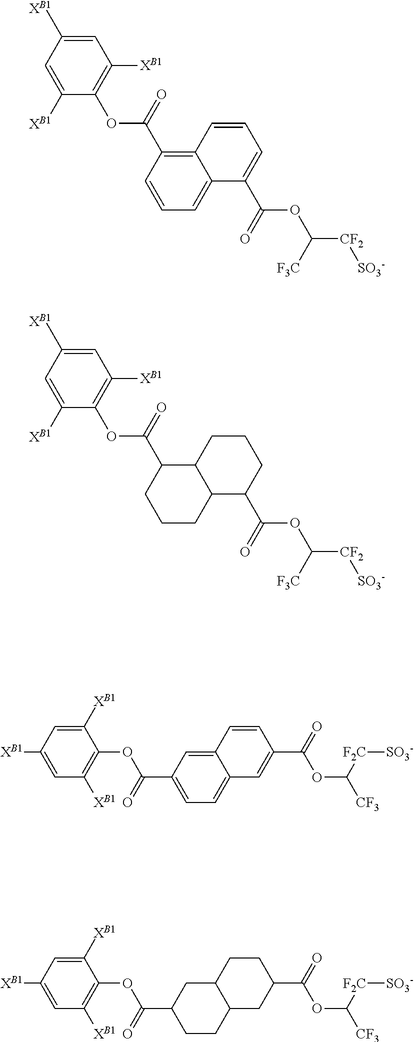

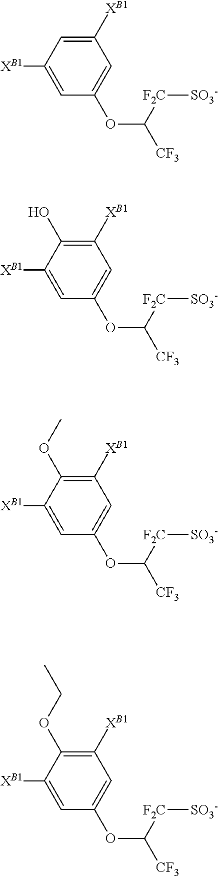

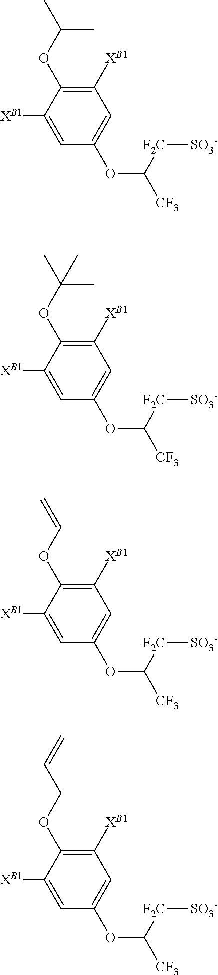

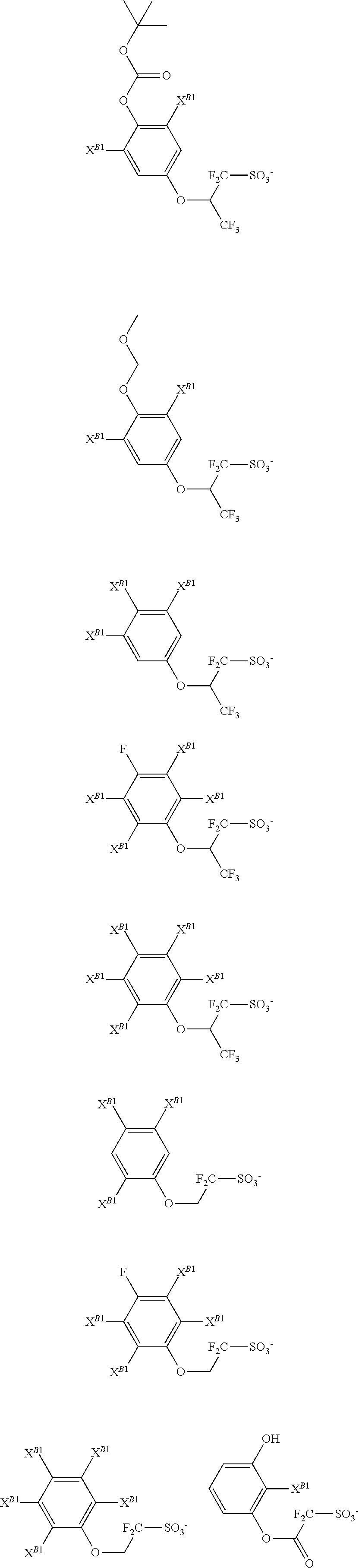

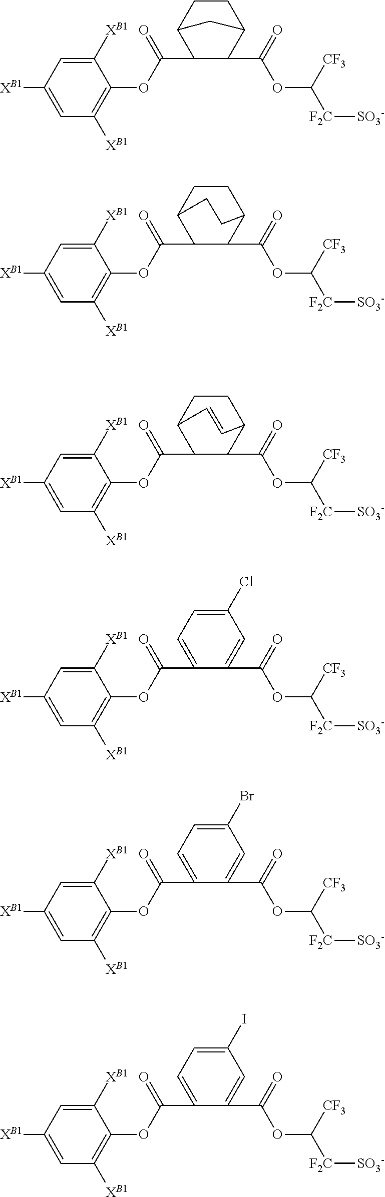

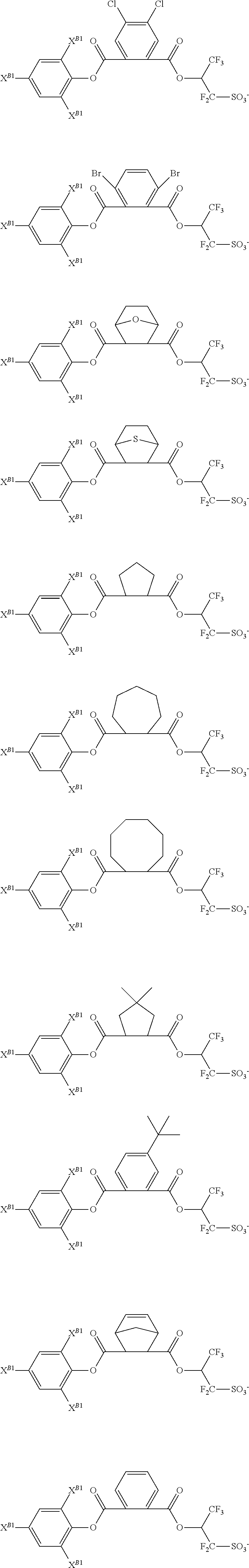

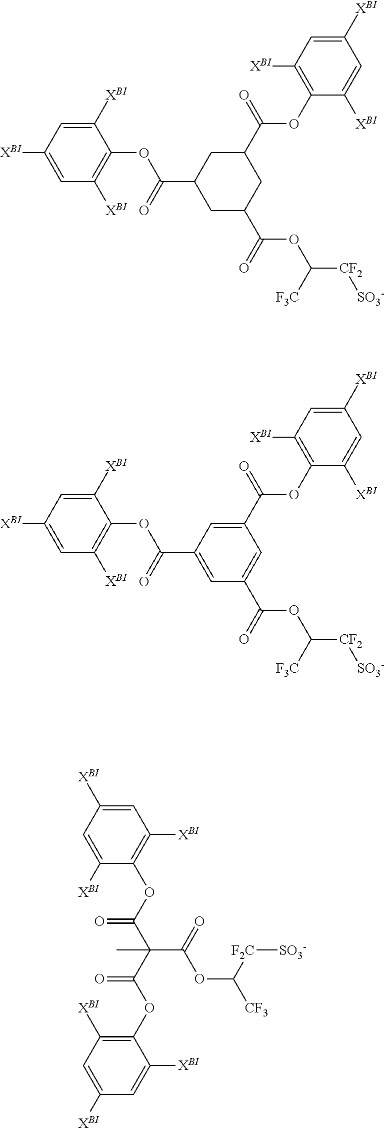

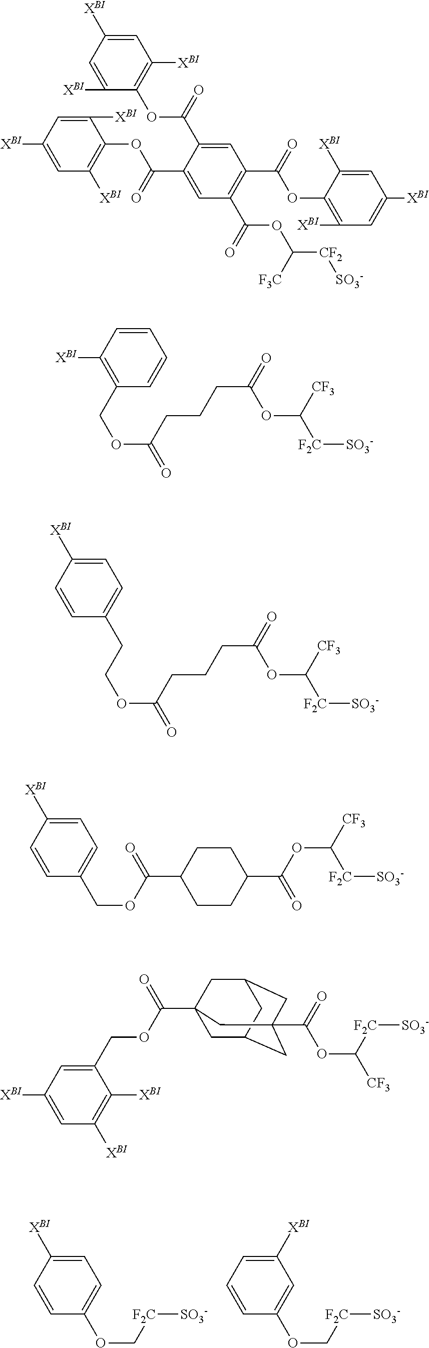

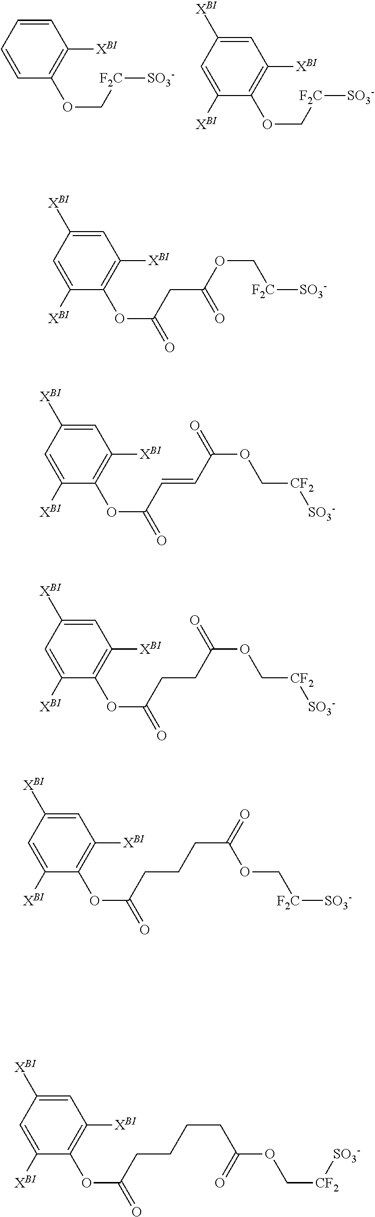

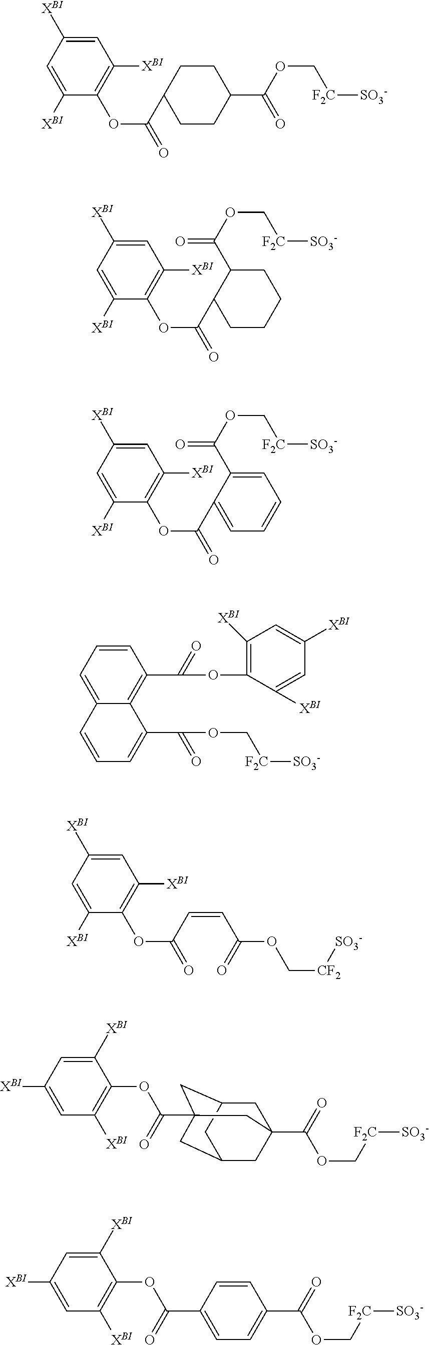

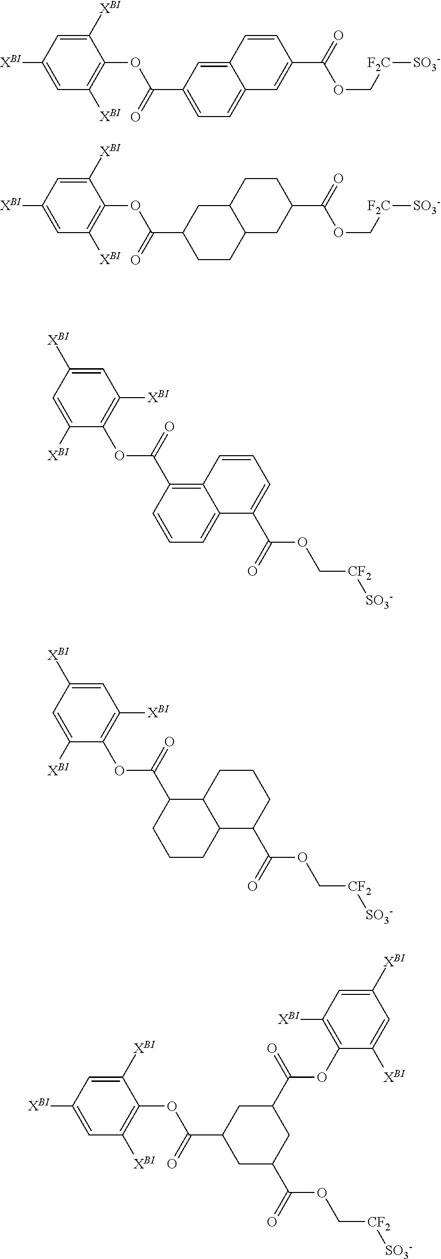

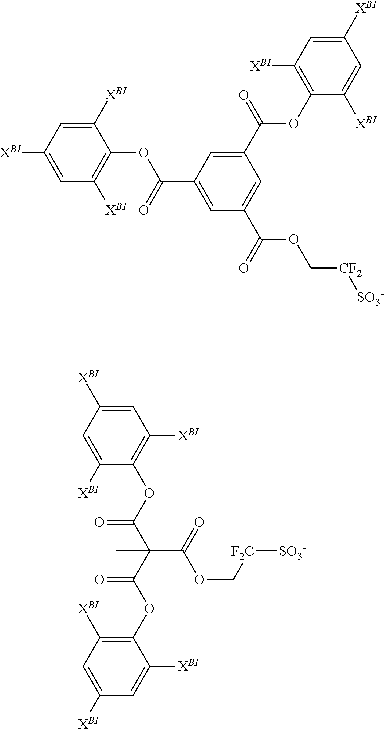

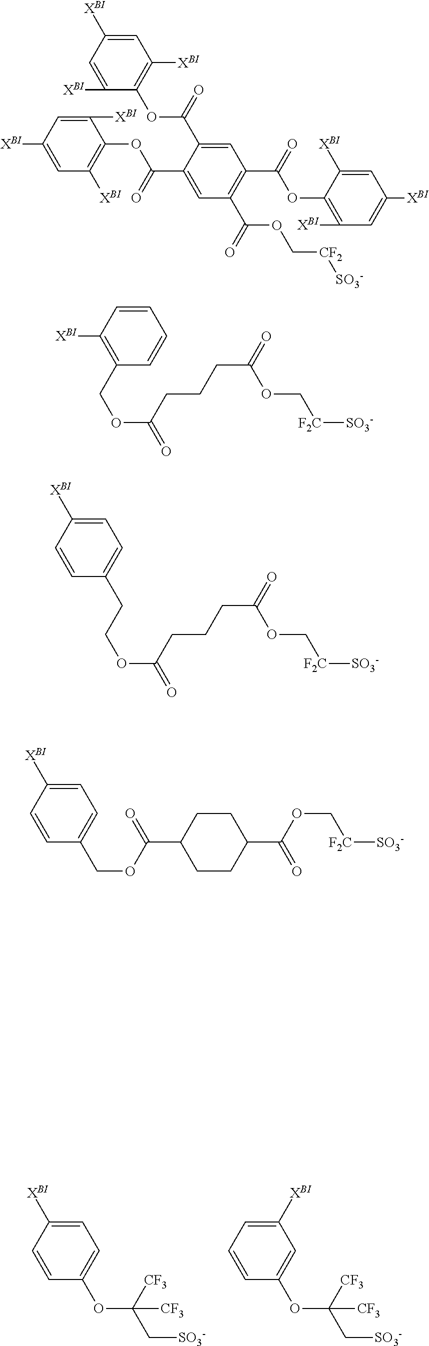

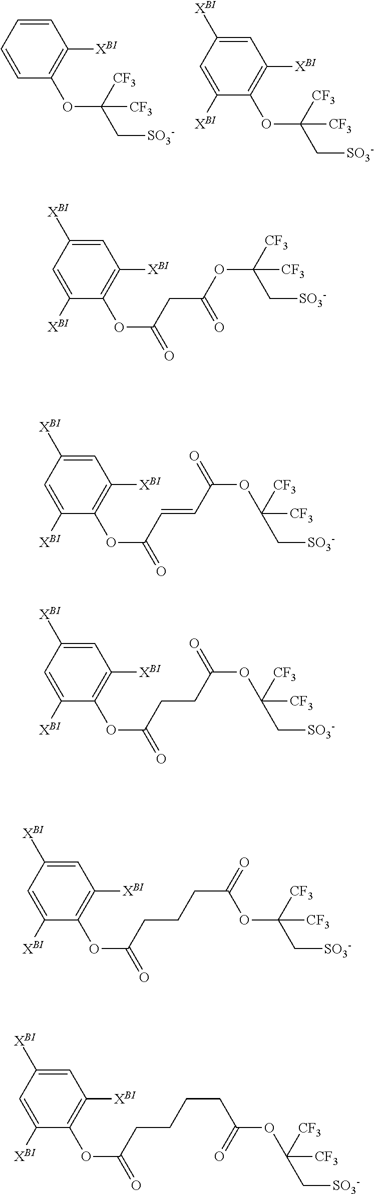

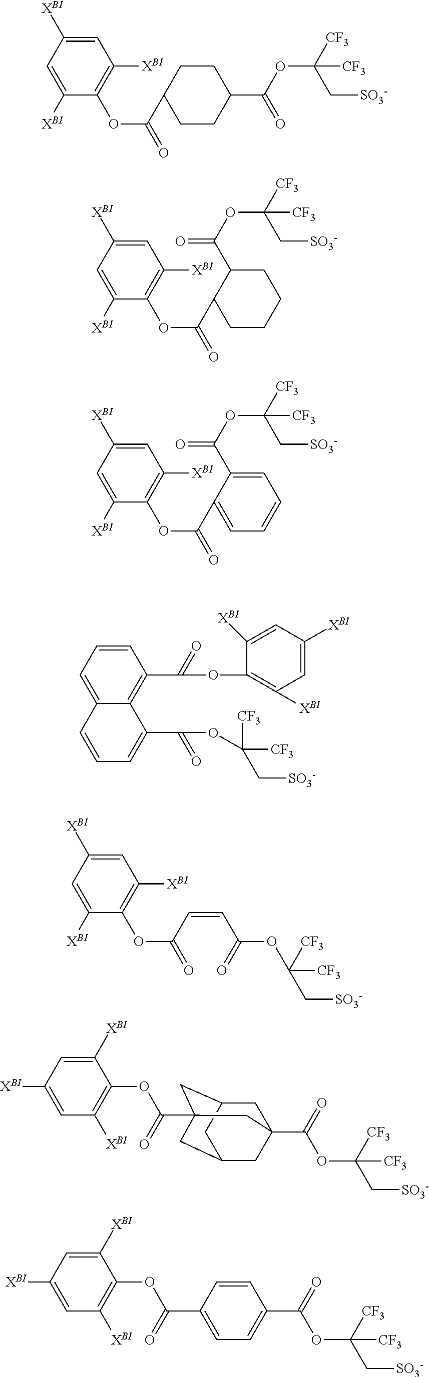

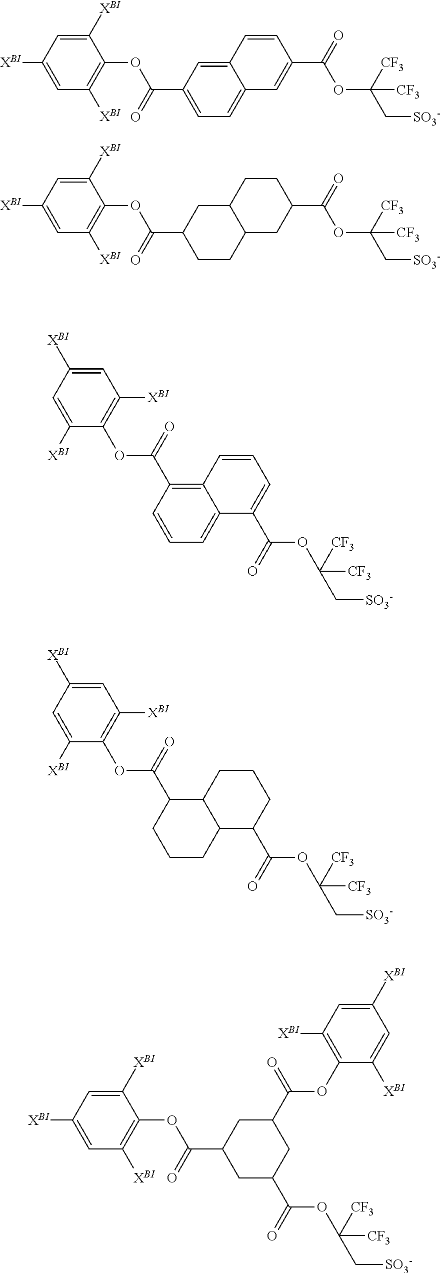

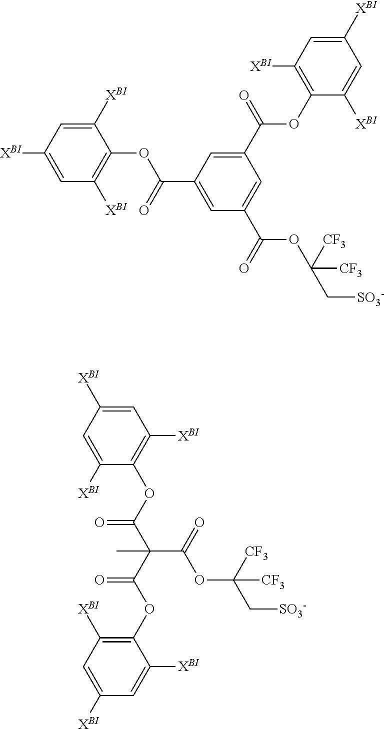

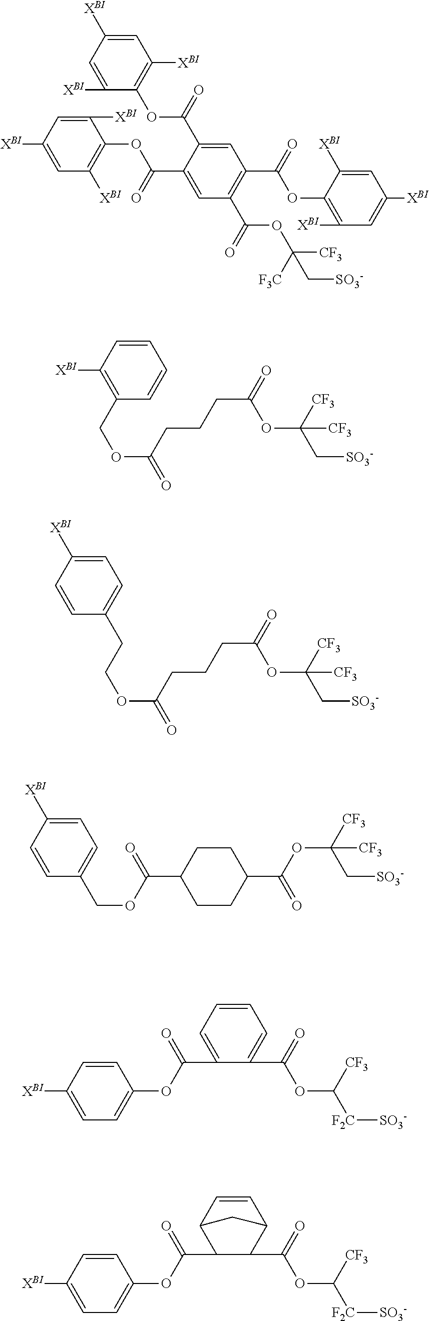

When the resist composition of the present invention contains the acid generator of addition type, the content thereof is preferably 0.1 to 50 parts by weight and more preferably 1 to 40 parts by weight per 100 parts by weight of the base polymer. The resist composition of the present invention can function as a chemically amplified resist composition when the base polymer includes any of the repeat units f1 to f3 and/or the acid generator of addition type is contained.

Organic Solvent

The resist composition of the present invention may comprise an organic solvent. The organic solvent is not particularly limited as long as each component described above and each component described below can be dissolved. Examples of the organic solvent include ketones such as cyclohexanone, cyclopentanone, methyl-2-n-pentyl ketone, and 2-heptanone: alcohols such as 3-methoxybutanol, 3-methyl-3-methoxybutanol, 1-methoxy-2-propanol, 1-ethoxy-2 propanol, and diacetone alcohol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone, which are described in JP-A 2008-111103, paragraphs [0144] to [0145].

The content of the organic solvent in the resist composition of the present invention is preferably 100 to 10000 parts by weight and more preferably 200 to 8000 parts by weight per 100 parts by weight of the base polymer. The organic solvent may be used alone or in admixture of two or more kinds thereof.

Other Components

The resist composition of the present invention may contain a surfactant, a dissolution inhibitor, a crosslinker, a quencher other than the sulfonium salt (referred to as the other quencher, hereinafter), a water repellency improver, acetylene alcohol, and the like, in addition to the components described above.

Examples of the surfactant include those described in JP-A 2008-111103, paragraphs to [0166]. Inclusion of a surfactant can improve or control the coating characteristics of the resist composition. When the resist composition of the present invention contains the surfactant, the content thereof is preferably 0.0001 to 10 parts by weight per 100 parts by weight of the base polymer. The surfactant may be used alone or in combination of two or more kinds thereof.

When the resist composition of the present invention is of positive tone, the inclusion of a dissolution inhibitor can lead to an increased difference in dissolution rate between exposed and unexposed areas and a further improvement in resolution. Examples of the dissolution inhibitor include a compound having two or more phenolic hydroxy groups in the molecule, in which an average of from 0 to 100 mol % of all the hydrogen atoms on the phenolic hydroxy groups are replaced by acid labile groups or a compound having a carboxy group in the molecule, in which an average of 50 to 100 mol % of the hydrogen atoms on the carboxy group are replaced by acid labile groups, both the compounds having a molecular weight of preferably 100 to 1000 and more preferably 150 to 800. Specific examples thereof include bisphenol A, trisphenol, phenolphthalein, cresol novolac, naphthalenecarboxylic acid adamantanecarboxylic acid, and cholic acid in which the hydrogen atom on the hydroxy group or carboxy group is replaced by an acid labile group, as described in, for example, JP-A 2008-122932, paragraphs [0155] to [0178].

When the resist composition of the present invention is of positive tone and contains the dissolution inhibitor, the content thereof is preferably 0 to 50 parts by weight and more preferably 5 to 40 parts by weight per 100 parts by weight of the base polymer. The dissolution inhibitor may be used alone or in combination of two or more kinds thereof.

On the other hand, when the resist composition of the present invention is of negative tone, a negative pattern can be obtained by adding a crosslinker to reduce the dissolution rate in the exposed area. Examples of the crosslinker include epoxy compounds, melamine compounds, guanamine compounds, glycoluril compounds or urea compounds having substituted thereon at least one group selected from a methylol group, an alkoxymethyl group, and an acyloxymethyl group, isocyanate compounds, azide compounds, and compounds having a double bond such as an alkenyloxy group. These compounds may be used as an additive or introduced into a polymer side chain as a pendant group. A compound containing a hydroxy group can also be used as a crosslinker.

Examples of the epoxy compounds include tris(2,3-epoxypropyl)isocyanurate, trimethylolmethane triglycidyl ether, trimethylolpropane triglycidyl ether, and triethylolethane triglycidyl ether.

Examples of the melamine compounds include hexamethylol melamine, hexamethoxymethyl melamine, hexamethylol melamine compounds having 1 to 6 methylol groups methoxymethylated and mixtures thereof, hexamethoxyethyl melamine, hexaacyloxymethyl melamine, hexamethylol melamine compounds having 1 to 6 methylol groups acyloxymethylated and mixtures thereof.

Examples of the guanamine compounds include tetramethylol guanamine, tetramethoxymethyl guanamine, tetramethylol guanamine compounds having 1 to 4 methylol groups methoxymethylated and mixtures thereof, tetramethoxyethyl guanamine, tetraacyloxyguanamine, tetramethylol guanamine compounds having 1 to 4 methylol groups acyloxymethylated and mixtures thereof.

Examples of the glycoluril compounds include tetramethylol glycoluril, tetramethoxy glycoluril, tetramethoxymethyl glycoluril, tetramethylol glycoluril compounds having 1 to 4 methylol groups methoxymethylated and mixtures thereof, tetramethylol glycoluril compounds having 1 to 4 methylol groups acyloxymethylated and mixtures thereof. Examples of the urea compounds include tetramethylol urea, tetramethoxymethyl urea, tetramethylol urea compounds having 1 to 4 methylol groups methoxymethylated and mixtures thereof, and tetramethoxyethyl urea.

Examples of the isocyanate compounds include tolylene diisocyanate, diphenylmethane diisocyanate, hexamethylene diisocyanate, and cyclohexane diisocyanate.

Examples of the azide compounds include 1,1′-biphenyl-4,4′-bisazide, 4,4′-methylidenebisazide, and 4,4′-oxybisazide.

Examples of the compounds containing an alkenyloxy group include ethylene glycol divinyl ether, triethylene glycol divinyl ether, 1,2-propanediol divinyl ether, 1,4-butanediol divinyl ether, tetramethylene glycol divinyl ether, neopentyl glycol divinyl ether, trimethylolpropane trivinyl ether, hexanediol divinyl ether, 1,4-cyclohexanediol divinyl ether, pentaerythritol trivinyl ether, pentaerythritol tetravinyl ether, sorbitol tetravinyl ether, sorbitol pentavinyl ether, and trimethylolpropane trivinyl ether.

When the resist composition of the present invention is of negative tone and contains the crosslinker, the content thereof is preferably 0.1 to 50 parts by weight and more preferably 1 to 40 parts by weight per 100 parts by weight of the base polymer. The crosslinker may be used alone or in combination of two or more kinds thereof.

Examples of the other quencher include conventional basic compounds. Examples of the conventional basic compounds include primary, secondary, and tertiary aliphatic amines, mixed amines, aromatic amines, heterocyclic amines, nitrogen-containing compounds with a carboxy group, nitrogen-containing compounds with a sulfonyl group, nitrogen-containing compounds with a hydroxy group, nitrogen-containing compounds with a hydroxyphenyl group, alcoholic nitrogen-containing compounds, anodes, insides, and carbamates. In particular, primary, secondary, and tertiary amine compounds, specifically amine compounds having a hydroxy group, an ether bond, an ester bond, a lactone ring, a cyano group, or a sulfonate bond as described in JP-A 2008-111103, paragraphs [0146] to [0164], and compounds having a carbamate group as described in JP 3790649 are preferred. Addition of such a basic compound can be effective, for example, for further suppressing the diffusion rate of acid in the resist film or correcting the pattern profile.

Examples of the other quencher include onium salts such as sulfonium, iodonium and ammonium salts of sulfonic acids which are not fluorinated at a position as described in JP-A 2008-158339, and similar onium salts of carboxylic acid. While an α fluorinated sulfonic acid, imide acid, and methide acid are necessary to deprotect the acid labile group of carboxylic acid ester, and an α-non-fluorinated sulfonic acid and a carboxylic acid are released by salt exchange with an α-non-fluorinated onium salt. An α-non-fluorinated sulfonic acid and a carboxylic acid function as a quencher because they do not induce deprotection reaction.

Examples of the other quencher further include quenchers of polymer type as described in JP-A 2008-239918. The polymeric quencher segregates at the surface of the resist film and thus enhances the rectangularity of resist pattern. When a protective film is applied as is often the case in the immersion lithography, the polymeric quencher is also effective for preventing a film thickness loss of resist pattern or rounding of pattern top.

When the resist composition of the present invention contains the other quencher, the content thereof is preferably 0 to 5 parts by weight and more preferably 0 to 4 parts by weight per 100 parts by weight of the base polymer. The other quencher may be used alone or in combination of two or more kinds thereof.

The water repellency improver improves the water repellency on the surface of the resist film, and can be used in the topcoatless immersion lithography. The water repellency improver is preferably polymers having a fluoroalkyl group, polymers of specific structure having a 1,1,1,3,3,3-hexafluoro-2-propanol residue, or the like, and is more preferably those described in JP-A 2007-297590, JP-A 2008-111103, and the like. The water repellency improver should be soluble in the alkaline developer and organic solvent developer. The water repellency improver of specific structure having a 1,1,1,3,3,3-hexafluoro-2-propanol residue is well soluble in the developer. As the water repellency improver, a polymer including repeat units having au amino group or amine salt is highly effective for preventing evaporation of acid during PEB and preventing any hole pattern opening failure after development. When the resist composition of the present invention contains the water repellency improver, the content thereof is preferably 0 to 20 parts by weight and more preferably 0.5 to 10 parts by weight per 100 parts by weight of the base polymer. The water repellency improver may be used alone or in combination of two or more kinds thereof.

Examples of the acetylene alcohol include those described in JP-A 2008-122932, paragraphs [0179] to [0182]. When the resist composition of the present invention contains the acetylene alcohol, the content thereof is preferably 0 to 5 parts by weight per 100 parts by weight of the base polymer. The acetylene alcohol may be used alone or in combination of two or more kinds thereof.

Pattern Forming Process

When the resist composition of the present invention is used in the fabrication of various integrated circuits, well-known lithography processes can be applied. Examples of the pattern forming process include a process including the steps of applying the above-described resist composition onto a substrate to form a resist film on the substrate, exposing the resist film to high-energy radiation, and developing the exposed resist film in a developer.

The resist composition of the present invention is first applied onto a substrate on which an integrated circuit is to be formed (such as Si. SiO₂, SiN, SiON, TiN, WSi, BPSG, SOG, or organic antireflective coating) or a substrate on which a mask circuit is to be formed (such as Cr, CrO, CrON, MoSiz, or SiO₂) by a suitable coating technique such as spin coating, roll coating, flow coating, dip coating, spray coating, or doctor coating so as to have a coating film thickness of 0.01 to 2 μm. The coating is prebaked on a hotplate preferably at 60 to 150′C for 10 seconds to 30 minutes, more preferably at 80 to 120° C. for 30 seconds to 20 minutes to form a resist film.

The resist film is then exposed using high-energy radiation. Examples of the high-energy radiation include ultraviolet rays, far ultraviolet rays, EB, EUV having a wavelength of 3 to 15 nm, X rays, soft X rays, excimer laser light, γ rays, and synchrotron radiation. When ultraviolet rays, far ultraviolet rays, EU V, X rays, soft X rays, excimer laser light, γ rays, synchrotron radiation, or the like is used as the high-energy radiation, the resist film is exposed thereto directly or through a mask for forming a target pattern in an exposure dose of preferably about 1 to 200 mJ/cm², more preferably about 10 to 100 mJ/cm². When EB is used as the high-energy radiation, the resist film is exposed thereto directly or through a mask for forming a target pattern in an exposure dose of preferably about 0.1 to 300 μC/cm², more preferably about 0.5 to 200 μC/cm². The resist composition of the present invention is particularly suitable for micropattering using KrF excimer laser light, ArF excimer laser light. EB. EUV. X rays, soft X rays, γ rays, or synchrotron radiation among the high-energy radiations, especially in micropatterning using EB or EUV.

After the exposure, PEB may or may not be performed on a hotplate in an oven preferably at 30 to 150′C for 10 seconds to 30 minutes, more preferably at 50 to 120° C. for 30 seconds to 20 minutes.

After the exposure or PEB, a target pattern is formed by developing the exposed resist film in 0.1 to 10 wt %, preferably 2 to 5 wt % of a developer of an alkali aqueous solution, such as tetramethylammonium hydroxide (TMAH), tetraethylammonium hydroxide, tetrapropylammonium hydroxide, or tetrabutylammonium hydroxide, for 3 seconds to 3 minutes, preferably 5 seconds to 2 minutes by conventional techniques such as dip, puddle, and spray techniques. In the case of a positive resist composition, the resist film in the exposed area is dissolved in the developer whereas the resist film in the unexposed area is not dissolved, and a target positive pattern is formed on the substrate. In the case of a negative resist composition, inversely with the case of a positive resist composition, the resist film in the exposed area is insolubilized in the developer whereas the resist film in the unexposed area is dissolved.

A negative pattern can also be obtained using the positive resist composition comprising a base polymer containing an acid labile group by organic solvent development. Examples of the developer used herein include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate. These organic solvents may be used alone or in admixture of two or more kinds thereof.

At the end of development, the resist film is rinsed. As a rinsing liquid, a solvent which is miscible with the developer and does not dissolve the resist film is preferred. As such a solvent, alcohols of 3 to 10 carbon atoms, ether compounds of 8 to 12 carbon atoms, alkanes, alkenes, and alkynes of 6 to 12 carbon atoms, and aromatic solvents are preferably used.

Examples of the alcohols of 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol.

Examples of ether compounds of 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether.

Examples of the alkanes of 6 to 12 carbon atoms include hexane, heptene, octane, nonane, decane, undecane, dodecane, methylcyclopentane, dimethylcyclopentane, cyclohexane, methylcyclohexane, dimethylcyclohexane, cycloheptane, cyclooctane, and cyclononane. Examples of the alkene of 6 to 12 carbon atoms include hexene, heptene, octene, cyclohexene, methylcyclohexene, dimethylcyclohexene, cycloheptene, and cyclooctene. Examples of the alkyne of 6 to 12 carbon atoms include hexyne, heptyne, and octyne.

Examples of the aromatic solvents include toluene, toluene, ethylbenzene, isopropylbenzene, tert-butylbenzene, and mesitylene.

Rinsing is effective for minimizing the risks of resist pattern collapse and defect formation. However, rinsing is not essential, and if rinsing is omitted, the amount of solvent used can be reduced.

A hole pattern or a trench pattern after development can also be shrunk by thermal flow, RELACS or DSA process. A hole pattern is shrunk by coating a shrink agent thereto, and baking such that the shrink agent may undergo crosslinking at the surface of the resist film as a result of the acid catalyst diffusing from the resist film during bake, and the shrink agent may attach to the sidewall of the hole pattern. The baking temperature is preferably 70 to 180° C. and more preferably 80 to 170° C., the baking tune is preferably 10 to 300 seconds, the extra shrink agent is stripped, and the hole pattern is shrunk.

### Examples

Hereinafter, the present invention is specifically described with reference to Synthesis Examples, Examples, and Comparative Examples, but the present invention is not limited to the following Examples.

The structures of quenchers Q-1 to Q-32 used for the resist composition are shown below.

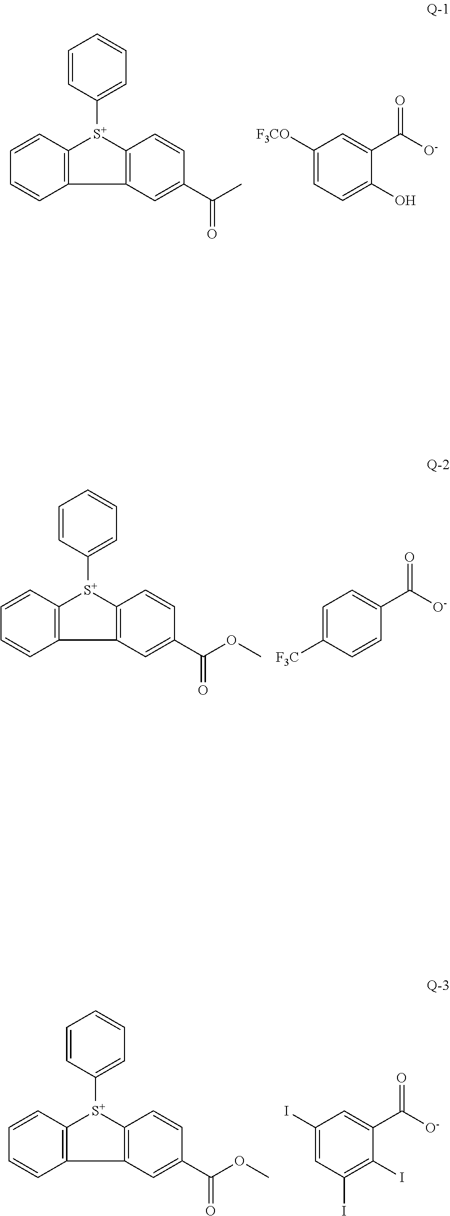 [SMILES: CC(=O)c1ccc2c(c1)c1ccccc1[s+]2-c1ccccc1 ; O=C([O-])c1cc(OC(F)(F)F)ccc1O ; COC(=O)c1ccc2c(c1)c1ccccc1[s+]2-c1ccccc1 ; O=C([O-])c1ccc(C(F)(F)F)cc1 ; COC(=O)c1ccc2c(c1)c1ccccc1[s+]2-c1ccccc1 ; O=C([O-])c1cc(I)cc(I)c1I]

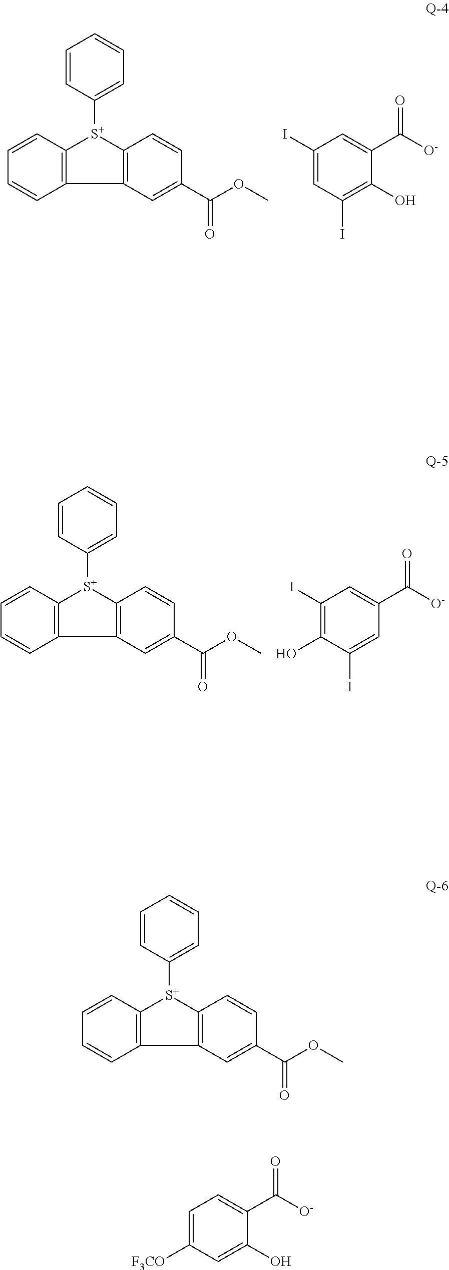 [SMILES: COC(=O)c1ccc2c(c1)c1ccccc1[s+]2-c1ccccc1 ; O=C([O-])c1cc(I)cc(I)c1O ; COC(=O)c1ccc2c(c1)c1ccccc1[s+]2-c1ccccc1 ; O=C([O-])c1cc(I)c(O)c(I)c1 ; COC(=O)c1ccc2c(c1)c1ccccc1[s+]2-c1ccccc1 ; O=C([O-])c1ccc(OC(F)(F)F)cc1O]

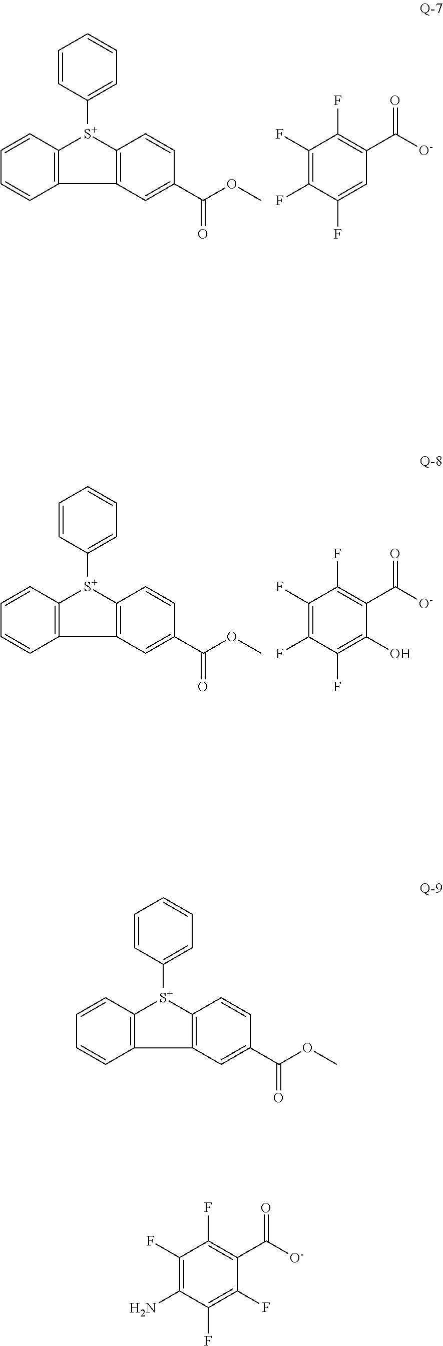 [SMILES: COC(=O)c1ccc2c(c1)c1ccccc1[s+]2-c1ccccc1 ; O=C([O-])c1cc(F)c(F)c(F)c1F ; COC(=O)c1ccc2c(c1)c1ccccc1[s+]2-c1ccccc1 ; O=C([O-])c1c(O)c(F)c(F)c(F)c1F ; COC(=O)c1ccc2c(c1)c1ccccc1[s+]2-c1ccccc1 ; Nc1c(F)c(F)c(C(=O)[O-])c(F)c1F]

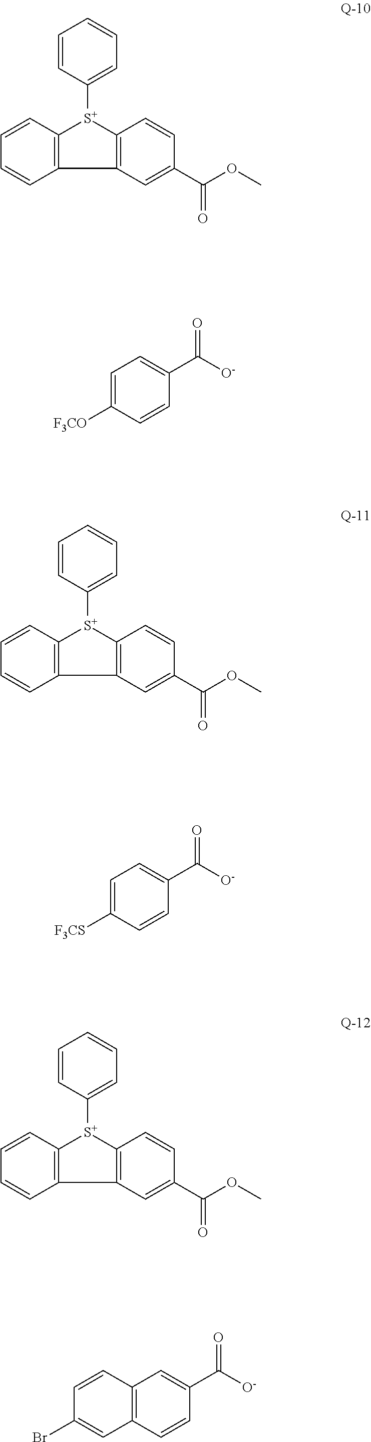

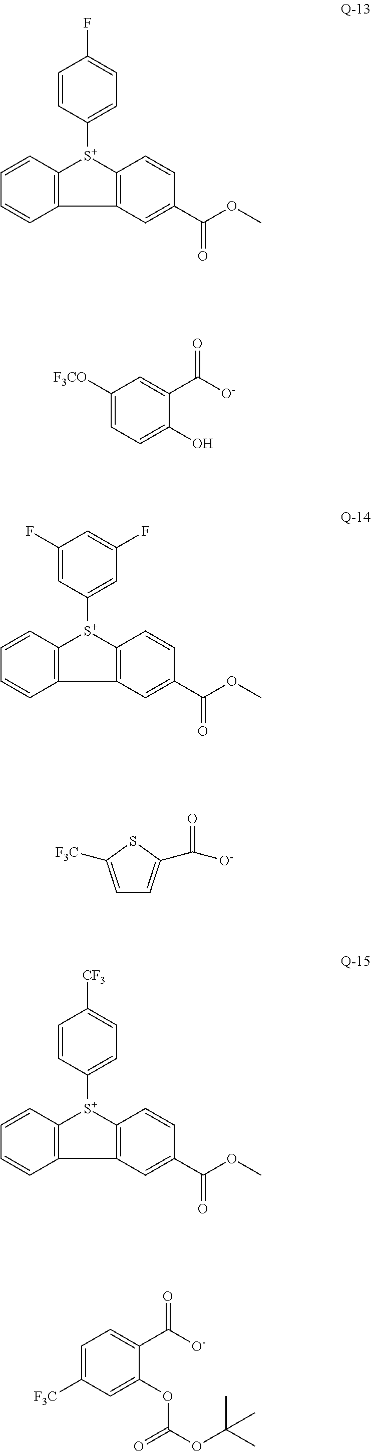 [SMILES: COC(=O)c1ccc2c(c1)c1ccccc1[s+]2-c1ccc(F)cc1 ; O=C([O-])c1cc(OC(F)(F)F)ccc1O ; COC(=O)c1ccc2c(c1)c1ccccc1[s+]2-c1cc(F)cc(F)c1 ; O=C([O-])c1ccc(C(F)(F)F)s1 ; COC(=O)c1ccc2c(c1)c1ccccc1[s+]2-c1ccc(C(F)(F)F)cc1 ; CC(C)(C)OC(=O)Oc1cc(C(F)(F)F)ccc1C(=O)[O-]]

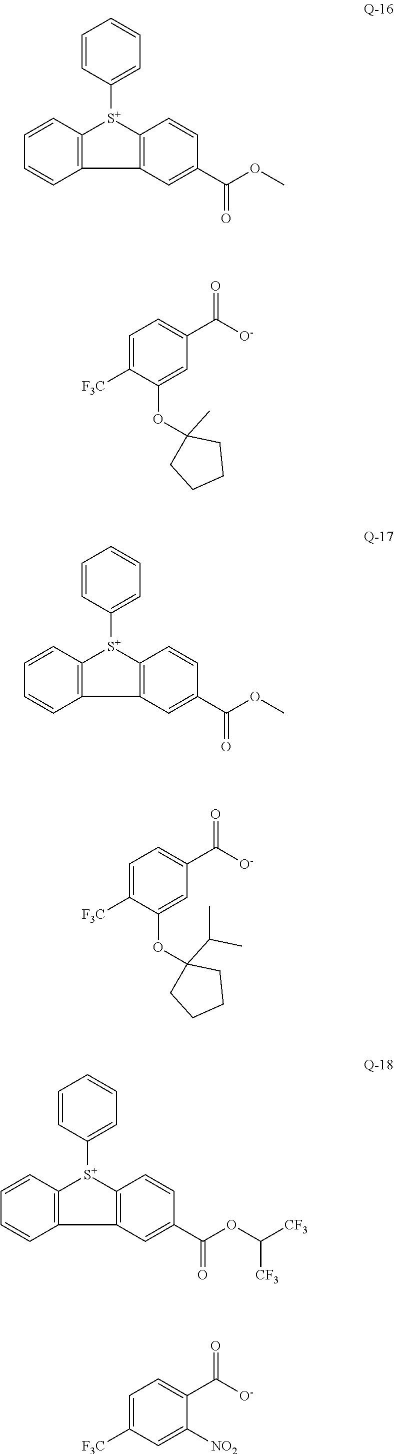 [SMILES: COC(=O)c1ccc2c(c1)c1ccccc1[s+]2-c1ccccc1 ; CC1(Oc2cc(C(=O)[O-])ccc2C(F)(F)F)CCCC1 ; COC(=O)c1ccc2c(c1)c1ccccc1[s+]2-c1ccccc1 ; CC(C)C1(Oc2cc(C(=O)[O-])ccc2C(F)(F)F)CCCC1 ; O=C(OC(C(F)(F)F)C(F)(F)F)c1ccc2c(c1)c1ccccc1[s+]2-c1ccccc1 ; O=C([O-])c1ccc(C(F)(F)F)cc1[N+](=O)[O-]]

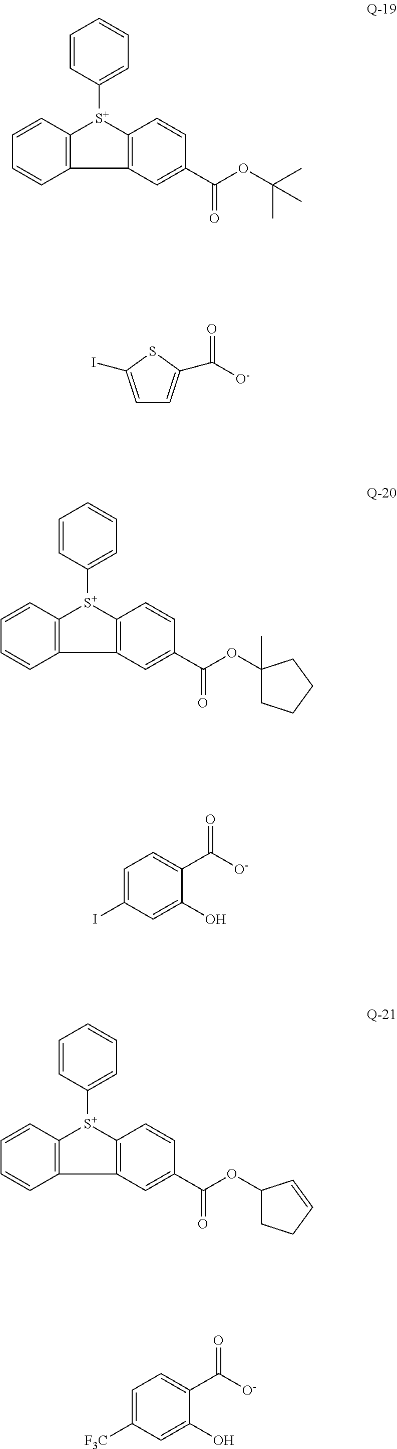 [SMILES: CC(C)(C)OC(=O)c1ccc2c(c1)c1ccccc1[s+]2-c1ccccc1 ; O=C([O-])c1ccc(I)s1 ; CC1(OC(=O)c2ccc3c(c2)c2ccccc2[s+]3-c2ccccc2)CCCC1 ; O=C([O-])c1ccc(I)cc1O ; O=C(OC1C=CCC1)c1ccc2c(c1)c1ccccc1[s+]2-c1ccccc1 ; O=C([O-])c1ccc(C(F)(F)F)cc1O]

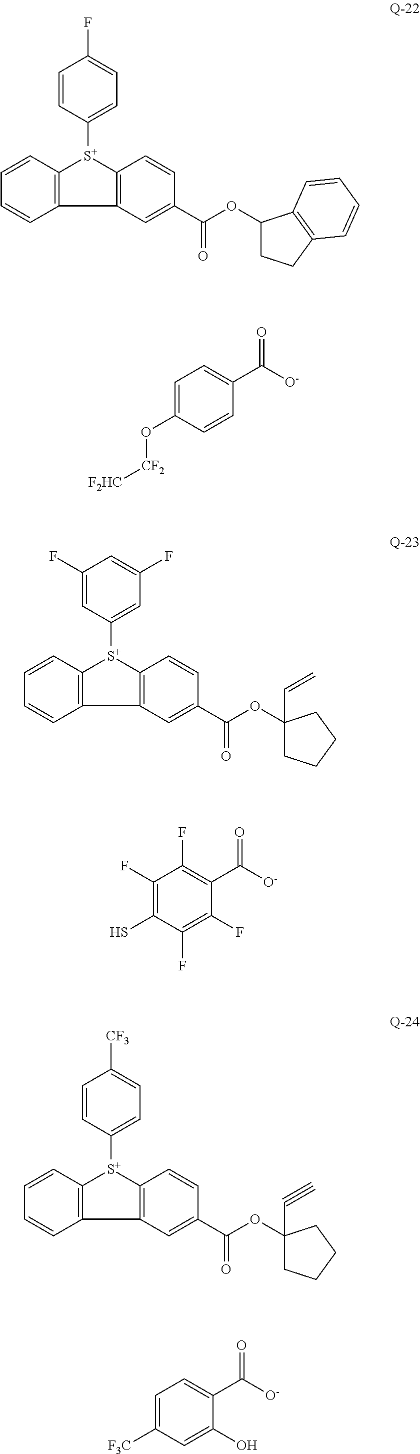 [SMILES: O=C(OC1CCc2ccccc21)c1ccc2c(c1)c1ccccc1[s+]2-c1ccc(F)cc1 ; O=C([O-])c1ccc(OC(F)(F)C(F)F)cc1 ; C=CC1(OC(=O)c2ccc3c(c2)c2ccccc2[s+]3-c2cc(F)cc(F)c2)CCCC1 ; O=C([O-])c1c(F)c(F)c(S)c(F)c1F ; C#CC1(OC(=O)c2ccc3c(c2)c2ccccc2[s+]3-c2ccc(C(F)(F)F)cc2)CCCC1 ; O=C([O-])c1ccc(C(F)(F)F)cc1O]

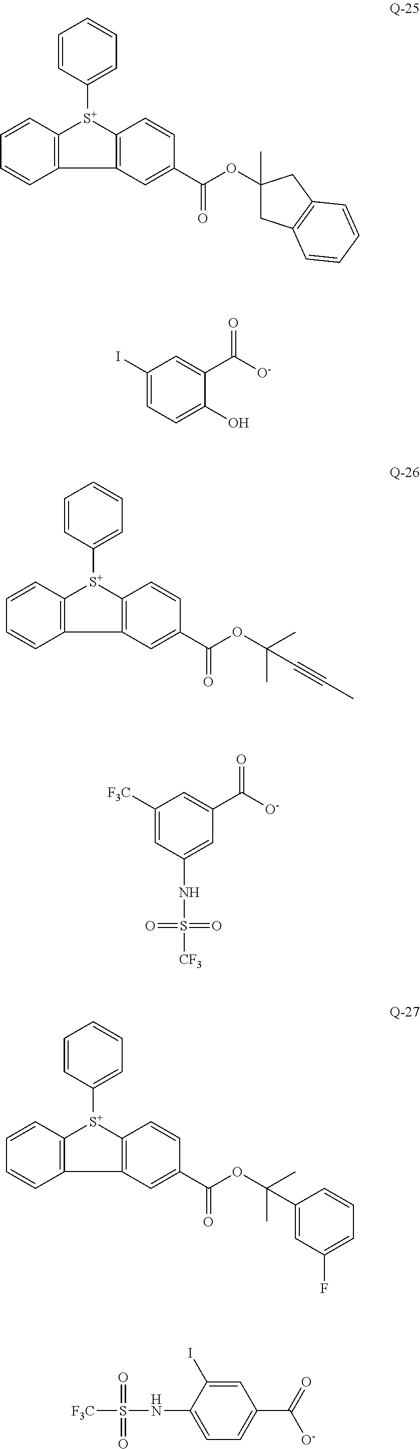 [SMILES: CC1(OC(=O)c2ccc3c(c2)c2ccccc2[s+]3-c2ccccc2)Cc2ccccc2C1 ; O=C([O-])c1cc(I)ccc1O ; CC#CC(C)(C)OC(=O)c1ccc2c(c1)c1ccccc1[s+]2-c1ccccc1 ; O=C([O-])c1cc(NS(=O)(=O)C(F)(F)F)cc(C(F)(F)F)c1 ; CC(C)(OC(=O)c1ccc2c(c1)c1ccccc1[s+]2-c1ccccc1)c1cccc(F)c1 ; O=C([O-])c1ccc(NS(=O)(=O)C(F)(F)F)c(I)c1]

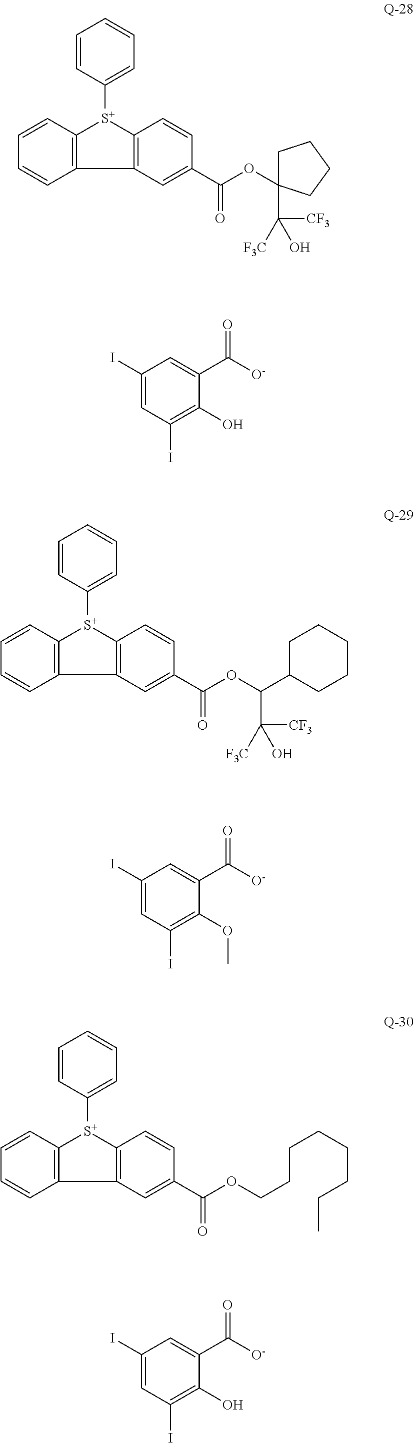 [SMILES: O=C(OC1(C(O)(C(F)(F)F)C(F)(F)F)CCCC1)c1ccc2c(c1)c1ccccc1[s+]2-c1ccccc1 ; O=C([O-])c1cc(I)cc(I)c1O ; O=C(OC(C1CCCCC1)C(O)(C(F)(F)F)C(F)(F)F)c1ccc2c(c1)c1ccccc1[s+]2-c1ccccc1 ; COc1c(I)cc(I)cc1C(=O)[O-] ; CCCCCCCCOC(=O)c1ccc2c(c1)c1ccccc1[s+]2-c1ccccc1 ; O=C([O-])c1cc(I)cc(I)c1O]

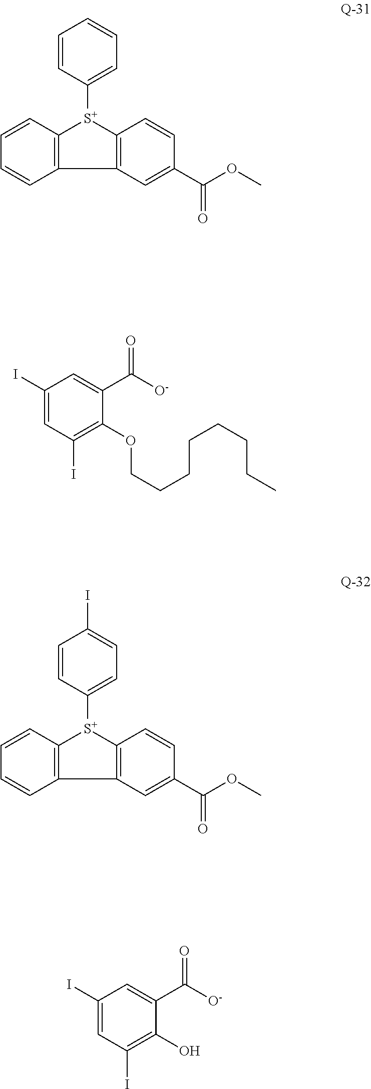 [SMILES: COC(=O)c1ccc2c(c1)c1ccccc1[s+]2-c1ccccc1 ; CCCCCCCCOc1c(I)cc(I)cc1C(=O)[O-] ; COC(=O)c1ccc2c(c1)c1ccccc1[s+]2-c1ccc(I)cc1 ; O=C([O-])c1cc(I)cc(I)c1O]

### Synthesis Examples

### Synthesis of Base Polymers (Polymers P-1 to P-5

Base polymers (Polymers P-1 to P-5) of the composition shown below were synthesized by combining respective monomers, effecting copolymerization reaction in THF as a solvent, pouring the reaction solution into methanol, washing the solid precipitate with hexane, isolation, and drying. The base polymers were analyzed for composition by ¹H-NMR spectroscopy and for Mw and Mw Mn by GPC versus polystyrene standards using THF solvent.

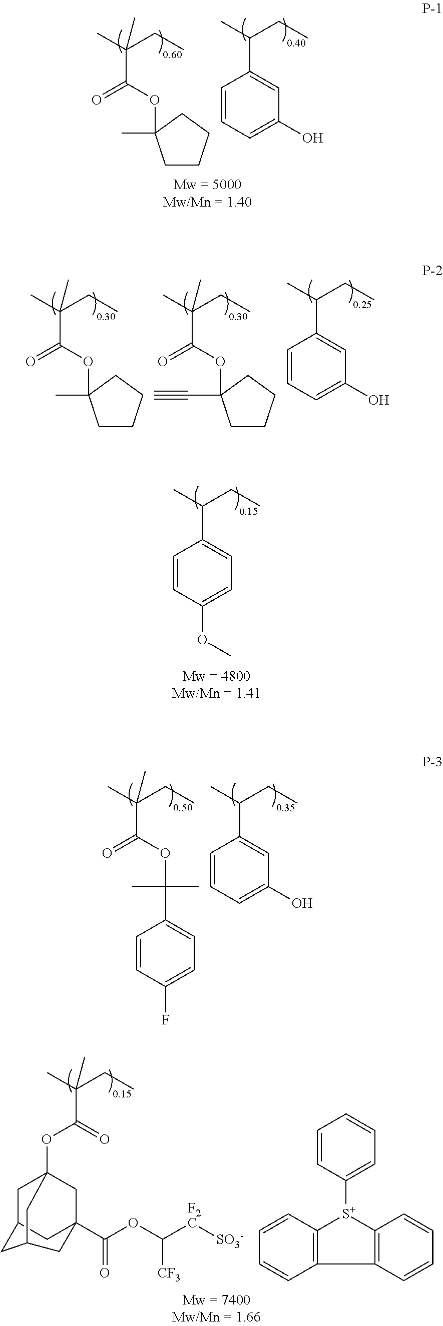

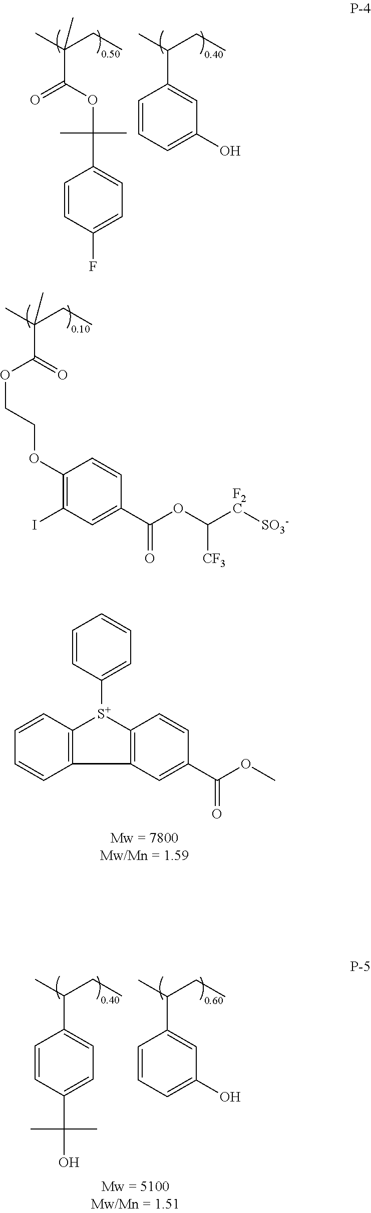

### Examples 1 to 37 and Comparative Examples 1 to 3

Preparation and Evaluation of Resist Compositions

(1) Preparation of Resist Compositions

Resist compositions were prepared by dissolving components in a solvent in accordance with the composition shown in Tables 1 to 3 and filtering the solution through a filter having a pore size of 0.2 μm. The resist compositions of Examples 1 to 36 and Comparative Examples 1 and 2 are of positive tone whereas the resist compositions of Example 37 and Comparative Example 3 are of negative tone.

The components in Tables 1 to 3 are identified below.

Organic solvents:
PGMEA (propylene glycol monomethyl ether acetate)
DAA (diacetone alcohol)
EL (ethyl lactate)

Acid generators: PAG-1 to PAG-4

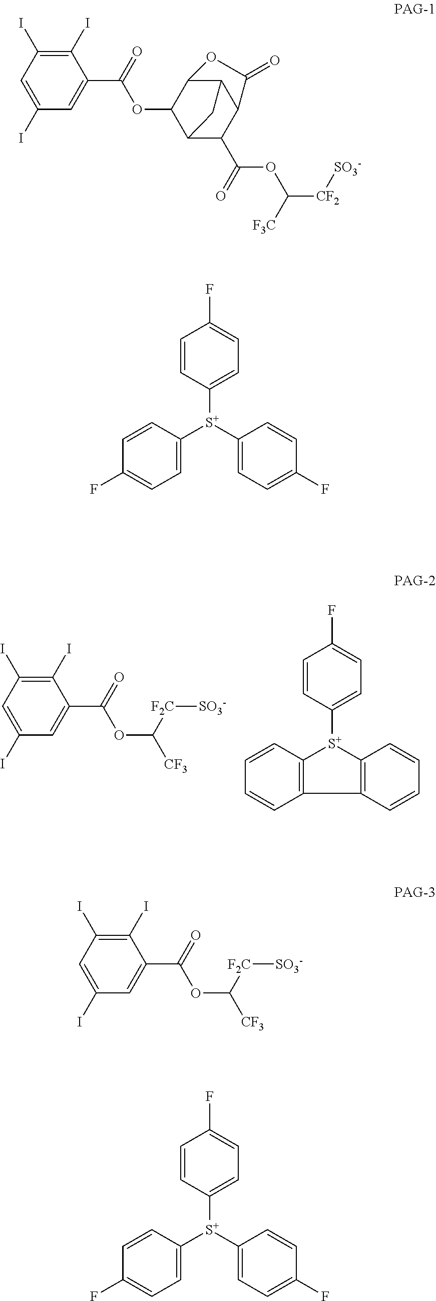

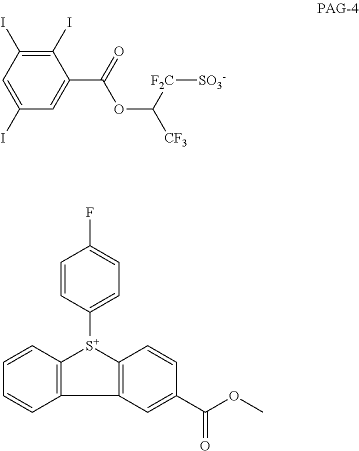

Blend quenchers: bQ-1 and bQ-2

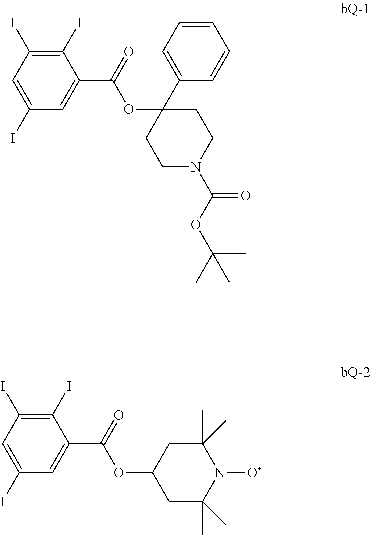

Comparative quenchers: cQ-1 and cQ-2

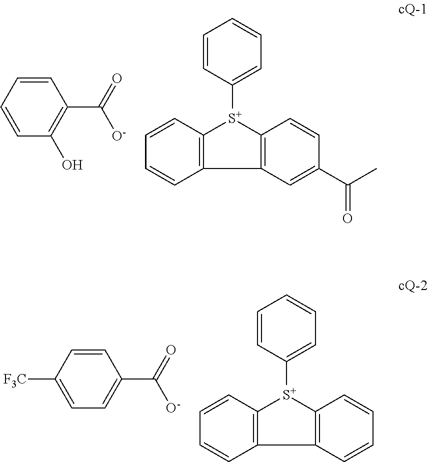 [SMILES: O=C([O-])c1ccccc1O ; CC(=O)c1ccc2c(c1)c1ccccc1[s+]2-c1ccccc1 ; O=C([O-])c1ccc(C(F)(F)F)cc1 ; c1ccc(-[s+]2c3ccccc3c3ccccc32)cc1]

(2) EUV Lithography Test

Each of the resist compositions shown in Tables 1 to 3 was spin coated on a silicon substrate having a 20-nm coating of silicon-containing spin-on hard mask SHB-A940 manufactured by Shin-Etsu Chemical Co., Ltd. (content of silicon: 43 wt %) and prebaked on a hotplate at 100° C. for 60 seconds to form a resist film of 60 nm thick. Using an EUV scanner NXE3400 (NA 0.33, σ0.9/0.6, quadrupole illumination, mask bearing a hole pattern at a pitch 44 nm (on-wafer size) and +20% bias) manufactured by ASML, the resist film was exposed to EUV, the resist film was baked (PEB) on a hotplate at the temperature shown in Tables 1 to 3 for 60 seconds and developed in a 2.38 wt % TMAH aqueous solution for 30 seconds to form a hole pattern having a size of 22 mu in Examples 1 to 36 and Comparative Examples 1 and 2 or a hole pattern having a size of 22 nm in Example 37 and Comparative Example 3.

The exposure dose that provides a hole or dot pattern having a size of 22 nm was measured using length measurement SEM (CG6300) manufactured by Hitachi High-Tech Corporation and taken as sensitivity, the size of 50 holes or dots at that dose was measured, from which a 3-fold value (3a) of the standard deviation (a) was computed and taken as CDU. The results are also shown in Tables 1 to 3.

TABLE 1

| | | Polymer | Acid generator | Quencher | Organic solvent | PEB temp. | Sensitivity | CDU |
|---|---|---|---|---|---|---|---|---|
| | | (pbw) | (pbw) | (pbw) | (pbw) | (° C.) | (mJ/cm²) | (nm) |
| Example | 1 | P-1 | PAG-1 | Q-1 | PGMEA (3000) | 90 | 26 | 2.6 |
| | | (100) | (30.2) | (5.24) | DAA (500) | | | |
| | 2 | P-1 | PAG-2 | Q-2 | PGMEA (3000) | 90 | 25 | 2.7 |
| | | (100) | (24.8) | (5.08) | DAA (500) | | | |
| | 3 | P-1 | PAG-2 | Q-3 | PGMEA (3000) | 90 | 24 | 2.4 |
| | | (100) | (24.8) | (8.18) | DAA (500) | | | |
| | 4 | P-1 | PAG-2 | Q-4 (3.84) | PGMEA (3000) | 90 | 27 | 2.4 |
| | | (100) | (24.8) | bQ-1 (3.80) | DAA (500) | | | |
| | 5 | P-1 | PAG-2 | Q-5 | PGMEA (3000) | 90 | 24 | 2.6 |
| | | (100) | (24.8) | (7.07) | DAA (500) | | | |
| | 6 | P-1 | PAG-2 | Q-6 | PGMEA (3000) | 90 | 26 | 2.7 |
| | | (100) | (24.8) | (5.40) | DAA (500) | | | |
| | 7 | P-1 | PAG-2 | Q-7 | PGMEA (3000) | 90 | 23 | 2.8 |
| | | (100) | (24.8) | (5.12) | DAA (500) | | | |
| | 8 | P-1 | PAG-2 | Q-8 | PGMEA (3000) | 90 | 25 | 2.6 |
| | | (100) | (24.8) | (5.28) | DAA (500) | | | |
| | 9 | P-1 | PAG-3 | Q-9 (2.64) | PGMEA (3000) | 90 | 27 | 2.5 |
| | | (100) | (25.7) | bQ-2 (3.27) | DAA (500) | | | |
| | 10 | P-1 | PAG-3 | Q-10 | PGMEA (3000) | 90 | 24 | 2.6 |
| | | (100) | (25.7) | (5.24) | DAA (500) | | | |
| | 11 | P-1 | PAG-3 | Q-11 | PGMEA (3000) | 90 | 24 | 2.5 |
| | | (100) | (25.7) | (5.40) | DAA (500) | | | |
| | 12 | P-1 | PAG-3 | Q-12 | EL (3000) | 90 | 28 | 2.4 |
| | | (100) | (25.7) | (5.69) | DAA (500) | | | |
| | 13 | P-1 | PAG-3 | Q-13 | EL (3500) | 90 | 26 | 2.3 |
| | | (100) | (25.7) | (5.58) | | | | |
| | 14 | P-1 | PAG-3 | Q-14 | PGMEA (3000) | 90 | 23 | 2.4 |
| | | (100) | (25.7) | (5.50) | DAA (500) | | | |
| | 15 | P-1 | PAG-3 | Q-15 | PGMEA (3000) | 90 | 26 | 2.5 |
| | | (100) | (25.7) | (6.92) | DAA (500) | | | |
| | 16 | P-1 | PAG-3 | Q-16 | PGMEA (3000) | 90 | 26 | 2.6 |
| | | (100) | (25.7) | (6.06) | DAA (500) | | | |
| | 17 | P-1 | PAG-3 | Q-17 | PGMEA (3000) | 90 | 27 | 2.4 |
| | | (100) | (25.7) | (6.34) | DAA (500) | | | |
| | 18 | P-1 | PAG-3 | Q-18 | PGMEA (3000) | 90 | 28 | 2.3 |
| | | (100) | (25.7) | (6.89) | DAA (500) | | | |
| | 19 | P-1 | PAG-3 | Q-19 | PGMEA (3000) | 90 | 24 | 2.3 |
| | | (100) | (25.7) | (6.14) | DAA (500) | | | |
| | 20 | P-1 | PAG-3 | Q-20 | PGMEA (3000) | 90 | 24 | 2.4 |
| | | (100) | (25.7) | (6.50) | DAA (500) | | | |

TABLE 2

| | | Polymer | Acid generator | Quencher | Organic solvent | PEB temp. | Sensitivity | CDU |
|---|---|---|---|---|---|---|---|---|
| | | (pbw) | (pbw) | (pbw) | (pbw) | (° C.) | (mJ/cm²) | (nm) |
| Example | 21 | P-1 | PAG-3 | Q-21 | PGMEA (3000) | 90 | 26 | 2.4 |
| | | (100) | (25.7) | (5.76) | DAA (500) | | | |
| | 22 | P-1 | PAG-3 | Q-22 | PGMEA (3000) | 90 | 27 | 2.4 |
| | | (100) | (25.7) | (6.76) | DAA (500) | | | |
| | 23 | P-1 | PAG-3 | Q-23 | PGMEA (3000) | 90 | 26 | 2.4 |
| | | (100) | (25.7) | (6.60) | DAA (500) | | | |
| | 24 | P-1 | PAG-3 | Q-24 | PGMEA (3000) | 90 | 25 | 2.3 |
| | | (100) | (25.7) | (6.70) | DAA (500) | | | |
| | 25 | P-1 | PAG-3 | Q-25 | PGMEA (3000) | 90 | 26 | 2.3 |
| | | (100) | (25.7) | (6.98) | DAA (500) | | | |
| | 26 | P-1 | PAG-3 | Q-26 | PGMEA (3000) | 90 | 25 | 2.3 |
| | | (100) | (25.7) | (7.34) | DAA (500) | | | |
| | 27 | P-1 | PAG-4 | Q-27 | PGMEA (3000) | 90 | 24 | 2.4 |
| | | (100) | (31.4) | (8.35) | DAA (500) | | | |
| | 28 | P-1 | PAG-3 | Q-28 | PGMEA (3000) | 90 | 27 | 2.3 |
| | | (100) | (25.7) | (9.27) | DAA (500) | | | |
| | 29 | P-1 | PAG-3 | Q-29 | PGMEA (3000) | 90 | 27 | 2.3 |
| | | (100) | (25.7) | (9.70) | DAA (500) | | | |
| | 30 | P-1 | PAG-3 | Q-30 | PGMEA (3000) | 90 | 28 | 2.3 |
| | | (100) | (25.7) | (8.06) | DAA (500) | | | |
| | 31 | P-1 | PAG-4 | Q-31 | PGMEA (3000) | 90 | 26 | 2.4 |
| | | (100) | (31.4) | (8.20) | DAA (500) | | | |
| | 32 | P-1 | PAG-4 | Q-32 | PGMEA (3000) | 90 | 28 | 2.5 |
| | | (100) | (31.4) | (8.34) | DAA (500) | | | |
| | 33 | P-2 | PAG-2 | Q-8 | PGMEA (3000) | 90 | 28 | 2.2 |
| | | (100) | (24.8) | (5.28) | DAA (500) | | | |
| | 34 | P-3 | — | Q-8 | PGMEA (3000) | 90 | 27 | 2.3 |
| | | (100) | | (5.28) | DAA (500) | | | |
| | 35 | P-4 | — | Q-8 | PGMEA (3000) | 90 | 23 | 2.3 |
| | | (100) | | (5.28) | DAA (500) | | | |
| | 36 | P-4 | PAG-4 | Q-8 | PGMEA (3000) | 90 | 21 | 2.3 |
| | | (100) | (10.5) | (5.28) | DAA (500) | | | |
| | 37 | P-5 | PAG-1 | Q-8 | PGMEA (3000) | 110 | 32 | 3.2 |
| | | (100) | (24.1) | (5.28) | DAA (500) | | | |

TABLE 3

| | | Polymer | Acid generator | Quencher | Organic solvent | PEB temp. | Sensitivity | CDU |
|---|---|---|---|---|---|---|---|---|
| | | (pbw) | (pbw) | (pbw) | (pbw) | (° C.) | (mJ/cm²) | (nm) |
| Comparative | 1 | P-1 | PAG-2 | cQ-1 | PGMEA (3000) | 90 | 31 | 3.3 |
| Example | | (100) | (24.8) | (4.40) | DAA (500) | | | |
| | 2 | P-1 | PAG-2 | cQ-2 | PGMEA (3000) | 90 | 33 | 3.2 |
| | | (100) | (24.8) | (4.50) | DAA (500) | | | |
| | 3 | P-5 | PAG-1 | cQ-1 | PGMEA (3000) | 110 | 38 | 4.0 |
| | | (100) | (24.1) | (4.40) | DAA (500) | | | |

From the results shown in Tables 1 to 3, it was found that the resist composition of the present invention comprising a quencher containing a sulfonium salt composed of a C₅-C₂₀ aromatic carboxylic acid anion substituted with a halogen atom or a halogen atom-containing group and a sulfonium cation having formula (1) has a high sensitivity and improved CDU.

Japanese Patent Application No. 2022-162391 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a quencher containing a sulfonium salt composed of a C₅-C₂₀ aromatic carboxylic acid anion substituted with a halogen atom or a halogen atom-containing group and a sulfonium cation having the following formula (1): 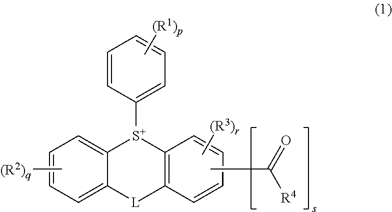
wherein p, q, and r are each independently an integer of 0 to 3, s is 1 or 2, provided that 1≤r+s≤3,
R¹ and R² are each independently a halogen atom, a trifluoromethyl group, a trifluoromethoxy group, a trifluoromethylthio group, a nitro group, a cyano group, —C(═O)—R⁴, —O—C(═O)—R⁵, or —O—R⁵,
R³ is a halogen atom, a trifluoromethyl group, a trifluoromethoxy group, a trifluoromethylthio group, a nitro group, a cyano group, —O—C(═O)—R⁵, or —O—R⁵,
R⁴ is a C₁-C₁₀ hydrocarbyl group, a C₁-C₁₀ hydrocarbyloxy group, or —O—R^{4A}, the hydrocarbyl group and hydrocarbyloxy group may be substituted with a fluorine atom or a hydroxy group, R^{4A} is an acid labile group,
R⁵ is a C₁-C₁₀ hydrocarbyl group,
L is a single bond, an ether bond, a carbonyl group, —N(R)—, a sulfide bond, or a sulfonyl group, and R is a hydrogen atom or a C₁-C₆ saturated hydrocarbyl group.

2. The resist composition according to claim 1, wherein the C₅-C₂₀ aromatic carboxylic acid anion substituted with a halogen atom or a halogen atom-containing group has the following formula (2): 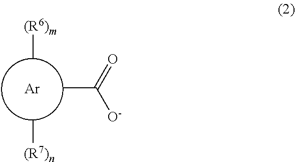
wherein m is an integer of 1 to 5, n is an integer of 0 to 4,
circle Ar is a group derived from benzene, naphthalene, or thiophene,
R⁶ is a halogen atom, —R^{6A}, —O—R^{6A}, —S—R^{6A}, —C(═O)—O—R, —O—C(═O)—R^{6A}, —O—C(═O)—O—R^{6A}, —N(R^{6B})—S(═O)₂—R^{6A}, —O—S(═O)₂—R⁶, or a halogenated phenyl group, R^{6A} is a C₁-C₄ halogenated alkyl group, R^{6B} is a C₁-C₆ saturated hydrocarbyl group,
R⁷ is a hydroxy group, a cyano group, a nitro group, an amino group, a mercapto group, —R^{7A}, —O—R^{7A}, —O—C(═O)—R^{7A}, —O—C(═O)—O—R^{7A}, or —N(R^{7B})—C(═O)—R^{7C}, R^{7A} is a C₁-C₁₆ hydrocarbyl group, R^{7B} is a hydrogen atom or a C₁-C₆ saturated hydrocarbyl group, and R^{7C} is a C₁-C₁₆ aliphatic hydrocarbyl group, a C₆-C₁₄ aryl group, or a C₇-C₁₅ aralkyl group, which may contain a halogen atom, a hydroxy group, a C₁-C₆ saturated hydrocarbyloxy group, a C₂-C₆ saturated hydrocarbylcarbonyl group, or a C₂-C₆ saturated hydrocarbylcarbonyloxy group.

3. The resist composition according to claim 1, further comprising a base polymer.

4. The resist composition according to claim 3, wherein the base polymer comprises repeat units having the following formula (a1) or repeat units having the following formula (a2): 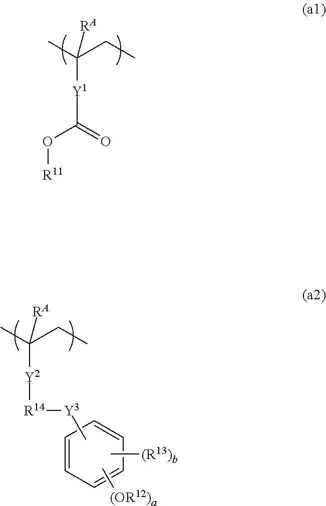
wherein R^{A} is each independently a hydrogen atom or a methyl group,
Y¹ is a single bond, a phenylene group, a naphthalene group, or a C₁-C₁₂ linking group containing at least one selected from an ester bond and a lactone ring,
Y² is a single bond or an ester bond,
Y³ is a single bond, an ether bond, or an ester bond,
R¹¹ and R¹² are each independently an acid labile group,
R¹³ is a fluorine atom, a trifluoromethyl group, a cyano group, or a C₁-C₆ saturated hydrocarbyl group,
R¹⁴ is a single bond or a C₁-C₆ alkanediyl group in which some of carbon atoms may be replaced by an ether bond or an ester bond,
a is 1 or 2, and b is an integer of 0 to 4, provided that 1≤a+b≤5.

5. The resist composition according to claim 4, which is a chemically amplified positive resist composition.

6. The resist composition according to claim 3, wherein the base polymer is free of an acid labile group.

7. The resist composition according to claim 6, which is a chemically amplified negative resist composition.

8. The resist composition according to claim 3, wherein the base polymer comprises at least one selected from repeat units having the following formulae (f1) to (f3): 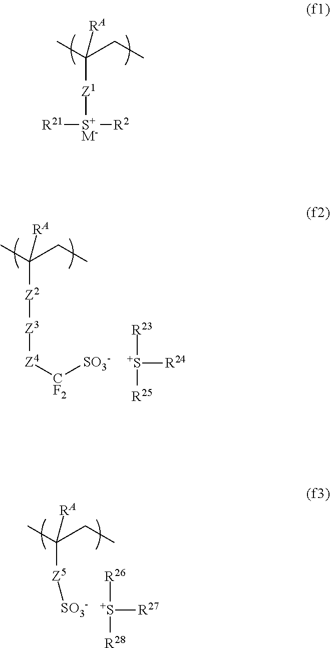
wherein R^{A} is each independently a hydrogen atom or a methyl group,
Z¹ is a single bond, a C₁-C₆ aliphatic hydrocarbylene group, a phenylene group, a naphthylene group, or a C₇-C₁₈ group obtained by combining the foregoing, or —O—Z¹¹—, —C(═O)—O—Z¹¹—, or —C(═O)—NH—Z¹¹—, Z¹¹ is a C₁-C₆ aliphatic hydrocarbylene group, a phenylene group, a naphthylene group, or a C₇-C₁₈ group obtained by combining the foregoing, which may contain a carbonyl group, an ester bond, an ether bond, or a hydroxy group,
Z² is a single bond or an ester bond,
Z³ is a single bond, —Z³¹—C(═O)—O—, —Z³¹—O—, or —Z³¹—O—C(═O)—, Z³¹ is a C₁-C₁₂ aliphatic hydrocarbylene group, a phenylene group, or a C₇-C₁₈ group obtained by combining the foregoing, which may contain a carbonyl group, an ester bond, an ether bond, a urethane bond, a nitro group, a cyano group, a fluorine atom, an iodine atom, or a bromine atom,
Z⁴ is a methylene group, a 2,2,2-trifluoro-1,1-ethanediyl group, or a carbonyl group,
Z⁵ is a single bond, a methylene group, an ethylene group, a phenylene group, a fluorinated phenylene group, a trifluoromethyl-substituted phenylene group, —O—Z⁵¹—, —C(═O)—O—Z⁵¹—, or —C(═O)—NH—Z⁵¹—, Z⁵¹ is a C₁-C₆ aliphatic hydrocarbylene group, a phenylene group, a fluorinated phenylene group, or a trifluoromethyl-substituted phenylene group, which may contain a carbonyl group, an ester bond, an ether bond, a halogen atom, or a hydroxy group,
R²¹ to R²⁸ are each independently a halogen atom, or a C₁-C₂₀ hydrocarbyl group which may contain a heteroatom, a pair of R²³ and R²⁴ or R²⁶ and R²⁷ may bond together to form a ring with a sulfur atom to which they are attached, and
M⁻is a non-nucleophilic counter ion.

9. The resist composition according to claim 1, further comprising an acid generator capable of generating a strong acid.

10. The resist composition according to claim 9, wherein the acid generator generates a sulfonic acid, imide acid, or methide acid.

11. The resist composition according to claim 1, further comprising an organic solvent.

12. The resist composition according to claim 1, further comprising a surfactant.

13. A pattern forming process comprising the steps of:
applying the resist composition according to claim 1 onto a substrate to form a resist film on the substrate;
exposing the resist film to high-energy radiation; and
developing the exposed resist film in a developer.

14. The pattern forming process according to claim 13, wherein the high-energy radiation is KrF excimer laser light, ArF excimer laser light, an electron beam, or extreme ultraviolet having a wavelength of 3 to 15 nm.
